(19) United States
(12) Patent Application Publication
(10) Pub. No.: US 2023/0284529 A1
(43) Pub. Date: Sep. 7, 2023

(54) LIGHT EMITTING DEVICE AND FUSED POLYCYCLIC COMPOUND FOR THE LIGHT EMITTING DEVICE

(71) Applicant: Samsung Display Co., Ltd., Yongin-si (KR)

(72) Inventors: JUNHA PARK, Gwacheon-si (KR); TAEIL KIM, Hwaseong-si (KR); MUN-KI SIM, Seoul (KR); SERAN KIM, Suwon-si (KR); SUN YOUNG PAK, Suwon-si (KR); JANG YEOL BAEK, Yongin-si (KR)

(21) Appl. No.: 18/117,302

(22) Filed: Mar. 3, 2023

(30) Foreign Application Priority Data
Mar. 4, 2022 (KR) 10-2022-0028397

(51) Int. Cl. H10K 85/60; H10K 50/11; C07F 5/02; H10K 85/30

(52) U.S. Cl. CPC H10K 85/658; H10K 50/11; H10K 85/6572; C07F 5/027; H10K 85/346; H10K 2102/302

(57) ABSTRACT

A light emitting device that includes a first electrode, a second electrode oppositely disposed to the first electrode, and an emission layer disposed between the first electrode and the second electrode is provided. The emission layer includes a first compound represented by Formula 1.

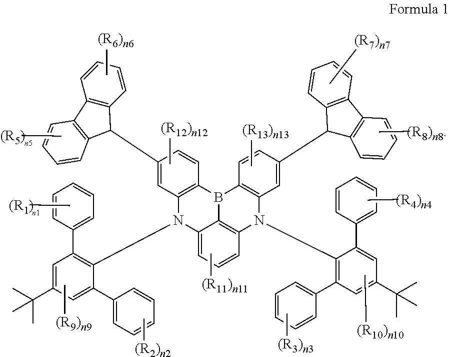

### CROSS-REFERENCE TO RELATED APPLICATION

This application claims priority to and the benefit of Korean Patent Application No. 10-2022-0028397, filed on Mar. 4, 2022, the entire content of which is hereby incorporated by reference.

### BACKGROUND

### 1. Field

Aspects of one or more embodiments of the present disclosure relate to a light emitting device and a fused polycyclic compound utilized in the light emitting device.

### 2. Description of Related Art

Recently, research into the development of an organic electroluminescence display as an image display is being actively conducted. The organic electroluminescence display is different from a liquid crystal display and is a self-luminescent display in which holes and electrons injected from a first electrode and a second electrode recombine in an emission layer so that a light emitting material including an organic compound in the emission layer emits light to achieve display (e.g., to display an image).

In the application of an organic electroluminescence device to a display, the decrease of a driving voltage, and the increase of the emission efficiency and life of the organic electroluminescence device are desired or required (beneficial), and development on materials for an organic electroluminescence device stably or suitably achieving the requirements is being continuously required (sought).

For example, recently, in order to accomplish an organic electroluminescence device with high efficiency, techniques on phosphorescence emission which uses energy in a triplet state or delayed fluorescence emission which uses the generating phenomenon of singlet excitons by the collision of triplet excitons (triplet-triplet annihilation, TTA) are being developed, and development (and research) on a material for thermally activated delayed fluorescence (TADF) utilizing delayed fluorescence phenomenon is being conducted.

### SUMMARY

An aspect of one or more embodiments of the present disclosure is directed toward a light emitting device having improved emission efficiency and device life.

An aspect of one or more embodiments of the present disclosure is directed toward a fused polycyclic compound which is capable of improving the emission efficiency and device life of a light emitting device.

Additional aspects will be set forth in part in the description which follows and, in part, will be apparent from the description, or may be learned by practice of the presented embodiments of the disclosure.

An embodiment of the present disclosure provides a light emitting device including a first electrode, a second electrode oppositely disposed to the first electrode, and an emission layer between the first electrode and the second electrode, wherein the emission layer includes a first compound represented by Formula 1.

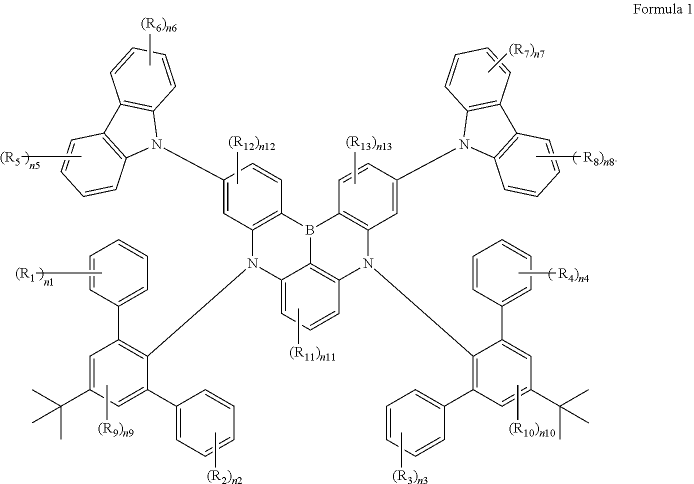

In Formula 1, R₁ to R₁₃ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, n1 to n4 may each independently be an integer from 0 to 5, n5 to n8 may each independently be an integer from 0 to 4, n9 and n10 may each independently be an integer from 0 to 2, and n11 to n13 may each independently be an integer from 0 to 3.

In an embodiment, R₁ to R₄ may be deuterium atoms, and a sum of n1 to n4 may be 1 to 20.

In an embodiment, the first compound represented by Formula 1 may be represented by any one selected from among Formula 2-1 to Formula 2-4.

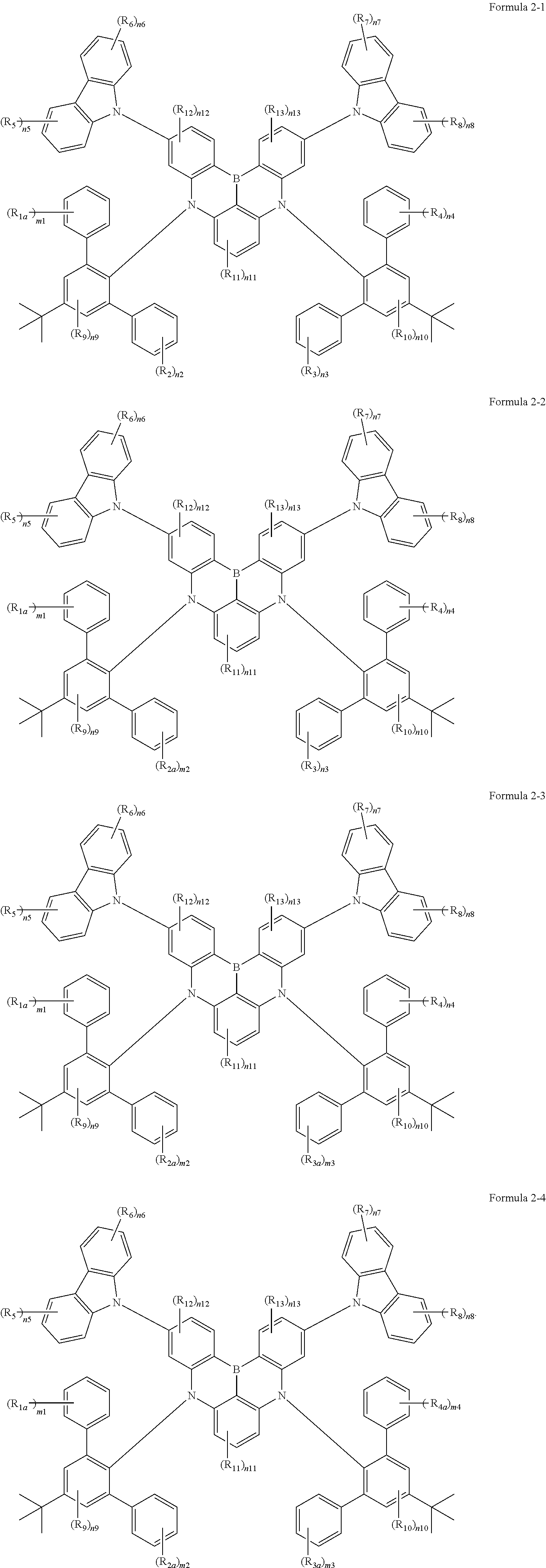

In Formula 2-1 to Formula 2-4, R₁ₐ to R₄ₐ may be deuterium atoms, and m1 to m4 may each independently be an integer from 1 to 5.

In Formula 2-1 to Formula 2-4, the same explanation for R₂ to R₁₃, and n2 to n13 defined in Formula 1 may be applied.

In an embodiment, the first compound represented by Formula 1 may be represented by any one selected from among Formula 3-1 to Formula 3-3.

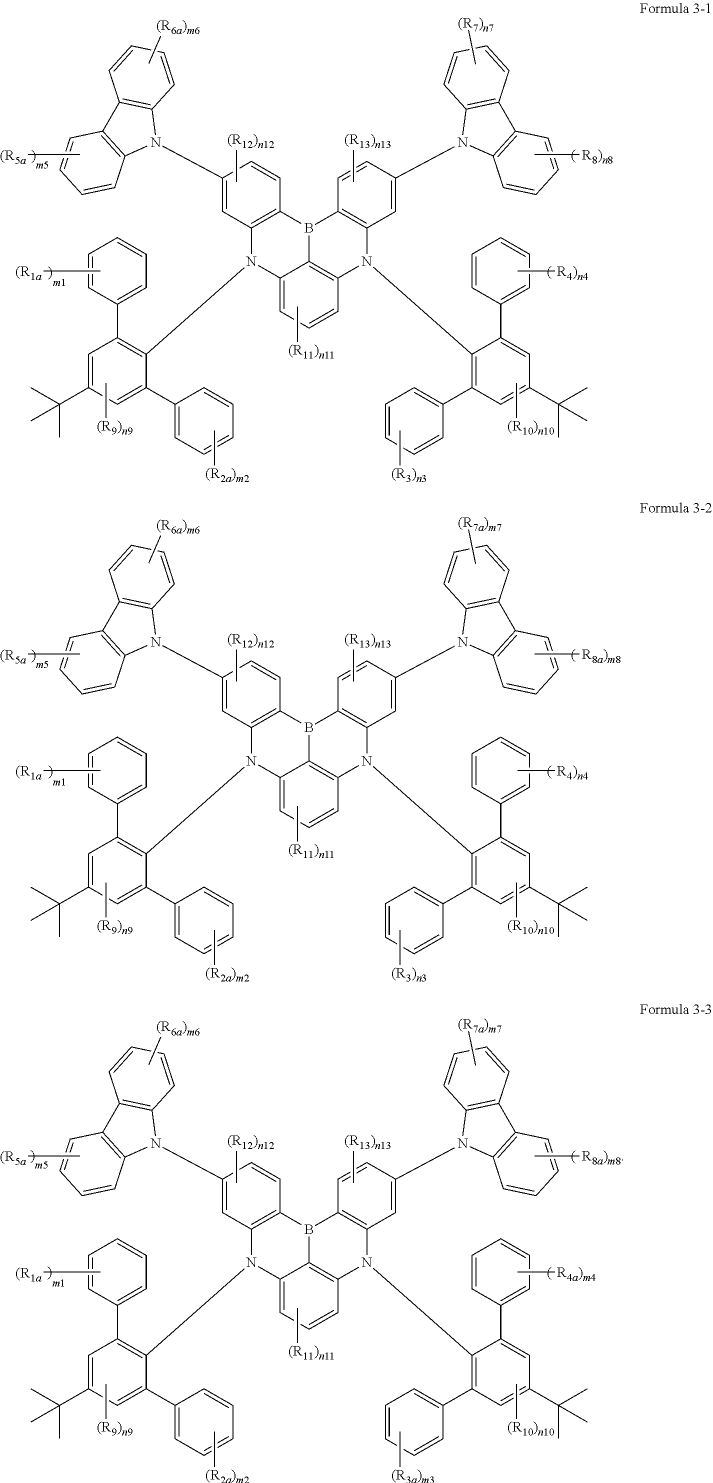

In Formula 3-1 to Formula 3-3, R₅ₐ to R₈ₐ may be deuterium atoms, and m5 to m8 may each independently be an integer from 1 to 4.

In Formula 3-1 to Formula 3-3, the same explanation for R₁ₐ to R₄ₐ, R₃, R₄, R₇ to R₁₃, m1 to m4, n3, n4, and n7 to n13 defined in Formula 1 and Formula 2-1 to Formula 2-4, may be applied.

In an embodiment, the first compound represented by Formula 1 may be represented by any one selected from among Formula 4-1 to Formula 4-8.

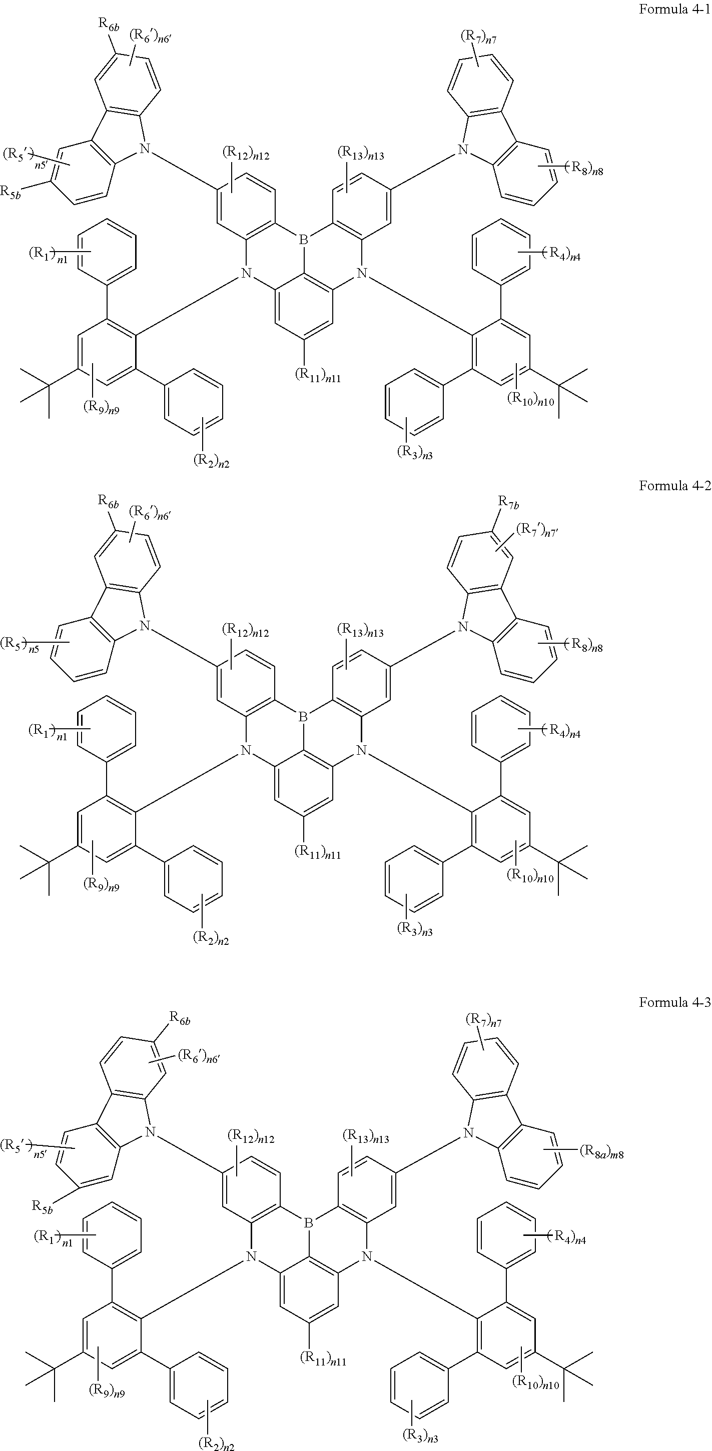

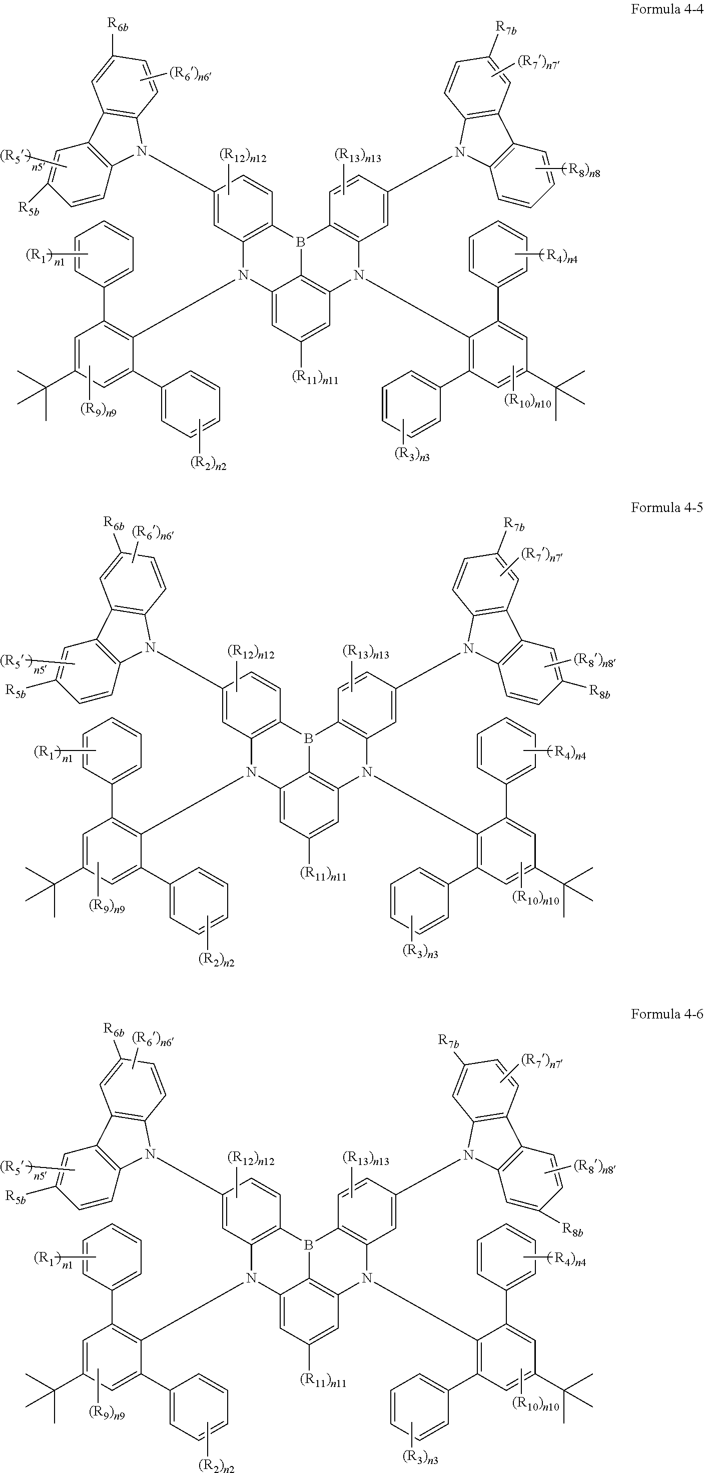

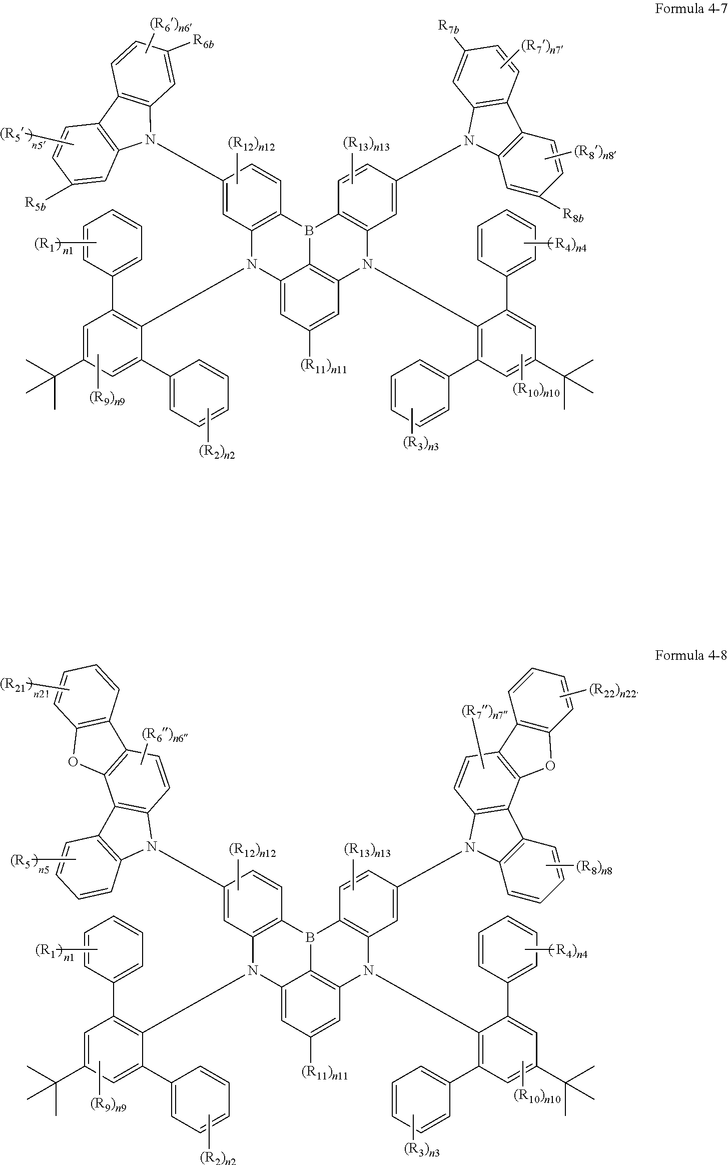

In Formula 4-1 to Formula 4-8, R_{5b} to R_{8b} may each independently be a deuterium atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, R₅′ to R₈′, R₆″, R₇″, R₂₁, and R₂₂ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, n5′ to n8′ may each independently be an integer from 0 to 3, n6″ and n7″ may each independently be an integer from 0 to 2, and n21 and n22 may each independently be an integer from 0 to 4.

In Formula 4-1 to Formula 4-8, the same explanation for R₁ to R₅, R₇ to R₁₃, n1 to n5, and n7 to n13 defined in Formula 1 may be applied.

In an embodiment, the first compound represented by Formula 1 may be represented by any one selected from among Formula 5-1 to Formula 5-3.

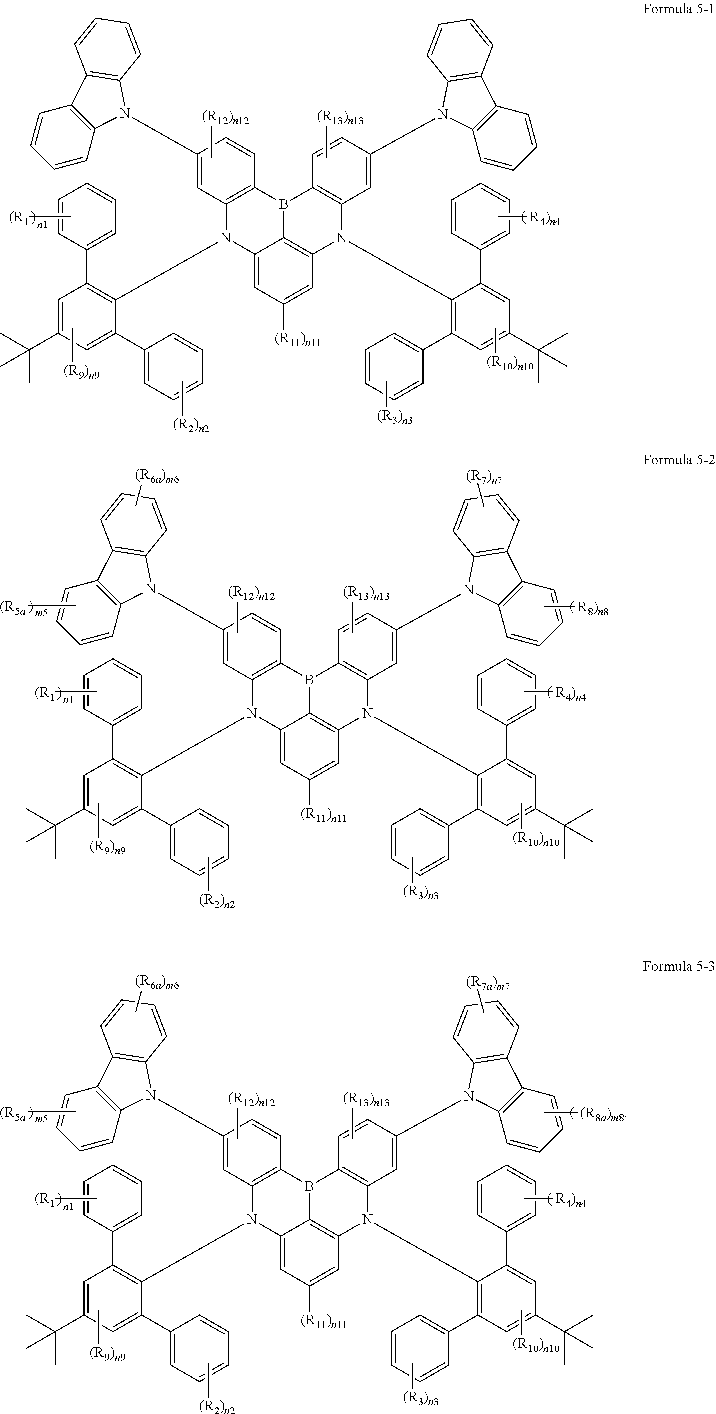

In Formula 5-1 to Formula 5-3, R₅ₐ to R₈ₐ may be deuterium atoms, and m5 to m8 may each independently be an integer from 1 to 4.

In Formula 5-1 to Formula 5-3, the same explanation for R₁ to R₄, R₇ to R₁₃, n1 to n4, and n7 to n13 defined in Formula 1 may be applied.

In an embodiment, the first compound represented by Formula 1 may be represented by Formula 6.

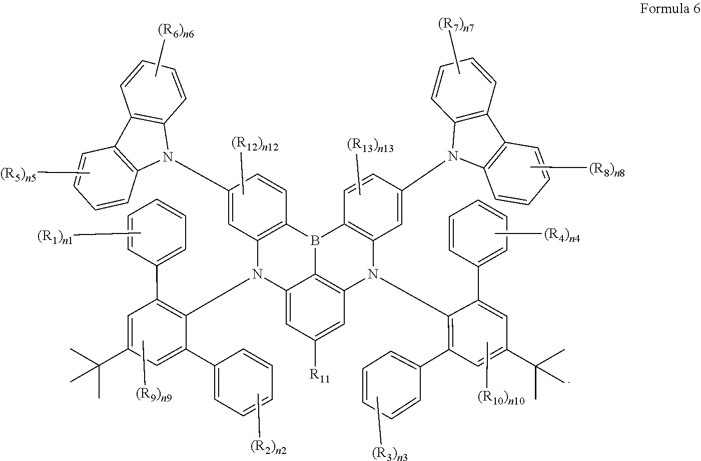

In Formula 6, the same explanation for R₁ to R₁₃, n1 to n10, n12, and n13 defined in Formula 1 may be applied.

In an embodiment, R₁₁ may be a hydrogen atom, a substituted or unsubstituted alkyl group of 1 to 10 carbon atoms, or a substituted or unsubstituted cycloalkyl group of 3 to 10 ring-forming carbon atoms.

In an embodiment, the emission layer may further include a second compound represented by Formula H-1.

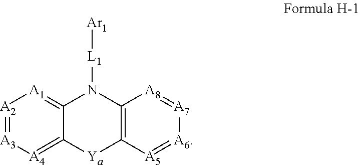

In Formula H-1, A₁ to A₈ are each independently N or CR₅₁, L₁ is a direct linkage, a substituted or unsubstituted arylene group of 6 to 30 ring-forming carbon atoms, or a substituted or unsubstituted heteroarylene group of 2 to 30 ring-forming carbon atoms, Yₐ is a direct linkage, CR₅₂R₅₃, or SiR₅₄R₅₅, Ar₁ is a substituted or unsubstituted aryl group of 6 to 30 ring-forming carbon atoms, or a substituted or unsubstituted heteroaryl group of 2 to 30 ring-forming carbon atoms, and R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In an embodiment, the emission layer may further include a third compound represented by Formula H-2.

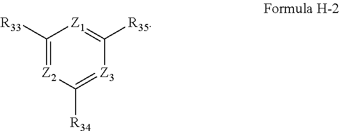

In Formula H-2, Z₁ to Z₃ may each independently be N or CR₃₆, at least one selected from among Z₁ to Z₃ may be N, and R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring.

In an embodiment, the emission layer may further include a fourth compound represented by Formula D-1.

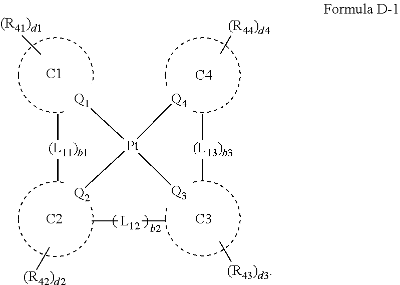

In Formula D-1, Q1 to Q₄ may each independently be C or N, C1 to C4 may each independently be a substituted or unsubstituted hydrocarbon ring of 5 to 30 ring-forming carbon atoms, or a substituted or unsubstituted heterocycle of 2 to 30 ring-forming carbon atoms, L₁₁ to L₁₃ may each independently be a direct linkage,

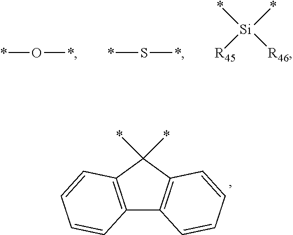

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, b1 to b3 may each independently be 0 or 1, R₄₁ to R₄₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, and d1 to d4 may each independently be an integer from 0 to 4.

A fused polycyclic compound according to an embodiment of the present disclosure is represented by Formula 1.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a plan view of a display apparatus according to an embodiment of the present disclosure,

FIG. 2 is a cross-sectional view of a display apparatus according to an embodiment of the present disclosure;

FIG. 3 is a cross-sectional view schematically showing a light emitting device according to an embodiment of the present disclosure;

FIG. 4 is a cross-sectional view schematically showing a light emitting device according to an embodiment of the present disclosure;

FIG. 5 is a cross-sectional view schematically showing a light emitting device according to an embodiment of the present disclosure;

FIG. 6 is a cross-sectional view schematically showing a light emitting device according to an embodiment of the present disclosure;

FIG. 7 and FIG. 8 are cross-sectional views on display apparatuses according to embodiments of the present disclosure;

FIG. 9 is a cross-sectional view showing a display apparatus according to an embodiment of the present disclosure; and

FIG. 10 is a cross-sectional view showing a display apparatus according to an embodiment of the present disclosure.

### DETAILED DESCRIPTION

The present disclosure may have one or more suitable modifications and may be embodied in different forms, and example embodiments will be explained in more detail with reference to the accompany drawings. The present disclosure may, however, be embodied in different forms and should not be construed as limited to the embodiments set forth herein. Rather, all modifications, equivalents, and substituents which are included in the spirit and technical scope of the present disclosure should be included in the present disclosure.

Like reference numerals refer to like elements throughout, and duplicative descriptions thereof may not be provided. In the drawings, the dimensions of structures may be exaggerated for clarity of illustration. It will be understood that, although the terms first, second, etc. may be utilized herein to describe one or more suitable elements, these elements should not be limited by these terms. These terms are only utilized to distinguish one element from another element. Thus, a first element could be termed a second element without departing from the teachings of the present disclosure. Similarly, a second element could be termed a first element. As utilized herein, the singular forms are intended to include the plural forms as well, unless the context clearly indicates otherwise. As used herein, the singular forms “a”, “an” and “the” are intended to include the plural forms as well, unless the context clearly indicates otherwise.

In the disclosure, it will be further understood that the terms “comprises,” “includes,” “comprising,” and/or “including” when utilized in this disclosure, specify the presence of stated features, numerals, steps, operations, elements, parts, or the combination thereof, but do not preclude the presence or addition of one or more other features, numerals, steps, operations, elements, parts, or the combination thereof.

In the disclosure, when a layer, a film, a region, a plate, etc. is referred to as being “on” or “above” another part, it can be “directly on” the other part, or intervening layers may also be present. In contrast, when a layer, a film, a region, a plate, etc. is referred to as being “under” or “below” another part, it can be “directly under” the other part, or intervening layers may also be present. Also, when an element is referred to as being disposed “on” another element, it can be disposed under the other element.

In the disclosure, the term “substituted or unsubstituted” corresponds to substituted or unsubstituted with at least one substituent selected from the group including (e.g., consisting of) a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In some embodiments, each of the exemplified substituents may be substituted or unsubstituted. For example, a biphenyl group may be interpreted as an aryl group or a phenyl group substituted with a phenyl group.

In the disclosure, the term “forming a ring via the combination with an adjacent group” may refer to forming a substituted or unsubstituted hydrocarbon ring, or a substituted or unsubstituted heterocycle via the combination with an adjacent group. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In some embodiments, the ring formed via the combination with an adjacent group may be combined with another ring to form a spiro structure.

In the disclosure, the term “adjacent group” may refer to a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In some embodiments, in 4,5-dimethylphenanthrene, two methyl groups may be interpreted as “adjacent groups” to each other.

In the disclosure, the halogen atom may be a fluorine atom, a chlorine atom, a bromine atom or an iodine atom.

In the disclosure, the alkyl group may be a linear, or branched type or kind. The carbon number of the alkyl group may be 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the disclosure, a cycloalkyl group may refer to a ring-type or kind alkyl group. The carbon number of the cycloalkyl group may be 3 to 50, 3 to 30, 3 to 20, or 3 to 10. Examples of the cycloalkyl group include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., without limitation.

In the disclosure, an alkenyl group refers to a hydrocarbon group including one or more carbon double bonds in the middle or at the terminal of an alkyl group having a carbon number of 2 or more. The alkenyl group may be a linear chain or a branched chain. The carbon number is not limited, but may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styrylvinyl group, etc., without limitation.

In the disclosure, an aryl group refers to an arbitrary functional group or substituent derived from an aromatic hydrocarbon ring. The aryl group may be a monocyclic aryl group or a polycyclic aryl group. The carbon number for forming rings in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, etc., without limitation.

In the disclosure, a heteroaryl group may include one or more selected from among B, O, N, P, Si, and S as heteroatoms. When the heteroaryl group includes two or more heteroatoms, two or more heteroatoms may be the same or different. The heteroaryl group may be a monocyclic heterocyclic group or polycyclic heterocyclic group. The carbon number for forming rings of the heteroaryl group may be 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the disclosure, the same explanation on the above-described aryl group may be applied to an arylene group except that the arylene group is a divalent group. The same explanation on the above-described heteroaryl group may be applied to a heteroarylene group except that the heteroarylene group is a divalent group.

In the disclosure, a silyl group includes an alkyl silyl group and/or an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the disclosure, a thio group may include an alkyl thio group and/or an aryl thio group. The thio group may refer to the above-defined alkyl group or aryl group combined with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., without limitation.

In the disclosure, an oxy group may refer to the above-defined alkyl group or aryl group which is combined with an oxygen atom. The oxy group may include an alkoxy group and/or an aryl oxy group. The alkoxy group may be a linear, branched or cyclic chain. The carbon number of the alkoxy group is not limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc. However, an embodiment of the present disclosure is not limited thereto.

In the disclosure, a boron group may refer to the above-defined alkyl group or aryl group, combined with a boron atom. The boron group includes an alkyl boron group and/or an aryl boron group. Examples of the boron group include a dimethylboron group, a diethylboron group, a t-butylmethylboron group, a diphenylboron group, a phenylboron group, etc., without limitation.

In the disclosure, the carbon number of the amine group is not limited, but may be 1 to 30. The amine group may include an alkyl amine group and/or an aryl amine group. Examples of the amine group include a methylamine group, a dimethylamine group, a phenylamine group, a diphenylamine group, a naphthylamine group, a 9-methyl-anthracenylamine group, a triphenylamine group, etc., without limitation.

In the disclosure, a direct linkage may refer to a single bond.

Hereinafter, embodiments of the present disclosure will be explained in more detail referring to the drawings.

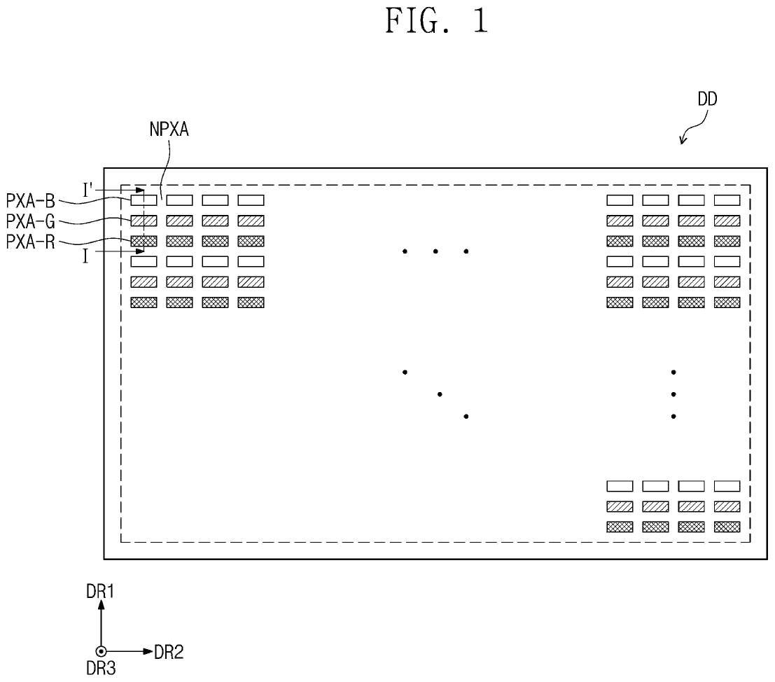

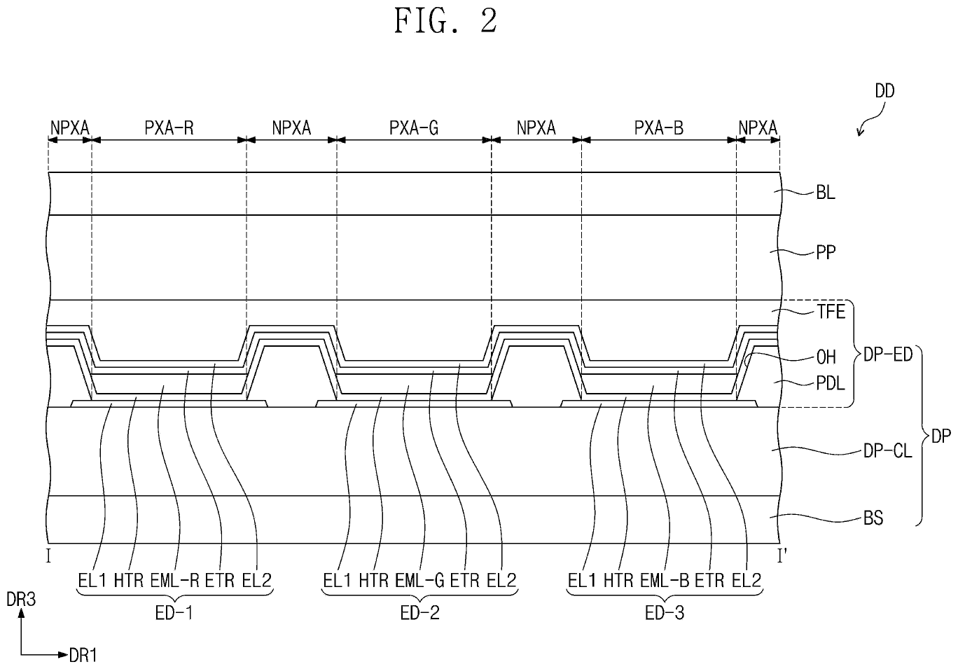

FIG. 1 is a plan view showing an embodiment of a display apparatus DD. FIG. 2 is a cross-sectional view of a display apparatus DD of an embodiment. FIG. 2 is a cross-sectional view showing a part corresponding to line I-I′.

The display apparatus DD may include a display panel DP and an optical layer PP disposed on the display panel DP. The display panel DP includes light emitting devices ED-1, ED-2 and ED-3. The display apparatus DD may include multiple light emitting devices ED-1, ED-2 and ED-3. The optical layer PP may be disposed on the display panel DP and control reflected light by external light at the display panel DP. The optical layer PP may include, for example, a polarization layer or a color filter layer. In some embodiments, the optical layer PP may not be provided in the display apparatus DD.

On the optical layer PP, a base substrate BL may be disposed. The base substrate BL may be a member providing a base surface where the optical layer PP is disposed. The base substrate BL may be a glass substrate, a metal substrate, a plastic substrate, etc. However, an embodiment of the present disclosure is not limited thereto, and the base substrate BL may be an inorganic layer, an organic layer or a composite material layer. In some embodiments, different from the drawings, the base substrate BL may not be provided.

The display apparatus DD according to an embodiment may further include a plugging layer. The plugging layer may be disposed between a display device layer DP-ED and a base substrate BL. The plugging layer may be an organic layer. The plugging layer may include at least one selected from among an acrylic resin, a silicon-based resin and an epoxy-based resin.

The display panel DP may include a base layer BS, a circuit layer DP-CL provided on the base layer BS and a display device layer DP-ED. The display device layer DP-ED may include a pixel definition layer PDL, light emitting devices ED-1, ED-2 and ED-3 disposed in the pixel definition layer PDL, and an encapsulating layer TFE on the light emitting devices ED-1, ED-2 and ED-3.

The base layer BS may be a member providing a base surface where the display device layer DP-ED is disposed. The base layer BS may be a glass substrate, a metal substrate, a plastic substrate, etc. However, an embodiment of the present disclosure is not limited thereto, and the base layer BS may be an inorganic layer, an organic layer or a composite material layer.

In an embodiment, the circuit layer DP-CL is disposed on the base layer BS, and the circuit layer DP-CL may include multiple transistors. Each of the transistors may include a control electrode, an input electrode, and an output electrode. For example, the circuit layer DP-CL may include switching transistors and driving transistors for driving the light emitting devices ED-1, ED-2 and ED-3 of the display device layer DP-ED.

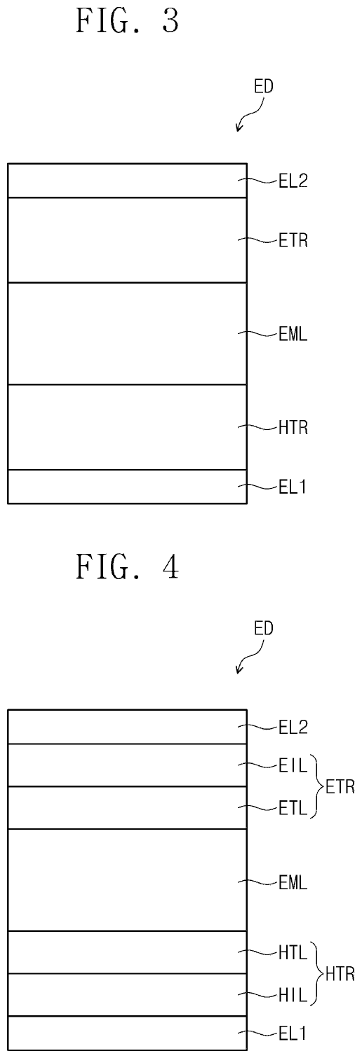

Each of the light emitting devices ED-1, ED-2 and ED-3 may have the structures of light emitting devices ED of embodiments according to FIGS. 3 to 6, which will be explained in more detail. Each of the light emitting devices ED-1, ED-2 and ED-3 may include a first electrode EL1, a hole transport region HTR, emission layers EML-R, EML-G and EML-B, an electron transport region ETR, and a second electrode EL2.

In FIG. 2, shown is an embodiment in which the emission layers EML-R, EML-G and EML-B of light emitting devices ED-1, ED-2 and ED-3, which are in opening portions OH defined in a pixel definition layer PDL, are disposed, and a hole transport region HTR, an electron transport region ETR and a second electrode EL2 are provided as common layers in all light emitting devices ED-1, ED-2 and ED-3. However, an embodiment of the present disclosure is not limited thereto. In an embodiment, the hole transport region HTR and the electron transport region ETR may be patterned and provided in the opening portions OH defined in the pixel definition layer PDL. For example, in an embodiment, the hole transport region HTR, the emission layers EML-R, EML-G and EML-B, and the electron transport region ETR of the light emitting devices ED-1, ED-2 and ED-3 may be patterned by an ink jet printing method and provided.

An encapsulating layer TFE may cover the light emitting devices ED-1, ED-2 and ED-3. The encapsulating layer TFE may encapsulate the display device layer DP-ED. The encapsulating layer TFE may be a thin film encapsulating layer. The encapsulating layer TFE may be one layer or a stacked layer of multiple layers. The encapsulating layer TFE includes at least one insulating layer. The encapsulating layer TFE according to an embodiment may include at least one inorganic layer (hereinafter, encapsulating inorganic layer). In some embodiments, the encapsulating layer TFE according to an embodiment may include at least one organic layer (hereinafter, encapsulating organic layer) and at least one encapsulating inorganic layer.

The encapsulating inorganic layer protects (reduces exposure to moisture/oxygen) the display device layer DP-ED from moisture/oxygen, and the encapsulating organic layer protects (reduces exposure to foreign materials) the display device layer DP-ED from foreign materials such as dust particles. The encapsulating inorganic layer may include silicon nitride, silicon oxy nitride, silicon oxide, titanium oxide, or aluminum oxide, without specific limitation. The encapsulating organic layer may include an acrylic compound, an epoxy-based compound, etc. The encapsulating organic layer may include a photopolymerizable organic material, without specific limitation.

The encapsulating layer TFE may be on the second electrode EL2 and may be disposed while filling the opening portion OH.

Referring to FIG. 1 and FIG. 2, the display apparatus DD may include a non-luminous area NPXA and luminous areas PXA-R, PXA-G and PXA-B. The luminous areas PXA-R, PXA-G and PXA-B may be areas emitting light produced from the light emitting devices ED-1, ED-2 and ED-3, respectively. The luminous areas PXA-R, PXA-G and PXA-B may be separated from each other on a plane (e.g., in a plan view).

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. In some embodiments, in the disclosure, each of the luminous areas PXA-R, PXA-G and PXA-B may correspond to each pixel. The pixel definition layer PDL may divide the light emitting devices ED-1, ED-2 and ED-3. The emission layers EML-R, EML-G and EML-B of the light emitting devices ED-1, ED-2 and ED-3 may be disposed and divided in the opening portions OH defined in the pixel definition layer PDL.

The luminous areas PXA-R, PXA-G and PXA-B may be divided into multiple groups according to the color of light produced from the light emitting devices ED-1, ED-2 and ED-3. In the display apparatus DD of an embodiment, shown in FIG. 1 and FIG. 2, three luminous areas PXA-R, PXA-G and PXA-B emitting red light, green light and blue light are illustrated as an embodiment. For example, the display apparatus DD of an embodiment may include a red luminous area PXA-R, a green luminous area PXA-G and a blue luminous area PXA-B, which are separated from each other.

In the display apparatus DD according to an embodiment, multiple light emitting devices ED-1, ED-2 and ED-3 may emit light having different wavelength regions. For example, in an embodiment, the display apparatus DD may include a first light emitting device ED-1 emitting red light, a second light emitting device ED-2 emitting green light, and a third light emitting device ED-3 emitting blue light. For example, each of the red luminous area PXA-R, the green luminous area PXA-G, and the blue luminous area PXA-B of the display apparatus DD may correspond to the first light emitting device ED-1, the second light emitting device ED-2, and the third light emitting device ED-3.

However, an embodiment of the present disclosure is not limited thereto, and the first to third light emitting devices ED-1, ED-2 and ED-3 may emit light in substantially the same wavelength region, or at least one thereof may emit light in a different wavelength region. For example, all the first to third light emitting devices ED-1, ED-2 and ED-3 may emit blue light.

The luminous areas PXA-R, PXA-G and PXA-B in the display apparatus DD according to an embodiment may be arranged in a stripe shape. Referring to FIG. 1, multiple red luminous areas PXA-R may be arranged with each other along a second direction axis DR2, multiple green luminous areas PXA-G may be arranged with each other along the second direction axis DR2, and multiple blue luminous areas PXA-B may be arranged with each other along the second direction axis DR2. In some embodiments, the red luminous area PXA-R, the green luminous area PXA-G and the blue luminous area PXA-B may be alternately arranged in turn along a first direction axis DR1. (DR3 is a third direction which is normal or perpendicular to the plane defined by the first direction DR1 and the second direction DR2).

In FIG. 1 and FIG. 2, the areas of the luminous areas PXA-R, PXA-G and PXA-B are shown similar, but an embodiment of the present disclosure is not limited thereto. The areas of the luminous areas PXA-R, PXA-G and PXA-B may be different from each other according to the wavelength region of light emitted. In some embodiments, the areas of the luminous areas PXA-R, PXA-G and PXA-B may refer to areas on a plane defined by the first direction axis DR1 and the second direction axis DR2 (e.g., in a plan view).

In some embodiments, the arrangement type or kind of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in one or more suitable combinations according to the properties of display quality required for the display apparatus DD. For example, the arrangement type or kind of the luminous areas PXA-R, PXA-G and PXA-B may be a pentile (PENTILE©) (for example, an RGBG matrix, an RGBG structure, or RGBG matrix structure) arrangement type or kind, or a diamond (Diamond Pixel™) arrangement type or kind. (e.g., a display (e.g., an OLED display) containing red, blue, and green (RGB) light emitting regions arranged in the shape of diamonds. PENTILE© is a duly registered trademark of Samsung Display Co., Ltd. Diamond Pixel™ is a trademark of Samsung Display Co., Ltd.

In some embodiments, the areas of the luminous areas PXA-R, PXA-G and PXA-B may be different from each other. For example, in an embodiment, the area of the green luminous area PXA-G may be smaller than the area of the blue luminous area PXA-B, but an embodiment of the present disclosure is not limited thereto.

Hereinafter, FIGS. 3 to 6 are cross-sectional views schematically showing light emitting devices according to embodiments. The light emitting device ED according to an embodiment may include a first electrode EL1, a hole transport region HTR, an emission layer EML, an electron transport region ETR, and a second electrode EL2 stacked in order (in the stated order).

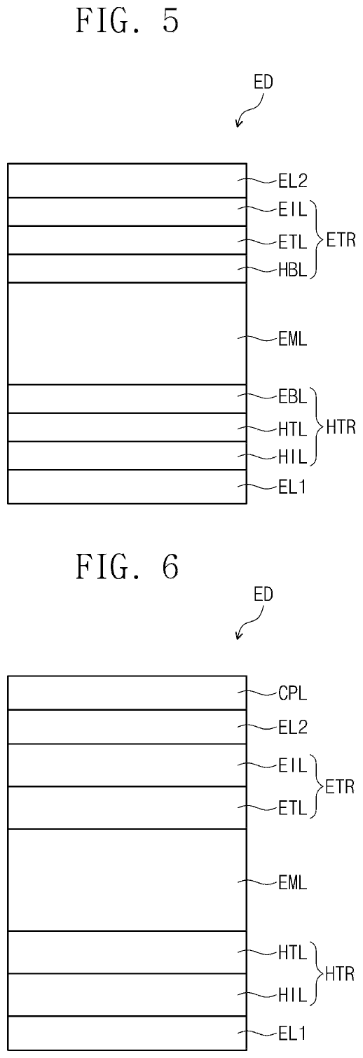

When compared with FIG. 3, FIG. 4 shows the cross-sectional view of a light emitting device ED of an embodiment, wherein a hole transport region HTR includes a hole injection layer HIL and a hole transport layer HTL, and an electron transport region ETR includes an electron injection layer EIL and an electron transport layer ETL. When compared with FIG. 3, FIG. 5 shows the cross-sectional view of a light emitting device ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared with FIG. 4, FIG. 6 shows the cross-sectional view of a light emitting device ED of an embodiment, including a capping layer CPL disposed on the second electrode EL2.

The first electrode EL1 has conductivity (e.g., is a conductor). The first electrode EL1 may be formed utilizing a metal material, a metal alloy or a conductive compound. The first electrode EL1 may be an anode or a cathode. However, an embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from Ag, Mg, Cu, Al, Pt, Pd, Au, Ni, Nd, Ir, Cr, Li, Ca, LiF, Mo, Ti, W, In, Sn, and Zn, one or more compounds of two or more selected therefrom, one or more mixtures of two or more selected therefrom, or one or more oxides thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, one or more compounds thereof, or one or more mixtures thereof (for example, a mixture of Ag and Mg). Also, the first electrode EL1 may have a structure including multiple layers including a reflective layer or a transflective layer formed utilizing the above materials, and a transmissive conductive layer formed utilizing ITO, IZO, ZnO, or ITZO. For example, the first electrode EL1 may include a three-layer structure of ITO/Ag/ITO. However, an embodiment of the present disclosure is not limited thereto. The first electrode EL1 may include the above-described metal materials, combinations of two or more metal materials selected from the above-described metal materials, or one or more oxides of the above-described metal materials. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer, an emission auxiliary layer or an electron blocking layer EBL. The thickness of the hole transport region HTR may be from about 50 Å to about 15,000 Å.

The hole transport region HTR may have a single layer formed utilizing a single material, a single layer formed utilizing multiple different materials, or a multilayer structure including multiple layers formed utilizing multiple different materials.

For example, the hole transport region HTR may have the structure of a single layer of a hole injection layer HIL or a hole transport layer HTL, and may have a structure of a single layer formed utilizing a hole injection material and a hole transport material. In some embodiments, the hole transport region HTR may have a structure of a single layer formed utilizing multiple different materials, or a structure stacked from the first electrode EL1 of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer EBL, without limitation.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-2.

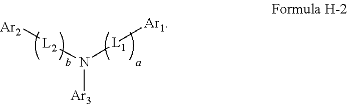

In Formula H-2, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. “a” and “b” may each independently be an integer from 0 to 10. In some embodiments, when “a” or “b” is an integer of 2 or more, multiple L₁ and L₂ may each independently be a substituted or unsubstituted arylene group of 6 to 30 ring-forming carbon atoms, or a substituted or unsubstituted heteroarylene group of 2 to 30 ring-forming carbon atoms.

In Formula H-2, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. In some embodiments, in Formula H-2, Ar₃ may be a substituted or unsubstituted aryl group of 6 to 30 ring-forming carbon atoms, or a substituted or unsubstituted heteroaryl group of 2 to 30 ring-forming carbon atoms.

The compound represented by Formula H-2 may be a monoamine compound. In some embodiments, the compound represented by Formula H-2 may be a diamine compound in which at least one selected from among Ar₁ to Ar₃ includes an amine group as a substituent. In some embodiments, the compound represented by Formula H-2 may be a carbazole-based compound in which at least one selected from among Ar₁ and Ar₂ includes a substituted or unsubstituted carbazole group, or a fluorene-based compound in which at least one selected from among Ar₁ and Ar₂ includes a substituted or unsubstituted fluorene group.

The compound represented by Formula H-2 may be represented by any one selected from among the compounds in Compound Group H. However, the compounds shown in Compound Group H are merely illustrations/examples, and the compound represented by Formula H-2 is not limited to the compounds represented in Compound Group H.

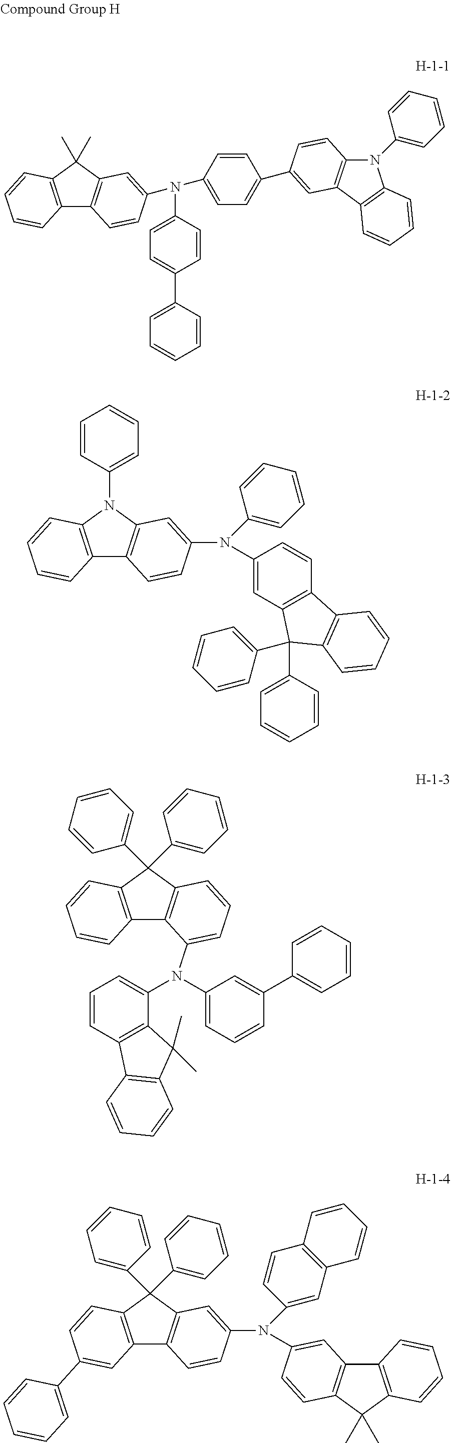

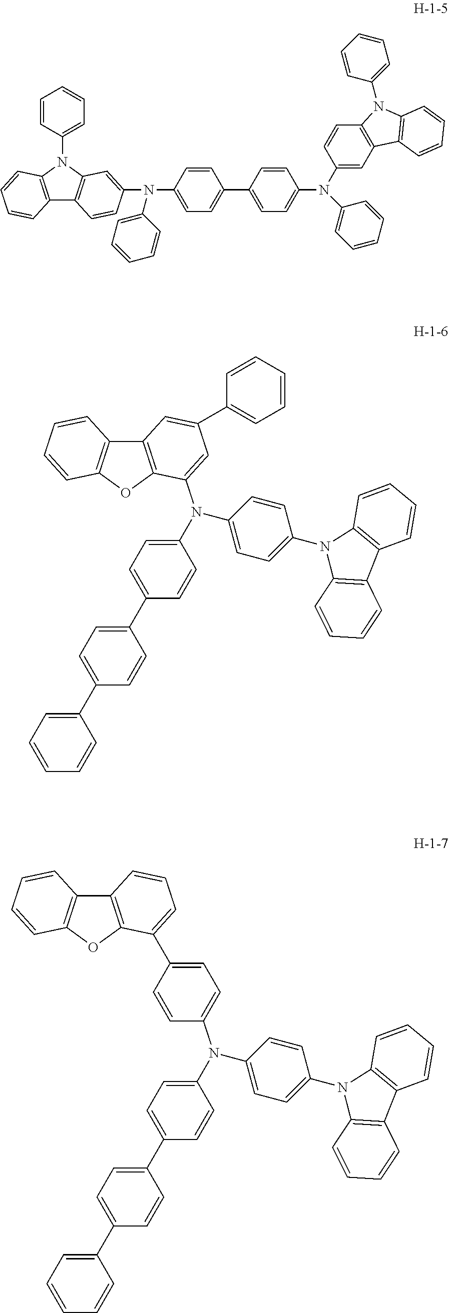

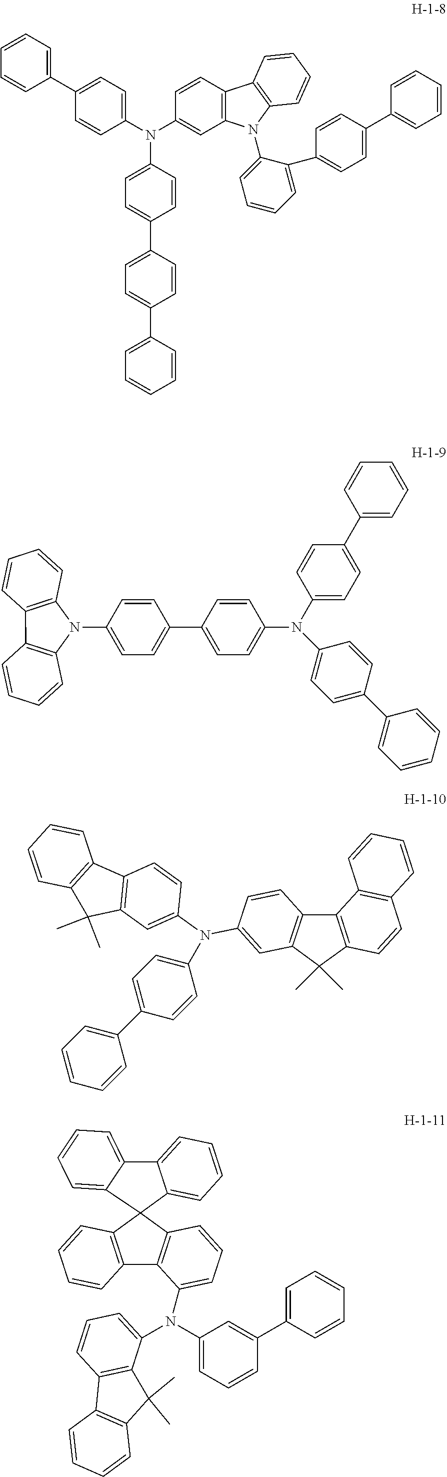

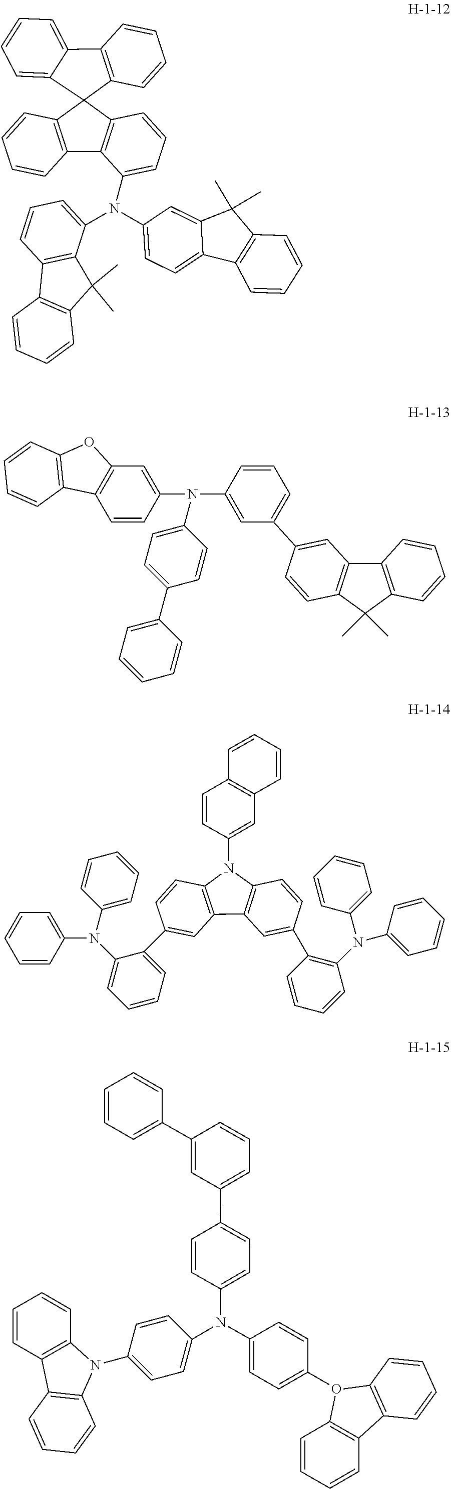

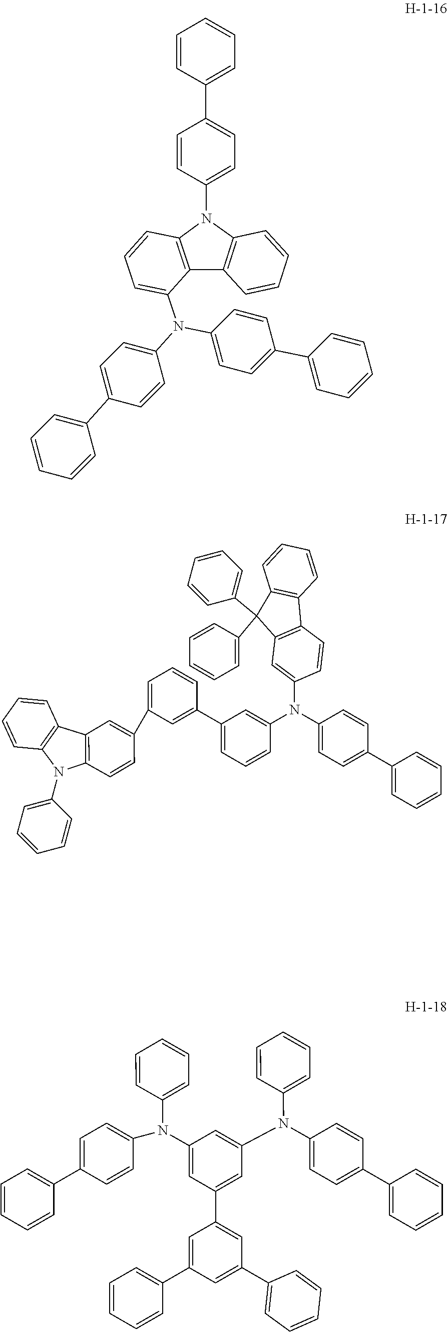 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

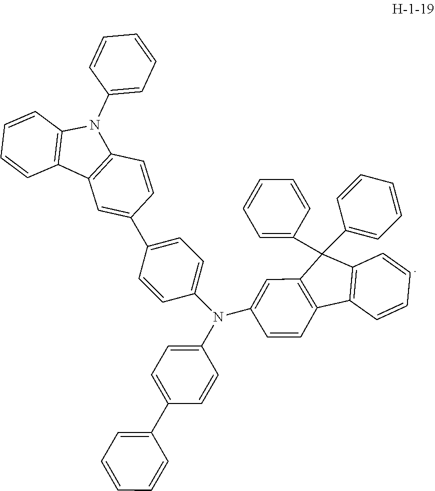 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and/or dipyrazino[2,3-f:2′,3′-h]quinoxaline-2,3,6,7,10,11-hexacarbonitrile (HAT-CN).

The hole transport region HTR may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region in at least one selected from among the hole injection layer HIL, hole transport layer HTL, and electron blocking layer EBL.

The thickness of the hole transport region HTR may be from about 100 Å to about 10,000 Å, for example, from about 100 Å to about 5,000 Å. When the hole transport region HTR includes a hole injection layer HIL, the thickness of the hole injection region HIL may be, for example, from about 30 Å to about 1,000 Å. When the hole transport region HTR includes a hole transport layer HTL, the thickness of the hole transport layer HTL may be from about 30 Å to about 1,000 Å. For example, when the hole transport region HTR includes an electron blocking layer, the thickness of the electron blocking layer EBL may be from about 10 Å to about 1,000 Å. When the thicknesses of the hole transport region HTR, the hole injection layer HIL, the hole transport layer HTL and the electron blocking layer EBL satisfy the above-described ranges, satisfactory (suitable) hole transport properties may be achieved without substantial increase of a driving voltage.

The hole transport region HTR may further include a charge generating material to increase conductivity in addition to the above-described materials. The charge generating material may be dispersed substantially uniformly or non-uniformly in the hole transport region HTR. The charge generating material may be, for example, a p-dopant. The p-dopant may include at least one selected from among metal halide compounds, quinone derivatives, metal oxides, and cyano group-containing compounds, without limitation. For example, the p-dopant may include metal halide compounds such as CuI and/or RbI, quinone derivatives such as tetracyanoquinodimethane (TCNQ) and/or 2,3,5,6-tetrafluoro-7,7′,8,8-tetracyanoquinodimethane (F4-TCNQ), metal oxides such as tungsten oxide and/or molybdenum oxide, cyano group-containing compounds such as dipyrazino[2,3-f: 2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile, etc., without limitation.

As described above, the hole transport region HTR may further include, at least one of a buffer layer or an electron blocking layer EBL, in addition to the hole injection layer HIL and the hole transport layer HTL. The buffer layer may compensate for resonance distance according to the wavelength of light emitted from an emission layer EML and may increase emission efficiency. Materials which may be included in the hole transport region HTR may be utilized as materials included in the buffer layer. The electron blocking layer EBL is a layer playing the role of blocking (or reducing) the injection of electrons from an electron transport region ETR to a hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed utilizing a single material, a single layer formed utilizing multiple different materials, or a multilayer structure having multiple layers formed utilizing multiple different materials.

In the light emitting device ED according to an embodiment, the emission layer EML may include the fused polycyclic compound of an embodiment. In an embodiment, the emission layer EML may include the fused polycyclic compound of an embodiment as a dopant. The fused polycyclic compound of an embodiment may be a dopant material of the emission layer EML. In the disclosure, the fused polycyclic compound of an embodiment, which will be explained in more detail, may be referred to as a first compound.

The fused polycyclic compound of an embodiment may include a fused structure in which multiple aromatic rings are fused via at least one boron atom and at least two nitrogen atoms. For example, the fused polycyclic compound of an embodiment may include a fused structure in which first to third aromatic rings are fused via one boron atom, a first nitrogen atom and a second nitrogen atom. The first aromatic ring and the second aromatic ring may be symmetric with respect to the boron atom in the fused structure.

The fused polycyclic compound of an embodiment may include a first substituent and a second substituent, which are sterically hindered substituents in a molecular structure. The first substituent and the second substituent may be connected with the nitrogen atom constituting a fused ring in the fused polycyclic compound of an embodiment. The first substituent may include a benzene moiety substituted with a t-butyl group, and may include a first sub-substituent and a second sub-substituent, substituted at carbon atoms at the specific positions of the benzene moiety. For example, the first substituent may be connected with the first nitrogen atom constituting the fused ring, the first sub-substituent and the second sub-substituent may be introduced at ortho positions with respect to the first nitrogen atom, and a t-butyl group may be substituted at a para position with respect to the first nitrogen atom. The second substituent may include a benzene moiety substituted with a t-butyl group, and a third sub-substituent and a fourth sub-substituent, substituted at carbon atoms at the specific positions of the benzene moiety may be included. For example, the second substituent may be connected with the second nitrogen atom constituting the fused ring, a third sub-substituent and a fourth sub-substituent may be introduced at ortho positions with respect to the second nitrogen atom, and a t-butyl group may be introduced at a para position with respect to the second nitrogen atom.

The fused polycyclic compound of an embodiment may include a third substituent and a fourth substituent, respectively connected with two aromatic rings among the aromatic rings composing the fused ring. The third substituent and the fourth substituent are electron donor substituents, and may include carbazole moieties, respectively. The third substituent and the fourth substituent may be connected with the first aromatic ring and the second aromatic ring, respectively. The third substituent and the fourth substituent may be connected with the first aromatic ring and the second aromatic ring at para positions with respect to the boron atom.

The fused polycyclic compound of an embodiment may be represented by Formula 1.

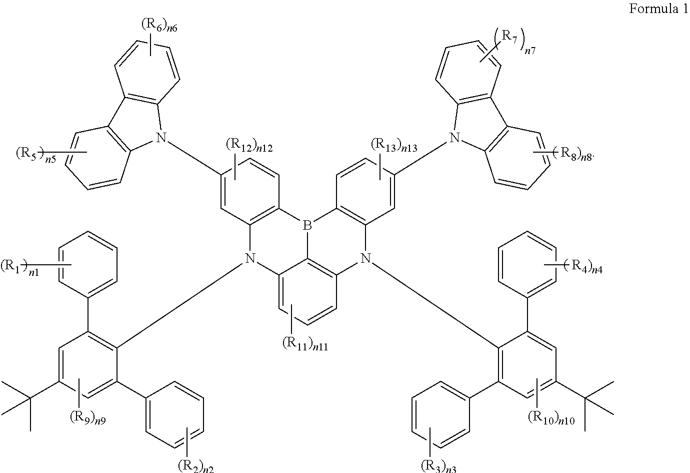

In Formula 1, R₁ to R₁₃ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In some embodiments, each of R₁ to R₁₃ may be combined with an adjacent group to form a ring. For example, R₁ to R₁₃ may each independently be a hydrogen atom, a deuterium atom, a cyano group, a substituted or unsubstituted methyl group, a substituted or unsubstituted ethyl group, a substituted or unsubstituted isopropyl group, a substituted or unsubstituted t-butyl group, a substituted or unsubstituted phenyl group, a substituted or unsubstituted pyridine group, or a substituted or unsubstituted carbazole group. In Formula 1, a R₁-substituted benzene ring corresponds to the above-described first sub-substituent, a R₂-substituted benzene ring corresponds to the above-described second sub-substituent, a R₃-substituted benzene ring corresponds to the above-described third sub-substituent, and a R₄-substituted benzene ring corresponds to the above-described fourth sub-substituent.

In Formula 1, n1 to n4 may each independently be an integer from 0 to 5. When n1 to n4 are each 0, it may indicate that the fused polycyclic compound of an embodiment is unsubstituted with R₁ to R₄, respectively. Embodiments in which n1 to n4 are each 5, and R₁ to R₄ are hydrogen atoms, may be the same as embodiments in which n1 to n4 are each 0, respectively. When n1 to n4 are integers of 2 or more, each of multiple R₁ to R₄ may be all the same, or one or more of multiple R₁ to R₄ may be different.

In Formula 1, n5 to n8 may each independently be an integer from 0 to 4. When n5 to n8 are each 0, it may indicate that the fused polycyclic compound of an embodiment is unsubstituted with R₅ to R₈, respectively. Embodiments in which n5 to n8 are each 4, and R₅ to R₈ are hydrogen atoms, may be the same as embodiments in which n5 to n8 are each 0, respectively. When n5 to n8 are integers of 2 or more, each of multiple R₅ to R₈ may be all the same, or one or more of multiple R₅ to R₈ may be different.

In Formula 1, n9 and n10 may each independently be an integer from 0 to 2. When n9 and n10 are each 0, it may indicate that the fused polycyclic compound of an embodiment is unsubstituted with R₉ and R₁₀, respectively. Embodiments in which n9 and n10 are each 2, and R₉ and R₁₀ are hydrogen atoms, may be the same as embodiments in which n9 and n10 are each 0, respectively. When n9 and n10 are integers of 2, each of multiple R₉ and R₁₀ may be all the same, or at one or more of multiple R₉ and R₁₀ may be different.

In Formula 1, n11 to n13 may each independently be an integer of 0 to 3. When n11 to n13 are each 0, it may indicated that the fused polycyclic compound of an embodiment is unsubstituted with R₁₁ to R₁₃, respectively. Embodiments in which n11 to n13 are each 3, and R₁₁ to R₁₃ are hydrogen atoms, may be the same as embodiments in which n11 to n13 are each 0, respectively. When n11 to n13 are integers of 2 or more, each of multiple R₁₁ to R₁₃ may be all the same, or one or more of multiple R₁₁ to R₁₃ may be different.

In an embodiment, R₁ to R₄ may be deuterium atoms, and a sum of n1 to n4 may be 1 to 20. For example, the fused polycyclic compound of an embodiment, represented by Formula 1 may include a structure in which a deuterium atom is substituted in at least one substituent selected from among first to fourth sub-substituents.

In an embodiment, the fused polycyclic compound represented by Formula 1 may be represented by any one selected from among Formula 2-1 to Formula 2-4.

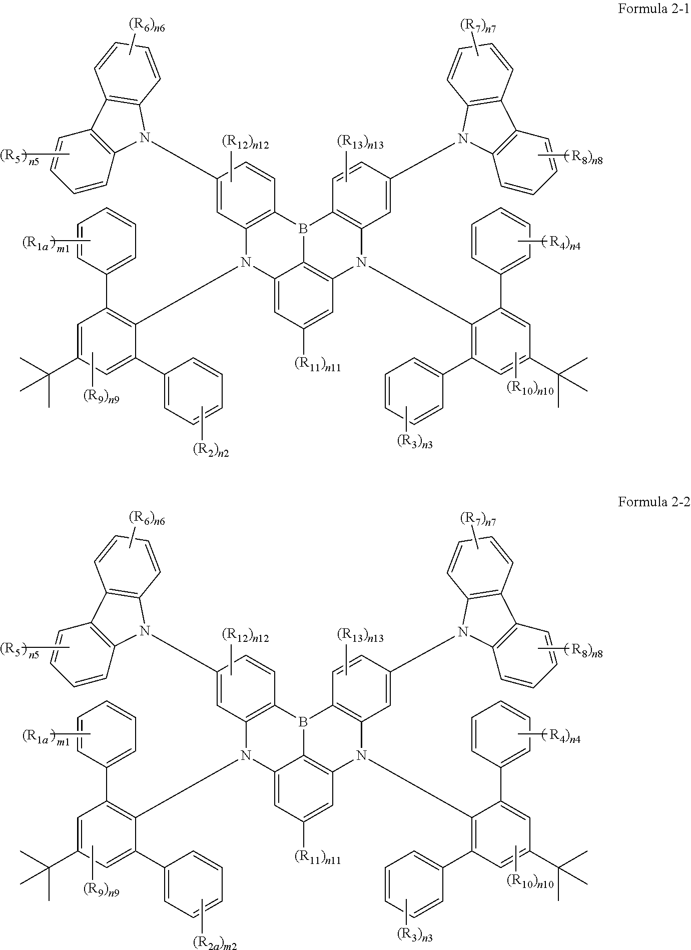

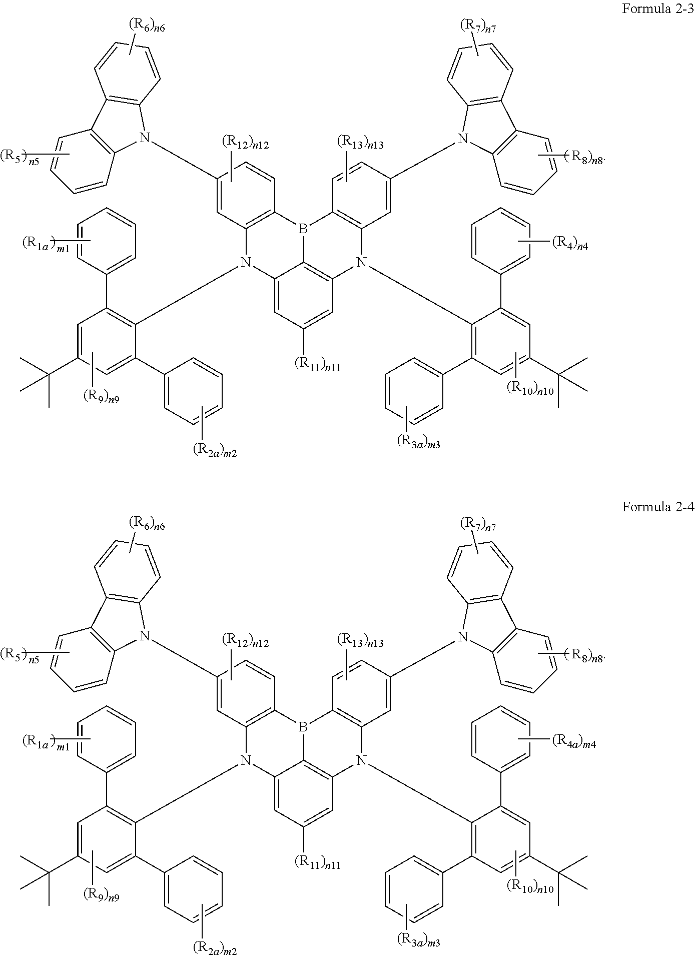

Formula 2-1 to Formula 2-4 represent Formula 1 in which the type or kind of at least one substituent among R₁ to R₄ is specified. For example, Formula 2-1 to Formula 2-4 represent embodiments of Formula 1 in which at least one deuterium atom is substituted in at least one selected from among first to fourth sub-substituents. Formula 2-1 represents an embodiment of Formula 1 in which the substituent represented by R₁ is a deuterium atom. Formula 2-2 represents an embodiment of Formula 1 in which the substituents represented by R₁ and R₂ are deuterium atoms. Formula 2-3 represents an embodiment of Formula 1 in which the substituents represented by R₁ to R₃ are deuterium atoms. Formula 2-4 represents an embodiment of Formula 1 in which the substituents represented by R₁ to R₄ are deuterium atoms.

In Formula 2-1 to Formula 2-4, R₁ₐ to R₄ₐ may be deuterium atoms.

In Formula 2-1 to Formula 2-4, m1 to m4 may each independently be an integer from 1 to 5. In an embodiment, m1 to m4 may each be 5.

In Formula 2-1 to Formula 2-4, the same explanation for R₂ to R₁₃, and n2 to n13 explained in Formula 1 may be applied.

In an embodiment, R₁ to R₈ may be deuterium atoms, and the sum of n1 to n8 may be 1 to 36. For example, the fused polycyclic compound of an embodiment, represented by Formula 1 may include a structure in which at least one deuterium atom is substituted in at least one selected from among the first to fourth sub-substituents, the third substituent and the fourth substituent.

In an embodiment, the fused polycyclic compound represented by Formula 1 may be represented by any one selected from among Formula 3-1 to Formula 3-3.

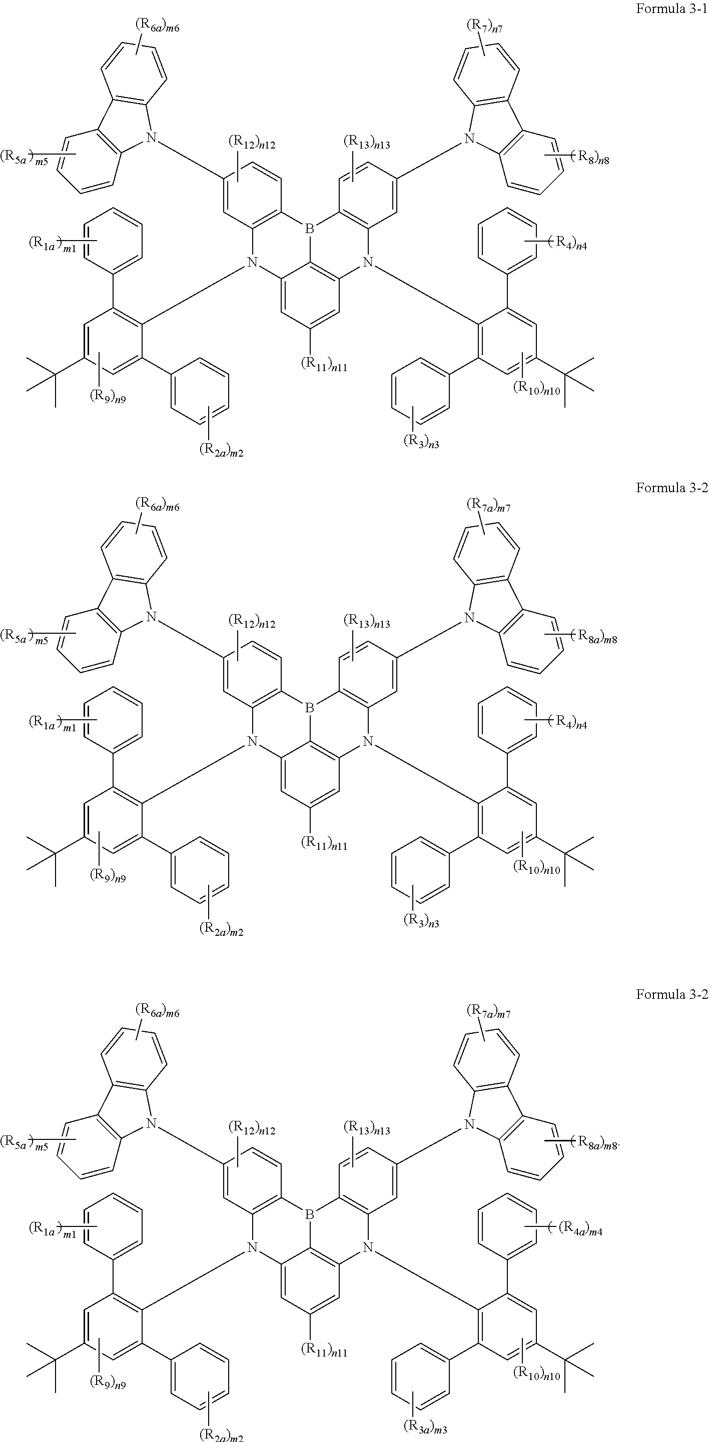

Formula 3-1 to Formula 3-3 represent Formula 1 in which the type or kind of at least one substituent among R₁ to R₈ is specified. Formula 3-1 represents an embodiment of Formula 1 in which the substituents represented by R₁, R₂, R₅, and R₆ are deuterium atoms. Formula 3-2 represents an embodiment of Formula 1 in which the substituents represented by R₁, R₂, and R₅ to R₈ are deuterium atoms. Formula 3-3 represents an embodiment of Formula 1 in which the substituents represented by R₁ to R₈ are deuterium atoms.

In Formula 3-1 to Formula 3-3, R₅ₐ to R₈ₐ may be deuterium atoms.

In Formula 3-1 to Formula 3-3, m5 to m8 may each independently be an integer from 1 to 4. In an embodiment, m5 to m8 may be 4.

In Formula 3-1 to Formula 3-3, the same contents explained in Formula 1 and Formula 2-1 to Formula 2-4 may be applied for R₁ₐ to R₄ₐ, R₃, R₄, R₇ to R₁₃, m1 to m4, n3, n4, and n7 to n13.

In an embodiment, the fused polycyclic compound represented by Formula 1 may be represented by any one selected from among Formula 4-1 to Formula 4-8.

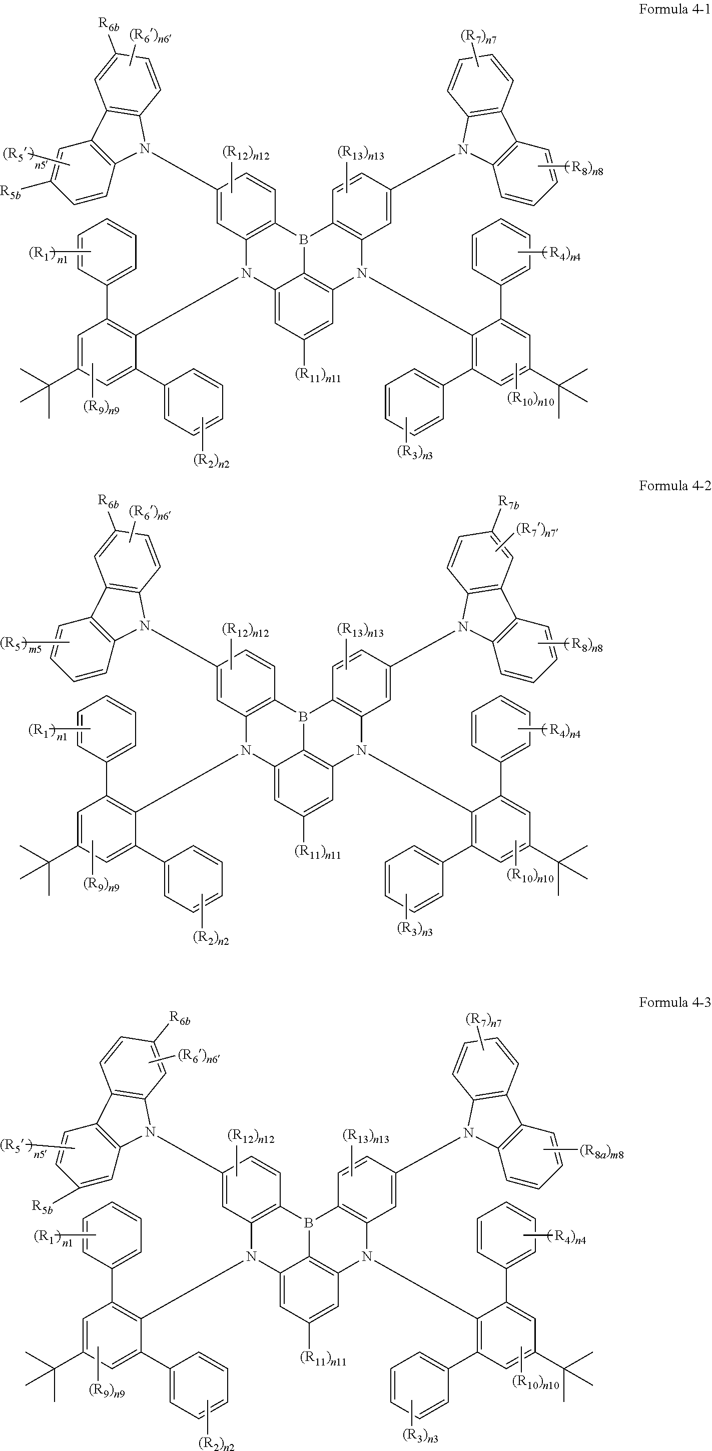

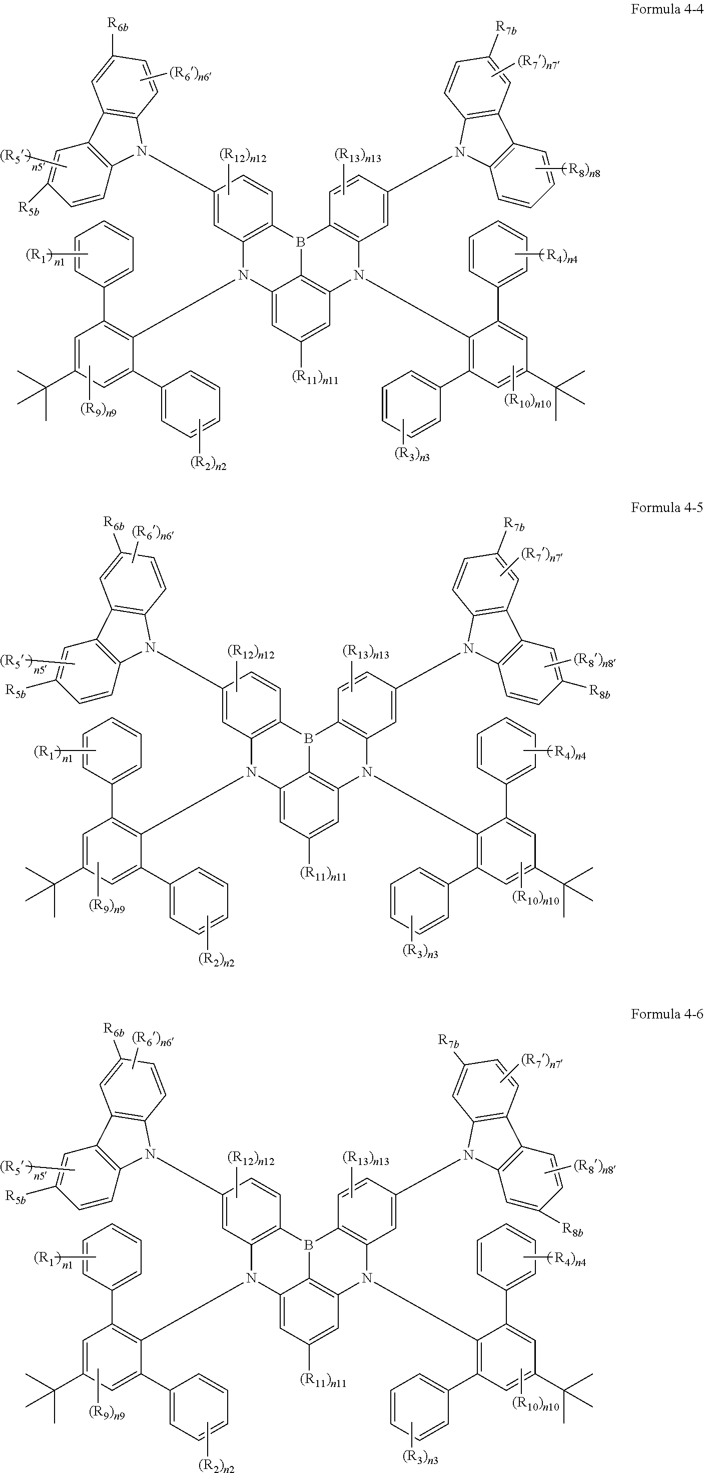

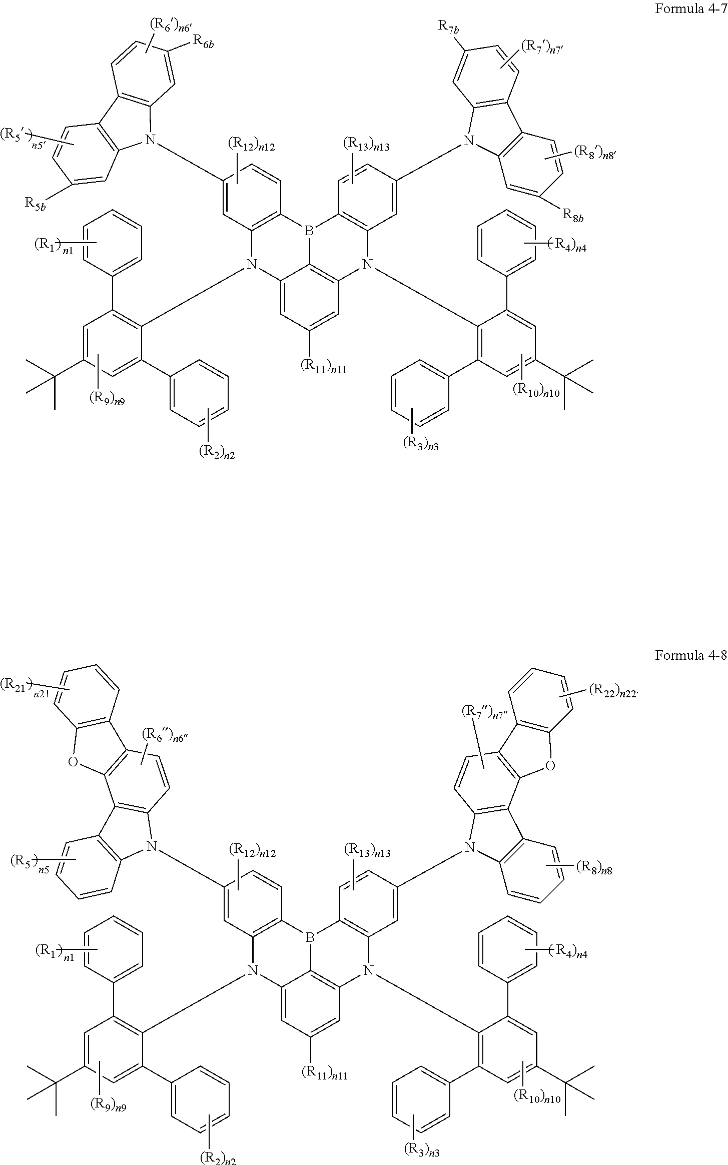

Formula 4-1 to Formula 4-8 represent embodiments of Formula 1 in which the type or kind and/or substitution position of at least one substituent among R₅ to R₈ are specified. Formula 4-1 represents Formula 1 in which each of R₅ and R₆ is a substituent other than a hydrogen atom and is substituted at the para position with respect to the nitrogen atom of the third substituent. Formula 4-2 represents Formula 1 in which R₆ is a substituent other than a hydrogen atom and is substituted at the para position with respect to the nitrogen atom of the third substituent, and R₇ is a substituent other than a hydrogen atom and is substituted at the para position with respect to the nitrogen atom of the fourth substituent. Formula 4-3 represents Formula 1 in which each of R₅ and R₆ is a substituent other than a hydrogen atom and is substituted at the meta position with respect to the nitrogen atom of the third substituent. Formula 4-4 represents Formula 1 in which each of R₅ and R₆ is a substituent other than a hydrogen atom and is substituted at the para position with respect to the nitrogen atom of the third substituent, and R₇ is a substituent other than a hydrogen atom and is substituted at the para position with respect to the nitrogen atom of the fourth substituent. Formula 4-5 represents Formula 1 in which each of R₅ and R₆ is a substituent other than a hydrogen atom and is substituted at the para position with respect to the nitrogen atom of the third substituent, and each of R₇ and R₈ is a substituent other than a hydrogen atom and is substituted at the para position with respect to the nitrogen atom of the fourth substituent. Formula 4-6 represents Formula 1 in which each of R₅ and R₆ is a substituent other than a hydrogen atom and is substituted at the para position with respect to the nitrogen atom of the third substituent, and each of R₇ and R₈ is a substituent other than a hydrogen atom and is substituted at the meta position with respect to the nitrogen atom of the fourth substituent. Formula 4-7 represents Formula 1 in which each of R₅ and R₆ is a substituent other than a hydrogen atom and is substituted at the meta position with respect to the nitrogen atom of the third substituent, and each of R₇ and R₈ is a substituent other than a hydrogen atom and is substituted at the meta position with respect to the nitrogen atom of the fourth substituent. Formula 4-8 represents Formula 1 in which each of R₆ and R₇ is combined with an adjacent group to form a ring.

In Formula 4-1 to Formula 4-8, R_{5b} to R_{8b} may each independently be a deuterium atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R_{5b} to R_{8b} may each independently be a deuterium atom, a cyano group, a substituted or unsubstituted methyl group, a substituted or unsubstituted ethyl group, a substituted or unsubstituted isopropyl group, a substituted or unsubstituted t-butyl group, a substituted or unsubstituted phenyl group, a substituted or unsubstituted pyridine group, or a substituted or unsubstituted carbazole group.

In Formula 4-1 to Formula 4-8, R₅′ to R₈′, R₆″, R₇″, R₂₁, and R₂₂ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. For example, R₅′ to R₈′, R₆″, R₇″, R₂₁, and R₂₂ may each independently be a hydrogen atom, or a deuterium atom.

In Formula 4-1 to Formula 4-7, n5′ to n8′ may each independently be an integer from 0 to 3. When n5′ to n8′ are each 0, it may indicate that the fused polycyclic compound of an embodiment may be unsubstituted with R₅′ to R₈′, respectively. Embodiments in which n5′ to n8′ are each 3, and R₅′ to R₈′ are all hydrogen atoms, may be the same as embodiments in which n5′ to n8′ are each 0. When n5′ to n8′ are integers of 2 or more, each of multiple R₅′ to R₈′ may be all the same, or one or more of R₅′ to R₈′ may be different.

In Formula 4-8, n6″ and n7″ may each independently be an integer of 0 to 2. When n6″ and n7″ are each 0, it may refer to that the fused polycyclic compound of an embodiment may be unsubstituted with R₆″ and R₇″, respectively. Cases in which n6″ and n7″ are each 2, and R₆″ and R₇″ are all hydrogen atoms, may be the same as embodiments in which n6″ and n7″ are each 0. When n6″ and n7″ are integers of 2, each of multiple R₆″ and R₇″ may be all the same, or one or more of R₆″ and R₇″ may be different.

In Formula 4-8, n21 and n22 may each independently be an integer from 0 to 4. When n21 and n22 are each 0, it may indicate that the fused polycyclic compound of an embodiment may be unsubstituted with R₂₁ and R₂₂, respectively. Embodiments in which n21 and n22 are each 4, and R₂₁ and R₂₂ are all hydrogen atoms, may be the same as embodiments in which n21 and n22 are each 0. When n21 and n22 are integers of 2 or more, each of multiple R₂₁ and R₂₂ may be all the same, or one or more of R₂₁ and R₂₂ may be different.

In Formula 4-1 to Formula 4-8, the same contents/definitions explained in Formula 1 may be applied for R₁ to R₅, R₇ to R₁₃, n1 to n5, and n7 to n13.

In an embodiment, the fused polycyclic compound represented by Formula 1 may be represented by any one selected from among Formula 5-1 to Formula 5-3.

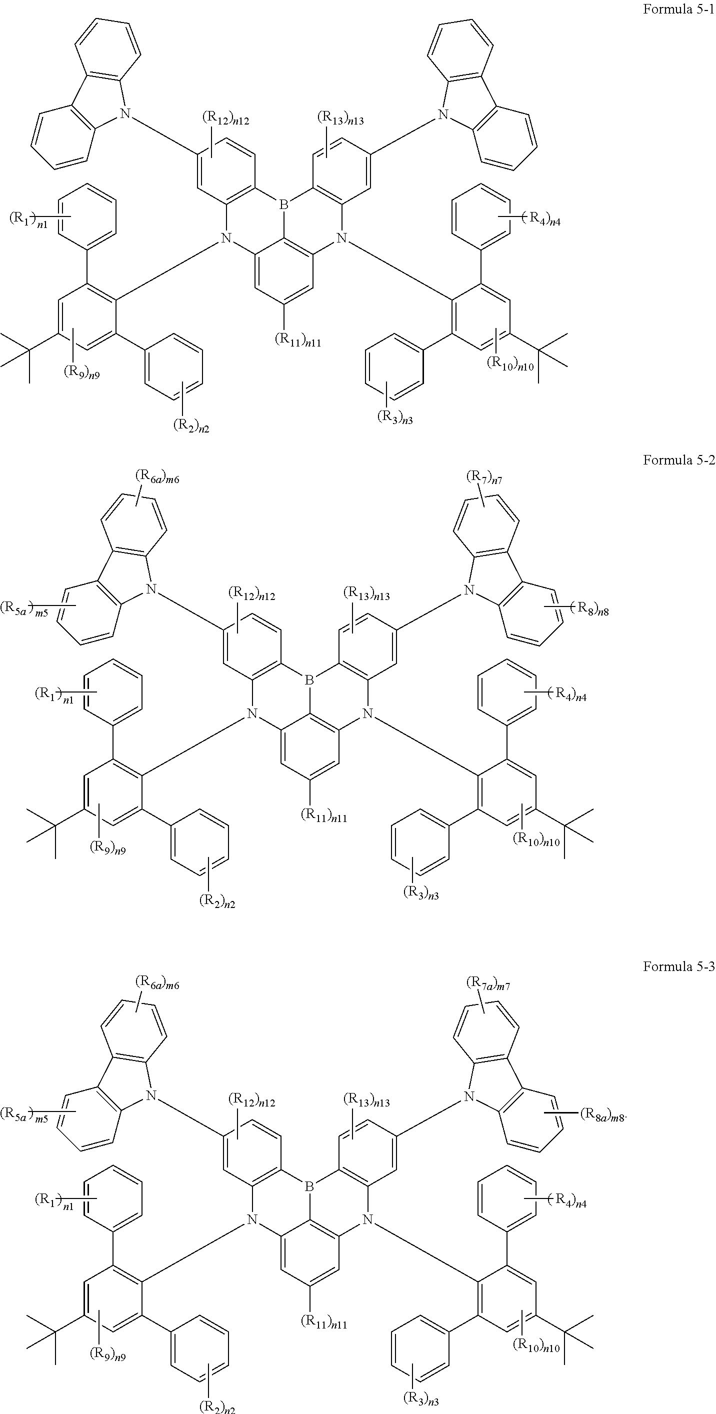

Formula 5-1 to Formula 5-3 represent Formula 1 in which the type or kind of at least one substituent among R₅ to R₈ is specified. Formula 5-1 represents an embodiment of Formula 1 in which the substituents represented by R₅ to R₈ are hydrogen atoms. Formula 5-2 represents an embodiment of Formula 1 in which the substituents represented by R₅ and R₆ are deuterium atoms. Formula 5-3 represents an embodiment of Formula 1 in which the substituents represented by R₅ to R₈ are deuterium atoms.

In Formula 5-1 to Formula 5-3, R₅ₐ to R₈ₐ may be deuterium atoms.

In Formula 5-2 and Formula 5-3, m5 to m8 may each independently be an integer from 1 to 4. In an embodiment, m5 to m8 may each be 4.

In Formula 5-1 to Formula 5-3, the same contents/definitions explained in Formula 1 may be applied for R₁ to R₄, R₇ to R₁₃, n1 to n4, and n7 to n13.

In an embodiment, the fused polycyclic compound represented by Formula 1 may be represented by Formula 6.

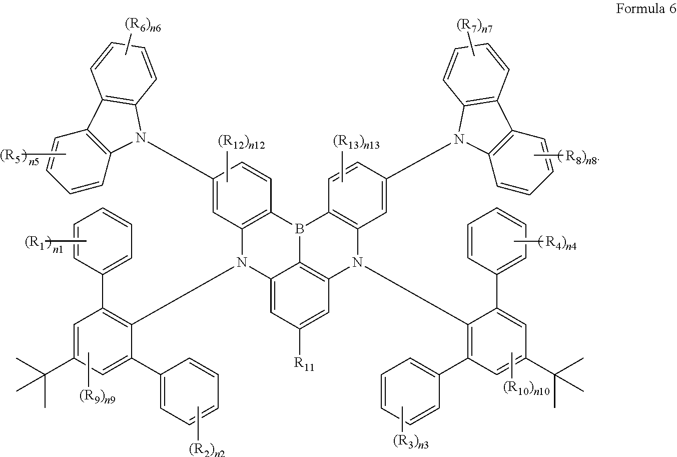

Formula 6 represents Formula 1 in which the substitution position of a substituent represented by R₁₁ is specified. Formula 6 represents an embodiment of Formula 1 in which the substituent represented by R₁₁ is substituted at the para position with respect to a boron atom.

In Formula 6, the same contents/definitions explained in Formula 1 may be applied for R₁ to R₁₃, n1 to n10, n12, and n13.

In an embodiment, R₁₁ may be a hydrogen atom, a substituted or unsubstituted alkyl group of 1 to 10 carbon atoms, or a substituted or unsubstituted cycloalkyl group of 3 to 10 ring-forming carbon atoms. For example, R₁₁ may be a hydrogen atom, a substituted or unsubstituted methyl group, a substituted or unsubstituted isopropyl group, a substituted or unsubstituted t-butyl group, or a substituted or unsubstituted cyclohexyl group.

The fused polycyclic compound of an embodiment may be any one selected from among the compounds represented in Compound Group 1. The light emitting device ED of an embodiment may include at least one fused polycyclic compound selected from among the compounds represented in Compound Group 1. Compound Group 1

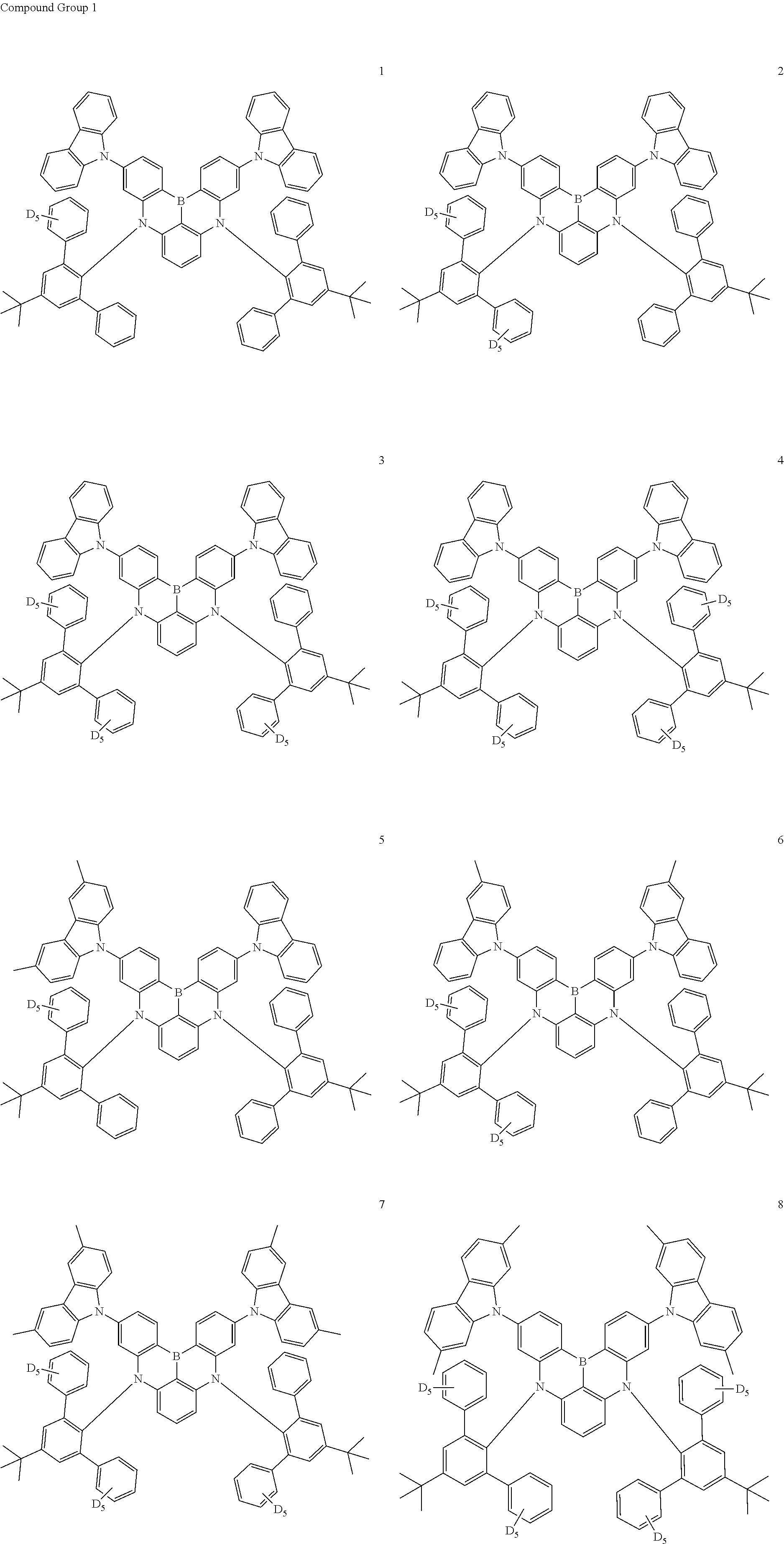

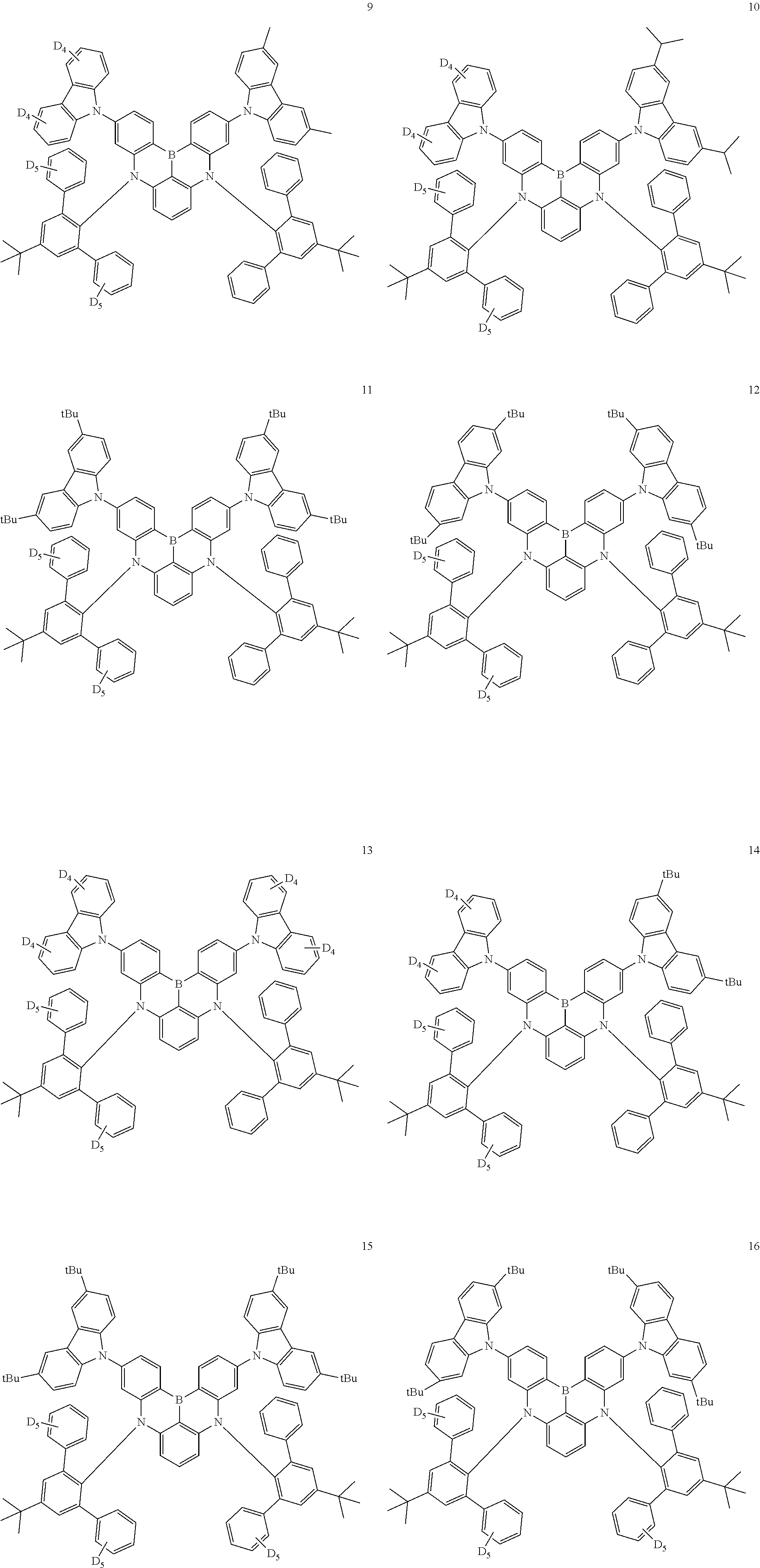

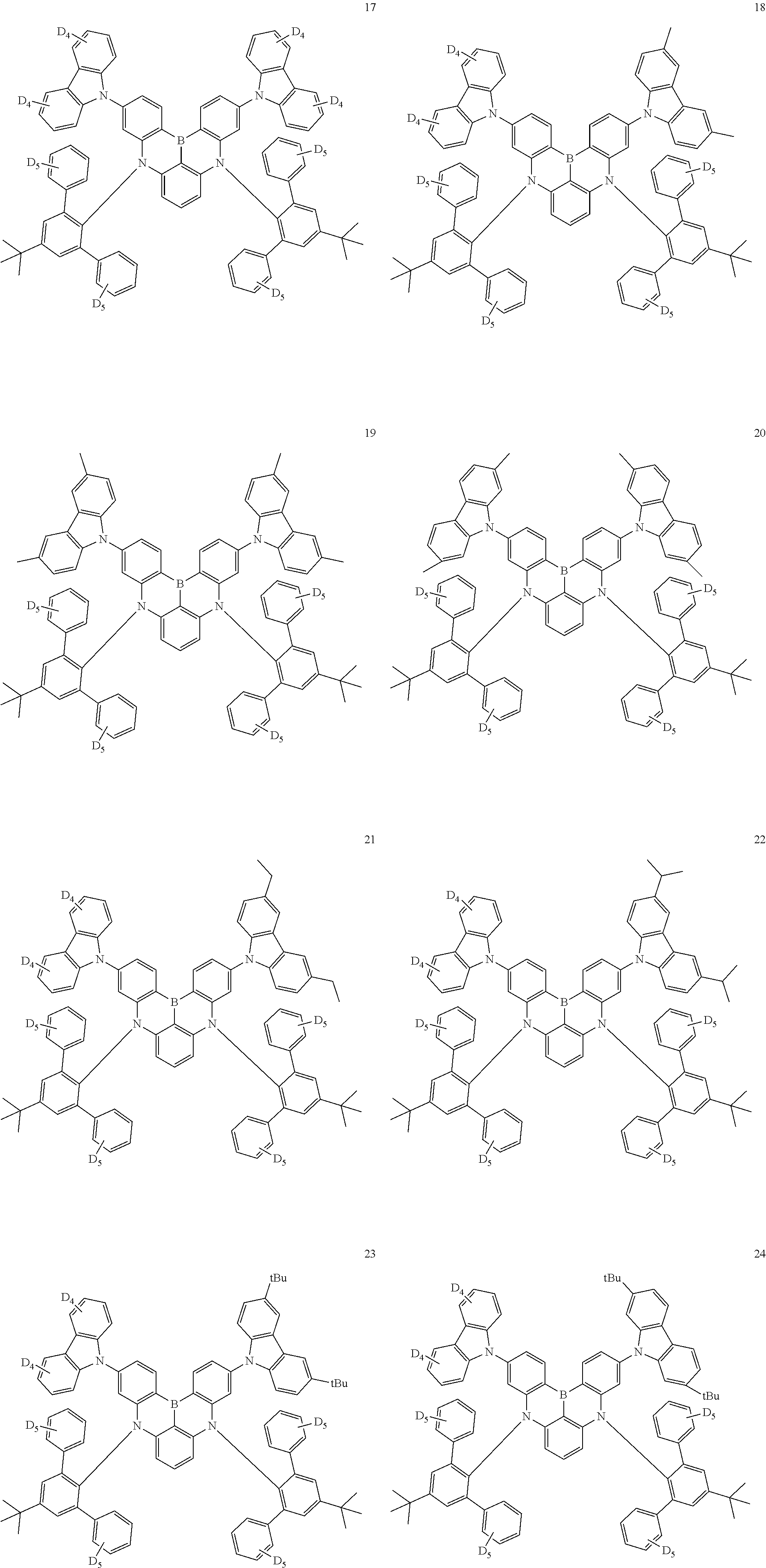

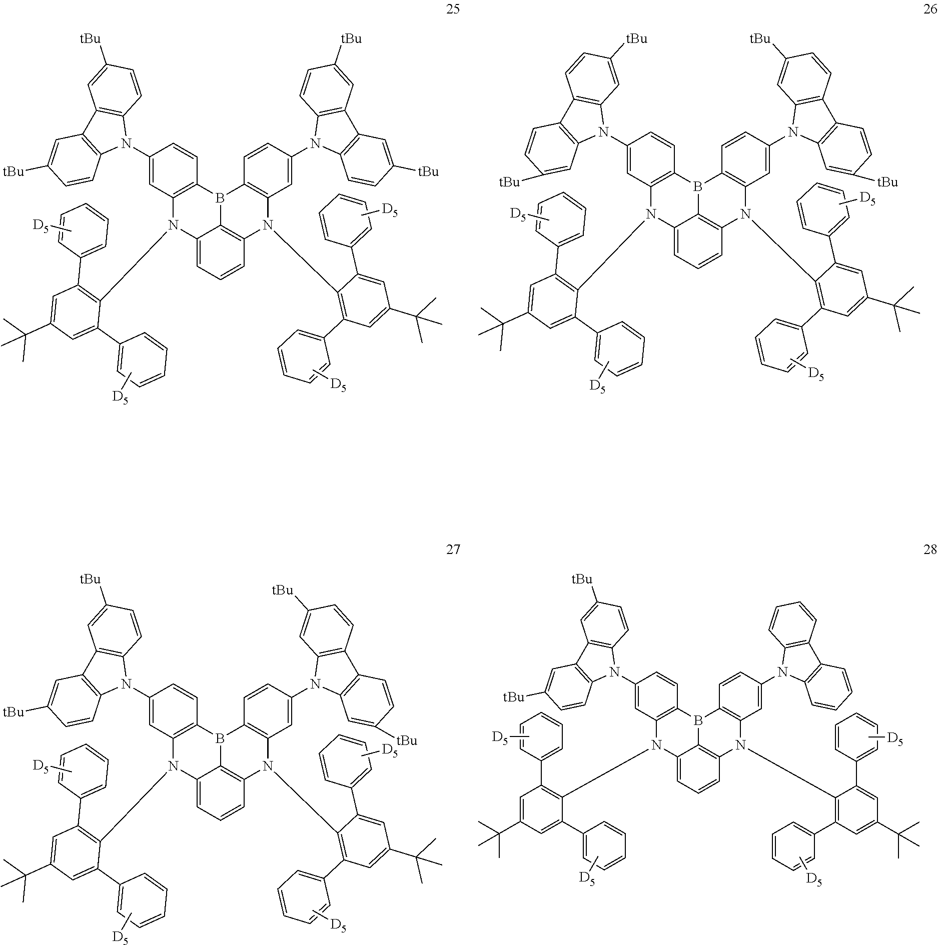

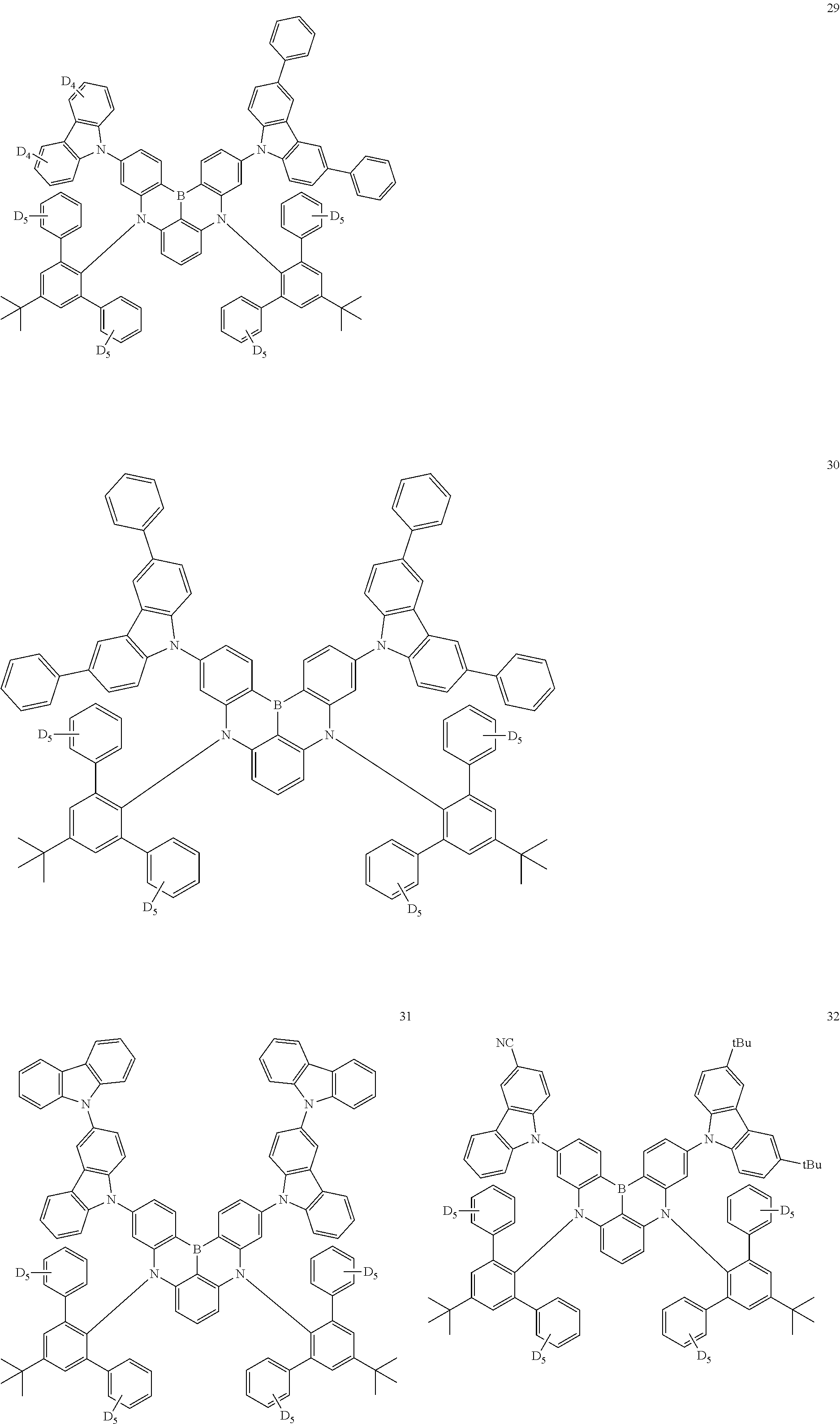

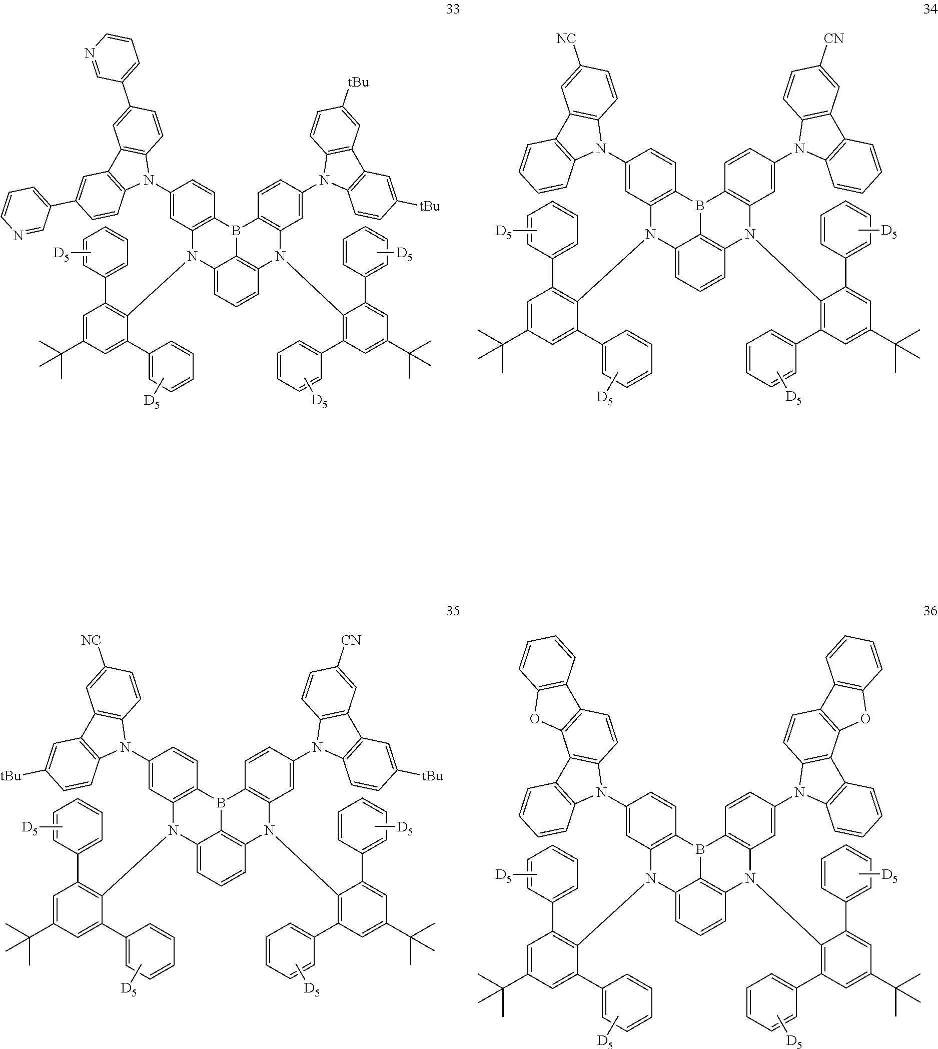

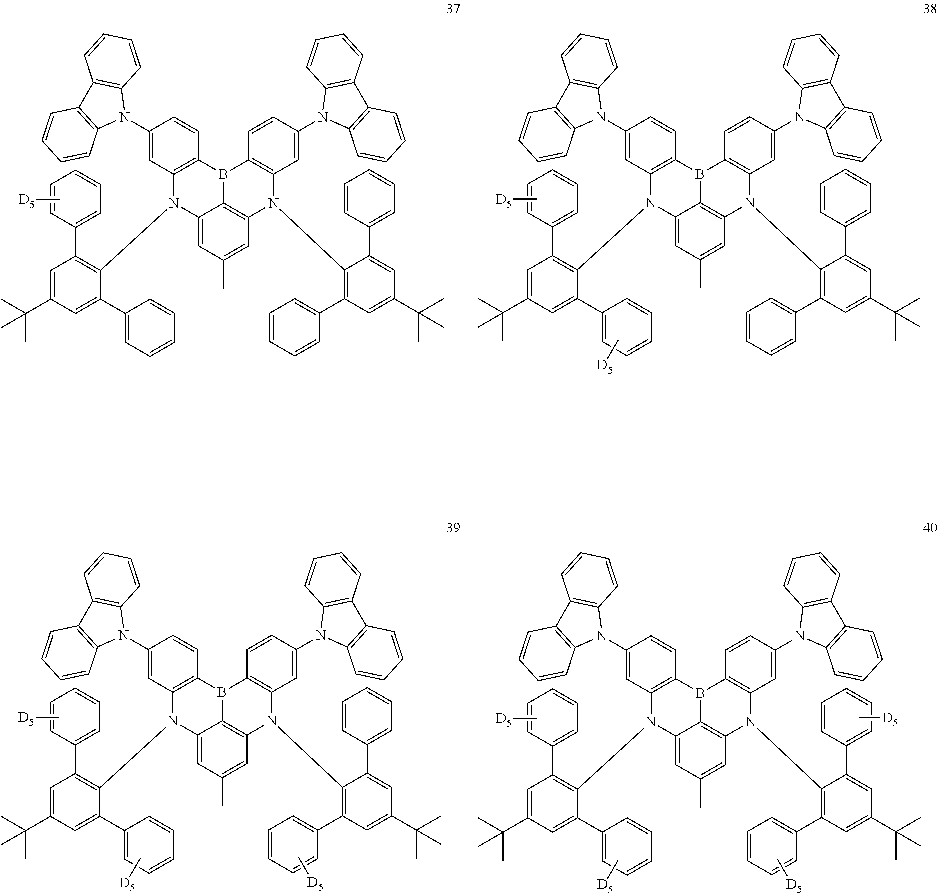

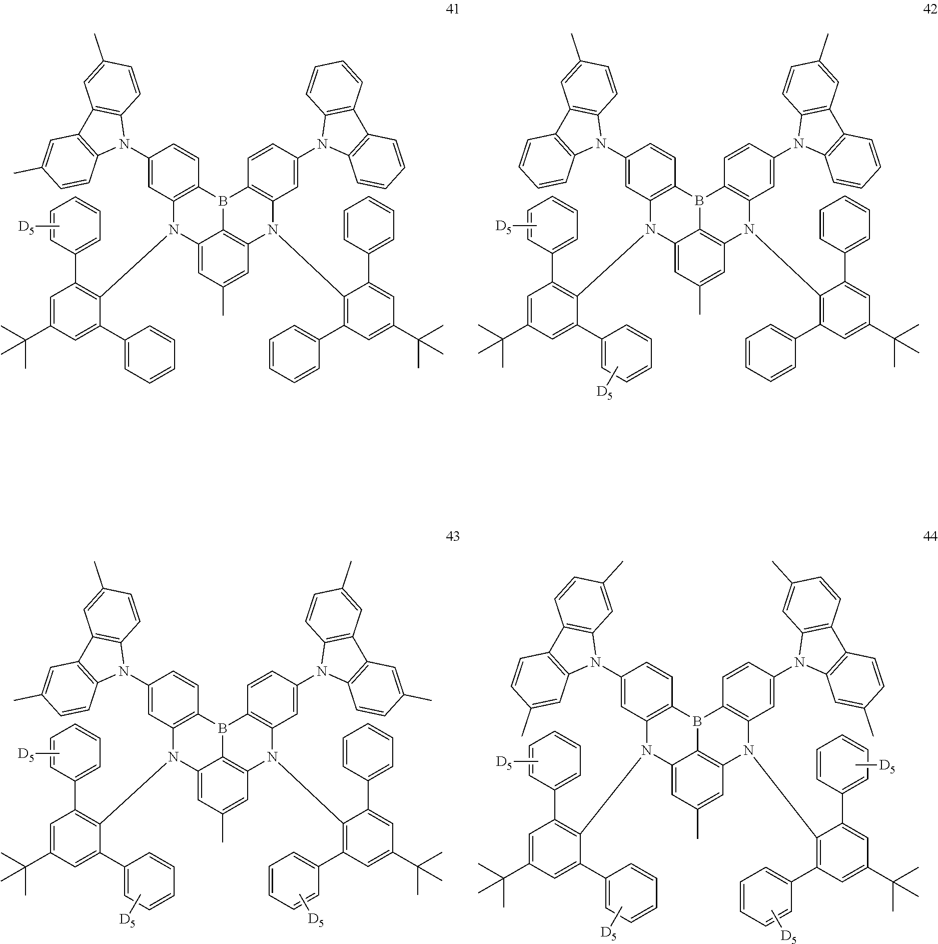

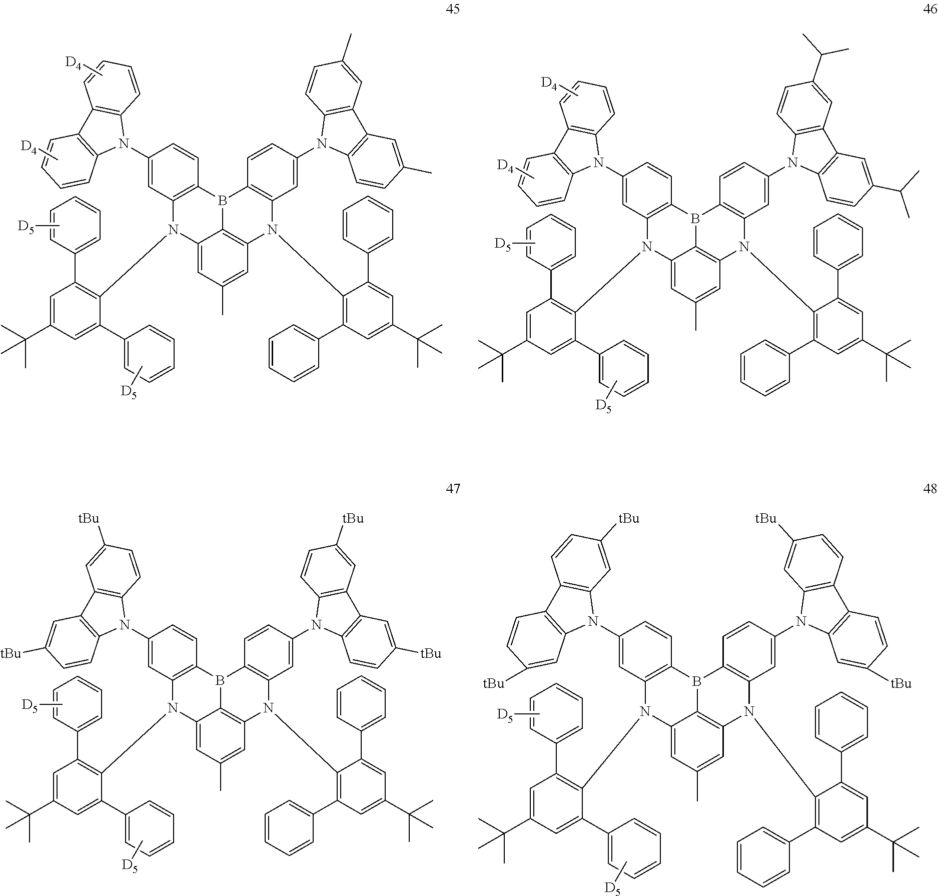

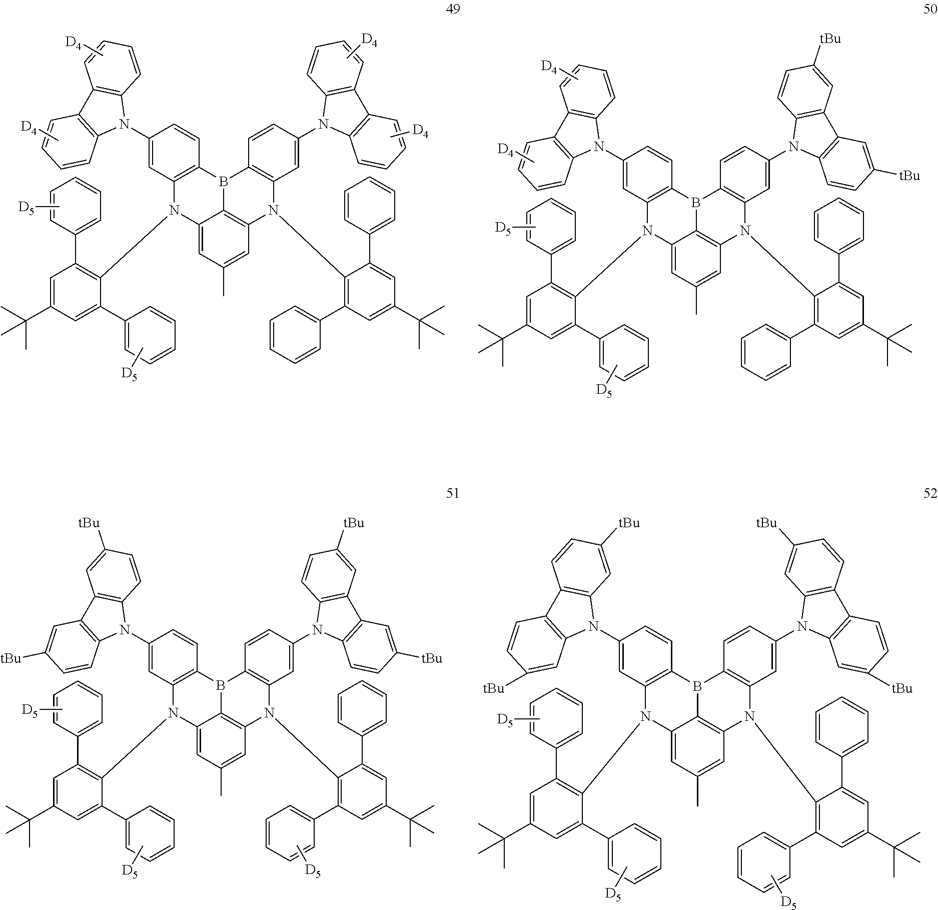

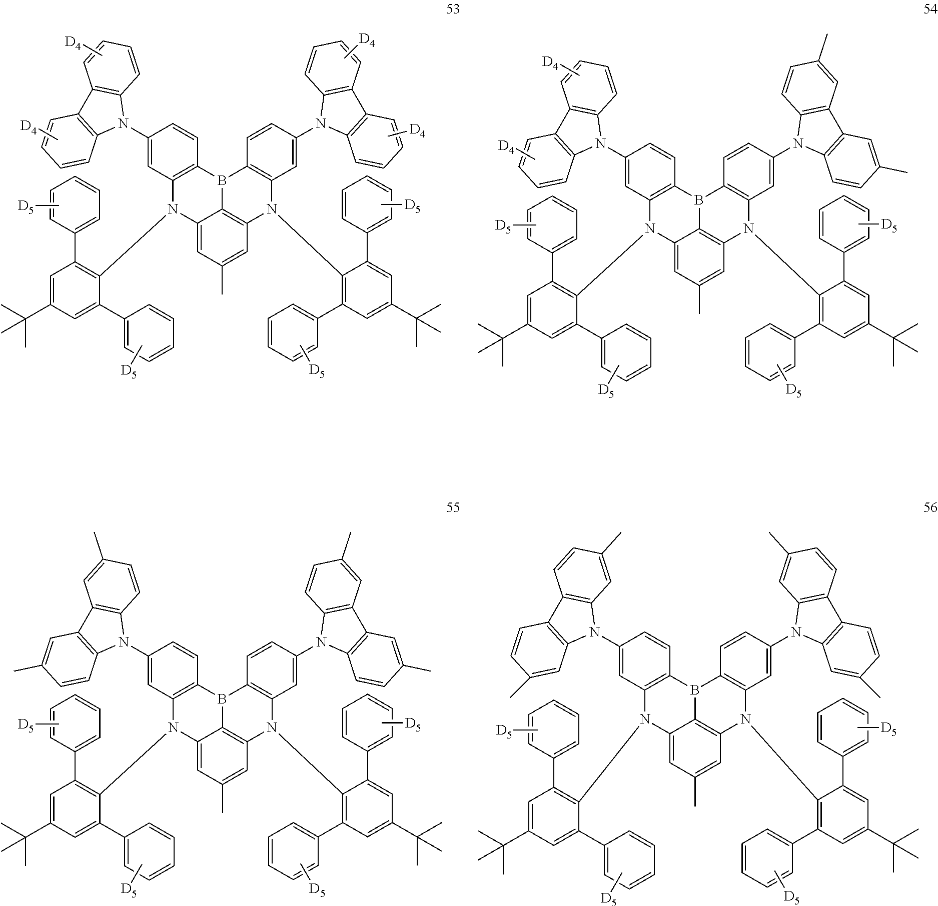

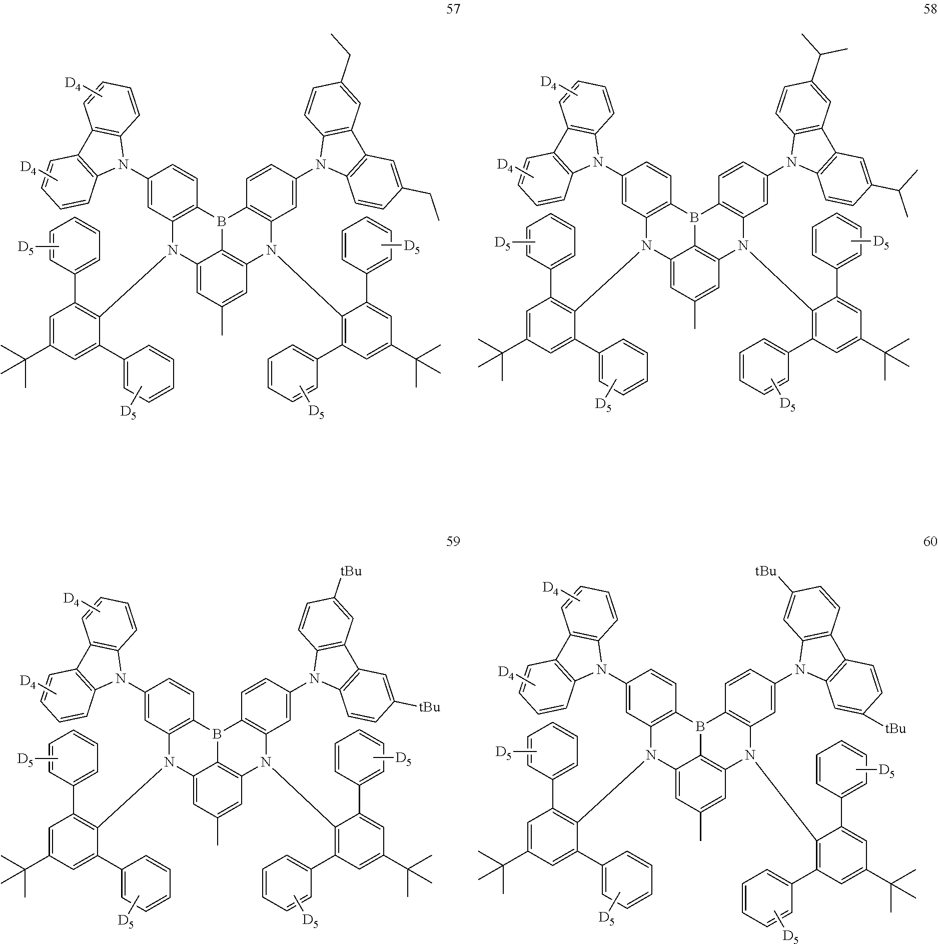

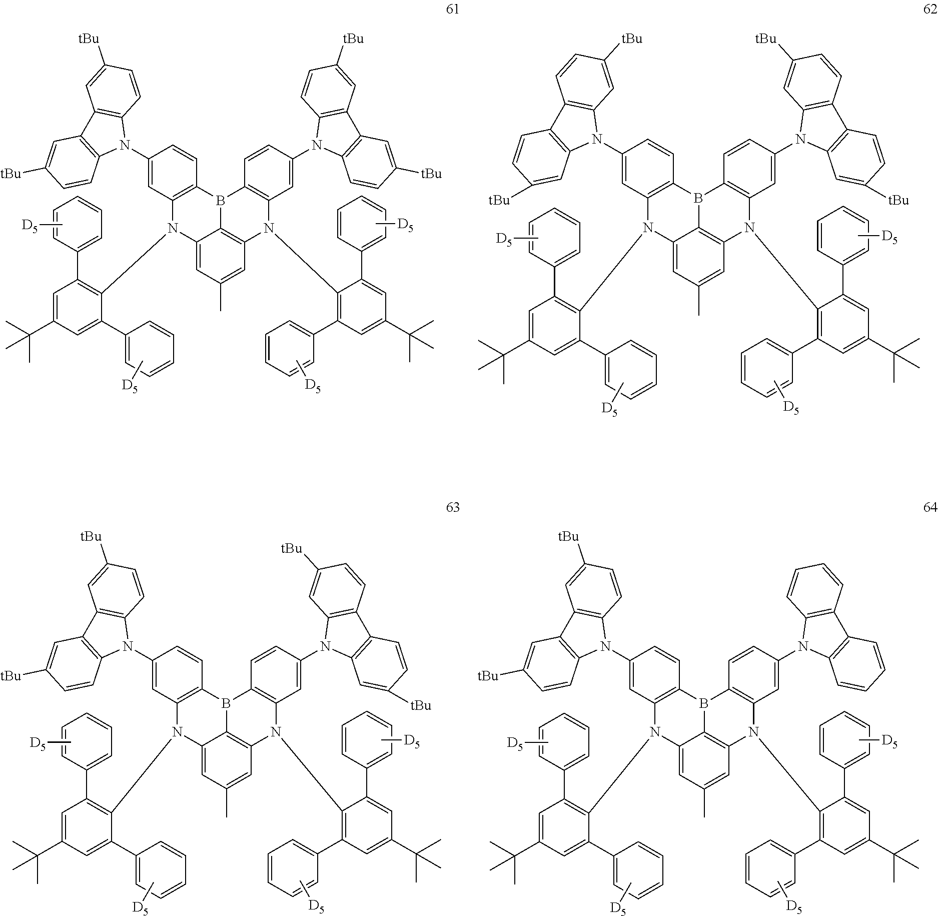

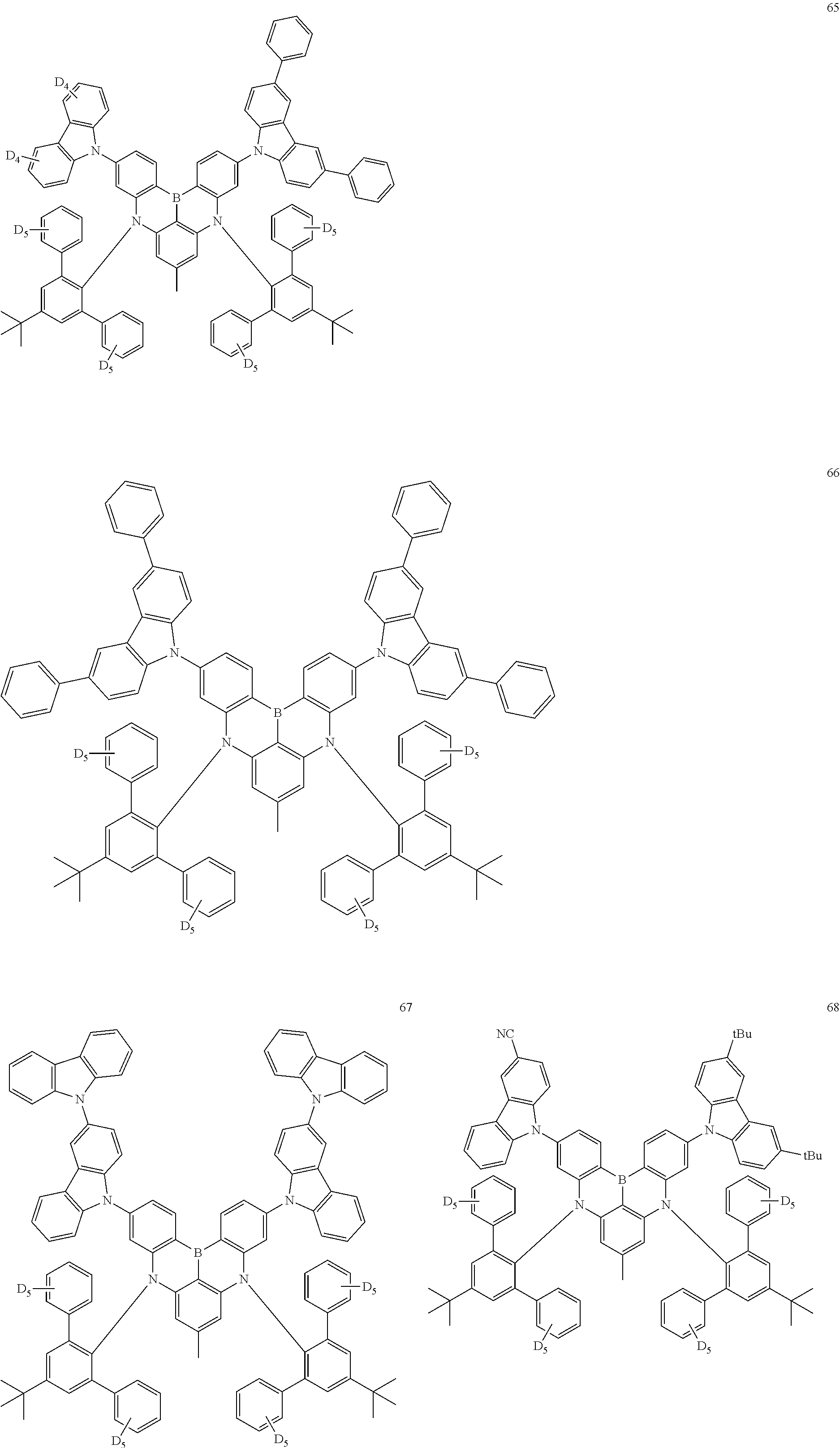

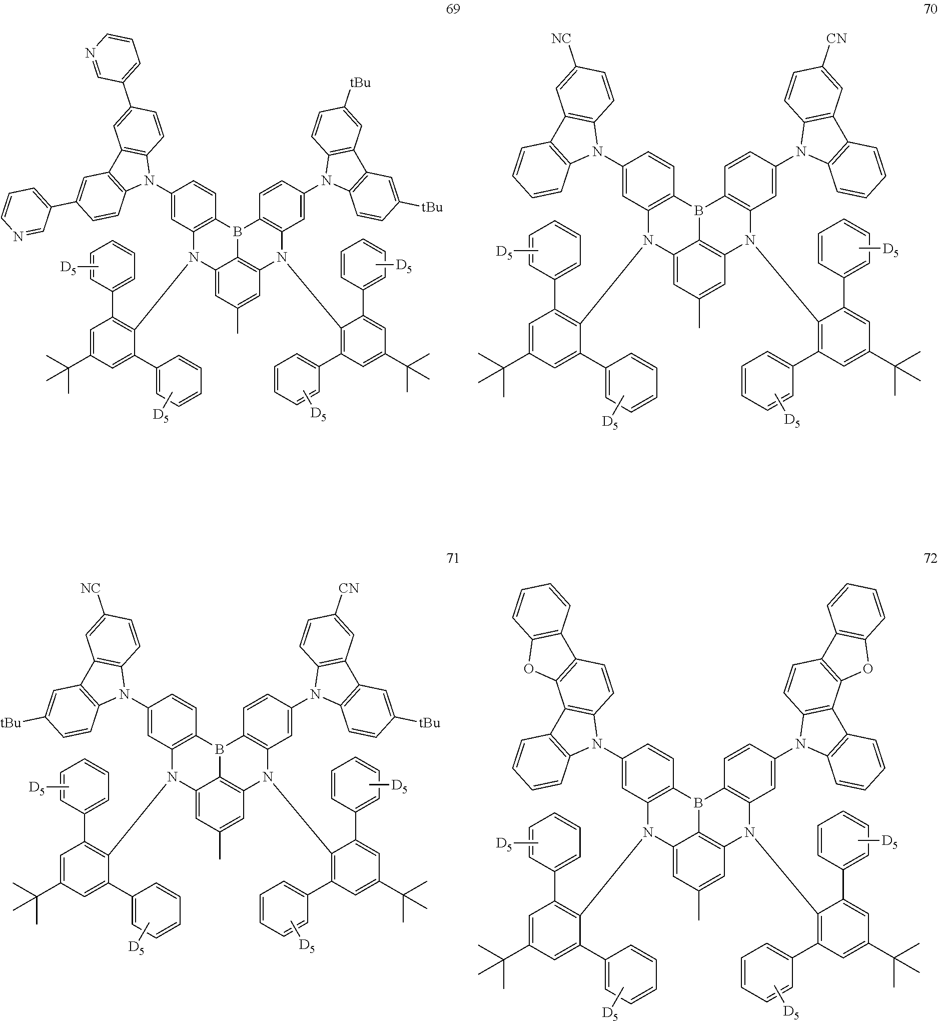

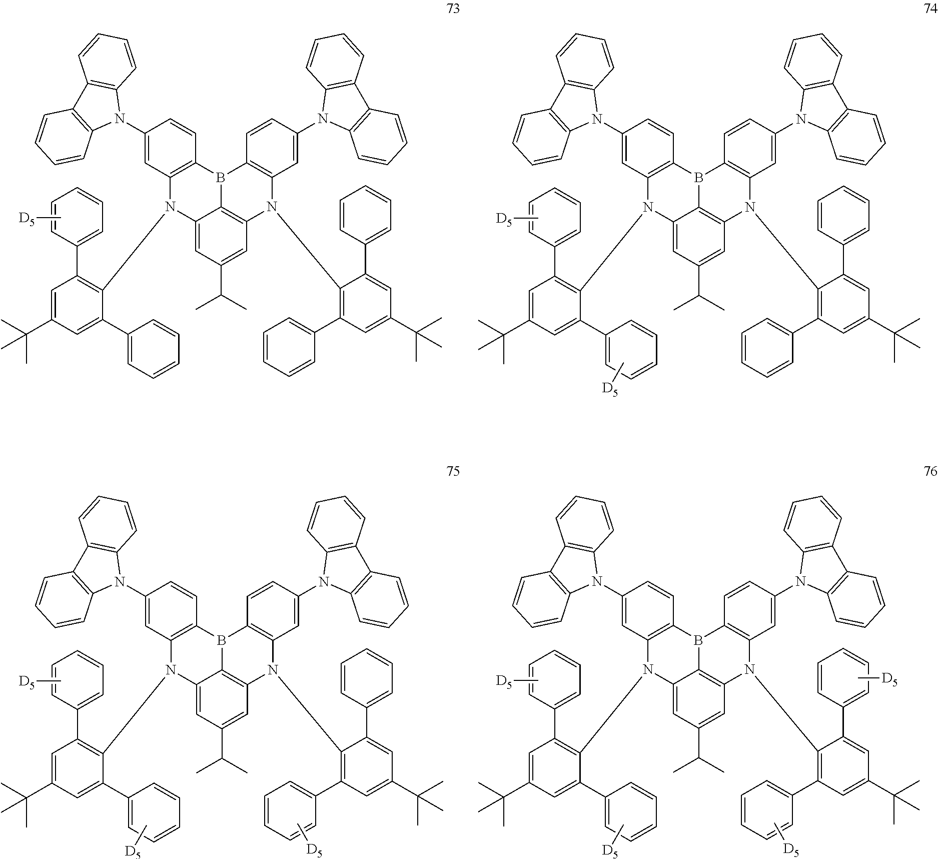

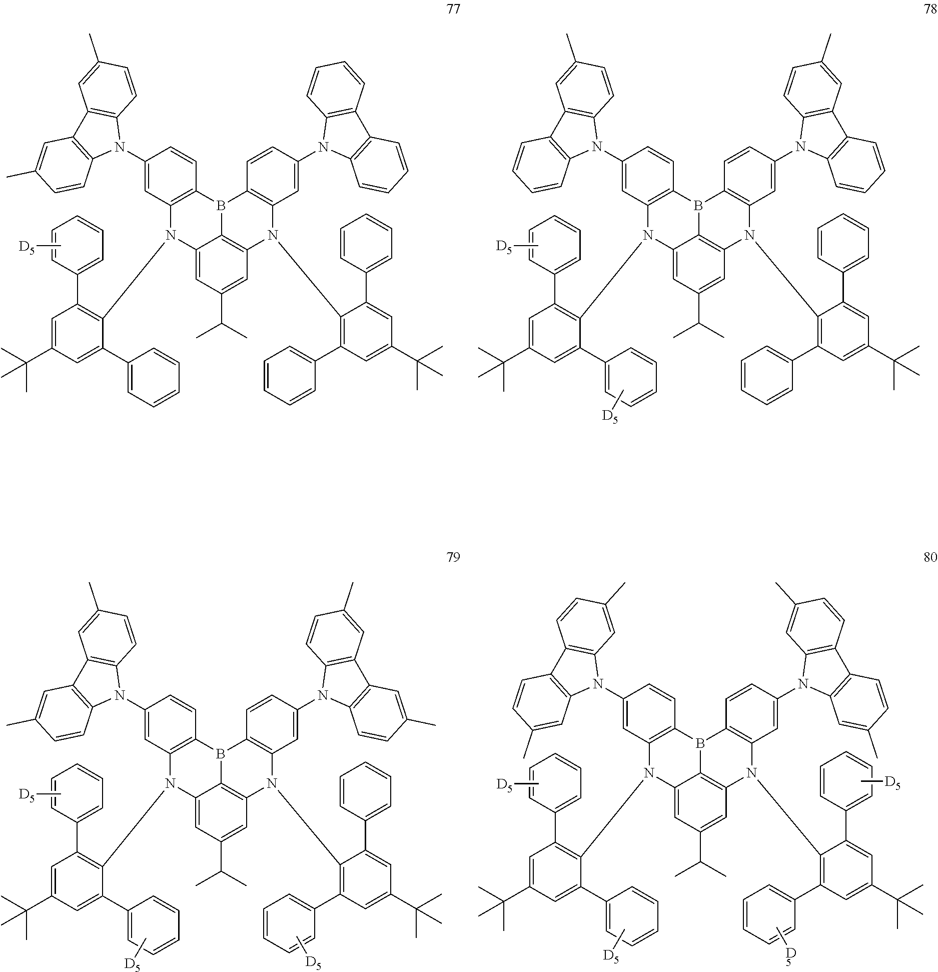

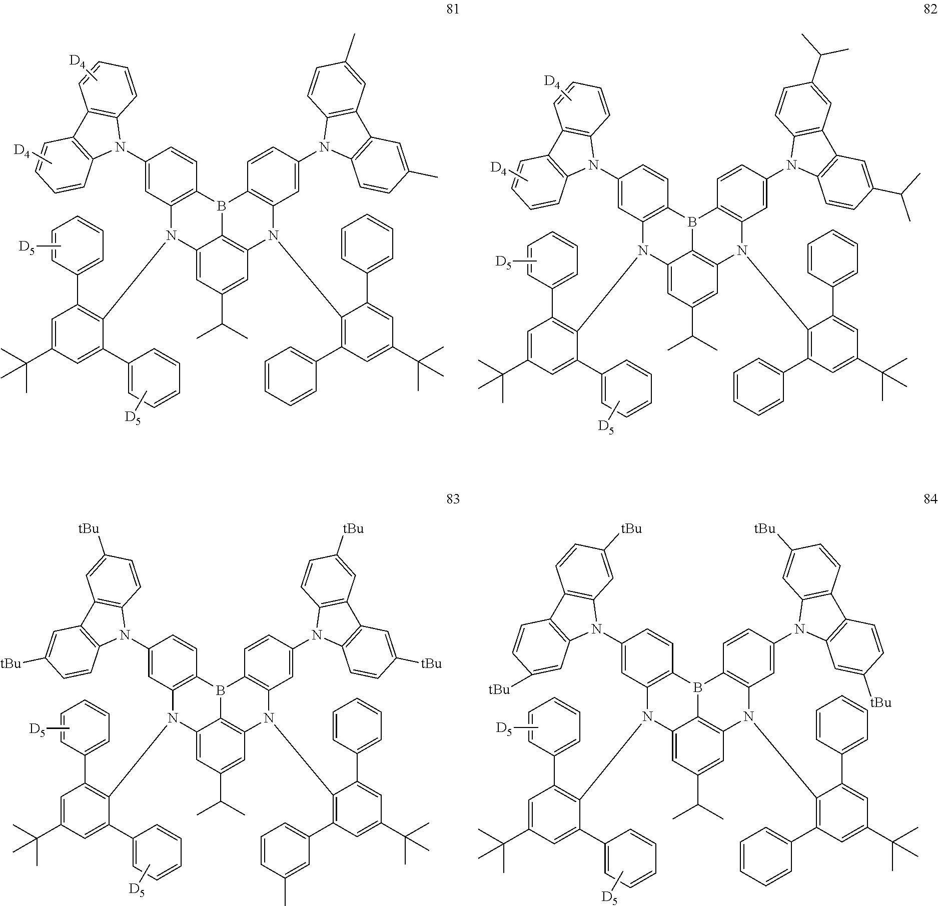

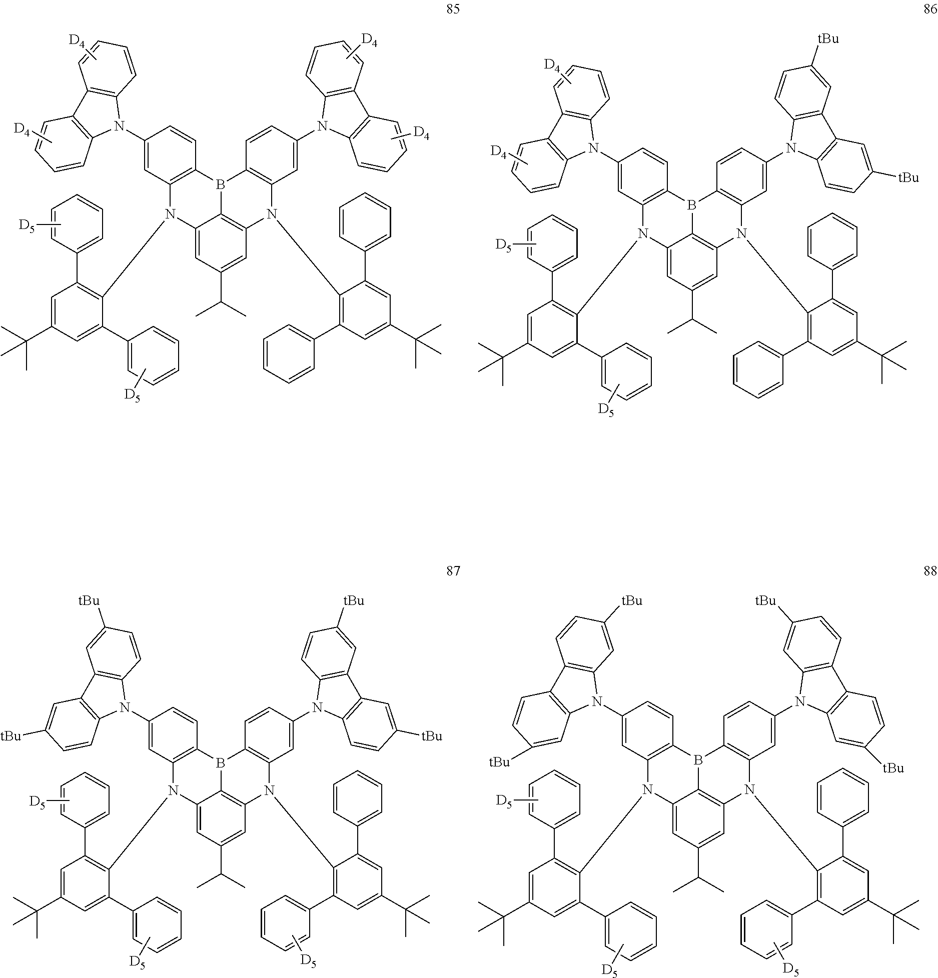

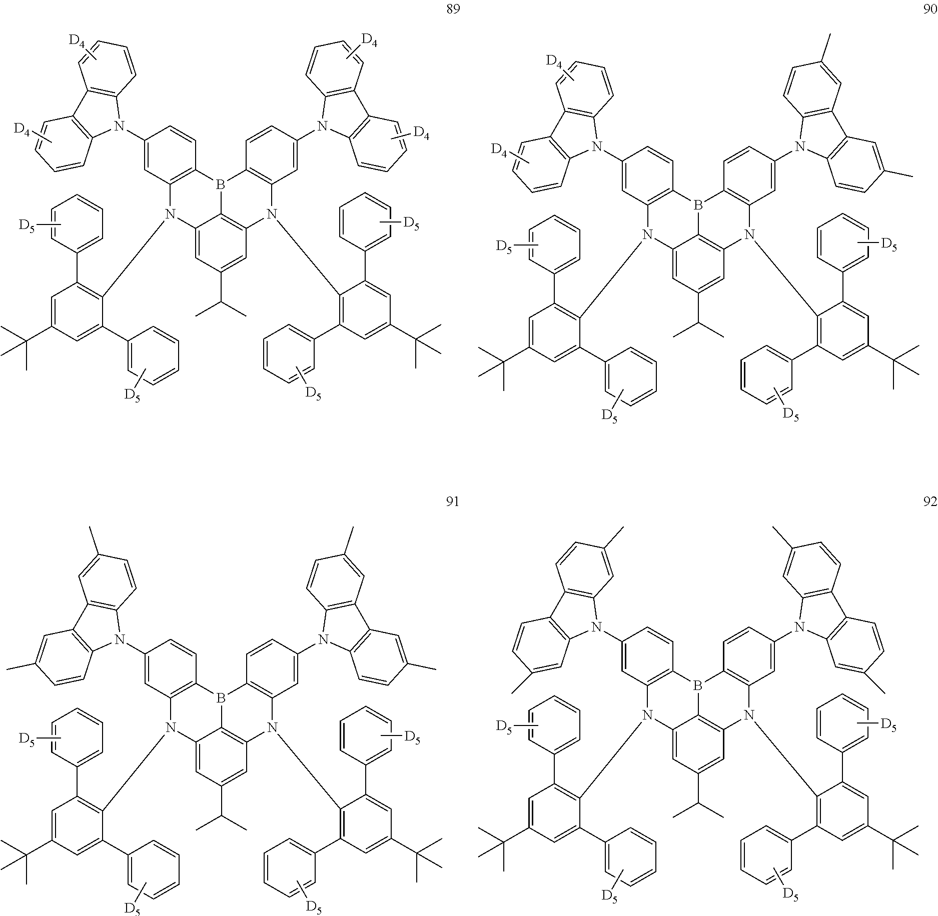

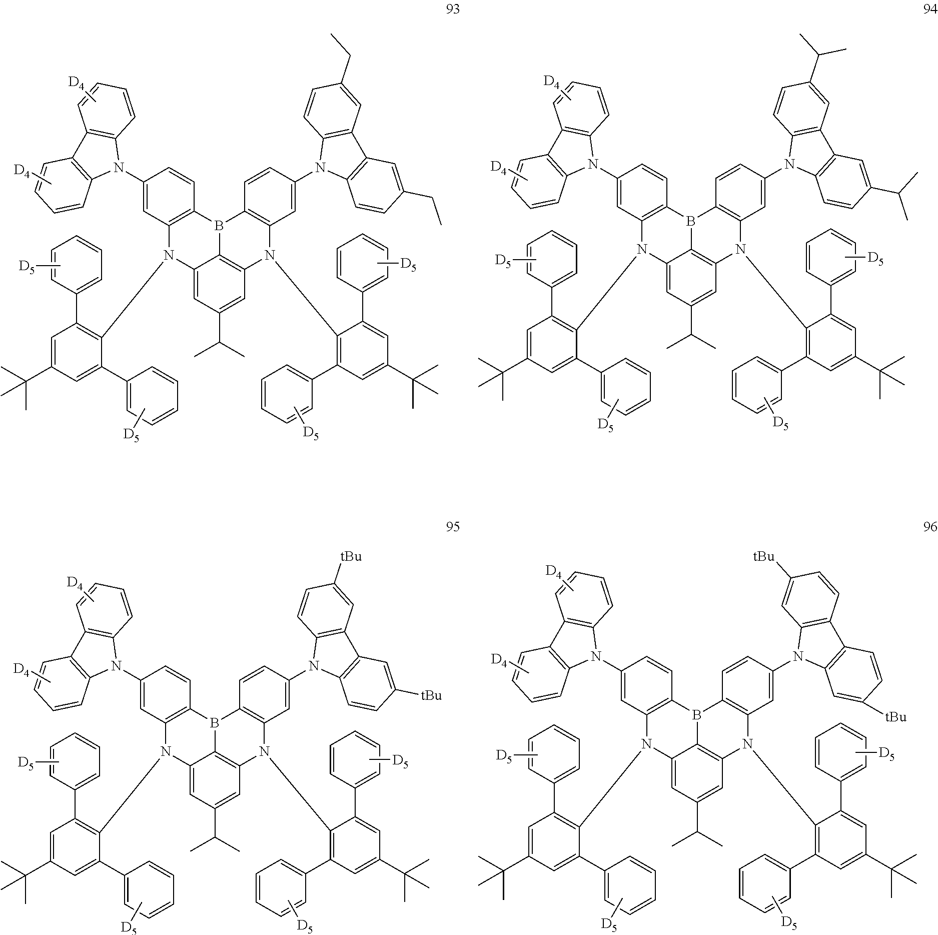

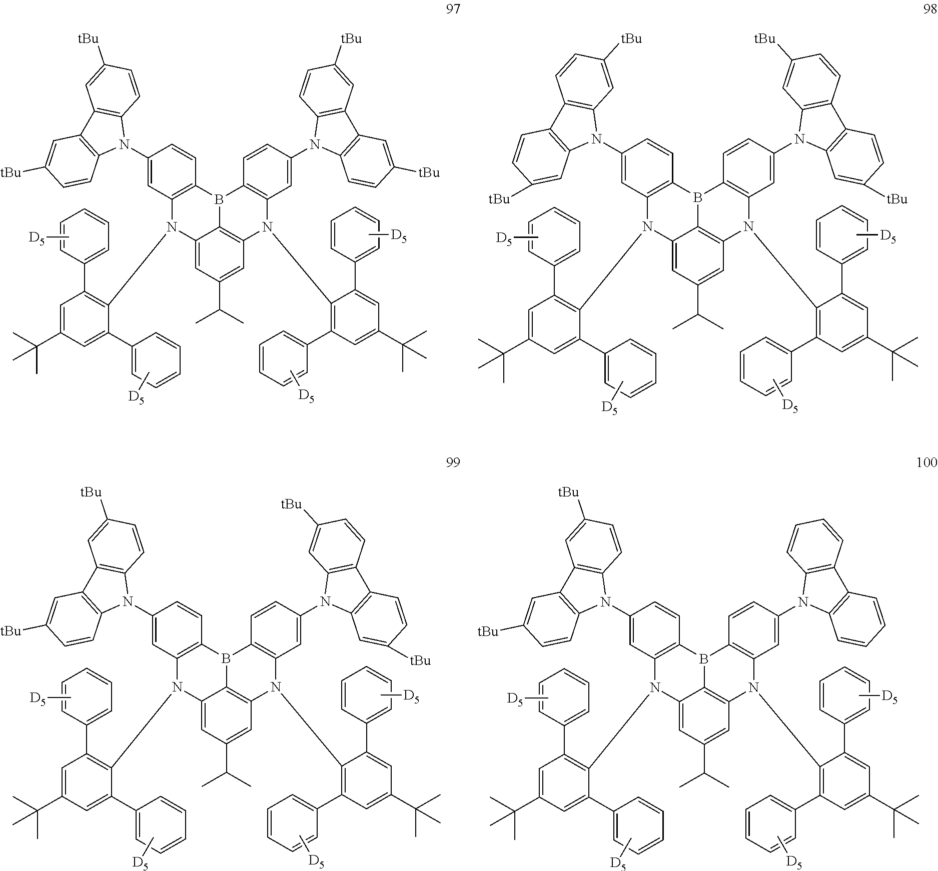

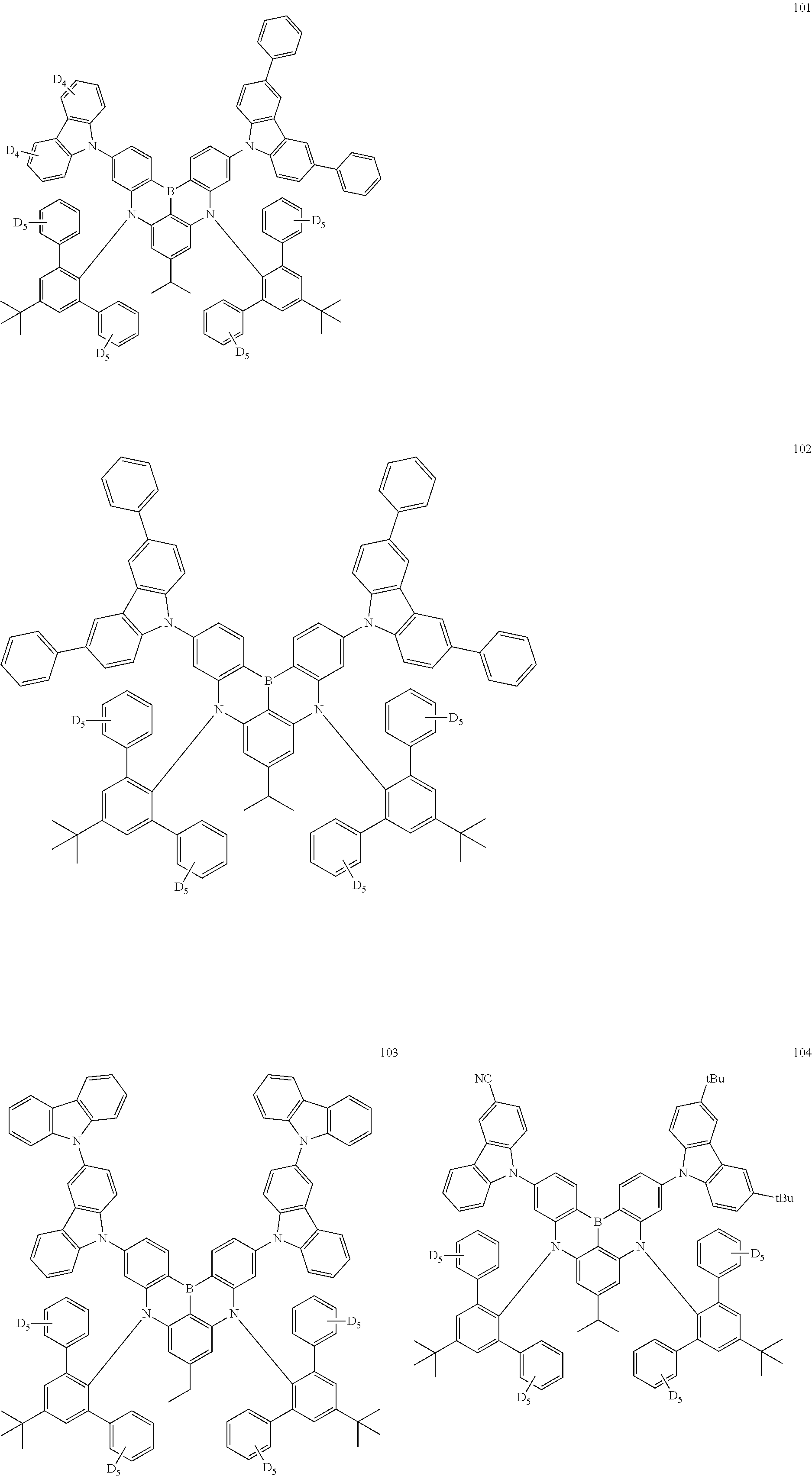

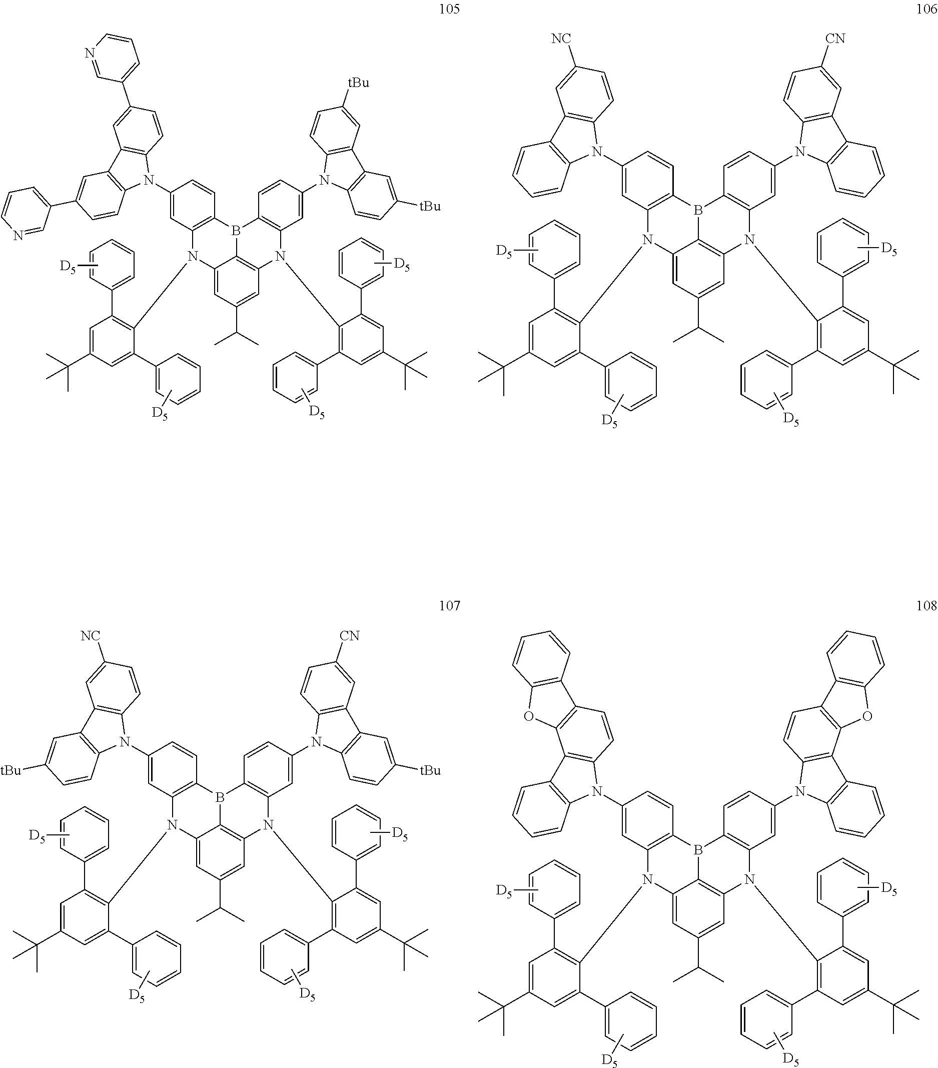

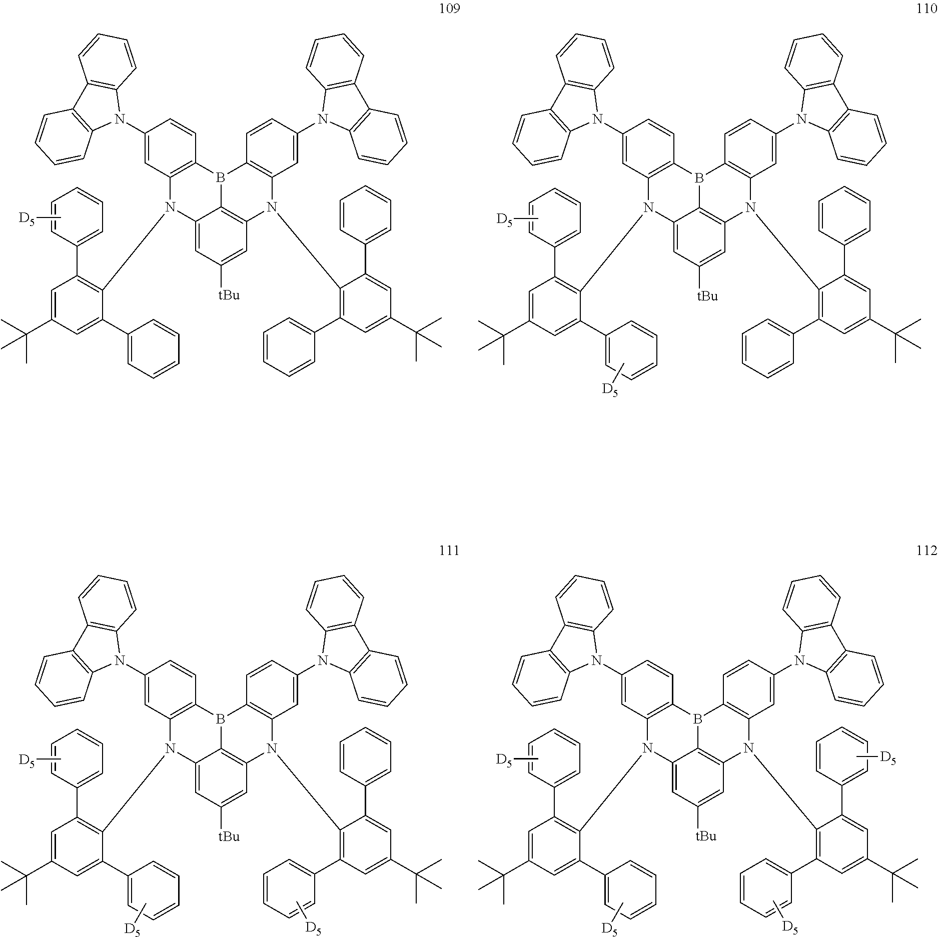

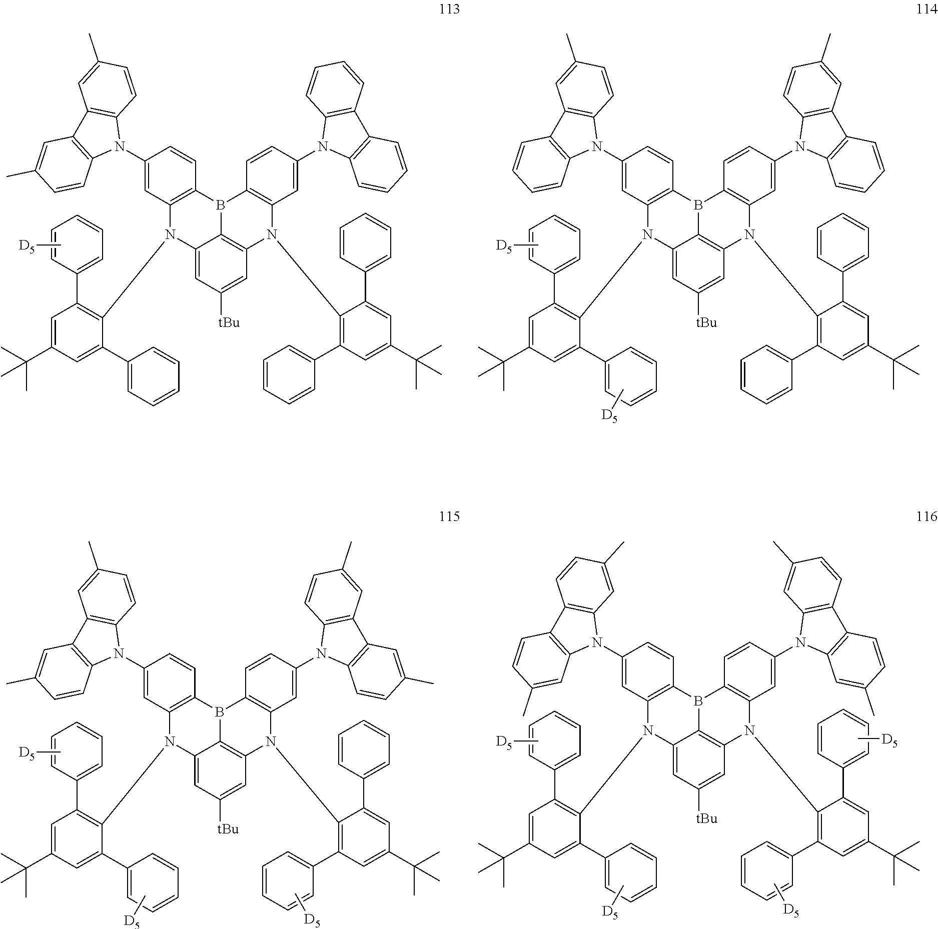

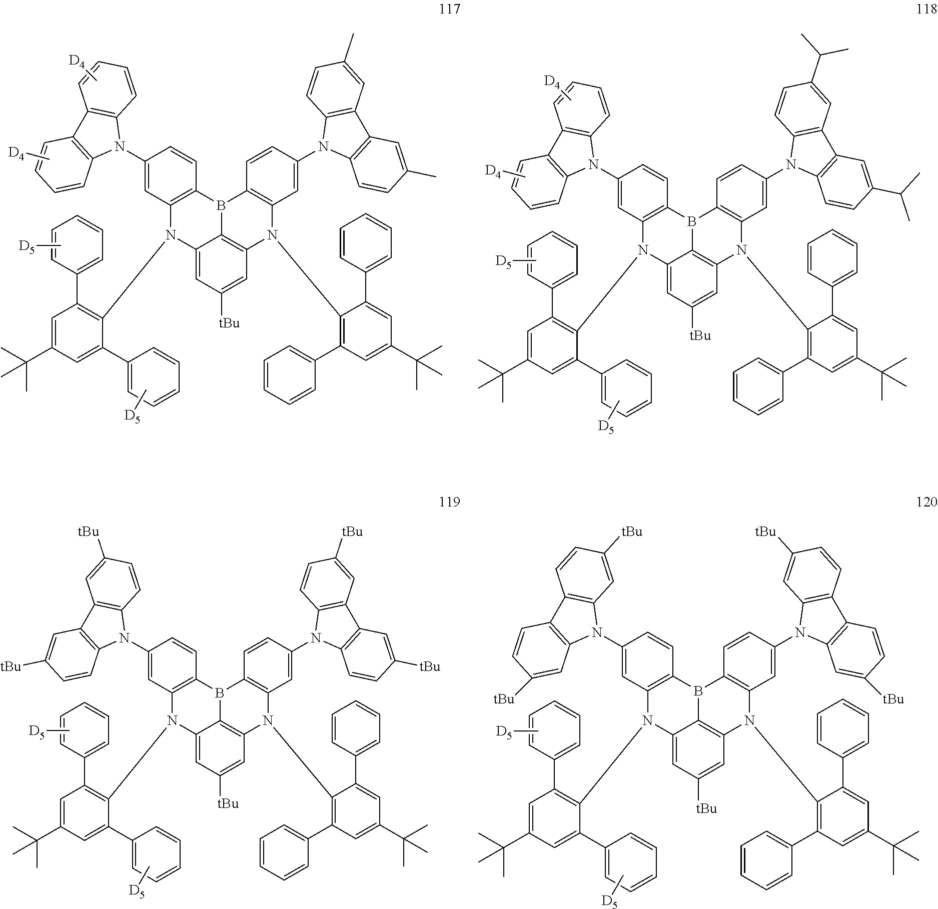

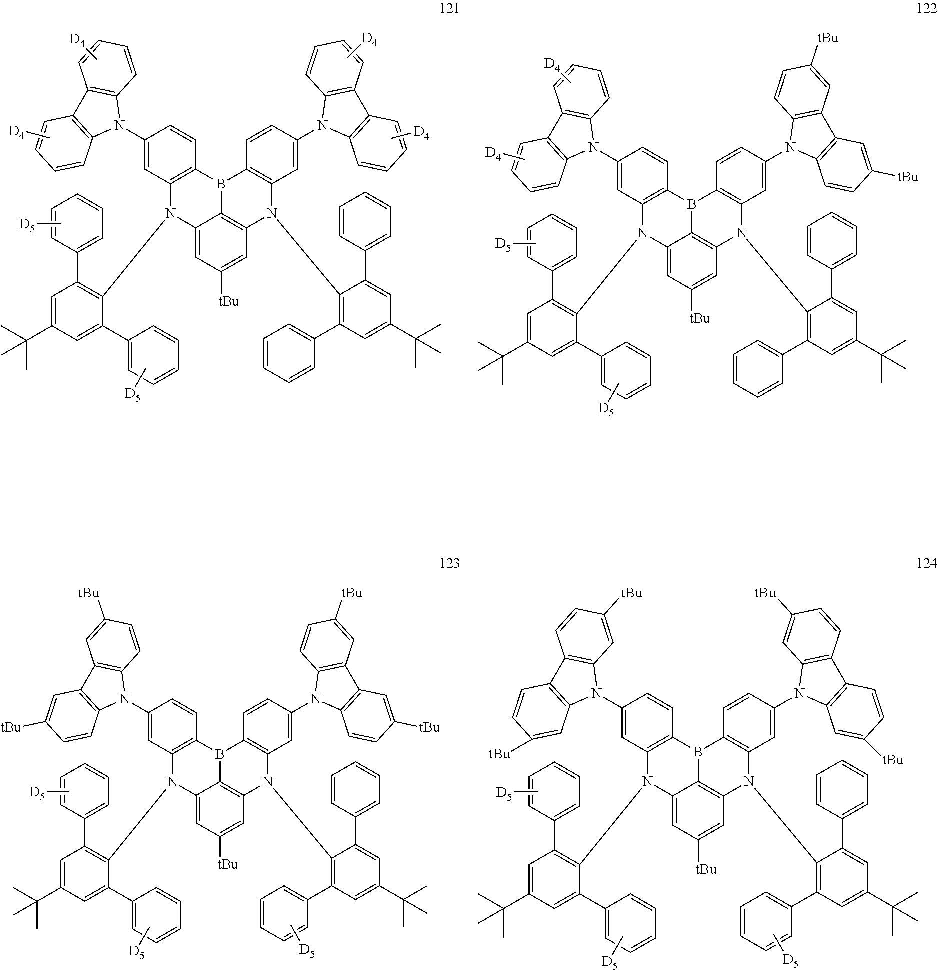

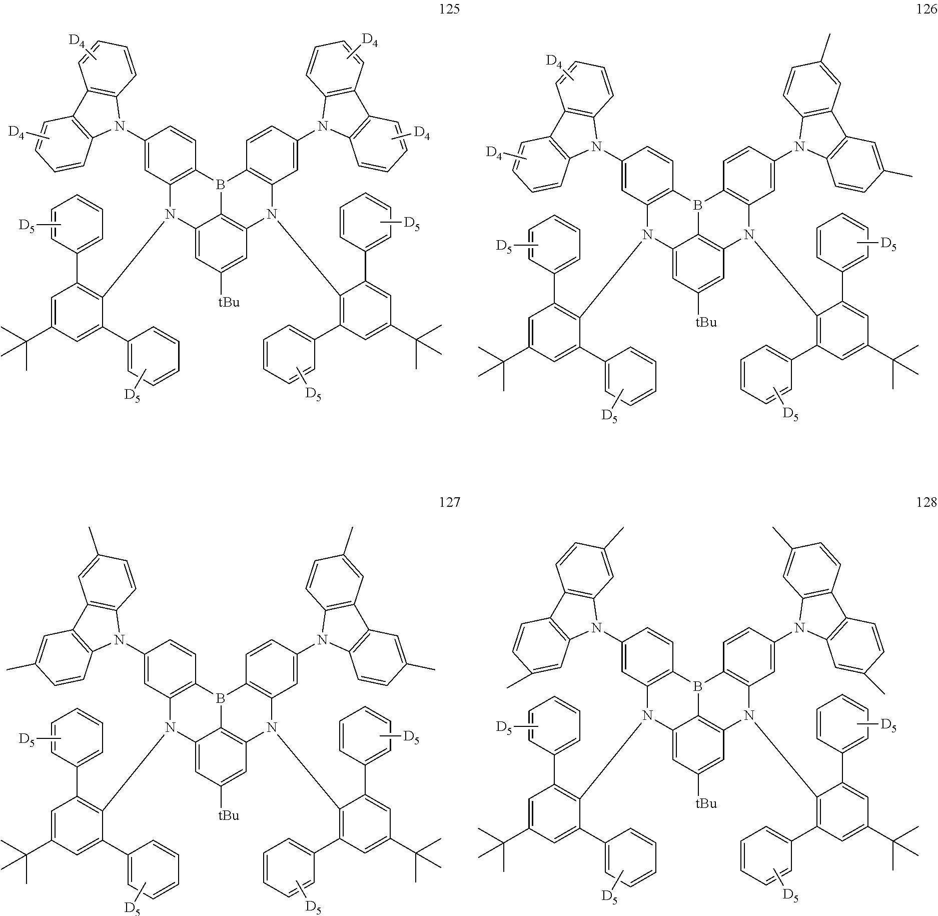

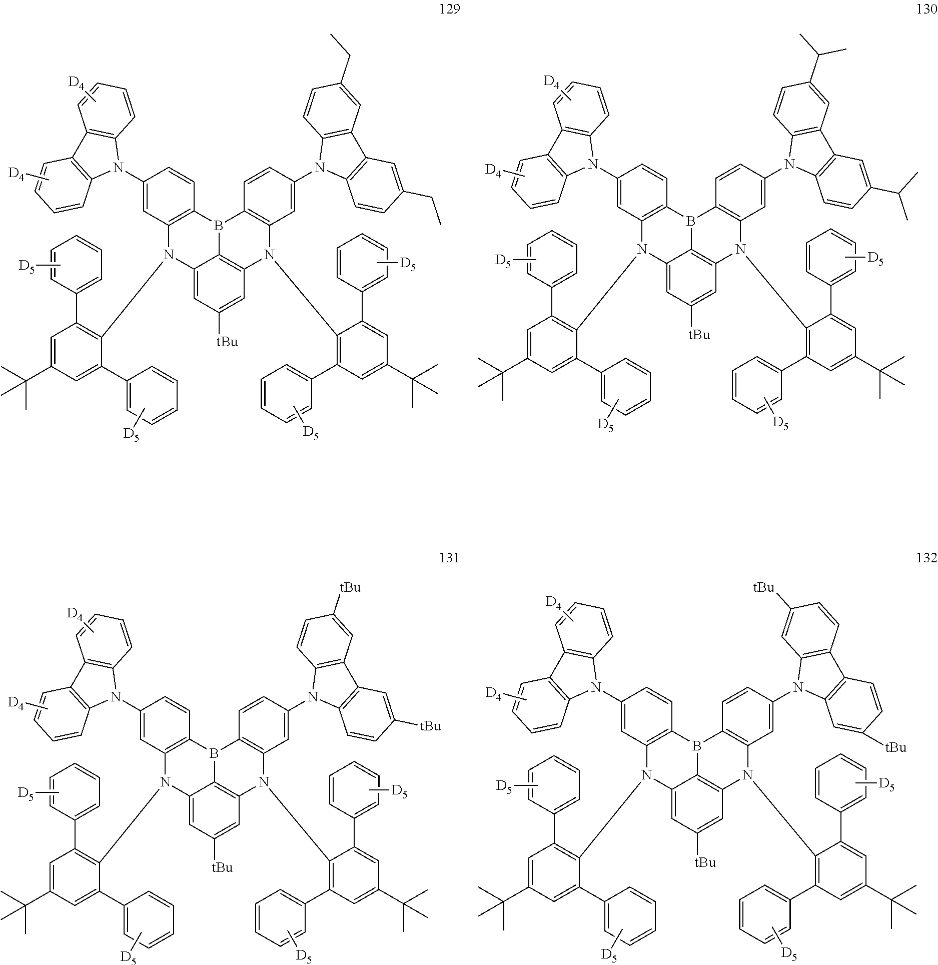

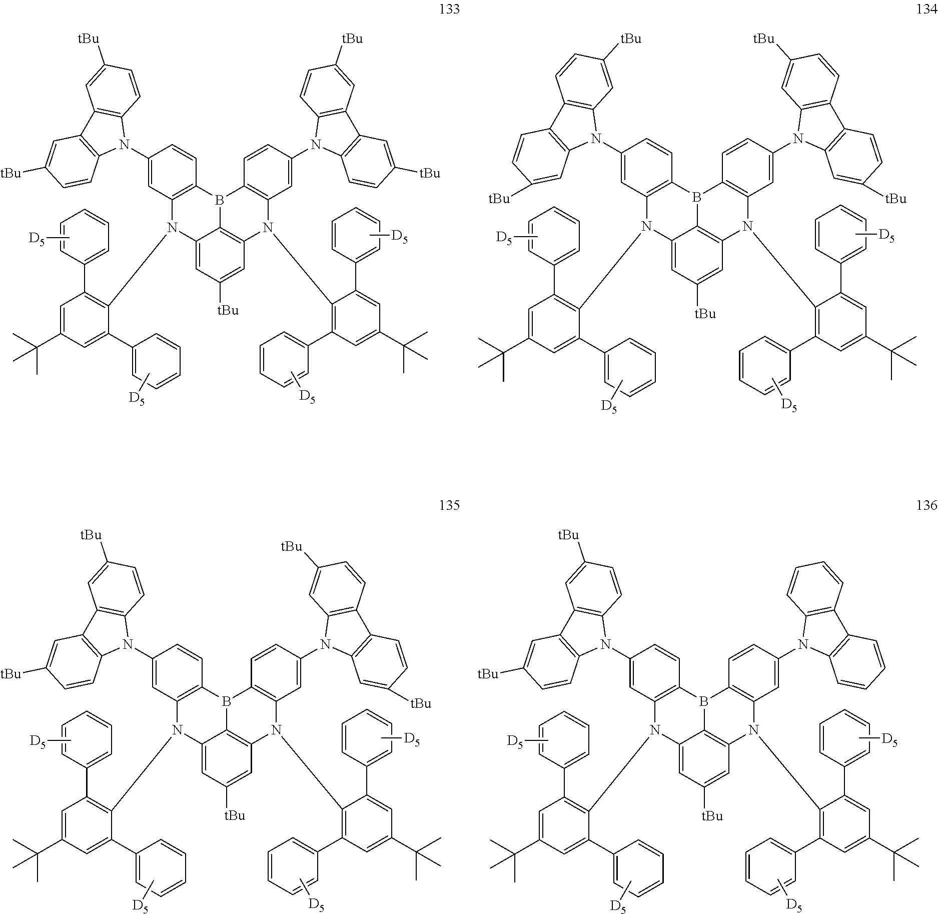

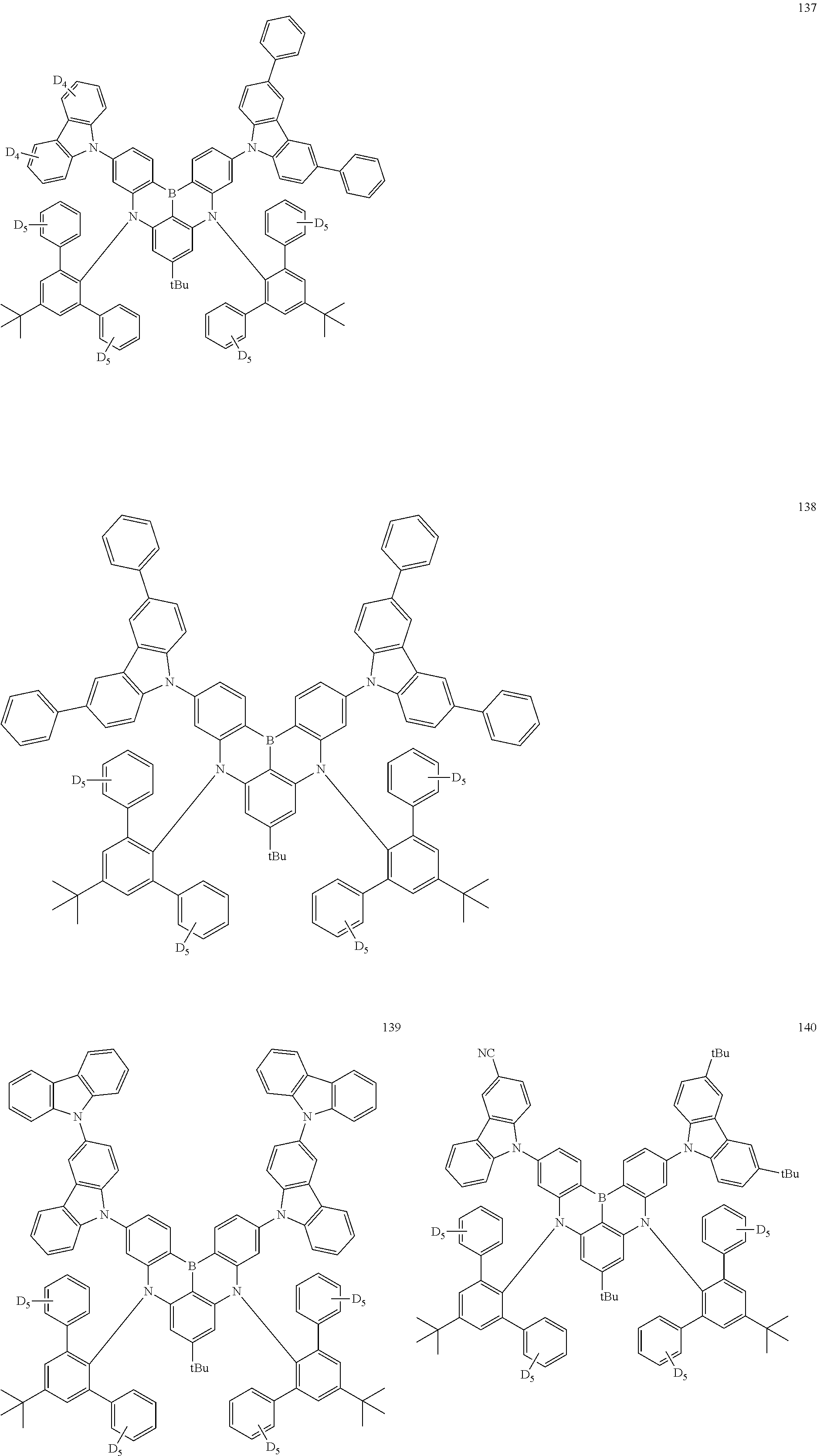

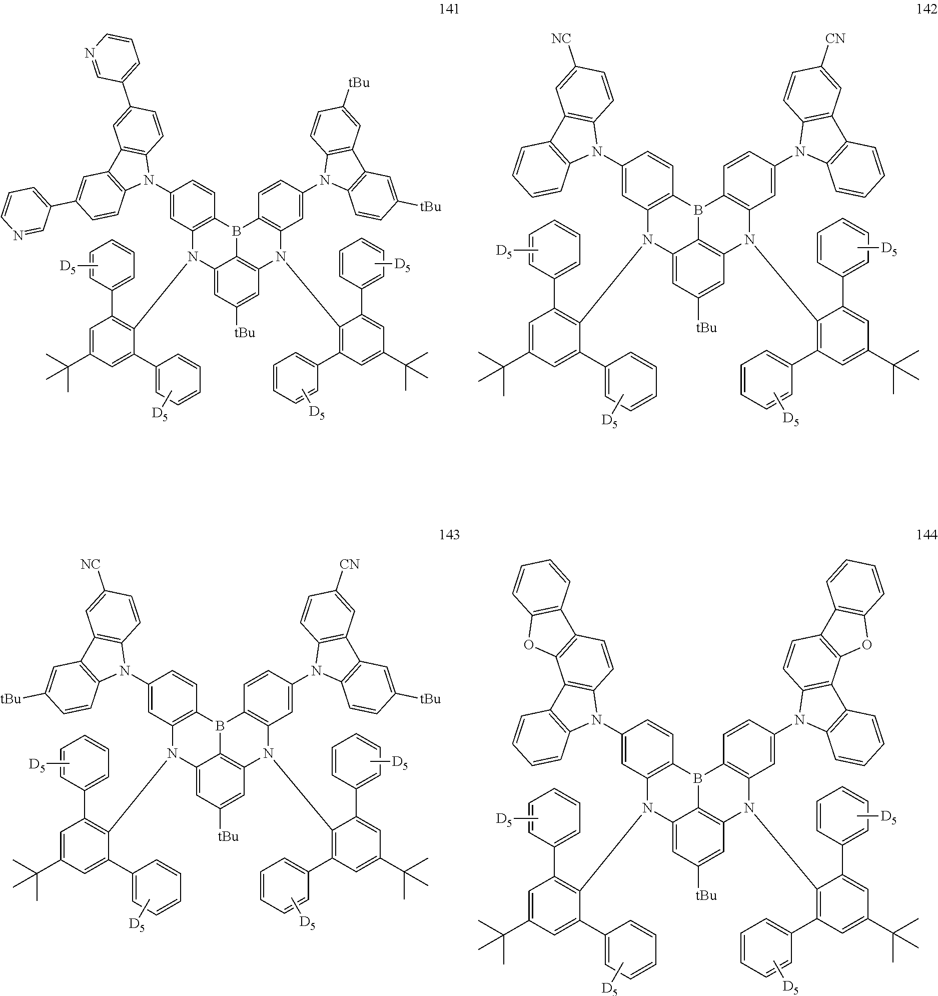

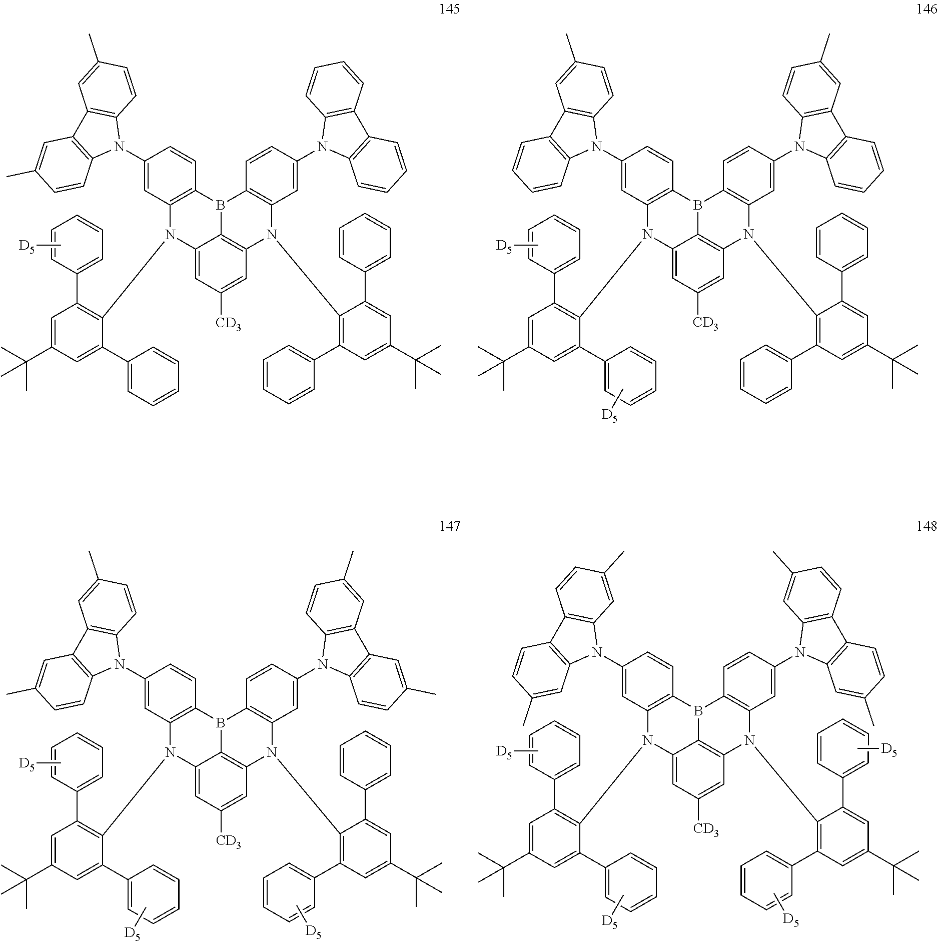

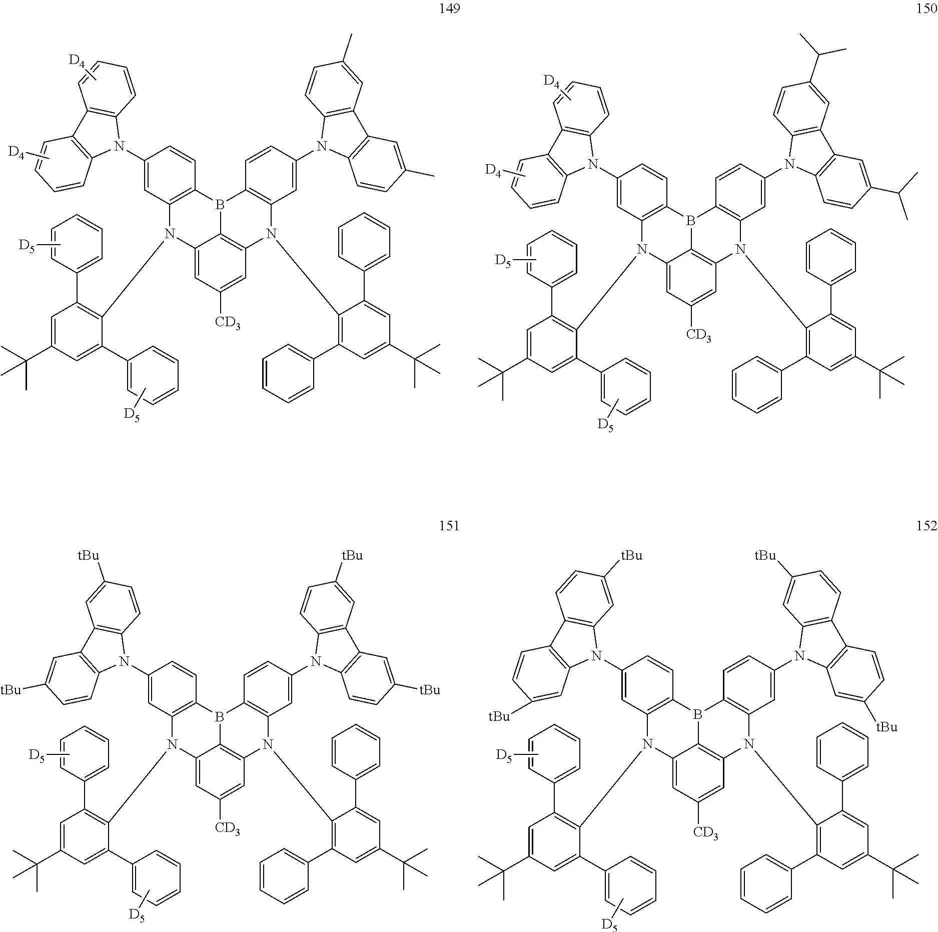

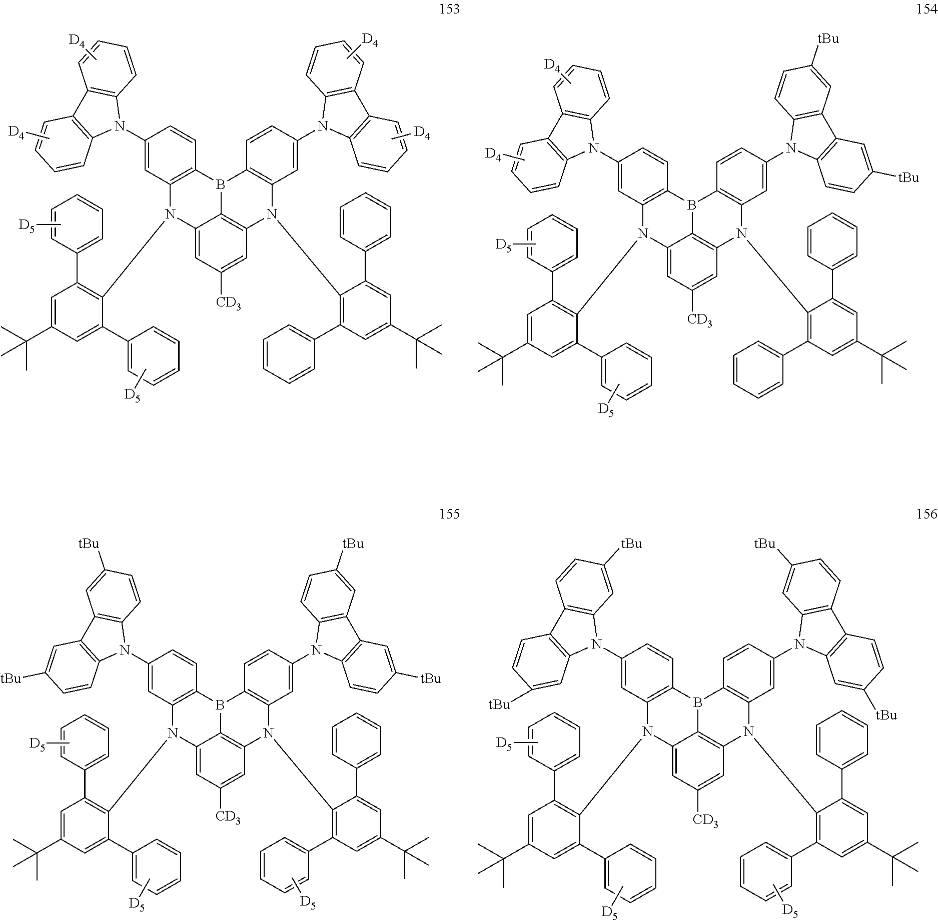

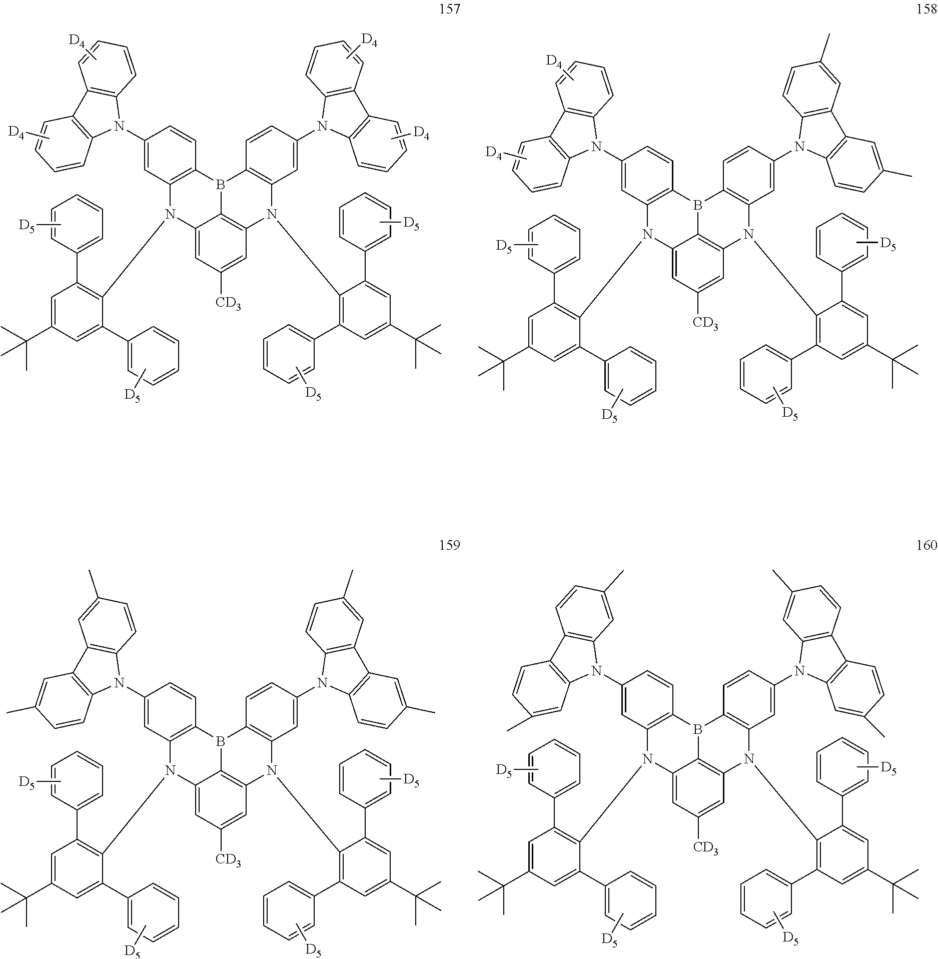

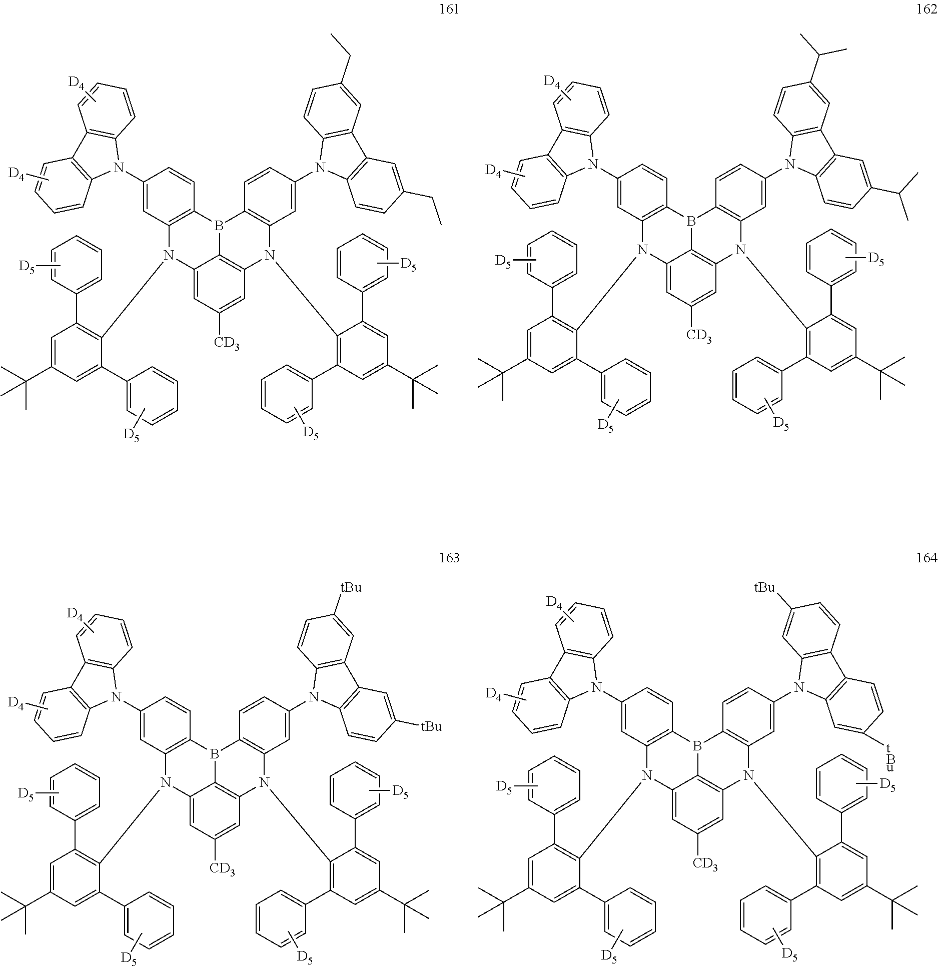

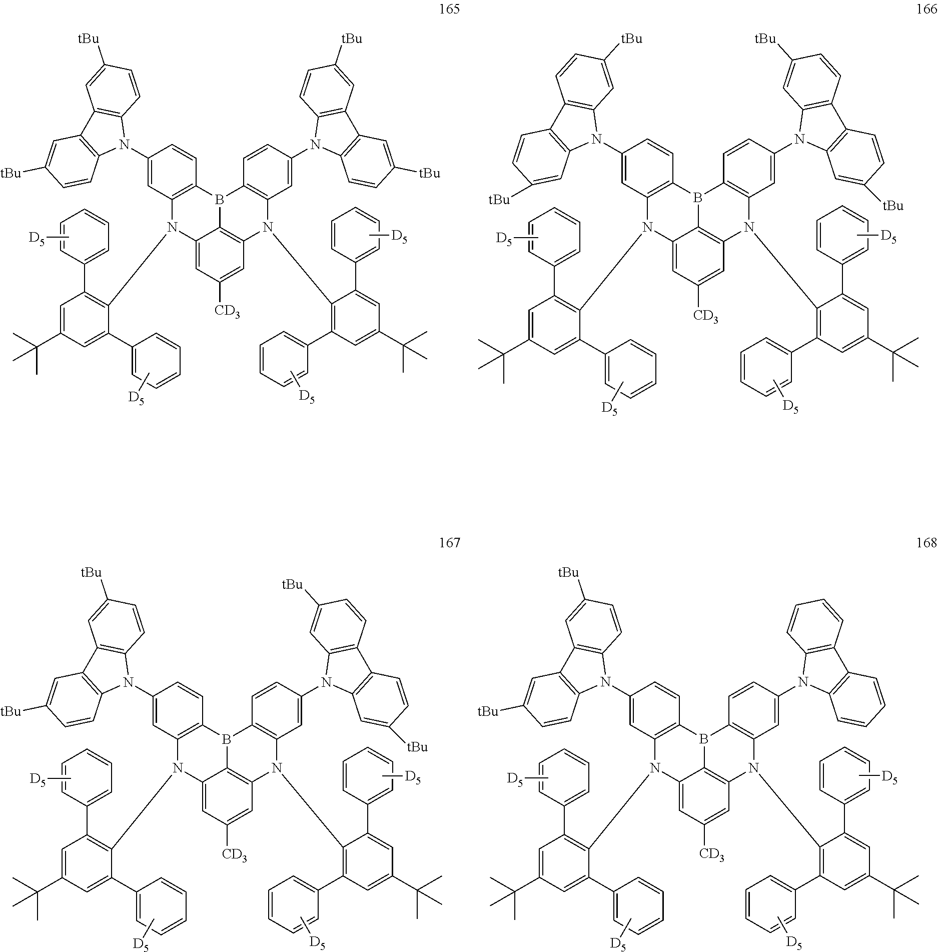

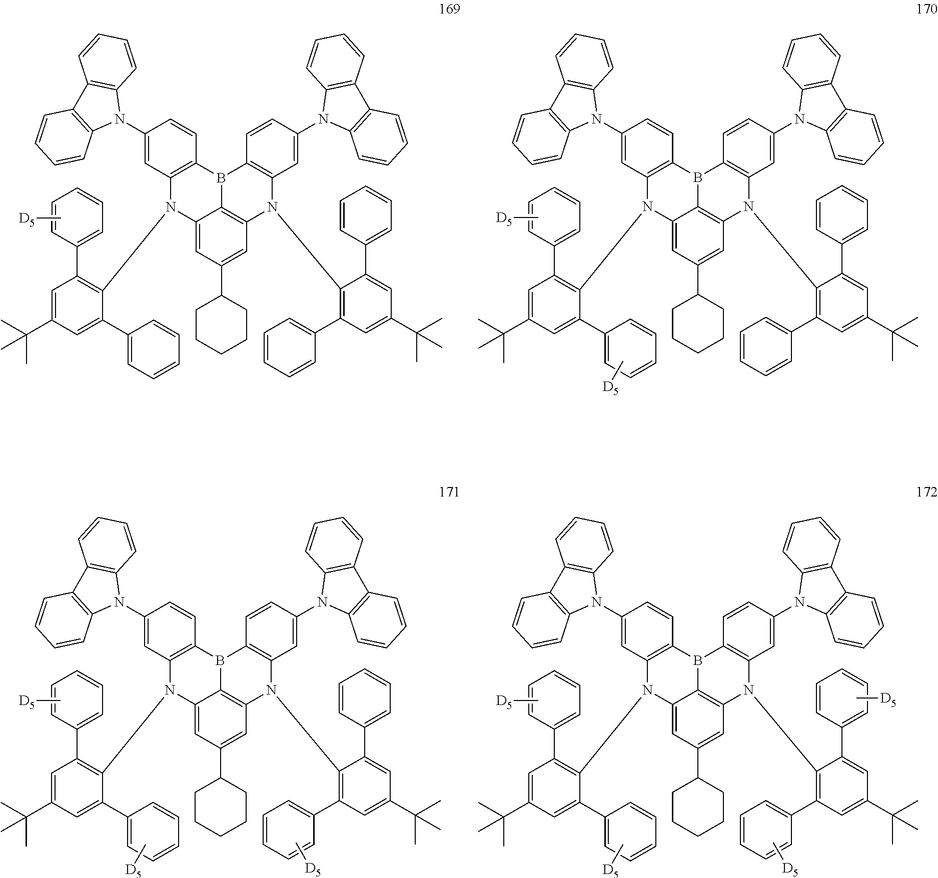

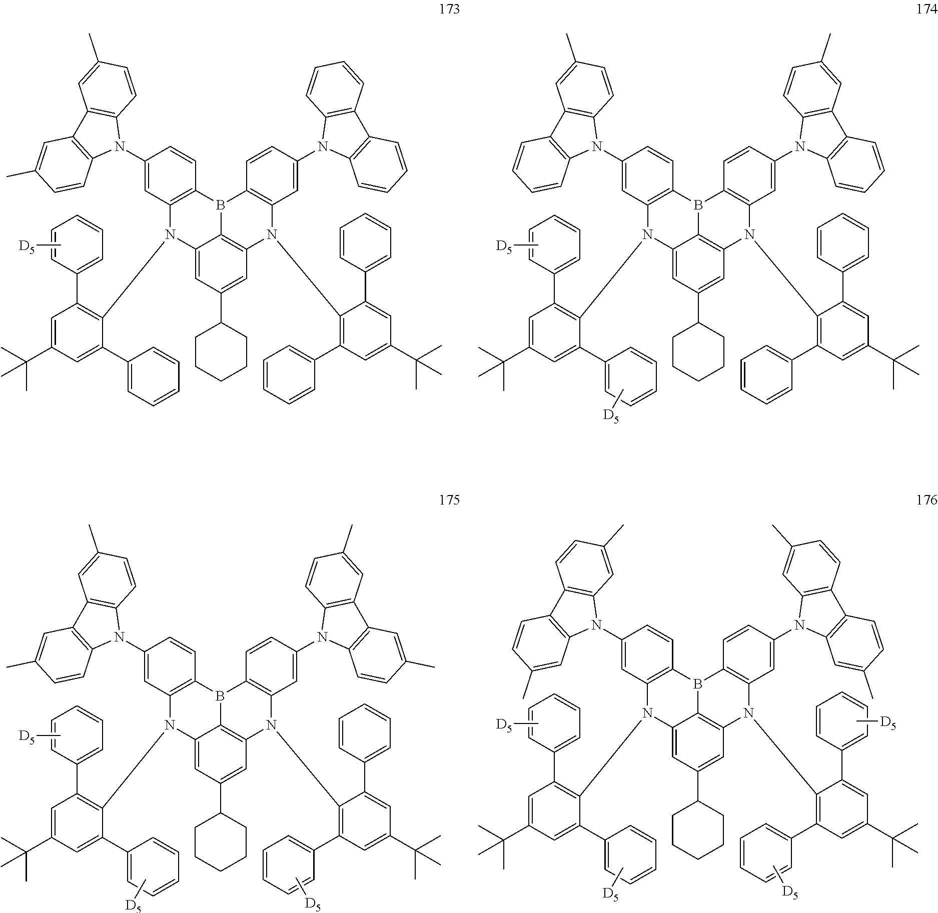

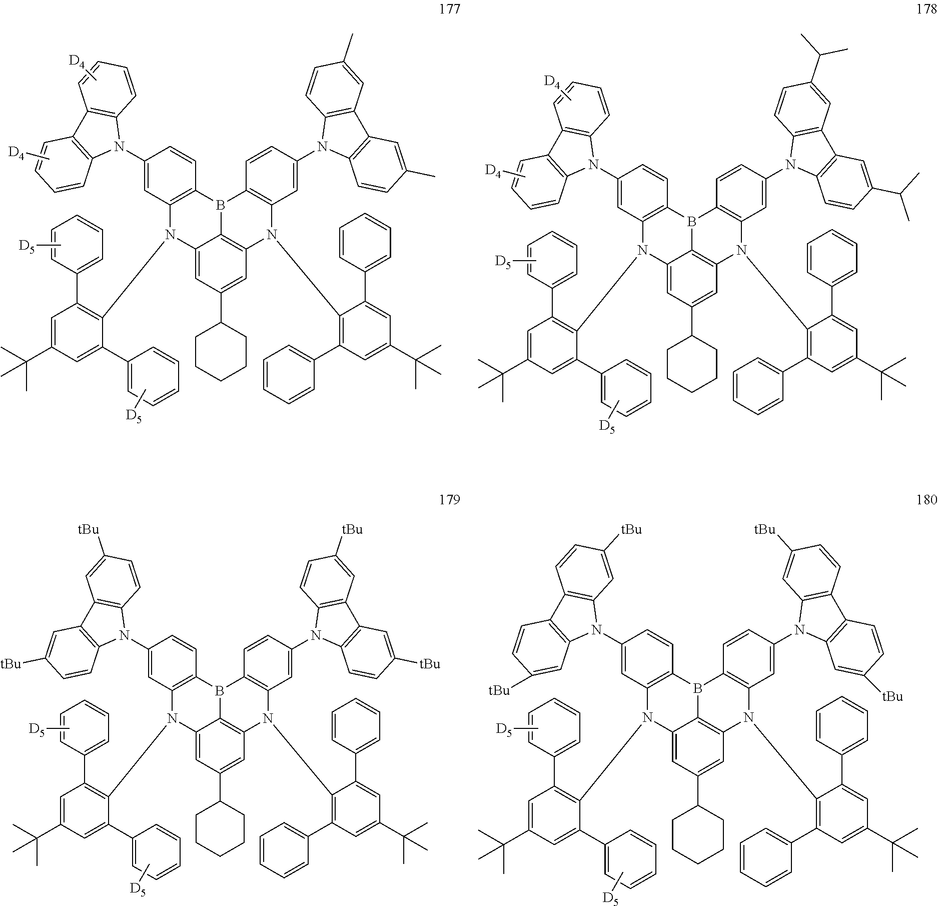

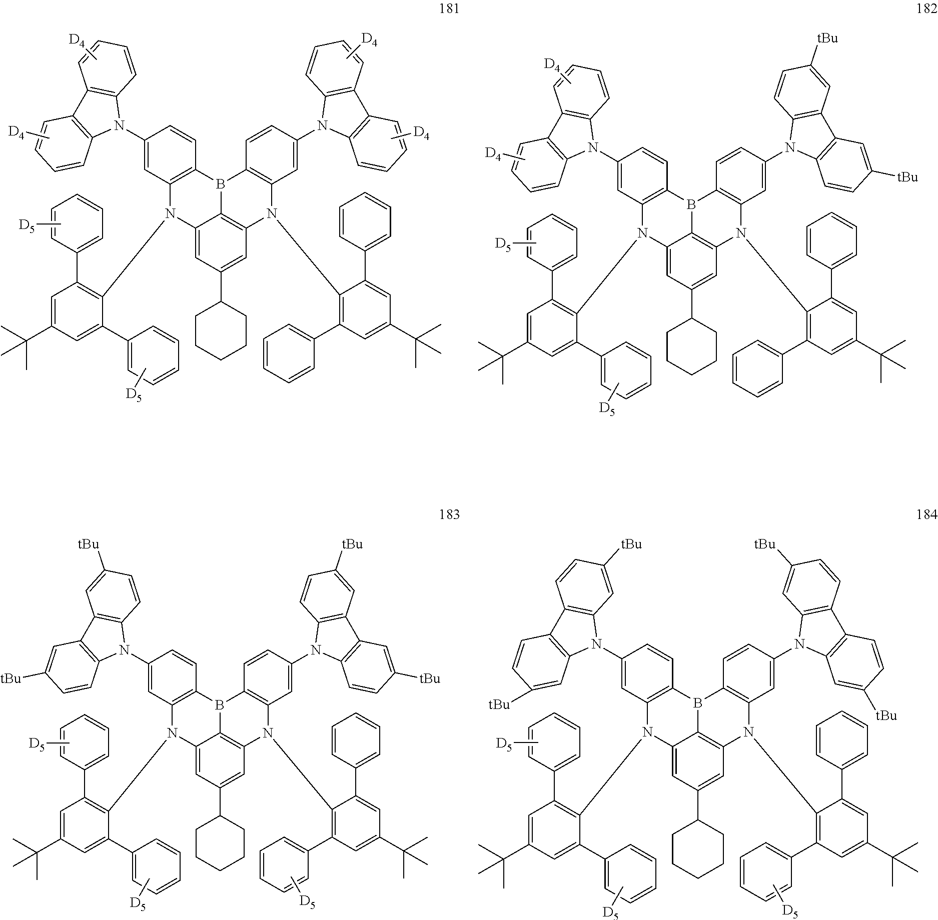

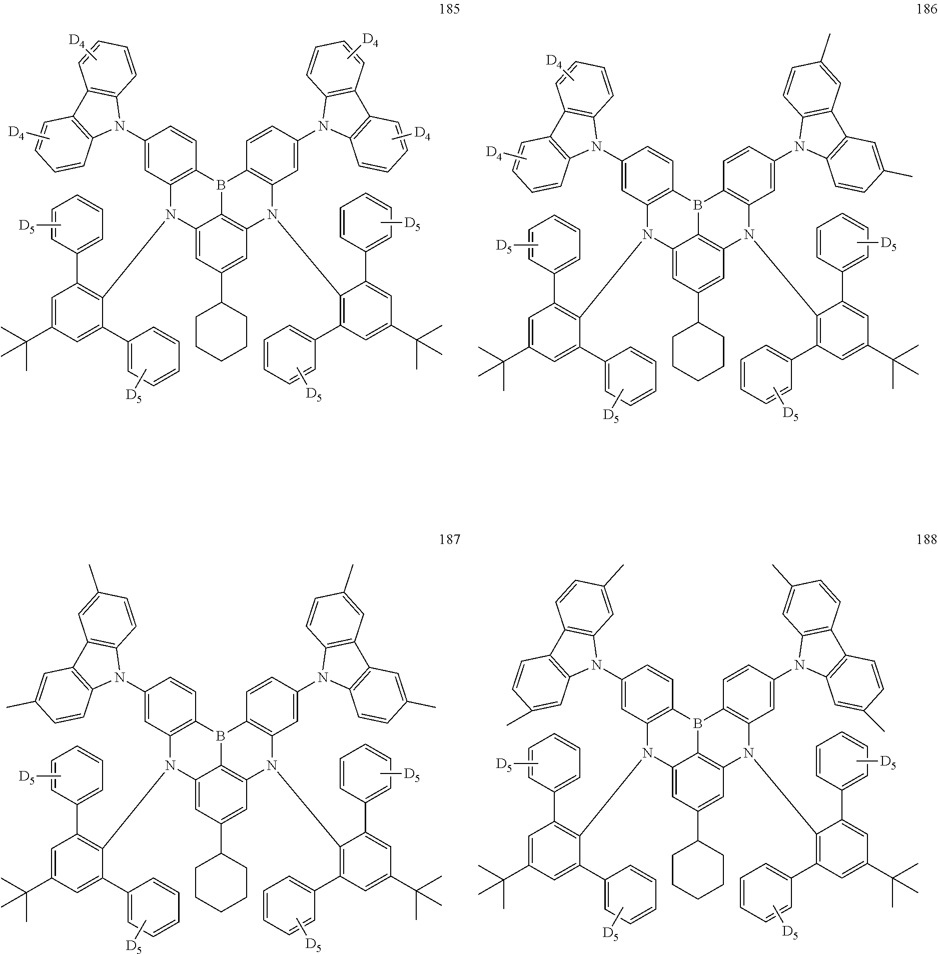

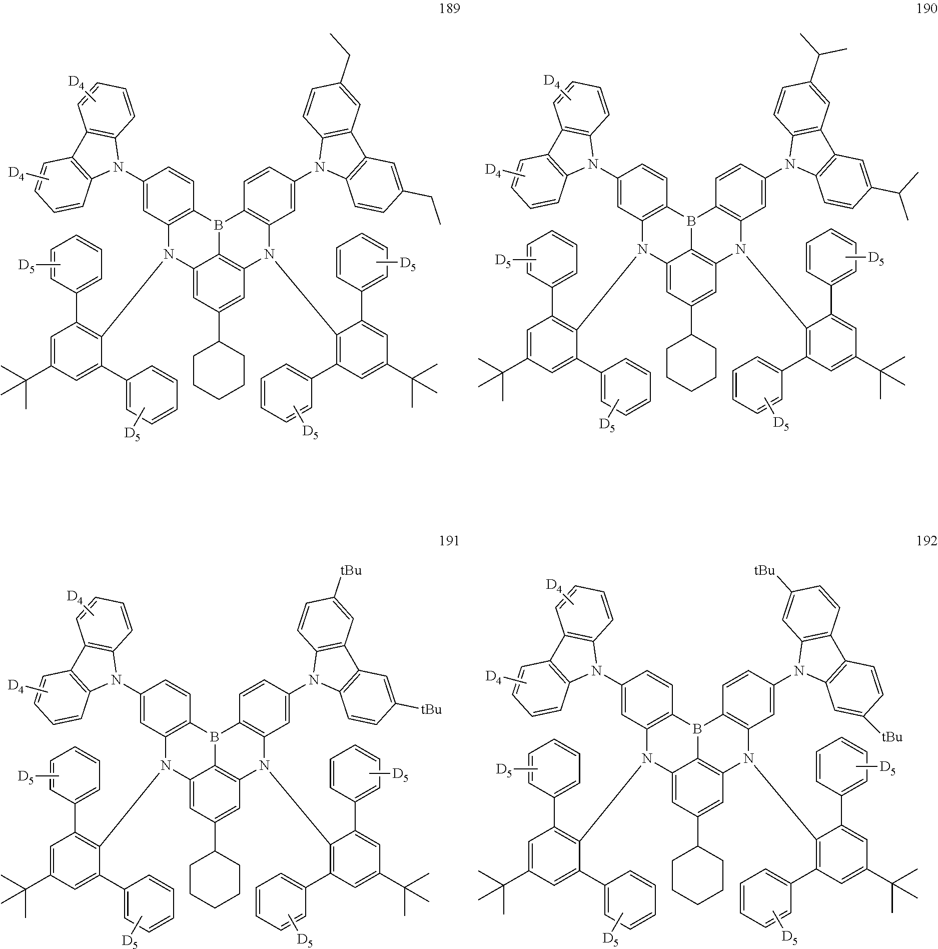

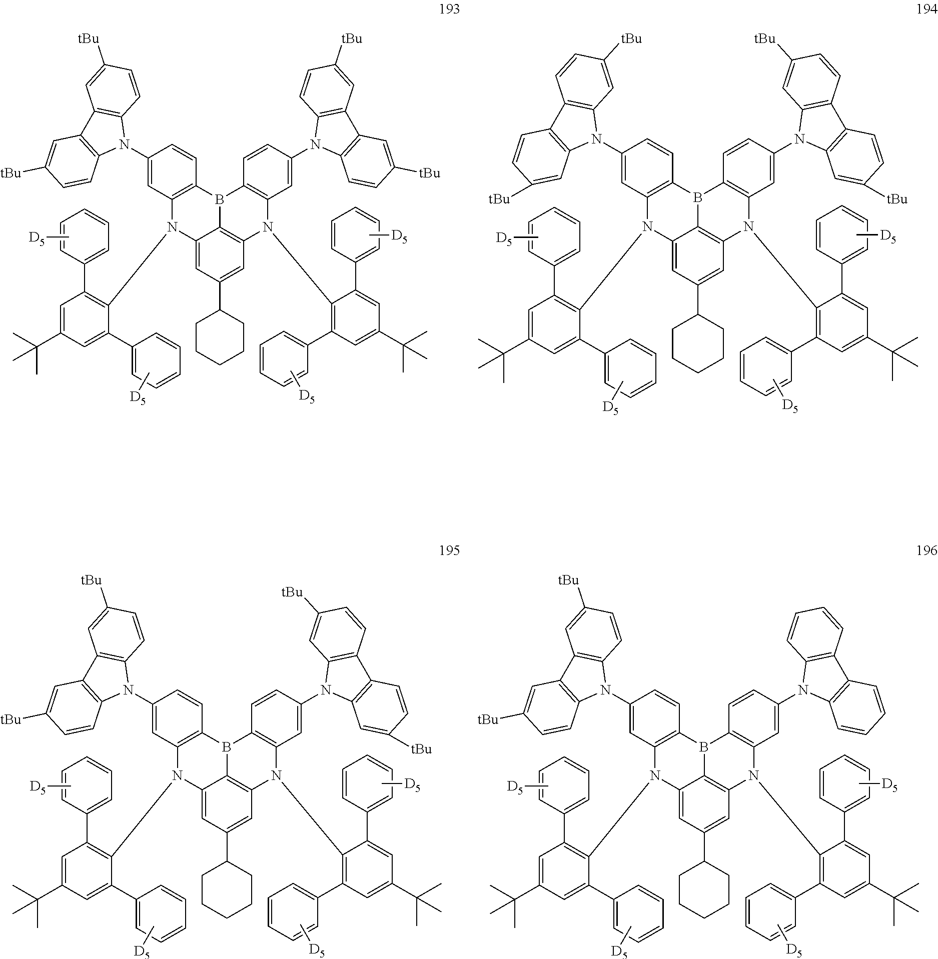

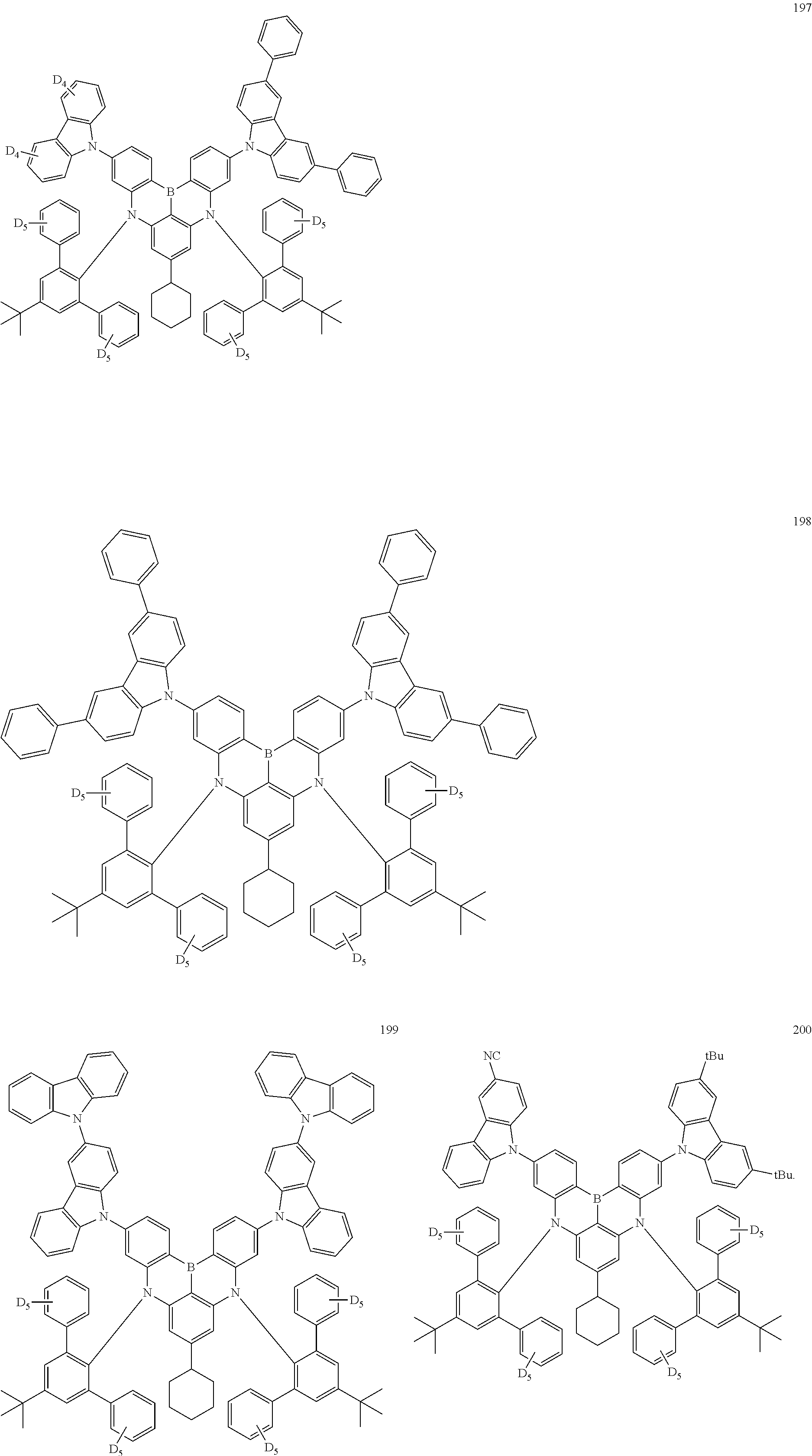

In the compounds included in Compound Group 1, “D” refers to a deuterium atom, “CD₃” refers to a methyl group substituted with deuterium atoms, and “tBu” refers to an unsubstituted t-butyl group.

The fused polycyclic compound represented by Formula 1 according to an embodiment includes sterically hindered substituents of a first substituent and a second substituent, and electron donor substituents of a third substituent and a fourth substituent, and may accomplish (result in) a high emission efficiency and a long lifetime.

The fused polycyclic compound of an embodiment has a fused structure in which first to third aromatic rings are fused by one boron atom, a first nitrogen atom, and a second nitrogen atom, and includes (e.g., consisting essentially of) a first substituent and a second substituent, respectively connected with first and second nitrogen atoms constituting of a fused ring, as substituents. The first substituent and the second substituent may be substituents which include a benzene moiety substituted with a t-butyl group, in which a substituted or unsubstituted phenyl group is introduced at a carbon at a specific position among carbon atoms constituting the benzene moiety. The fused polycyclic compound of an embodiment having such a structure may effectively maintain the trigonal planar structure of a boron atom through sterical hindrance effects by the first substituent and the second substituent. Because the boron atom has electron-deficient properties due to a vacant p-orbital, a bond may be formed with another nucleophile to change into a tetrahedral structure, and this may cause the deterioration of a device. According to the present disclosure, the fused polycyclic compound represented by Formula 1 includes the first substituent and the second substituent, which have sterically hindered structures, the vacant p-orbital of the boron atom may be effectively protected, thereby preventing or reducing the deterioration phenomenon due to structural deformation.

The fused polycyclic compound of an embodiment introduces the first and second substituents to suppress or reduce intermolecular interaction, and may control the formation of excimers or exciplexes to increase emission efficiency. The fused polycyclic compound of an embodiment, represented by Formula 1 includes the first and second substituents, and a dihedral angle between a plane including a fused ring core structure with a boron atom as a center and a plane including the first and second substituents may increase. For example, a first dihedral angle between a first plane including the first to third aromatic rings and a second plane including the first substituent, and a second dihedral angle between the first plane and a third plane including the second substituent may increase. Accordingly, an intermolecular distance may increase, and reducing effects of dexter energy transfer may be obtained. The dexter energy transfer is the intermolecular moving phenomenon of triplet excitons, and is increased with the reduction of the intermolecular distance, and may be a factor increasing quenching phenomenon according to the increase of the triplet concentration. According to the present disclosure, the fused polycyclic compound of an embodiment may have an increased distance between adjacent molecules due to a structure having large steric hindrance, and may suppress or reduce the dexter energy transfer. Accordingly, lifetime deterioration which occurs due to the increase of the concentration of the triplet may be suppressed or reduced. Accordingly, when the fused polycyclic compound of an embodiment is applied in the emission layer EML of the light emitting device ED, emission efficiency may be increased, and device lifetime may be improved.

The fused polycyclic compound of an embodiment may have a structure in which a third substituent and a fourth substituent are connected with a fused ring including a boron atom and a nitrogen atom. The third substituent and the fourth substituent include carbazole moieties and may be directly bonded to the first aromatic ring and the second aromatic ring forming the fused ring, respectively. Accordingly, the fused polycyclic compound of an embodiment has a broad plate-type or kind skeleton and shows multiple resonance, and may easily separate HOMO and LUMO states in a molecule, and accordingly, may be utilized as a material emitting delayed fluorescence. Due to the structure, the fused polycyclic compound of an embodiment may have a reduced difference (ΔEst) between the lowest triplet excitation energy level (T1 level) and the lowest singlet excitation energy level (S1 level), and accordingly, when utilized as a material emitting delayed fluorescence, the emission efficiency of a light emitting device may be improved even further.

Because the fused polycyclic compound of an embodiment has a structure in which at least one deuterium atom is substituted at the first to fourth substituents, emission efficiency and device life-characteristics may be improved even further. For example, the fused polycyclic compound of an embodiment may have a structure in which at least one deuterium atom is introduced into at least one substituent selected from among the first and second sub-substituents introduced into the first substituent, the third and fourth sub-substituents introduced in the second substituent, the third substituent, and the fourth substituent. Deuterium has a greater atomic weight than hydrogen, and has lowered zero point energy, i.e., ground state energy. Accordingly, the binding energy between carbon-deuterium increases more than the binding energy between carbon-hydrogen. When the carbon-hydrogen bond included in the first to fourth substituents is replaced with a carbon-deuterium bond, material stability may be improved, and lifetime deterioration due to material deterioration may be suppressed or reduced. In some embodiments, because the carbon-deuterium bond length is smaller than the carbon-hydrogen bond length, intermolecular Van der Waals force may be reduced to suppress or reduce the reduction of the emission efficiency. Accordingly, the fused polycyclic compound of an embodiment may improve the emission efficiency and device-life characteristics by including (e.g., consisting essentially of) the first to fourth substituents and introducing at least one deuterium atom in at least one substituent among the first to fourth substituents.

The fused polycyclic compound of an embodiment may be included in an emission layer EML. The fused polycyclic compound of an embodiment may be included in an emission layer EML as a dopant material. The fused polycyclic compound of an embodiment may be a material emitting thermally activated delayed fluorescence. The fused polycyclic compound of an embodiment may be utilized as a thermally activated delayed fluorescence dopant. For example, in the light emitting device ED of an embodiment, the emission layer EML may include at least one selected from among the fused polycyclic compounds represented in Compound Group 1, as a thermally activated delayed fluorescence dopant. However, the utilization of the fused polycyclic compound of an embodiment is not limited thereto.

In an embodiment, the emission layer EML may include multiple compounds. The emission layer EML of an embodiment may include the fused polycyclic compound represented by Formula 1, for example, a first compound, and may further include at least one selected from among a second compound represented by Formula H-1, a third compound represented by Formula H-2, and a fourth compound represented by Formula D-1.

In an embodiment, the second compound may be utilized as the hole transport host material of an emission layer EML.

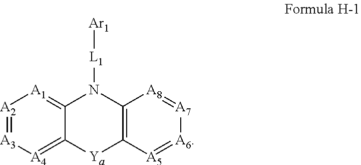

In Formula H-1, A₁ to A₈ may be each independently N or CR₅₁. For example, all A₁ to A₈ may be CR₅₁. Otherwise, any one among A₁ to A₈ may be N, and the remainder may be CR₅₁.

In Formula H-1, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, or the like, but an embodiment of the inventive concept is not limited thereto.

In Formula H-1, Yₐ may be a direct linkage, CR₅₂R₅₃, or SiR₅₄R₅₅. That is, it may mean that two benzene rings connected with the nitrogen atom of Formula H-1 may be connected via a direct linkage,

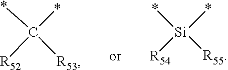

In Formula H-1, if Yₐ is a direct linkage, the substituent represented by Formula H-1 may include a carbazole moiety.

In Formula H-1, Ar₁ may be a substituted or unsubstituted aryl group of 6 to 30 ring-forming carbon atoms, or a substituted or unsubstituted heteroaryl group of 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, or the like, but an embodiment of the inventive concept is not limited thereto. In Formula H-1, R₅₁ to R₅₅ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 60 ring-forming carbon atoms. Otherwise, each of R₅₁ to R₅₅ may be combined with an adjacent group to form a ring. For example, R₅₁ to R₅₅ may be each independently a hydrogen atom or a deuterium atom. R₅₁ to R₅₅ may be each independently an unsubstituted methyl group or an unsubstituted phenyl group.

In an embodiment, the second compound represented by Formula 2 may be represented by any one selected from among the compounds represented in Compound Group 2. The emission layer EML may include at least one selected from among the compounds represented in Compound Group 2 as a hole transport host material.

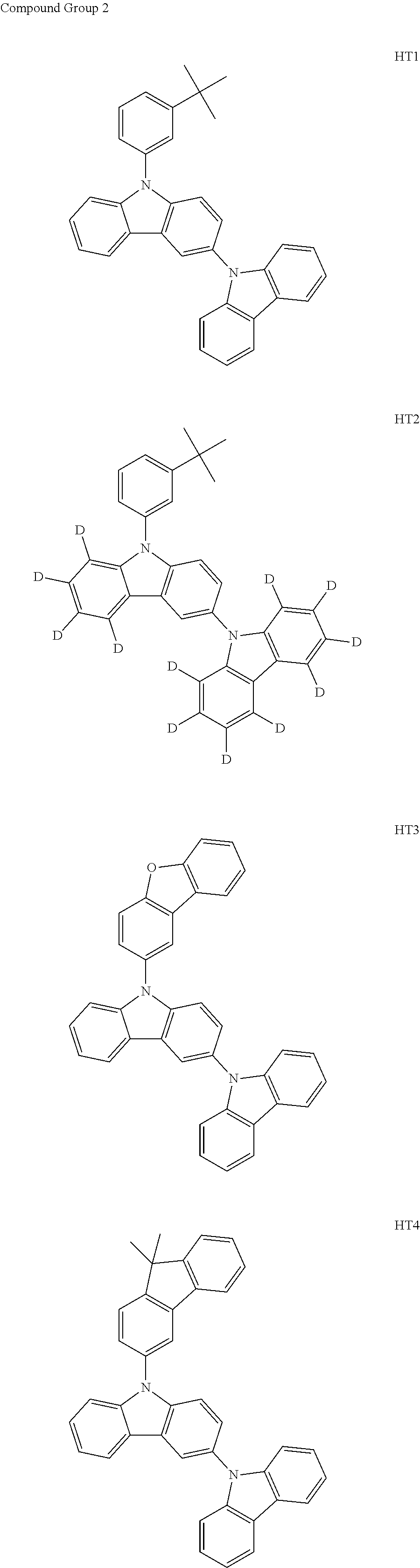 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12 ; CC1(C)c2ccccc2-c2cc(-n3c4ccccc4c4cc(-n5c6ccccc6c6ccccc65)ccc43)ccc21]

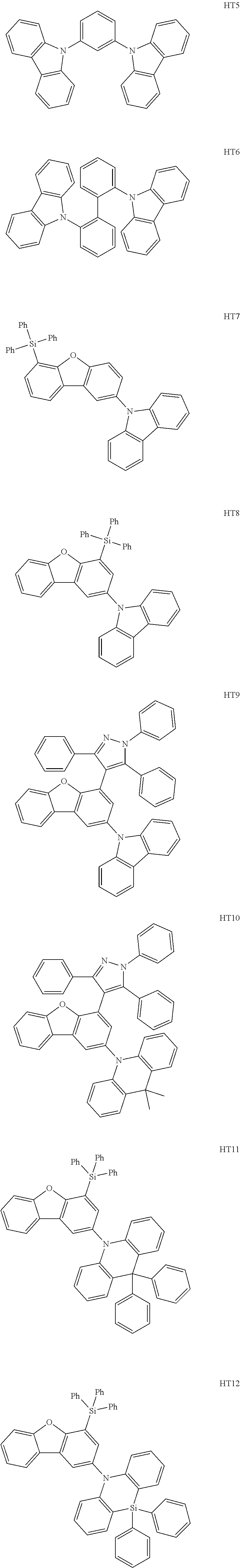

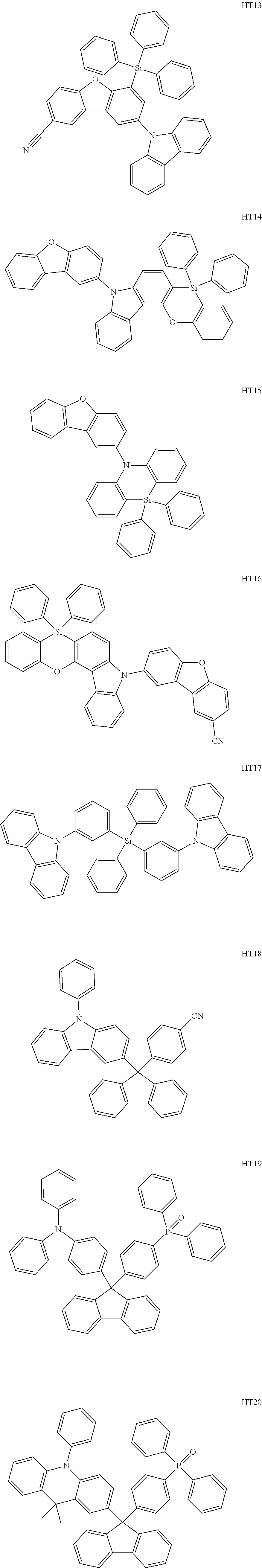

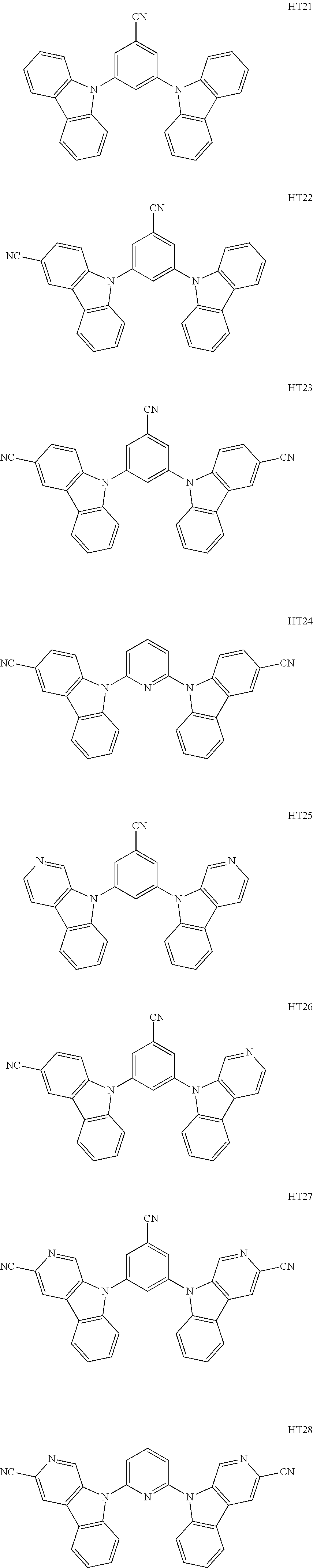

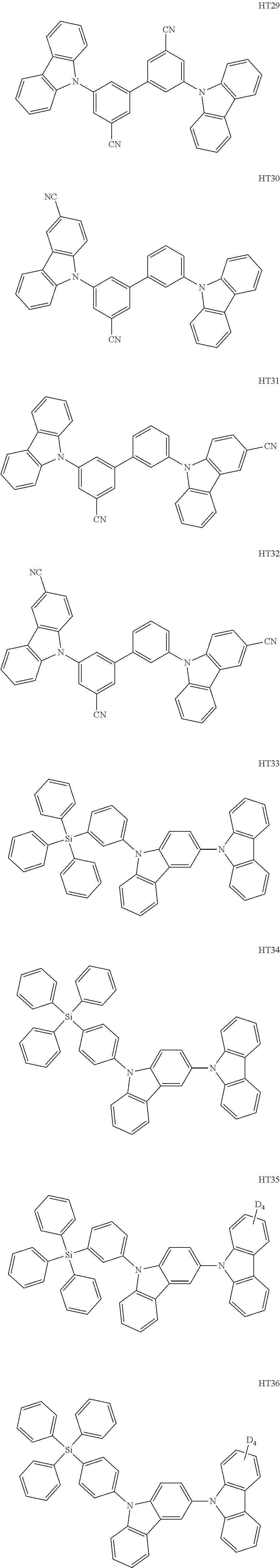

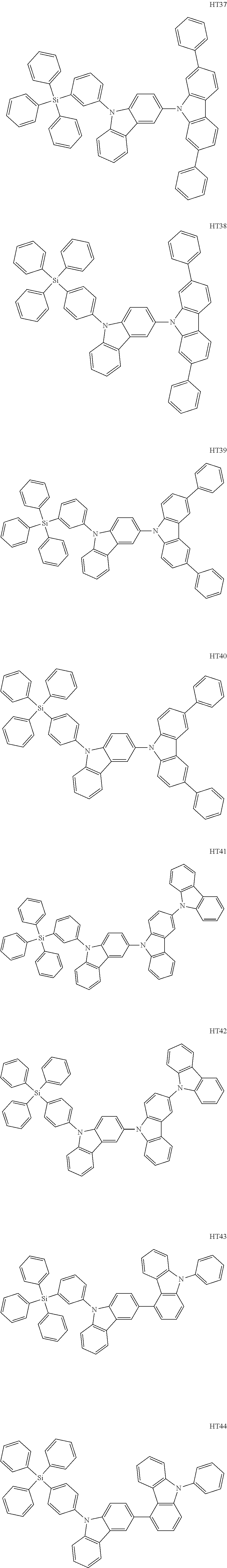

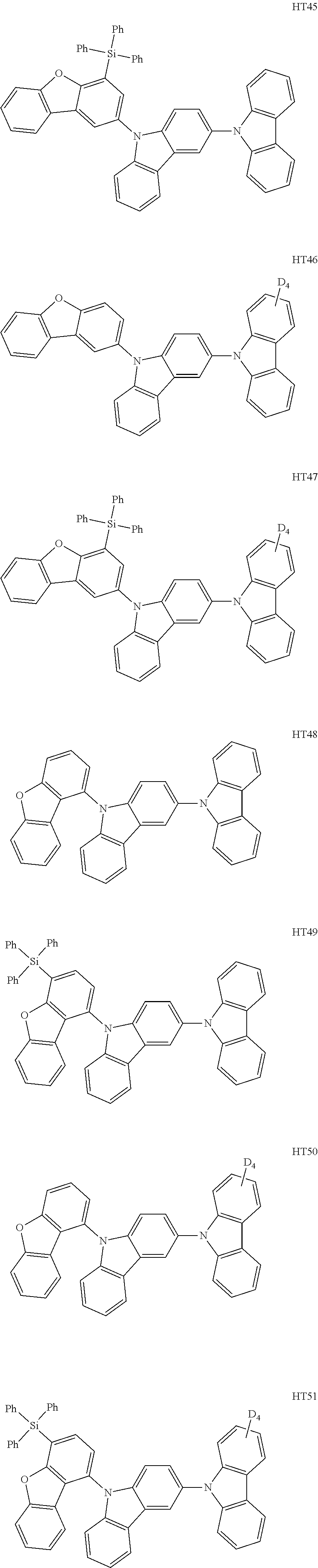

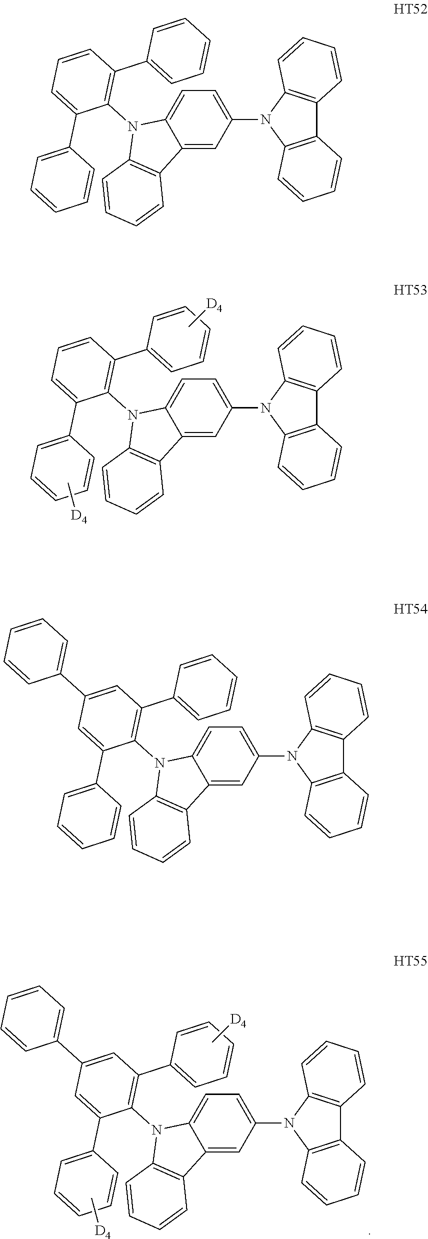

In the compounds included in Compound Group 2, “D” refers to a deuterium atom, and “Ph” refers to a substituted or unsubstituted phenyl group. For example, in the compounds included in Compound Group 2, “Ph” may be an unsubstituted phenyl group.

In an embodiment, the emission layer EML may include a third compound represented by Formula H-2. For example, the third compound may be utilized as the electron transport host material of an emission layer EML.

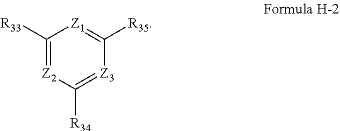

In Formula H-2, Z₁ to Z₃ may each independently be N or CR₃₆, in which at least one selected from among Z₁ to Z₃ may be N.

In Formula H-2, R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In some embodiments, R₃₃ to R₃₆ may be combined with an adjacent group to form a ring. For example, R₃₃ to R₃₆ may each independently be a substituted or unsubstituted phenyl group, a substituted or unsubstituted carbazole group, and/or the like, but an embodiment of the present disclosure is not limited thereto.

In an embodiment, the third compound represented by Formula 3 may be represented by any one selected from among the compounds represented in Compound Group 3. An emission layer EML may include at least one selected from among the compounds represented in Compound Group 3 as an electron transport host material.

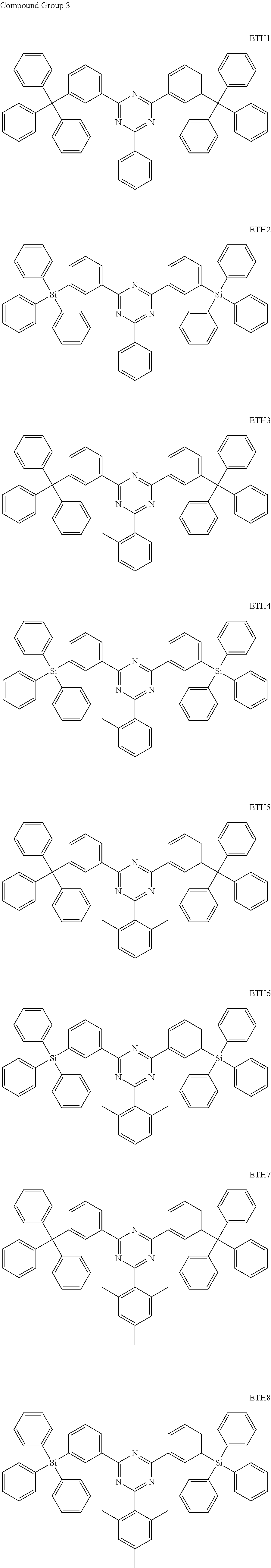

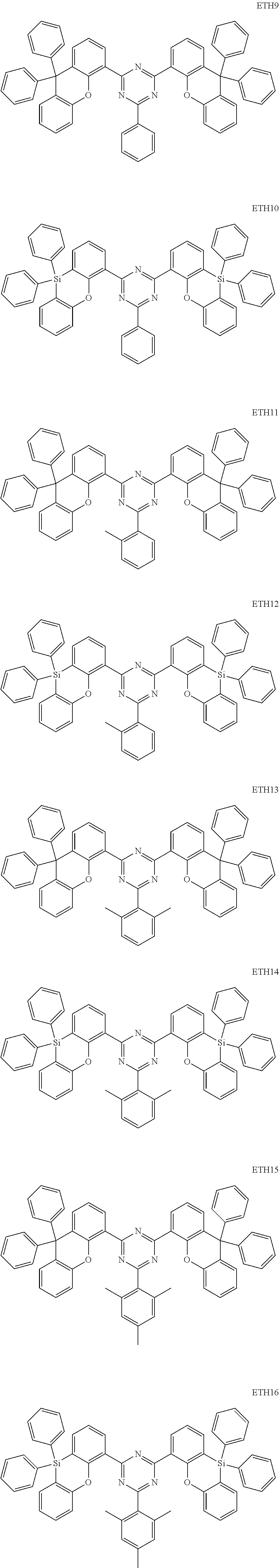

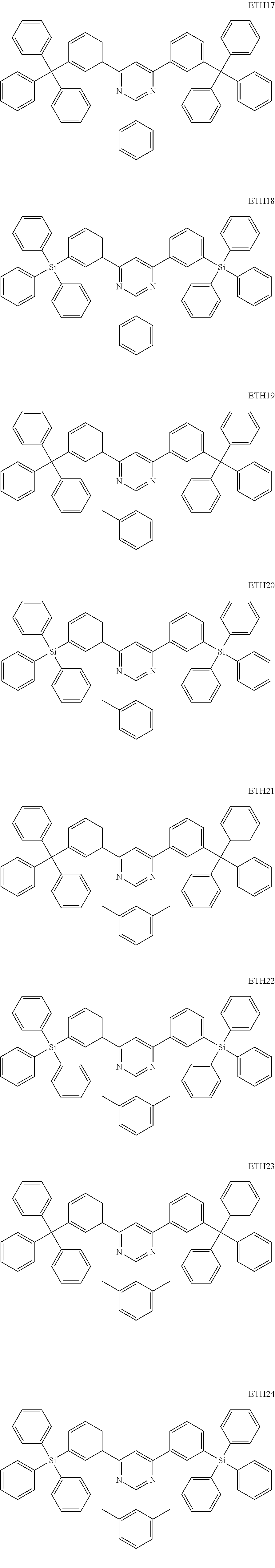

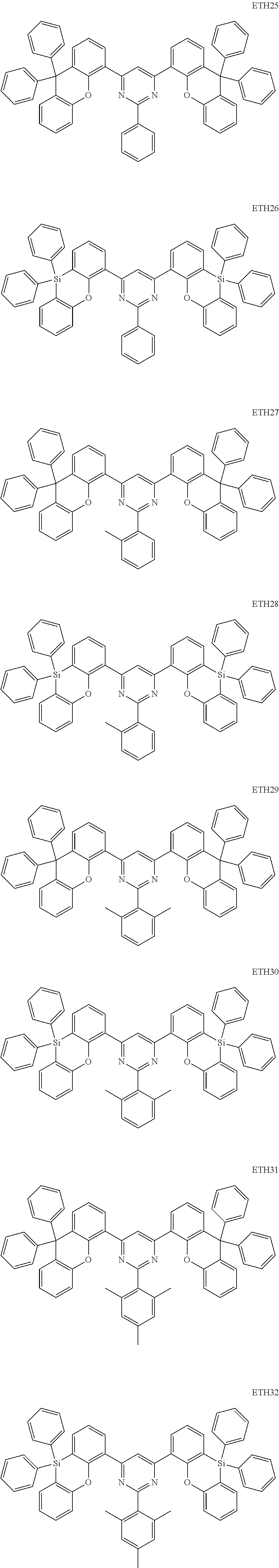

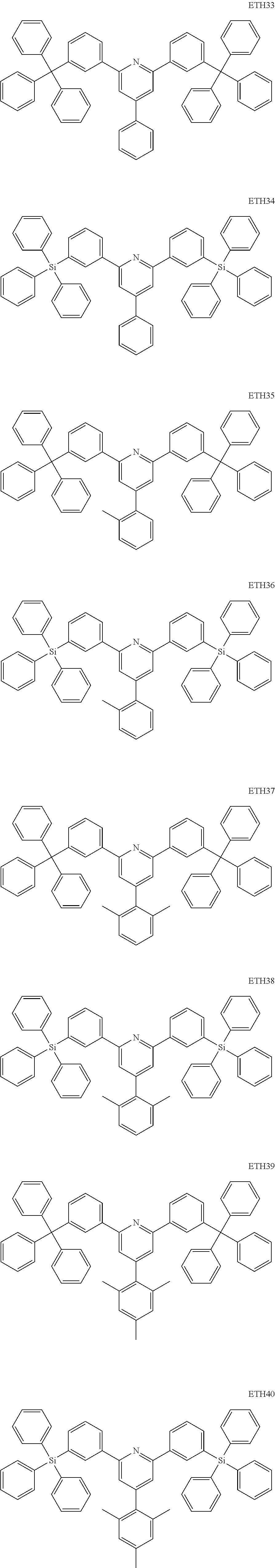

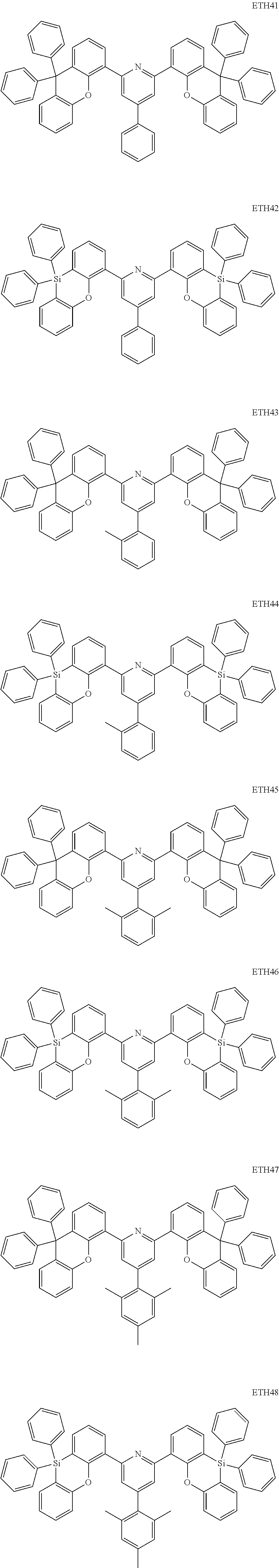

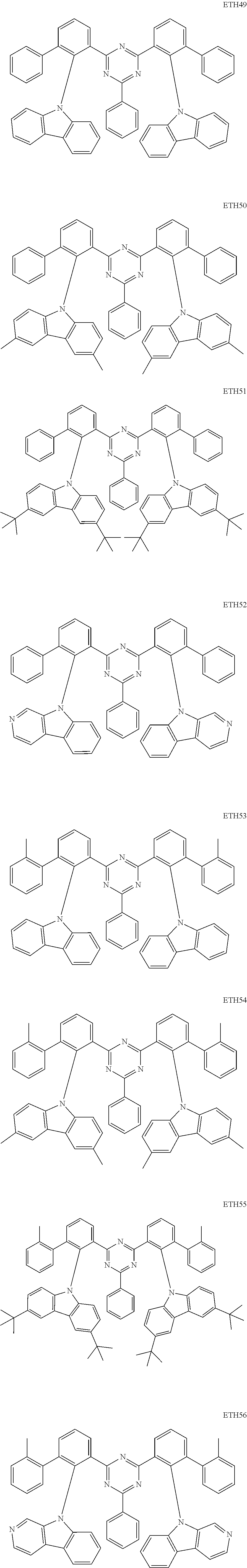

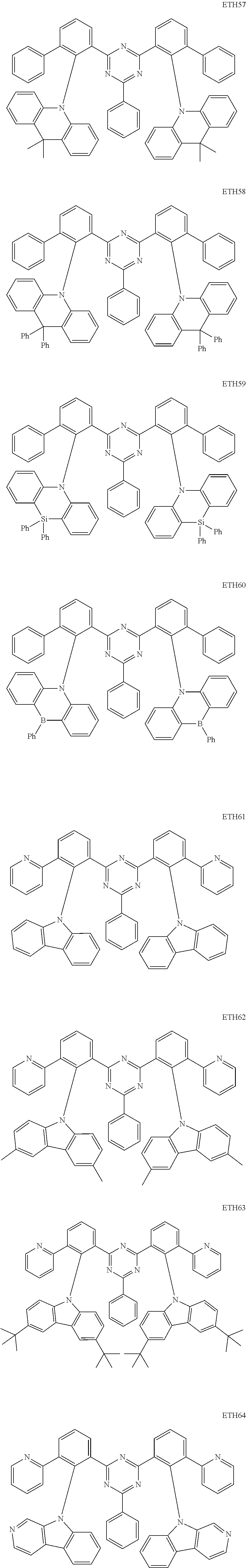

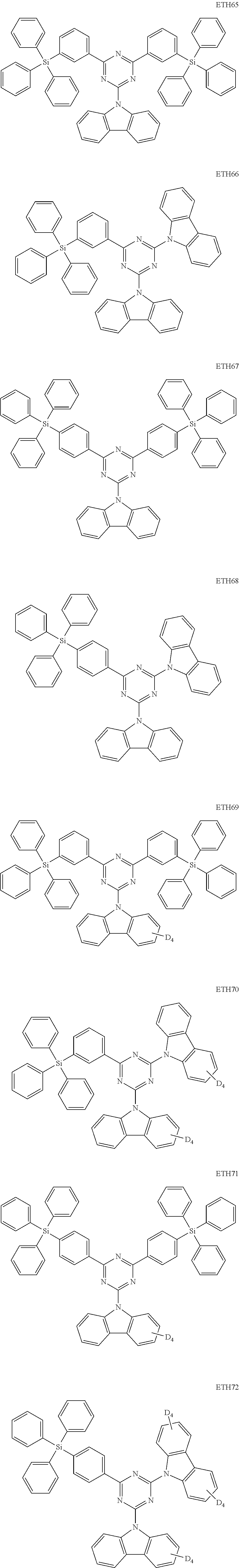

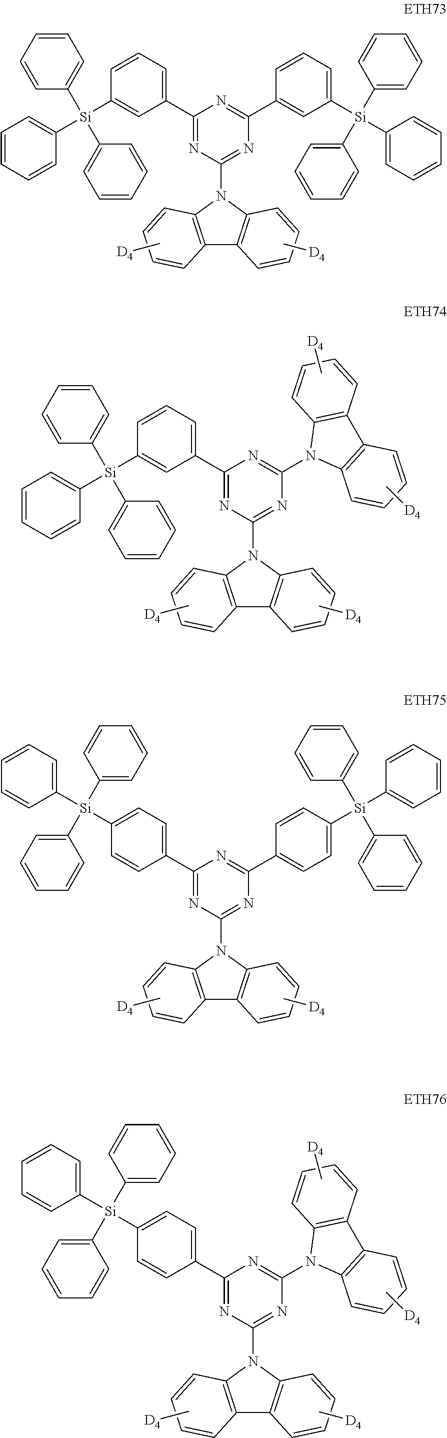

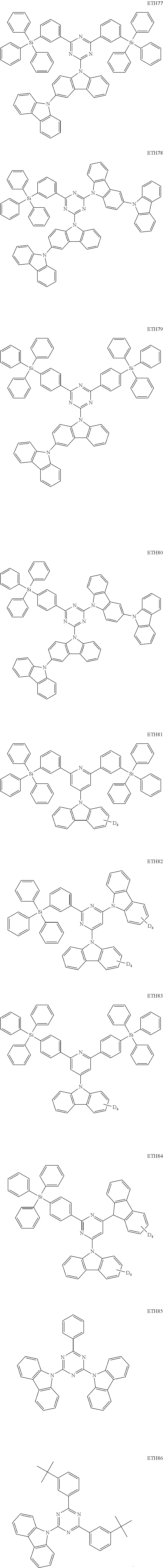

In the compounds included in Compound Group 3, “D” refers to a deuterium atom, and “Ph” refers to an unsubstituted phenyl group.

An emission layer EML may include the second compound and the third compound, and the second compound and the third compound may form exciplexes. In the emission layer EML, exciplexes may be formed by a hole transport host and an electron transport host. In this embodiment, the triplet energy of the exciplexes formed by the hole transport host and the electron transport host may correspond to a difference between the lowest unoccupied molecular orbital (LUMO) energy level of the electron transport host and the highest occupied molecular orbital (HOMO) energy level of the hole transport host.

For example, the absolute value of the triplet energy level (T1) of the exciplexes formed by the hole transport host and the electron transport host may be about 2.4 eV to about 3.0 eV. In some embodiments, the triplet energy of the exciplexes may be a value smaller than the energy gap of each host material. The exciplexes may have a triplet energy of about 3.0 eV or less which is the energy gap of the hole transport host and the electron transport host.

In an embodiment, the emission layer EML may include a fourth compound in addition to the first compound to the third compound. The fourth compound may be utilized as the phosphorescence sensitizer of the emission layer EML. By the energy transfer from the fourth compound to the first compound, light may be emitted.

For example, the emission layer EML may include an organometallic complex including platinum (Pt) as a central metal atom and ligands bonded to the central metal atom, as the fourth compound. In the light emitting device ED of an embodiment, the emission layer EML may include a compound represented by Formula D-1 as the fourth compound.

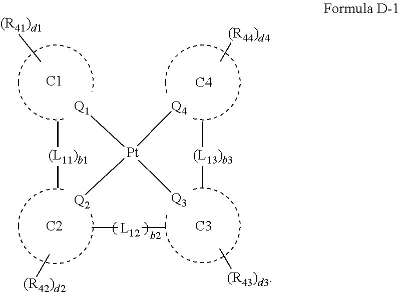

In Formula D-1, Q₁ to Q₄ may each independently be C or N.

In Formula D-1, C1 to C4 may each independently be a substituted or unsubstituted hydrocarbon ring of 5 to 30 ring-forming carbon atoms, or a substituted or unsubstituted heterocycle of 2 to 30 ring-forming carbon atoms.

In Formula D-1, L₁₁ to L₁₃ may each independently be a direct linkage,

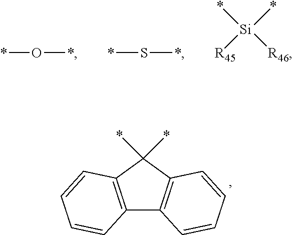

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L11 to L13, “—*” refers to a connection part with C1 to C4.

In Formula D-1, b1 to b3 may each independently be 0 or 1. When b1 is 0, C1 and C2 may not be connected to each other. When b2 is 0, C2 and C3 may not be connected with each other. When b3 is 0, C3 and C4 may not be connected to each other.

In Formula D-1, R₄₁ to R₄₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In some embodiments, R₄₁ to R₄₆ may be combined with an adjacent group to form a ring. R₄₁ to R₄₆ may each independently be a substituted or unsubstituted methyl group, or a substituted or unsubstituted t-butyl group.

In Formula D-1, d1 to d4 may each independently be an integer from 0 to 4. In Formula D-1, when d1 to d4 are each 0, the fused polycyclic compound of an embodiment may be unsubstituted with R₄₁ to R₄₄. Embodiments in which d1 to d4 are each 4, and R₄₁ to R₄₄ are hydrogen atoms, may be the same as embodiments in which d1 to d4 are each 0, respectively. When d1 to d4 are integers of 2 or more, each of multiple R₄₁ to R₄₄ may be all the same or one or more of multiple R₄₁ to R₄₄ may be different.

In Formula D-1, C1 to C4 may each independently be a substituted or unsubstituted hydrocarbon ring or a substituted or unsubstituted heterocycle, represented by any one selected from among C-1 to C-4.

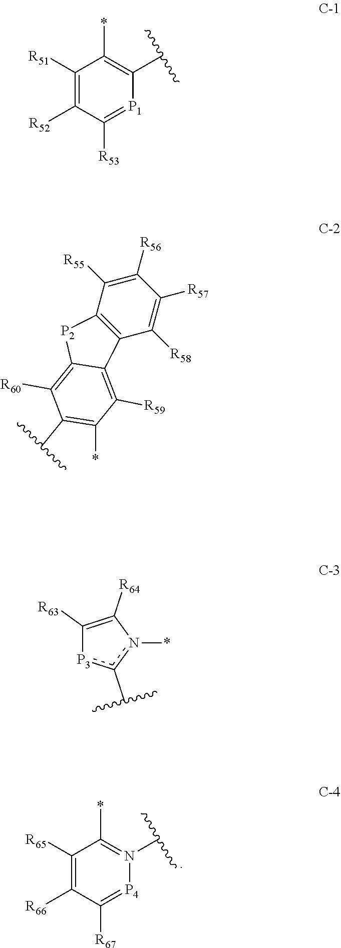

In C-1 to C-4, P₁ may be “C—*” or CR₅₄, P₂ may be “N—*” or NR₆₁, P₃ may be “N—*” or NR₆₂, and P₄ may be “C—*” or CR₆₈. R₅₁ to R₆₈ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In some embodiments, in C-1 to C-4,

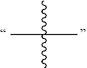

is a part connected with a Pt central metal element, and “—*” is a part connected with a neighboring ring group (C1 to C4) or a linker (L₁₁ to L₁₃).

The emission layer EML of an embodiment may include the first compound, and at least one selected from among the second to fourth compounds, which are polycyclic compounds. For example, the emission layer EML may include the first compound, the second compound and the third compound. In the emission layer EML, the second compound and the third compound may form exciplexes, and energy transfer from the exciplex to the first compound may induce light emission.

In some embodiments, the emission layer EML may include the first compound, the second compound, the third compound and the fourth compound. In the emission layer EML, the second compound and the third compound may form exciplexes, and energy transfer from the exciplex to the fourth compound and the first compound may induce light emission. In an embodiment, the fourth compound may be a sensitizer. In the light emitting device ED of an embodiment, the fourth compound included in the emission layer EML may play the role of a sensitizer and may play the role of transferring energy from the host to the first compound which is an emission dopant. For example, the fourth compound which plays the role of an auxiliary dopant may accelerate the energy transfer to the first compound and may increase the emission ratio of the first compound. Accordingly, the emission layer EML of an embodiment may improve emission efficiency. In some embodiments, when the energy transfer to the first compound is increased, excitons formed in the emission layer EML may not be accumulated in the emission layer EML but instead rapidly emit light, and the deterioration of the device may be reduced. Accordingly, the lifetime of the light emitting device ED of an embodiment may be increased.

The light emitting device ED of an embodiment includes all of the first compound, the second compound, the third compound and the fourth compound, and the emission layer EML may include the combinations of two host materials and two dopant materials. In the light emitting device ED of an embodiment, the emission layer EML may include two different hosts, a first compound emitting delayed fluorescence, and a fourth compound containing an organometallic complex, concurrently (e.g., simultaneously), and may show excellent or suitable emission efficiency properties.

In an embodiment, the fourth compound represented by Formula D-1 may be represented by at least one selected from among the compounds represented in Compound Group 4. The emission layer EML may include at least one selected from among the compounds represented in Compound Group 4 as the sensitizer material.

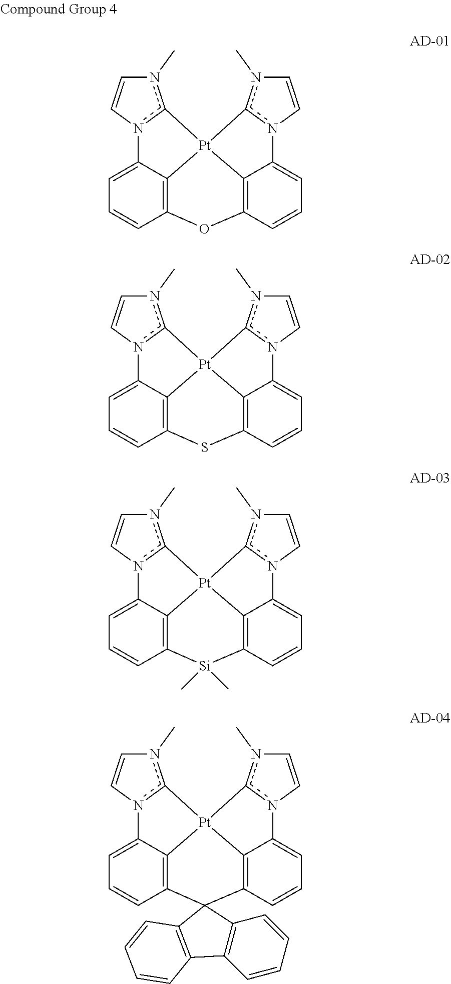

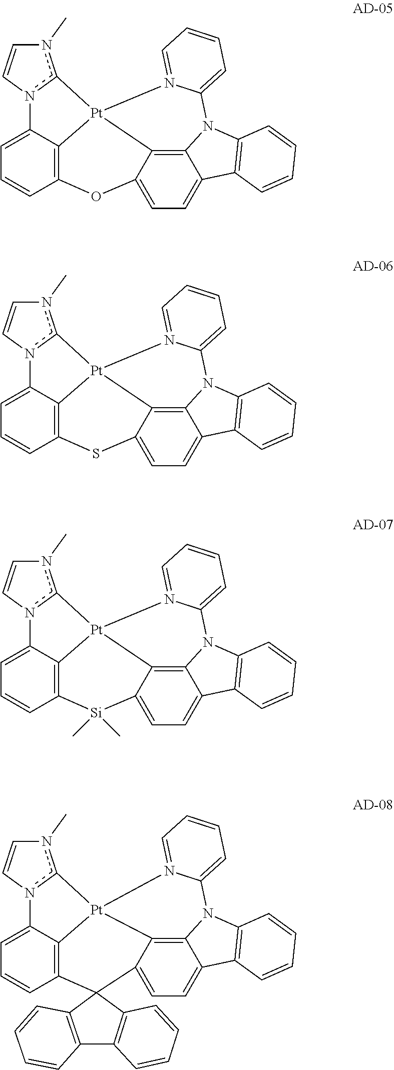

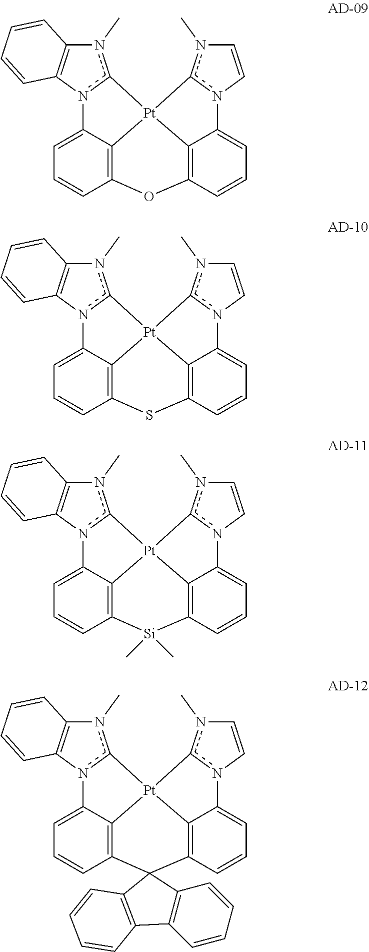

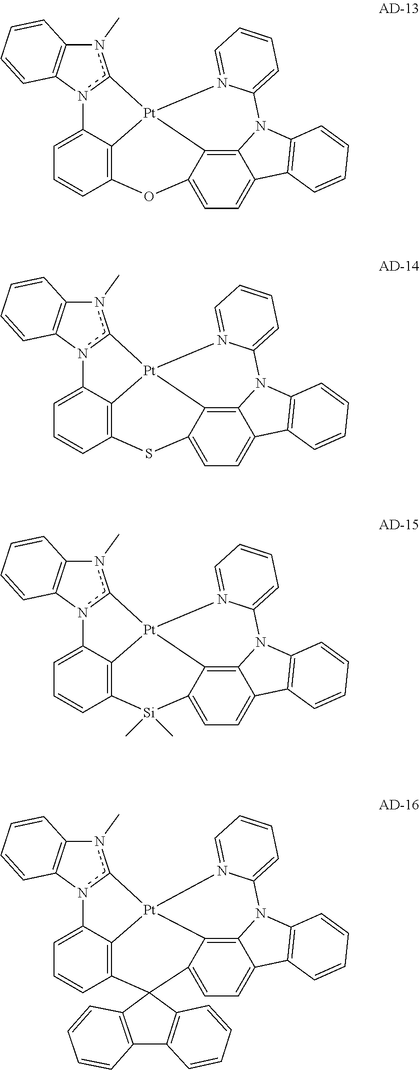

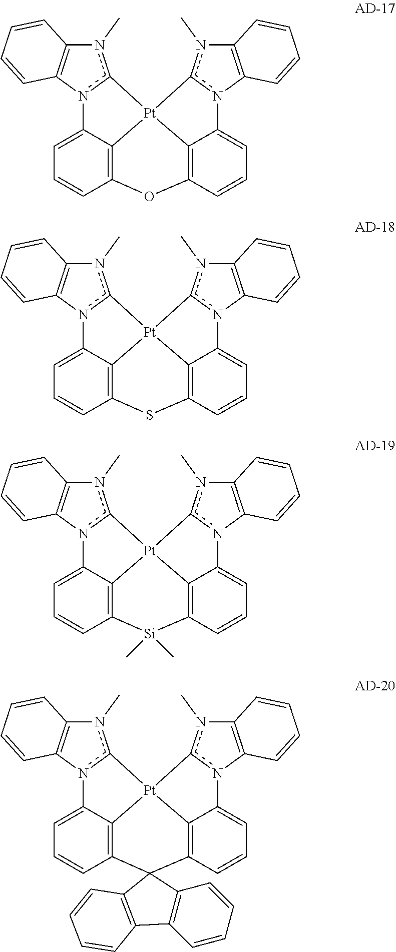

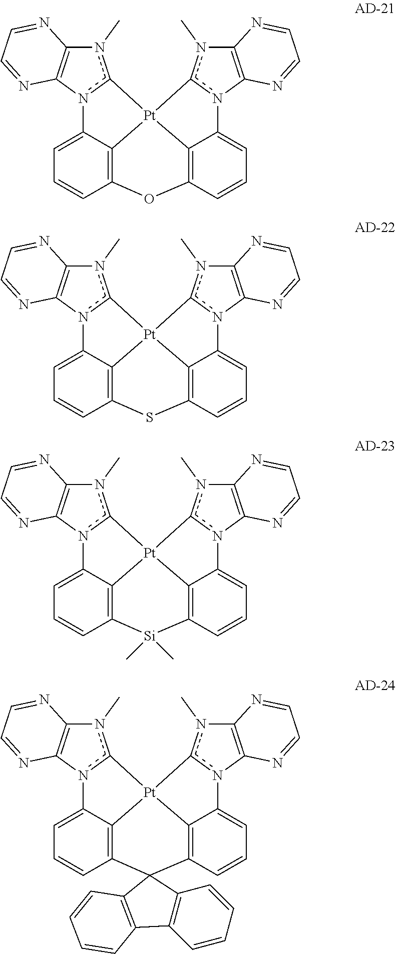

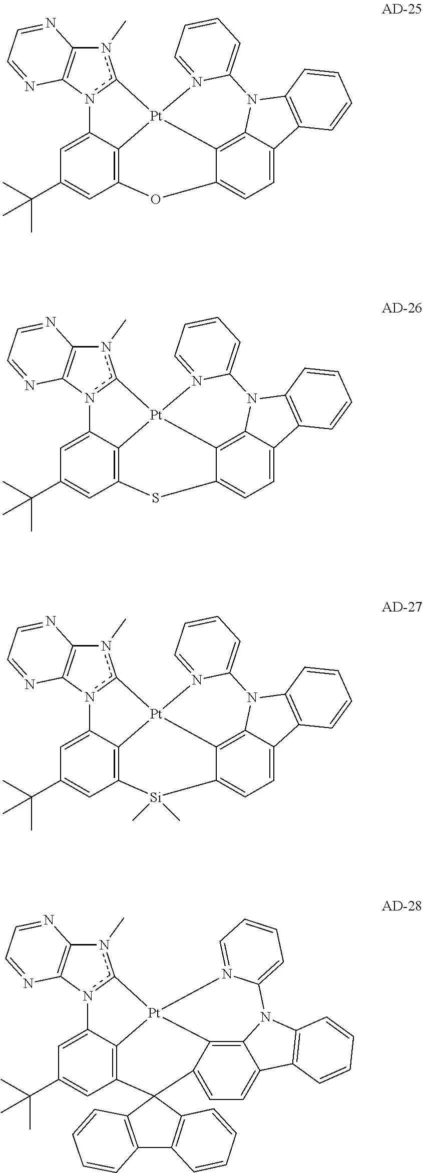

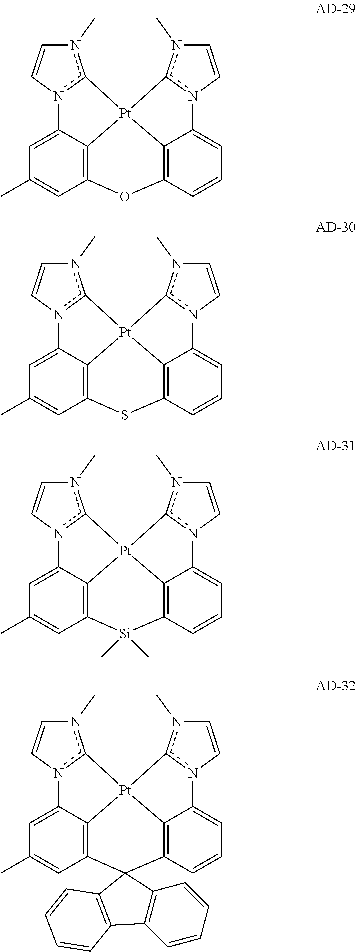

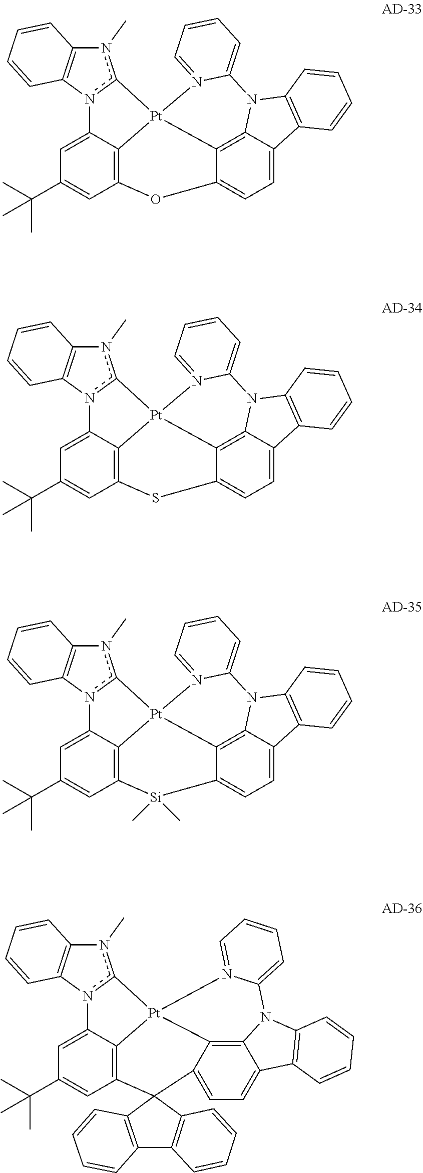

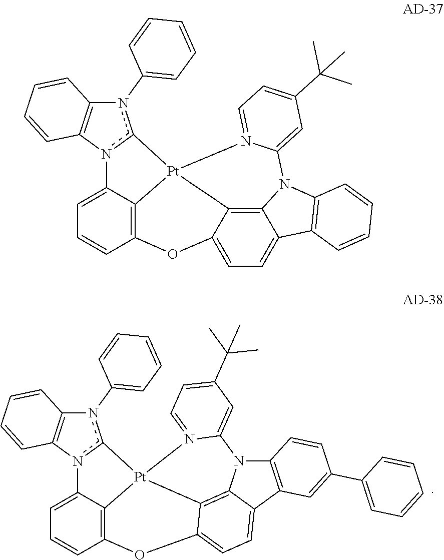

The light emitting device ED of an embodiment may include multiple emission layers. The multiple emission layers may be provided by stacking in order, for example, the light emitting device ED including the multiple emission layers may emit white light. The light emitting device including the multiple emission layers may be a light emitting device with a tandem structure. When the light emitting device ED includes multiple emission layers, at least one emission layer EML may include the first compound represented by Formula 1 of an embodiment. In some embodiments, when the light emitting device ED includes multiple emission layers, at least one emission layer EML may include all of the first compound, the second compound, the third compound and the fourth compound as described above.

When the emission layer EML in the light emitting device ED of an embodiment includes all the first compound, the second compound, the third compound and the fourth compound as described above, the amount of the first compound may be about 0.2 wt % to about 20 wt % based on the total amount of the first compound, the second compound, the third compound and the fourth compound. However, an embodiment of the present disclosure is not limited thereto. When the amount of the first compound satisfies the above-described ratio, the energy transfer from the second compound and the third compound to the first compound may increase, and accordingly, emission efficiency and device life may increase.

In the emission layer EML, the total amount of the second compound and the third compound may be a remaining amount excluding the amounts of the first compound and the fourth compound. For example, in the emission layer EML, the total amount of the second compound and the third compound may be about 50 wt % to about 98.8 wt % based on the total amount of the first compound, the second compound, the third compound and the fourth compound.

In the total amount of the second compound and the third compound, the weight ratio of the second compound and the third compound may be about 2:8 to about 8:2.

When the amounts of the second compound and the third compound satisfy the above-described ratio, charge balance properties in the emission layer EML may be improved, and emission efficiency and device life may increase. When the amounts of the second compound and the third compound deviate from the above-described ratio, charge balance in the emission layer EML may be lost, and emission efficiency may be degraded, and the device may be easily deteriorated.

The amount of the fourth compound in the emission layer EML may be about 1 wt % to about 30 wt % based on the total amount of the first compound, the second compound, the third compound and the fourth compound. However, an embodiment of the present disclosure is not limited thereto. When the amount of the fourth compound satisfies the above-described amount, the energy transfer from the host to the first compound that is a light emitting dopant may increase to improve a light emitting ratio, and accordingly, the emission efficiency of the emission layer EML may be improved.

When the first compound, the second compound, the third compound and the fourth compound, included in the emission layer EML satisfies the above-described range, excellent or suitable emission efficiency and long lifetime may be achieved.

In the light emitting device ED of an embodiment, the emission layer EML may include anthracene derivatives, pyrene derivatives, fluoranthene derivatives, chrysene derivatives, dihydrobenzanthracene derivatives, or triphenylene derivatives. For example, the emission layer EML may include anthracene derivatives or pyrene derivatives.

In the light emitting devices ED of embodiments, shown in FIGS. 3 to 6, the emission layer EML may further include generally utilized/generally available hosts and dopants in addition to the above-described host and dopant. For example, the emission layer EML may include a compound represented by Formula E-1. The compound represented by Formula E-1 may be utilized as a fluorescence host material.

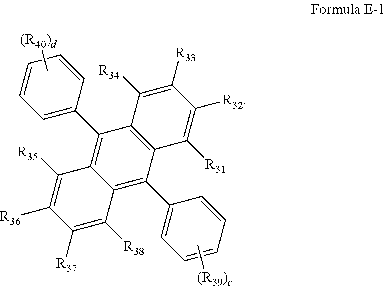

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 1 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In some embodiments, R₃₁ to R₄₀ may be combined with an adjacent group to form a saturated hydrocarbon ring, an unsaturated hydrocarbon ring, a saturated heterocycle or an unsaturated heterocycle.

In Formula E-1, “c” and “d” may each independently be an integer from 0 to 5.

Formula E-1 may be represented by any one selected from among Compound E1 to Compound E19.

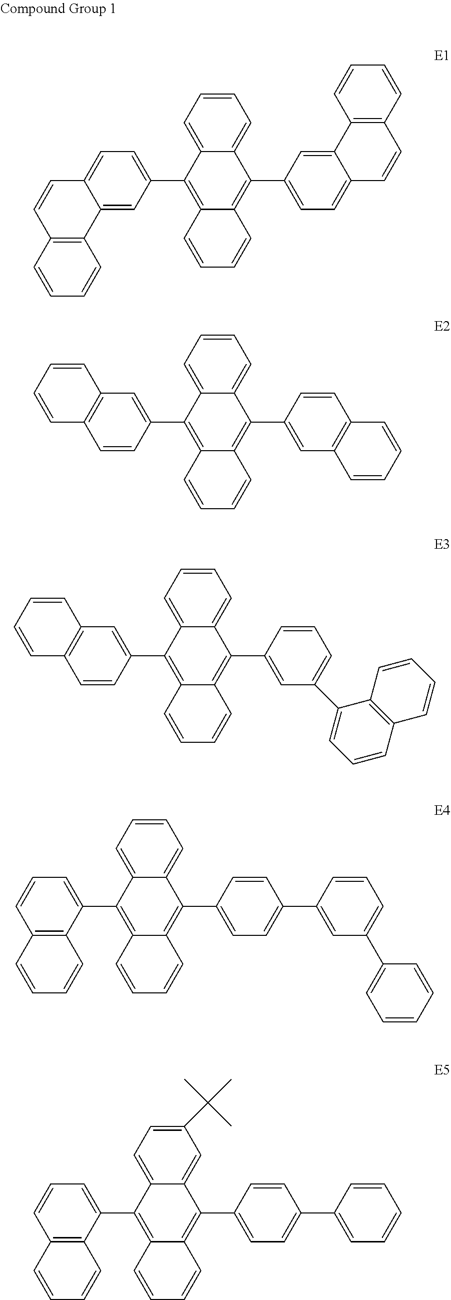

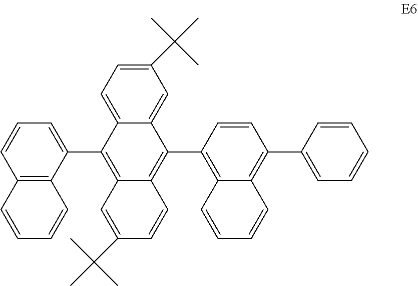 [SMILES: CC(C)(C)c1ccc2c(-c3ccc(-c4ccccc4)c4ccccc34)c3cc(C(C)(C)C)ccc3c(-c3cccc4ccccc34)c2c1]

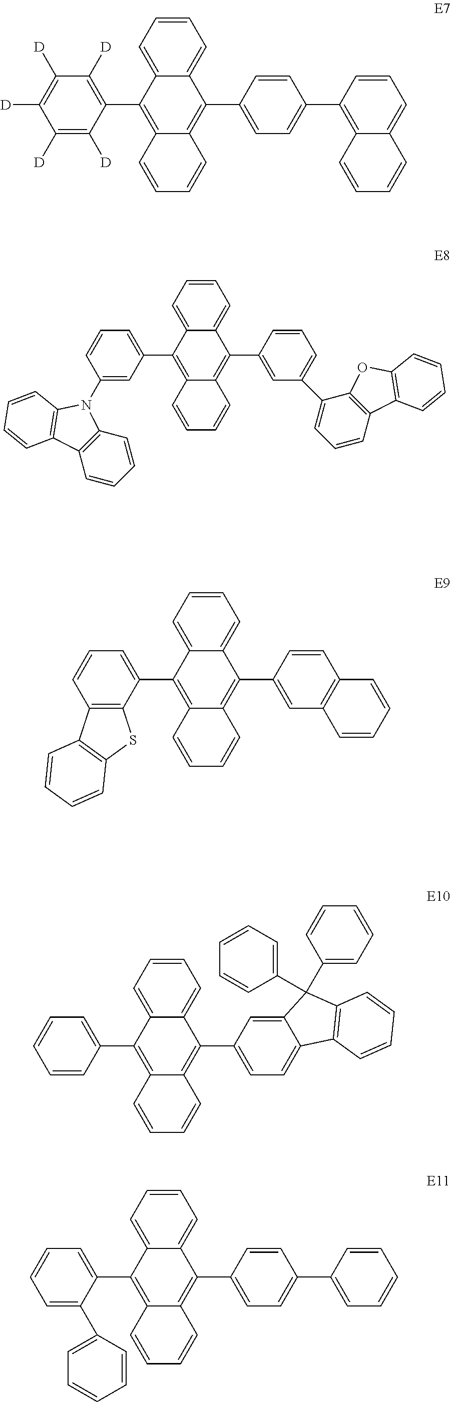

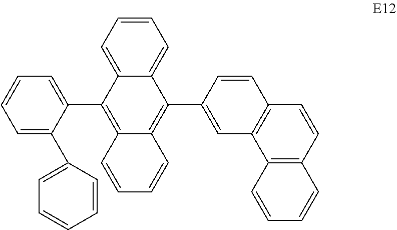 [SMILES: c1ccc(-c2ccccc2-c2c3ccccc3c(-c3ccc4ccc5ccccc5c4c3)c3ccccc23)cc1]

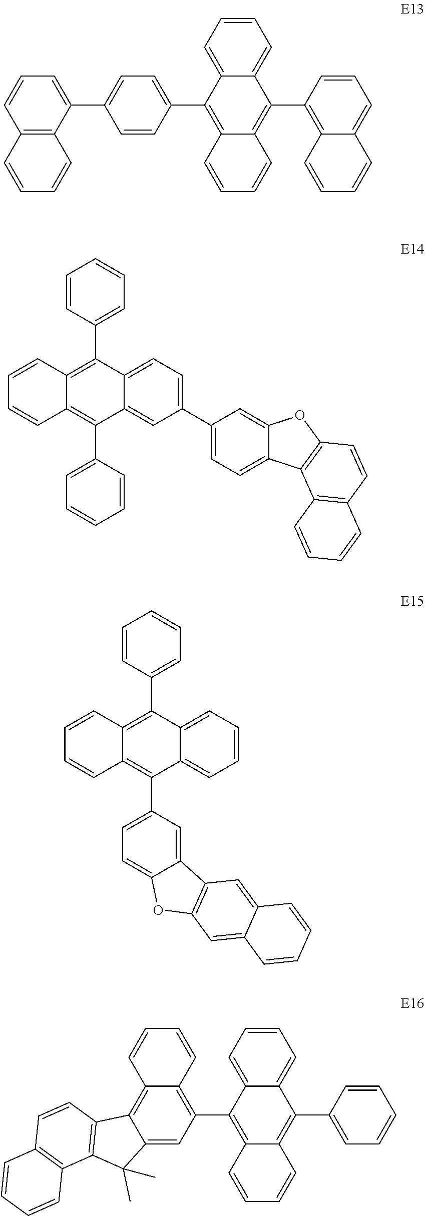

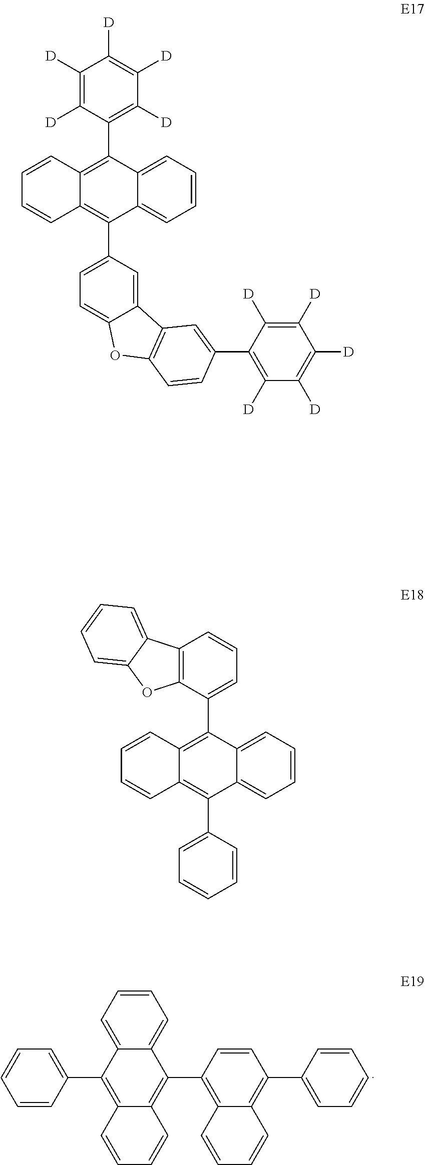

In an embodiment, the emission layer EML may further include a compound represented by Formula E-2a or Formula E-2b. The compound represented by Formula E-2a or Formula E-2b may be utilized as a phosphorescence host material.

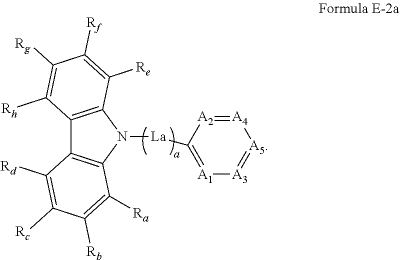

In Formula E-2b, “a” may be an integer from 0 to 10, La may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” is an integer of 2 or more, multiple La may each independently be a substituted or unsubstituted arylene group of 6 to 30 ring-forming carbon atoms, or a substituted or unsubstituted heteroarylene group of 2 to 30 ring-forming carbon atoms.

In some embodiments, in Formula E-2a, A₁ to A₅ may each independently be N or CRi. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Rₐ to Rᵢ may be combined with an adjacent group to form a hydrocarbon ring or a heterocycle including N, O, S, etc. as a ring-forming atom.

In some embodiments, in Formula E-2a, two or three substituents selected from A₁ to A₅ may be N, and the remainder may be CRᵢ.

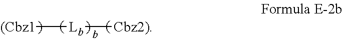

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” may be an integer from 0 to 10, and when “b” is an integer of 2 or more, multiple L_{b} may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one selected from among the compounds in Compound Group E-2. However, the compounds shown in Compound Group E-2 are merely illustrations/examples, and the compound represented by Formula E-2a or Formula E-2b is not limited to the compounds represented in Compound Group E-2.

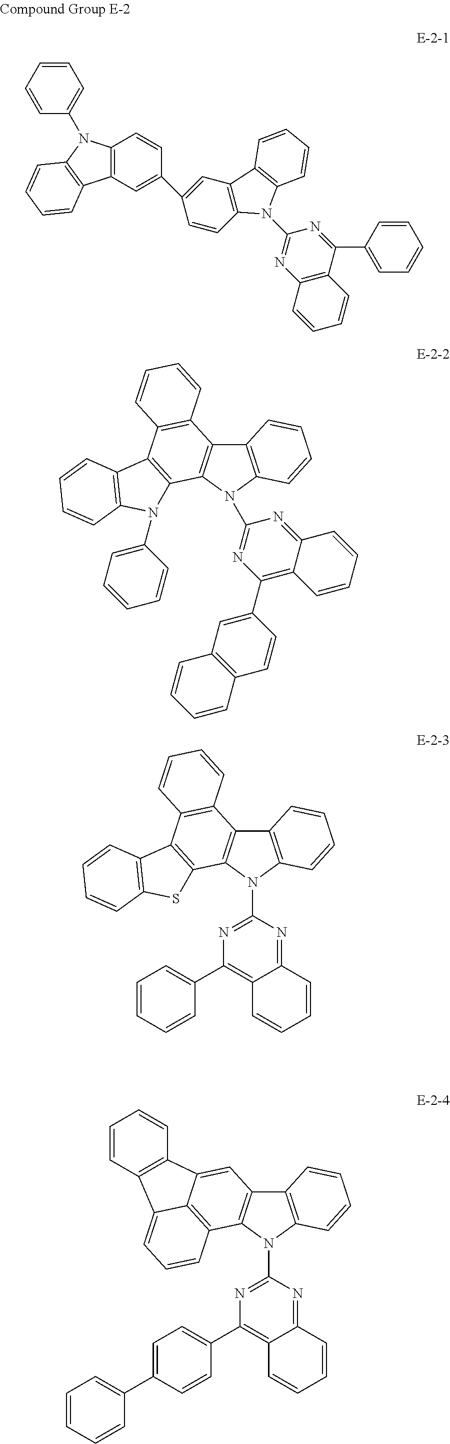

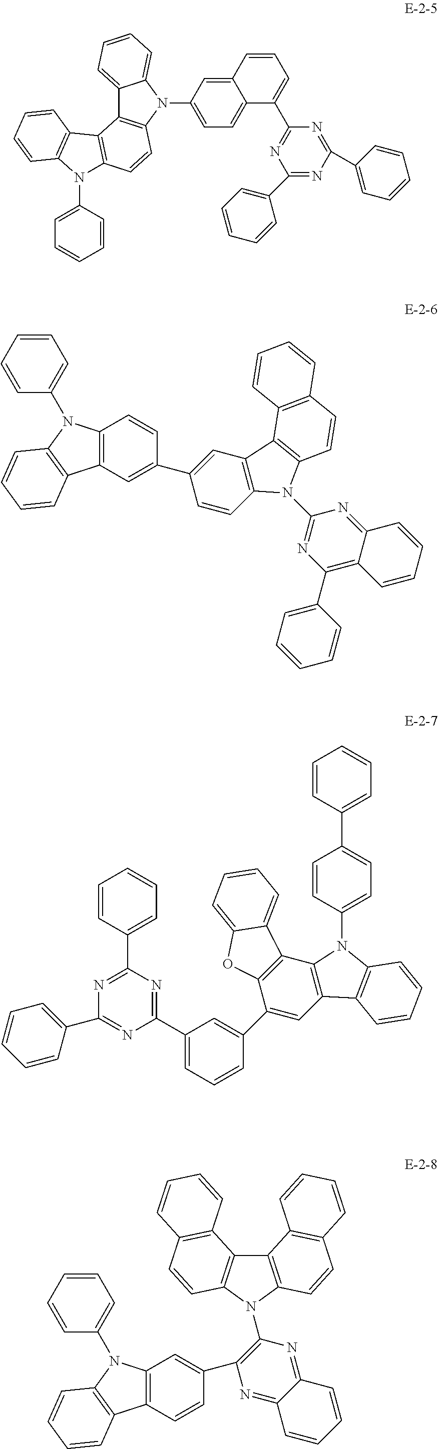 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

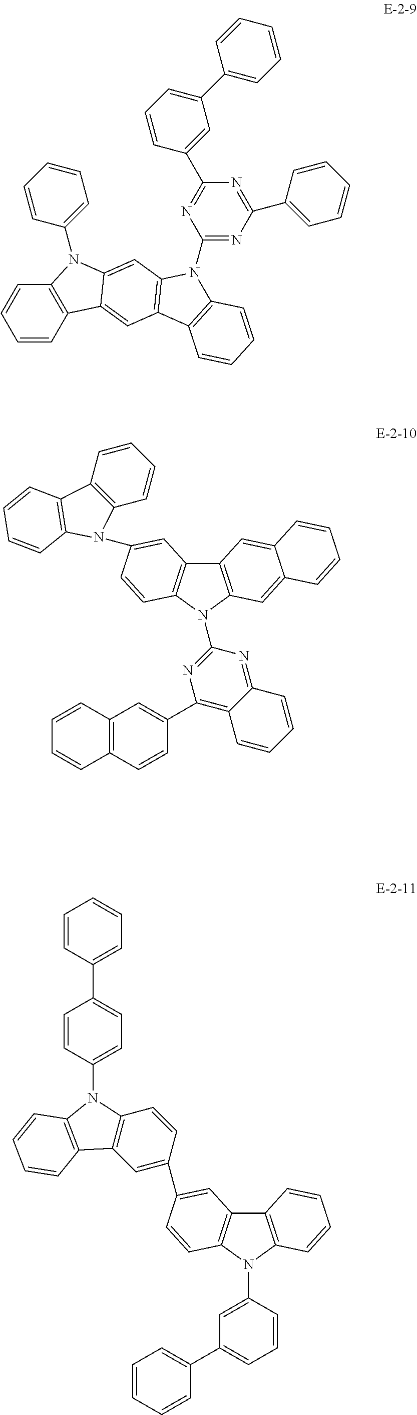 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

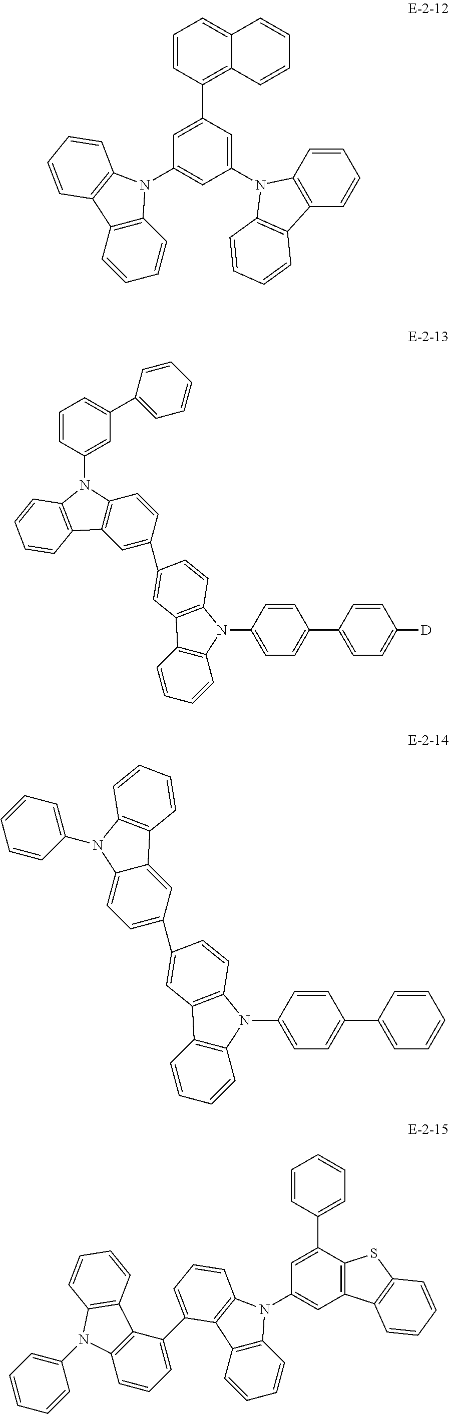 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

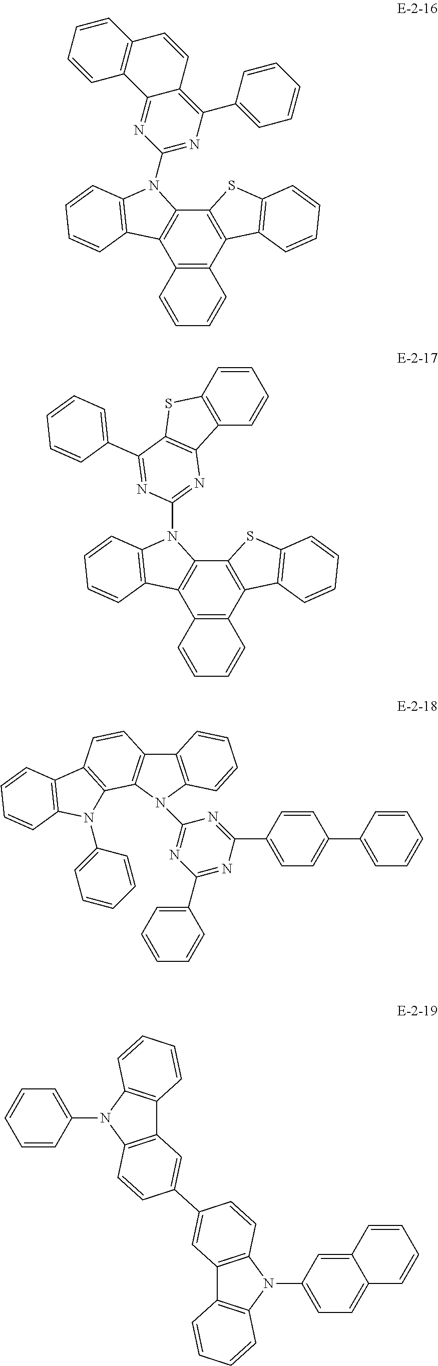

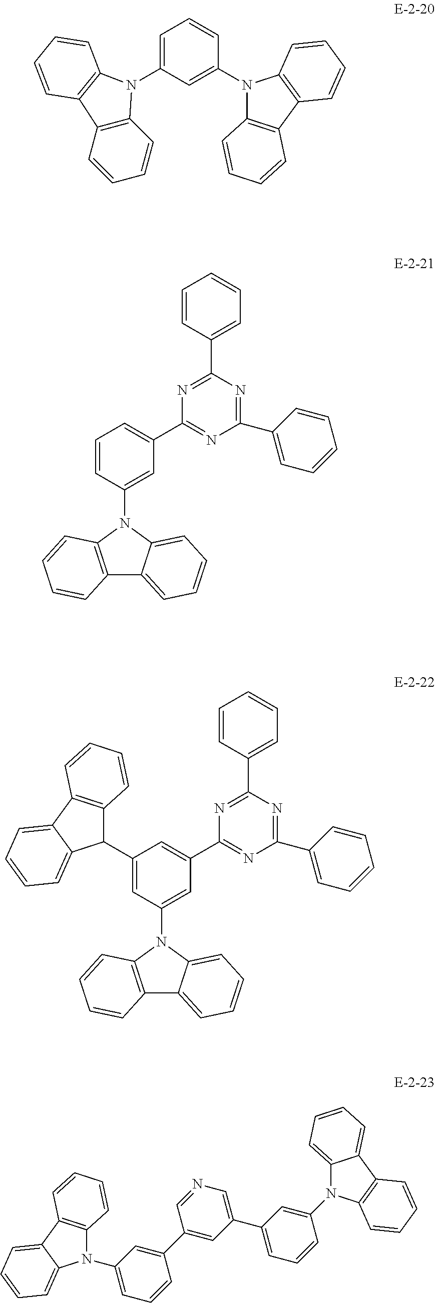 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(C4c5ccccc5-c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

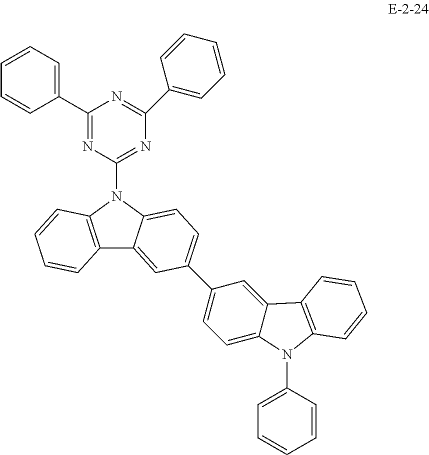 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a generally utilized/generally available material in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, an embodiment of the present disclosure is not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as the host material.

The emission layer EML may further include a compound represented by Formula M-a. The compound represented by Formula M-a may be utilized as a phosphorescence dopant material.

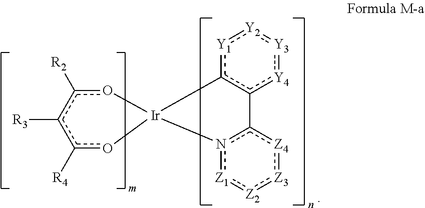

In Formula M-a, Y₁ to Y₄, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. In Formula M-a, “m” may be 0 or 1, and “n” may be 2 or 3. In Formula M-a, when “m” is 0, “n” is 3, and when “m” is 1, “n” is 2.

The compound represented by Formula M-a may be utilized as a phosphorescence dopant.

The compound represented by Formula M-a may be represented by any one selected from among Compounds M-a1 to M-a25. However, Compounds M-a1 to M-a25 are merely illustrations/examples, and the compound represented by Formula M-a is not limited to the compounds represented by Compounds M-a1 to M-a25.

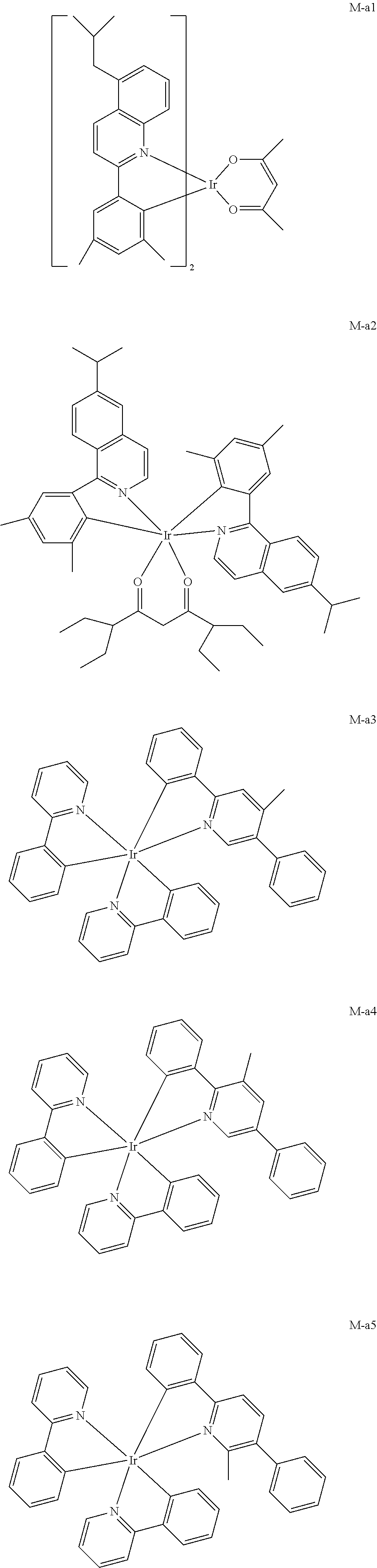

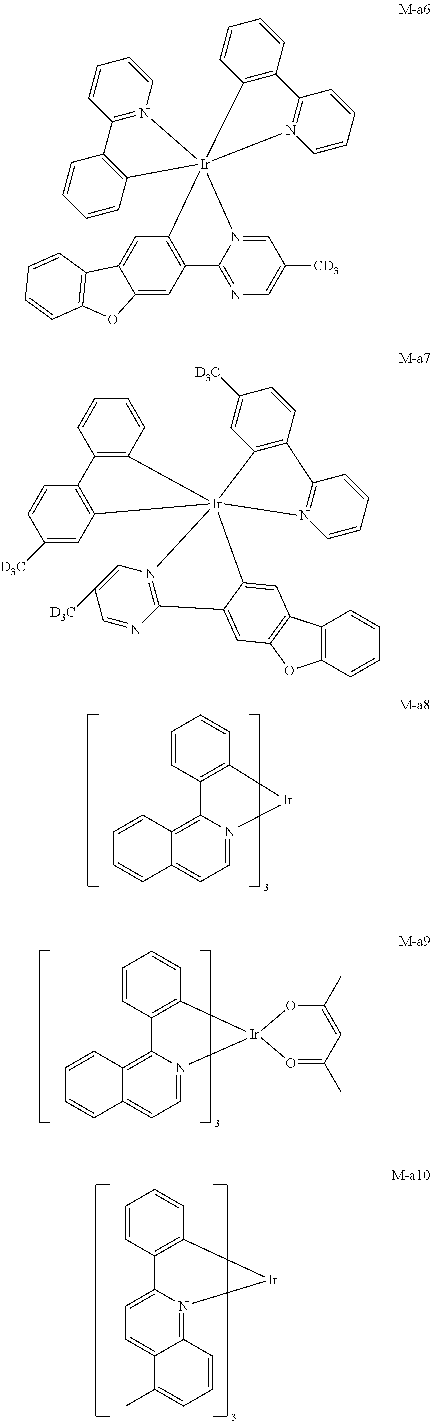

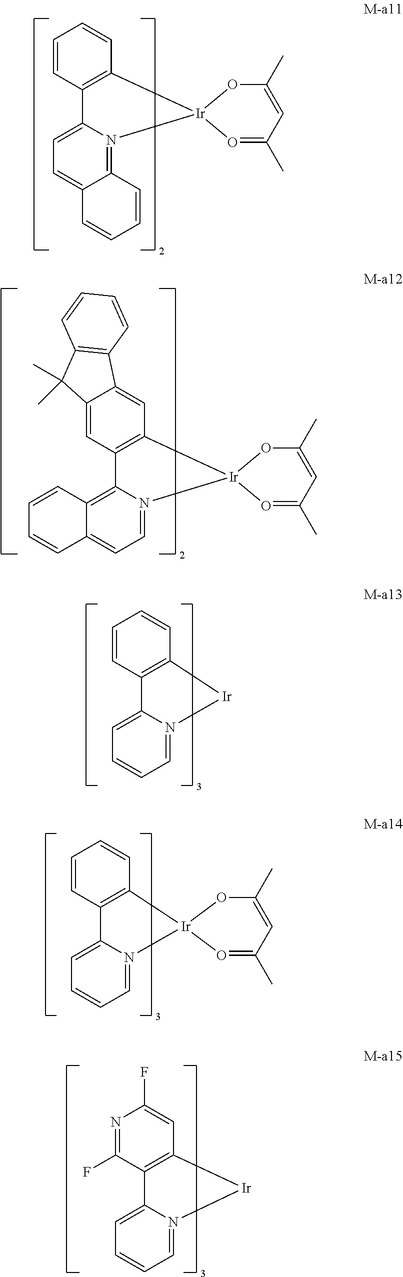

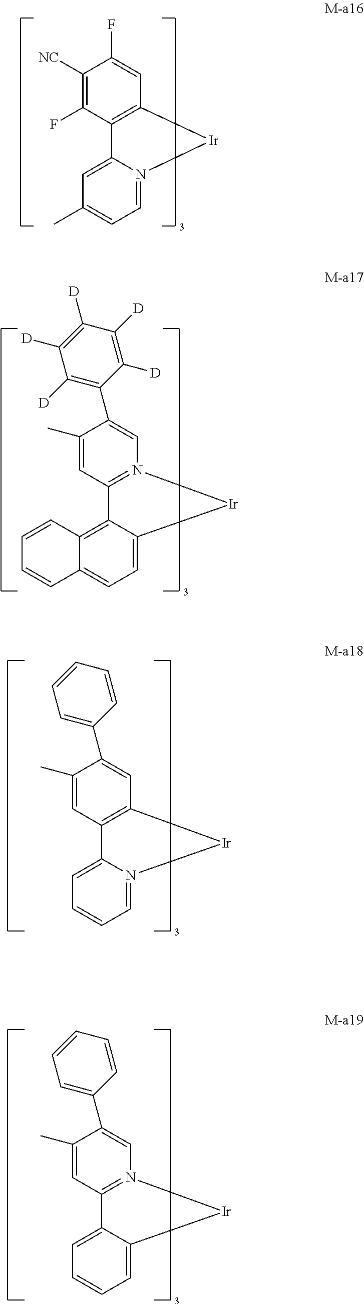

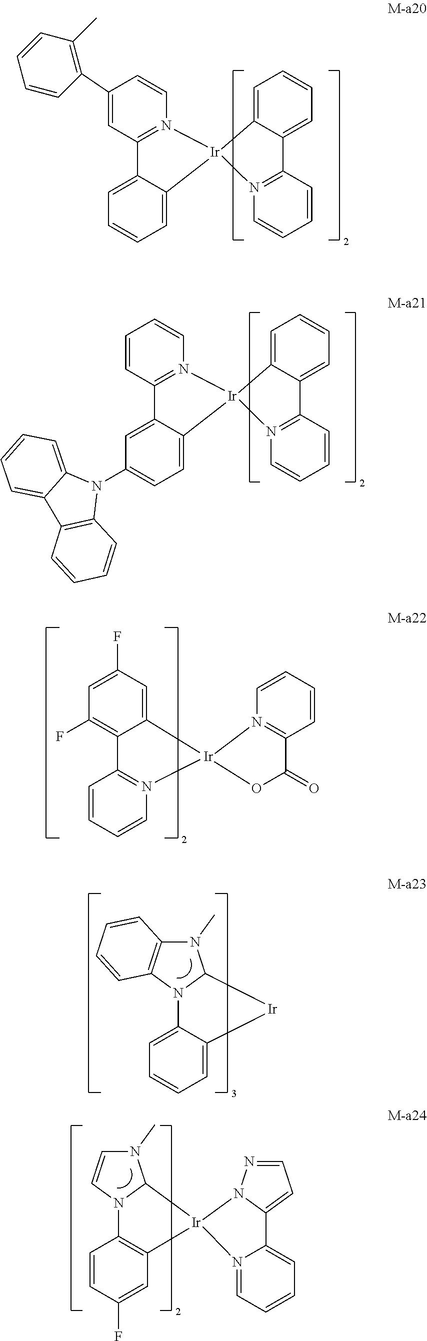

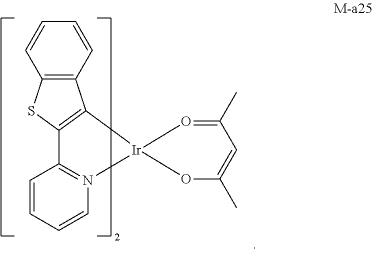

The emission layer EML may further include any one selected from among Formula F-a to Formula F-c. The compounds represented by Formula F-a to Formula F-c may be utilized as fluorescence dopant materials.

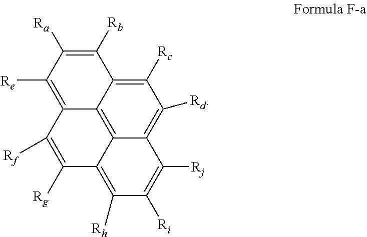

In Formula F-a, two substituents selected from among Rₐ to Rⱼ may each independently be substituted with *-NAr₁Ar₂. The remainder not substituted with *-NAr₁Ar₂ among Rₐ to Rⱼ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *-NAr₁Ar₂, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, at least one substituent selected from among Ar₁ and Ar₂ may be a heteroaryl group including O or S as a ring-forming atom.

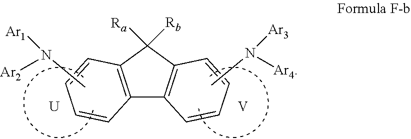

In Formula F-b, Ra and R_{b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms. At least one substituent selected from among Ar₁ to Ar₄ may be a heteroaryl group including O or S as a ring-forming atom.

In Formula F-b, the number of rings represented by U and V may each independently be 0 or 1. For example, in Formula F-b, when the number of U or V is 1, one ring forms a fused ring at the designated part by U or V, and when the number of U or V is 0, a ring is not present at the designated part by U or V. For example, when the number of U is 0, and the number of V is 1, or when the number of U is 1, and the number of V is 0, a fused ring having the fluorene core of Formula F-b may be a ring compound with four rings. In some embodiments, when the number of both (e.g., simultaneously) U and V is 0, the fused ring of Formula F-b may be a ring compound with three rings. In some embodiments, when the number of both (e.g., simultaneously) U and V is 1, a fused ring having the fluorene core of Formula F-b may be a ring compound with five rings.

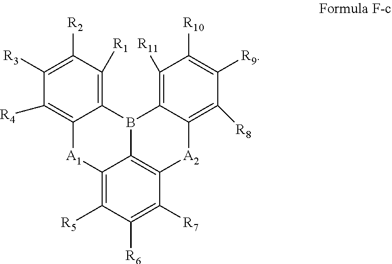

In Formula F-c, A₁ and A₂ may each independently be O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-c, A₁ and A₂ may each independently be combined with the substituents of an adjacent ring to form a fused ring. For example, when A₁ and A₂ may each independently be NRₘ, A₁ may be combined with R₄ or R₅ to form a ring. In some embodiments, A₂ may be combined with R₇ or R₈ to form a ring.

In an embodiment, the emission layer EML may include as a generally utilized/generally available dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and/or 4,4′-bis[2-(4-(N,N-diphenylamino)phenyl)vinyl]biphenyl (DPAVBi)), perylene and/or the derivatives thereof (for example, 2,5,8,11-tetra-t-butylperylene (TBP)), pyrene and/or the derivatives thereof (for example, 1,1-dipyrene, 1,4-dipyrenylbenzene, and/or 1,4-bis(N,N-diphenylamino)pyrene), etc.

The emission layer EML may include a generally utilized/generally available phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be utilized as the phosphorescence dopant. However, an embodiment of the present disclosure is not limited thereto.

The emission layer EML may include a quantum dot material. The core of the quantum dot may be selected from among a II-VI group compound, a III-VI group compound, a I-III-VI group compound, a III-V group compound, a III-II-V group compound, a IV-VI group compound, a IV group element, a IV group compound, and one or combinations thereof.

The II-VI group compound may be selected from the group including (e.g., consisting of): a binary compound selected from the group including (e.g., consisting of) CdSe, CdTe, CdS, ZnS, ZnSe, ZnTe, ZnO, HgS, HgSe, HgTe, MgSe, MgS, and one or more compounds or mixtures thereof; a ternary compound selected from the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and one or more compounds or mixtures thereof; and a quaternary compound selected from the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe, and one or more compounds or mixtures thereof.

The III-VI group compound may include a binary compound such as In₂S₃, and In₂Se₃, a ternary compound such as InGaS₃, and InGaSe₃, or one or more combinations thereof.

The I-III-VI group compound may be selected from a ternary compound selected from the group including (e.g., consisting of) AgInS, AgInS₂, CuInS, CuInS₂, AgGaS₂, CuGaS₂, CuGaO₂, AgGaO₂, AgAlO₂ and one or more compounds or mixtures thereof, or a quaternary compound such as AgInGaS₂, and CuInGaS₂ (the quaternary compound may be used alone or in combination with any of the foregoing compounds or mixtures; and the quaternary compound may also be combined with other quaternary compounds).

The III-V group compound may be selected from the group including (e.g., consisting of) a binary compound selected from the group including (e.g., consisting of) GaN, GaP, GaAs, GaSb, AlN, AlP, AlAs, AlSb, InN, InP, InAs, InSb, and one or more compounds or mixtures thereof, a ternary compound selected from the group including (e.g., consisting of) GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and one or more compounds or mixtures thereof, and a quaternary compound selected from the group including (e.g., consisting of) GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and one or more compounds or mixtures thereof. In some embodiments, the III-V group compound may further include a II group metal. For example, InZnP, etc. may be selected as a III-II-V group compound.

The IV-VI group compound may be selected from the group including (e.g., consisting of) a binary compound selected from the group including (e.g., consisting of) SnS, SnSe, SnTe, PbS, PbSe, PbTe, and one or more compounds or mixtures thereof, a ternary compound selected from the group including (e.g., consisting of) SnSeS, SnSeTe, SnSTe, PbSeS, PbSeTe, PbSTe, SnPbS, SnPbSe, SnPbTe, and one or more compounds or mixtures thereof, and a quaternary compound selected from the group including (e.g., consisting of) SnPbSSe, SnPbSeTe, SnPbSTe, and one or more compounds or mixtures thereof. The IV group element may be selected from the group including (e.g., consisting of) Si, Ge, and one or more elements or mixtures thereof. The IV group compound may be a binary compound selected from the group including (e.g., consisting of) SiC, SiGe, and one or more compounds or mixtures thereof.

In this embodiment, the binary compound, the ternary compound or the quaternary compound may be present at substantially uniform concentration in a particle form or may be present at a partially different concentration distribution state in substantially the same particle form. In some embodiments, a core/shell structure in which one quantum dot wraps another quantum dot may be possible. The interface of the core and the shell may have a concentration gradient in which the concentration of an element present in the shell decreases toward the center.

In some embodiments, the quantum dot may have the above-described core-shell structure including a core including a nanocrystal and a shell wrapping around (e.g., surrounding) the core. The shell of the quantum dot may play the role of a protection layer for preventing or reducing the chemical deformation of the core to maintain semiconductor properties and/or a charging layer for imparting the quantum dot with electrophoretic properties (beneficial properties). The shell may have a single layer or a multilayer. Examples of the shell of the quantum dot may include a metal or non-metal oxide, a semiconductor compound, or one or more combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄ and/or NiO, and/or a ternary compound such as MgAl₂O₄, CoFe₂O₄, NiFe₂O₄ and/or CoMn₂O₄, but an embodiment of the present disclosure is not limited thereto.

In some embodiments, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but an embodiment of the present disclosure is not limited thereto.

The quantum dot may have a full width of half maximum (FWHM) of emission wavelength spectrum of about 45 nm or less, about 40 nm or less, or about 30 nm or less. Within these ranges, color purity or color reproducibility may be improved. In some embodiments, light emitted via such a quantum dot is emitted in all directions, and light view angle properties may be improved.

In some embodiments, the shape/form of the quantum dot may be generally utilized/generally available shapes/form in the art, without limitation. For example, the shape of a substantially spherical, pyramidal, multi-arm, or cubic nanoparticle, nanotube, nanowire, nanofiber, nanoplate particle, etc. may be utilized.

The quantum dot may control (select) the color of light emitted according to the particle size, and accordingly, the quantum dot may have one or more suitable emission colors such as blue, red and green.

In the light emitting devices ED of embodiments, as shown in FIGS. 3 to 6, the electron transport region ETR is provided on the emission layer EML. The electron transport region ETR may include at least one of an electron blocking layer HBL, an electron transport layer ETL or an electron injection layer EIL. However, an embodiment of the present disclosure is not limited thereto.

The electron transport region ETR may have a single layer formed utilizing a single material, a single layer formed utilizing multiple different materials, or a multilayer structure having multiple layers formed utilizing multiple different materials.

For example, the electron transport region ETR may have a single layer structure of an electron injection layer EIL or an electron transport layer ETL, or a single layer structure formed utilizing an electron injection material and an electron transport material. Further, the electron transport region ETR may have a single layer structure formed utilizing multiple different materials, or a structure stacked from the emission layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1.

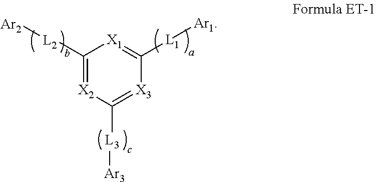

In Formula ET-1, at least one selected from among X₁ to X₃ may be N, and the remainder may be CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-1, “a” to “c” may each independently be an integer from 0 to 10. In Formula ET-1, L₁ to L₃ may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” to “c” may be integers of 2 or more, L₁ to L₃ may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, an embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), and/or one or more compounds or mixtures thereof, without limitation.

The electron transport region ETR may include at least one selected from among Compounds ET1 to ET36.

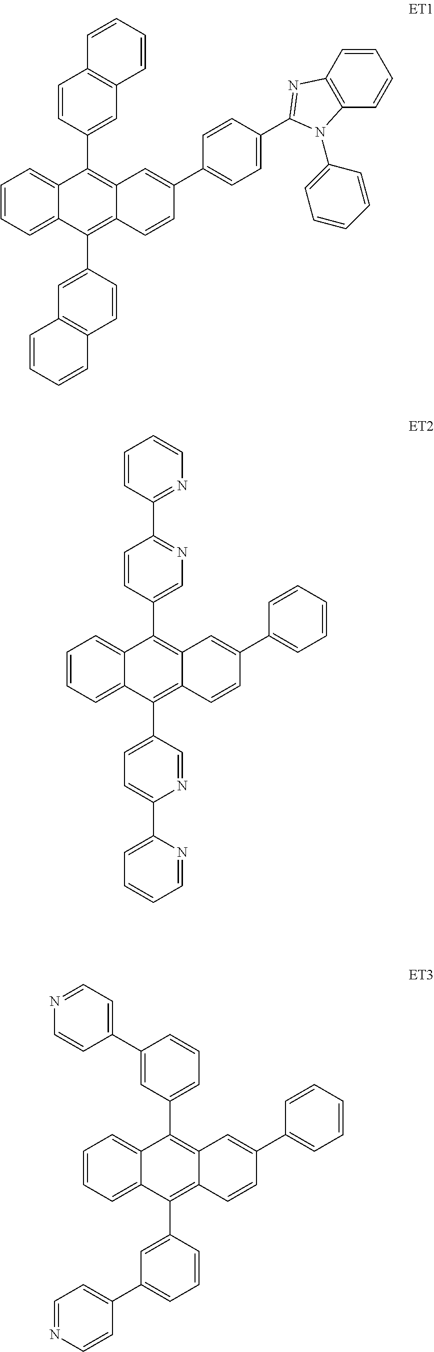 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

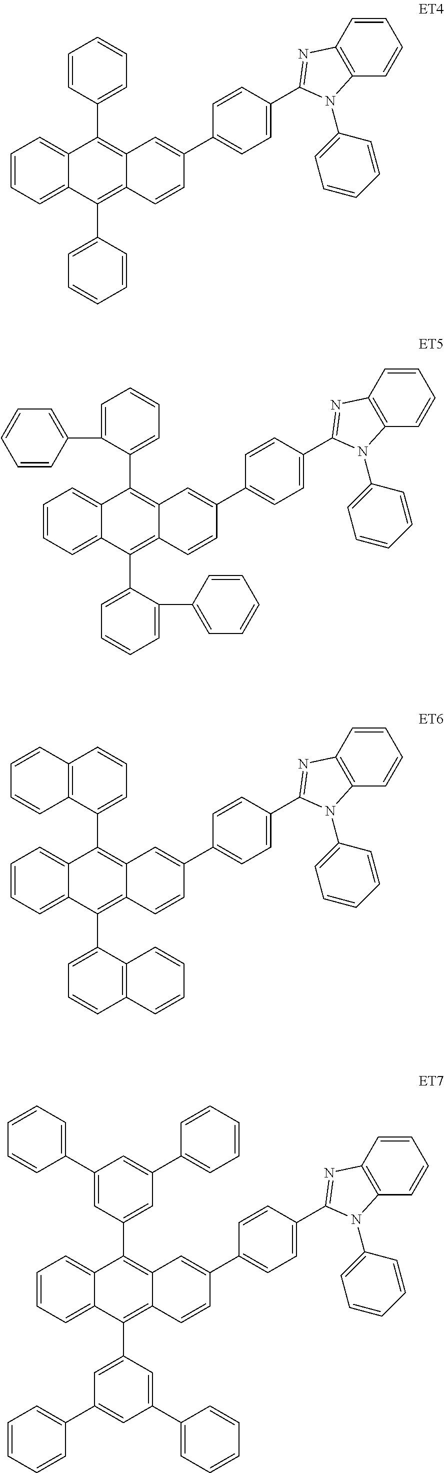 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

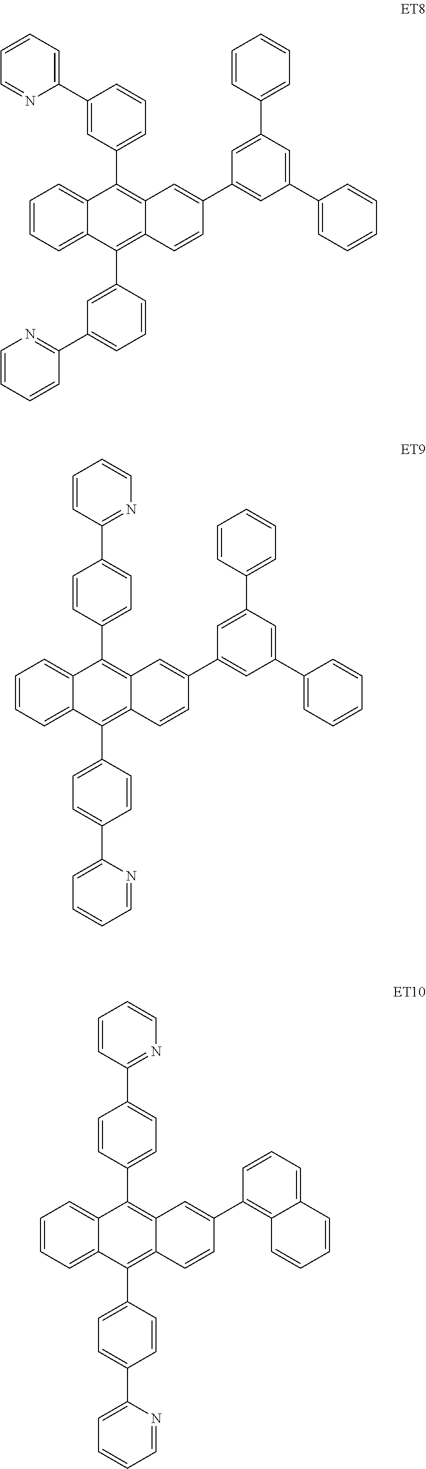 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

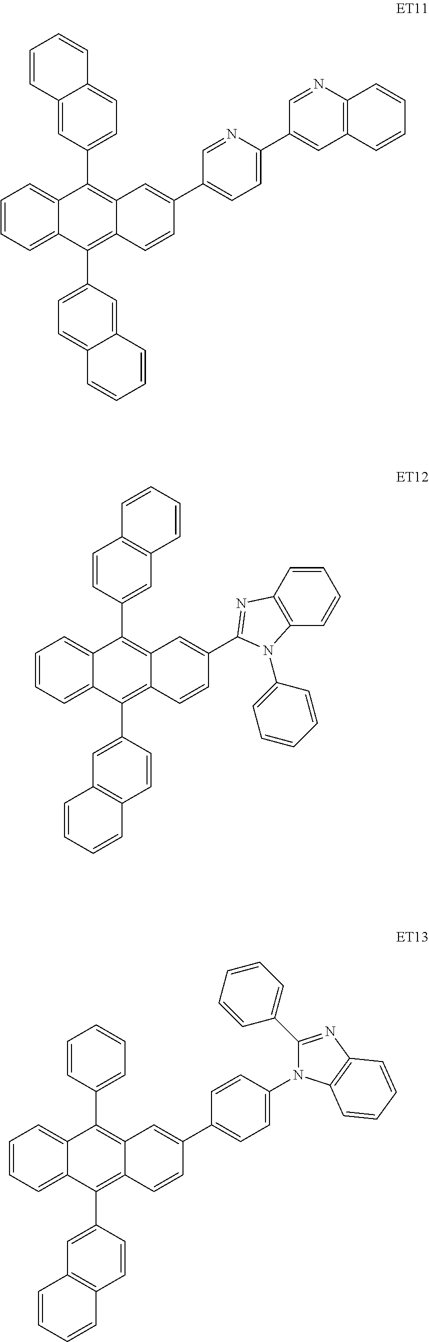 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

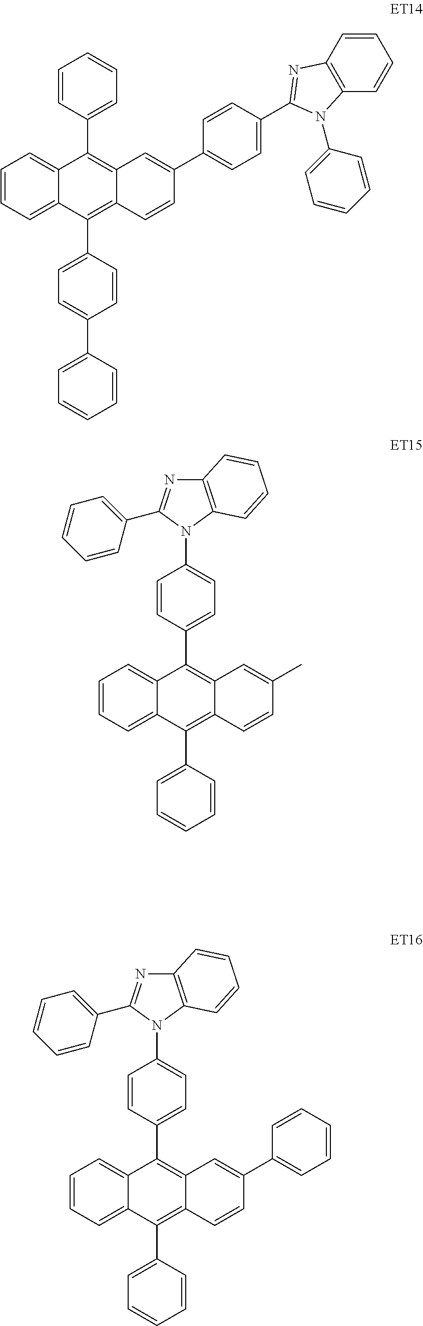 [SMILES: c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

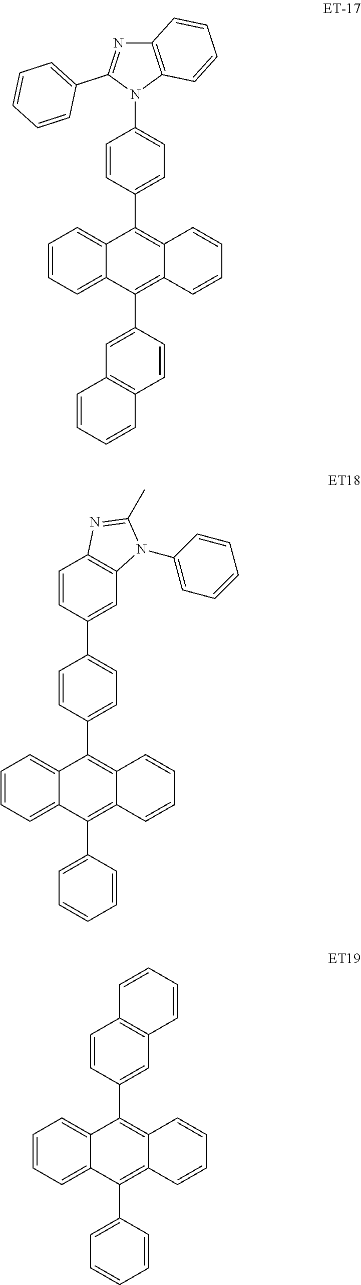

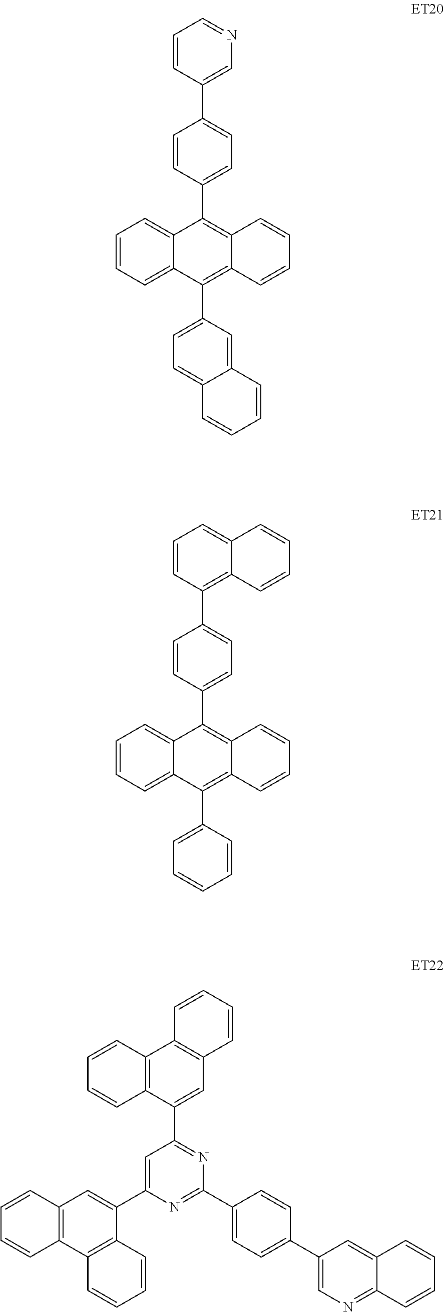

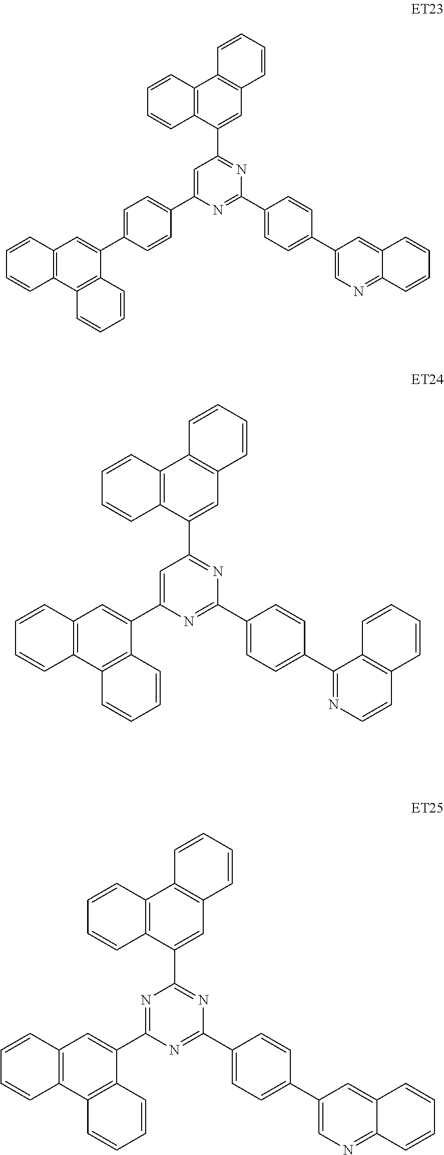 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

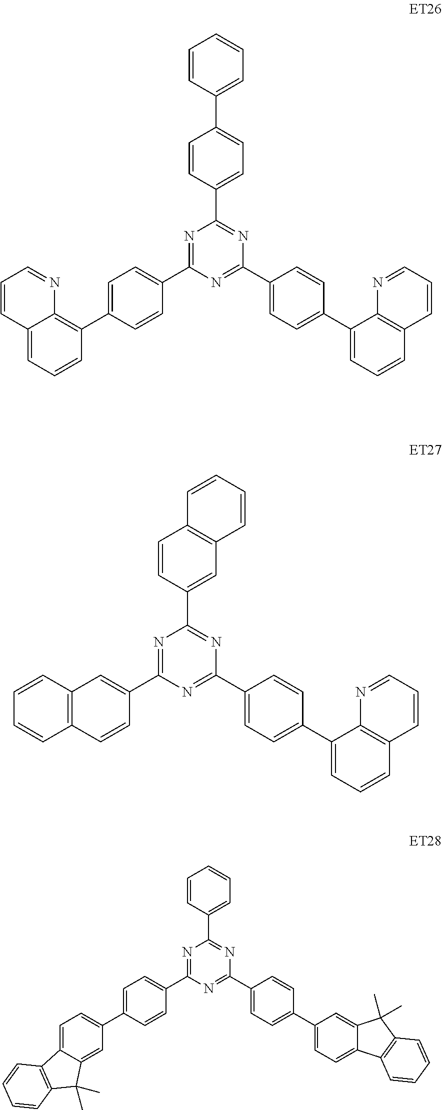 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

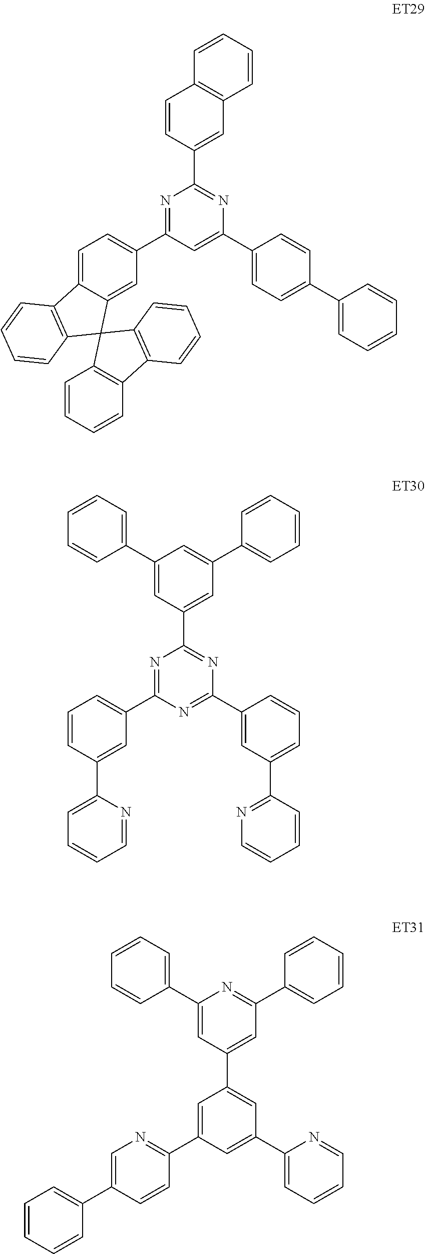 [SMILES: c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1]

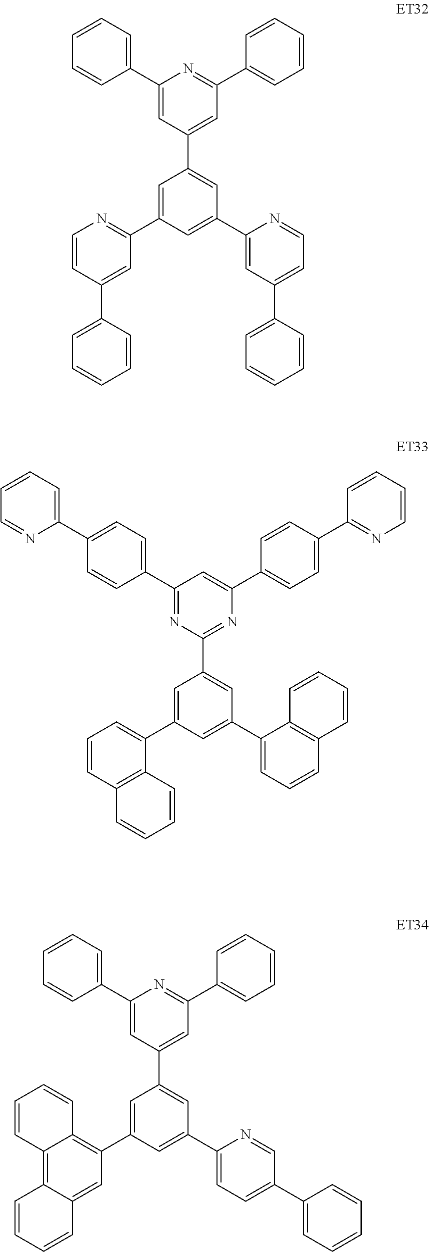 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1]

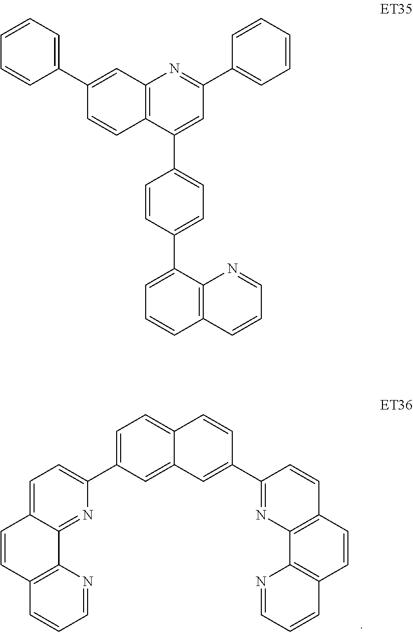 [SMILES: c1ccc(-c2ccc3c(-c4ccc(-c5cccc6cccnc56)cc4)cc(-c4ccccc4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI and/or KI, lanthanide metals such as Yb, co-deposition materials of a halogenated metal and/or a lanthanide metal. For example, the electron transport region ETR may include KI:Yb, RbI:Yb, LiF:Yb, etc., as the co-depositing material. In some embodiments, the electron transport region ETR may utilize a metal oxide such as Li₂O and/or BaO, and/or 8-hydroxy-lithium quinolate (Liq). However, an embodiment of the present disclosure is not limited thereto. The electron transport region ETR also may be formed utilizing a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, an embodiment of the present disclosure is not limited thereto.

The electron transport region ETR may include the compounds of the electron transport region in at least one selected from among an electron injection layer EIL, an electron transport layer ETL, and a hole blocking layer HBL.

When the electron transport region ETR includes the electron transport layer ETL, the thickness of the electron transport layer ETL may be from about 100 Å to about 1,000 Å, for example, from about 150 Å to about 500 Å. When the thickness of the electron transport layer ETL satisfies the above-described range, satisfactory (suitable) electron transport properties may be obtained without a substantial increase of a driving voltage. When the electron transport region ETR includes the electron injection layer EIL, the thickness of the electron injection layer EIL may be from about 1 A to about 100 Å, or from about 3 Å to about 90 Å. When the thickness of the electron injection layer EIL satisfies the above described range, satisfactory (suitable) electron injection properties may be obtained without inducing a substantial increase of a driving voltage.

The second electrode EL2 is provided on the electron transport region ETR. The second electrode EL2 may be a common electrode. The second electrode EL2 may be a cathode or an anode, but an embodiment of the present disclosure is not limited thereto. For example, when the first electrode EL1 is an anode, the second cathode EL2 may be a cathode, and when the first electrode EL1 is a cathode, the second electrode EL2 may be an anode.

The second electrode EL2 may be a transmissive electrode, a transflective electrode or a reflective electrode. When the second electrode EL2 is the transmissive electrode, the second electrode EL2 may include a transparent metal oxide, for example, ITO, IZO, ZnO, ITZO, etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, one or more compounds including thereof, or one or more mixtures thereof (for example, AgMg, AgYb, or MgYb). In some embodiments, the second electrode EL2 may have a multilayered structure including a reflective layer or a transflective layer formed utilizing the above-described materials and a transparent conductive layer formed utilizing ITO, IZO, ZnO, ITZO, etc. For example, the second electrode EL2 may include the aforementioned metal material(s), combination(s) of two or more metal materials selected from the aforementioned metal materials, or one or more oxides of the aforementioned metal materials.

The second electrode EL2 may be connected with an auxiliary electrode. When the second electrode EL2 is connected with the auxiliary electrode, the resistance of the second electrode EL2 may decrease.

On the second electrode EL2 in the light emitting device ED of an embodiment, a capping layer CPL may be further disposed. The capping layer CPL may include a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNx, SiOy, etc.

For example, when the capping layer CPL includes an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol-9-yl) triphenylamine (TCTA), etc., or includes an epoxy resin, or acrylate such as methacrylate. In some embodiments, a capping layer CPL may include at least one selected from among Compounds P1 to P5, but an embodiment of the present disclosure is not limited thereto.

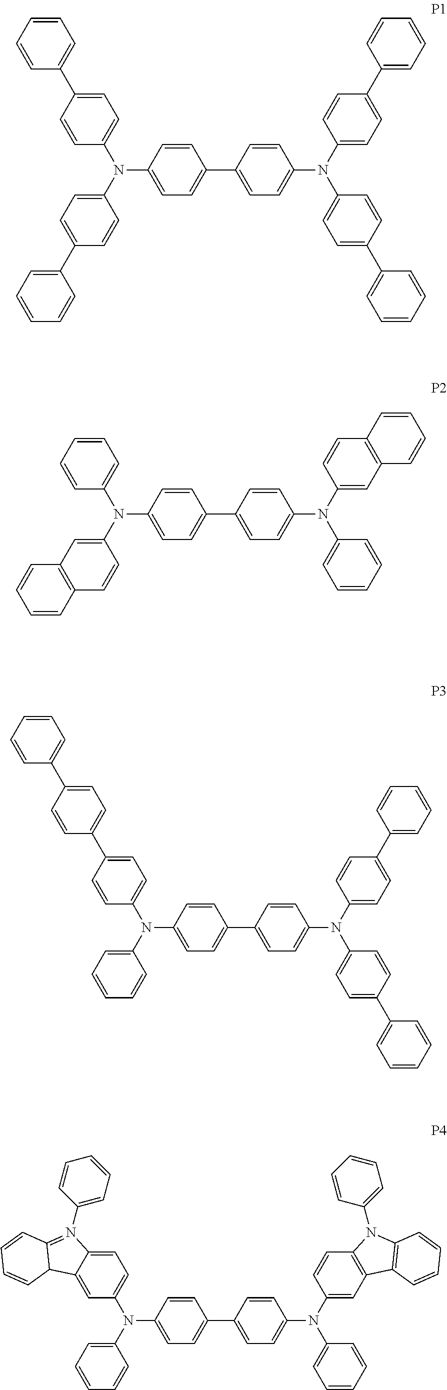

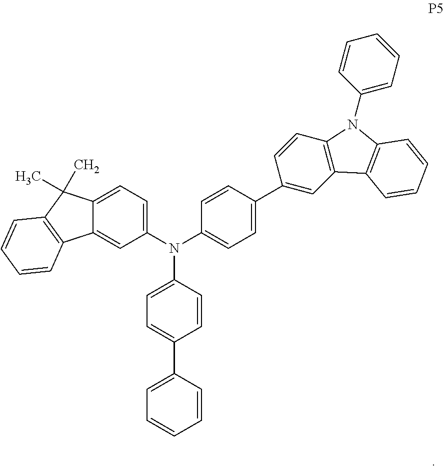 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL with respect to light in a wavelength range of about 550 nm to about 660 nm may be about 1.6 or more.

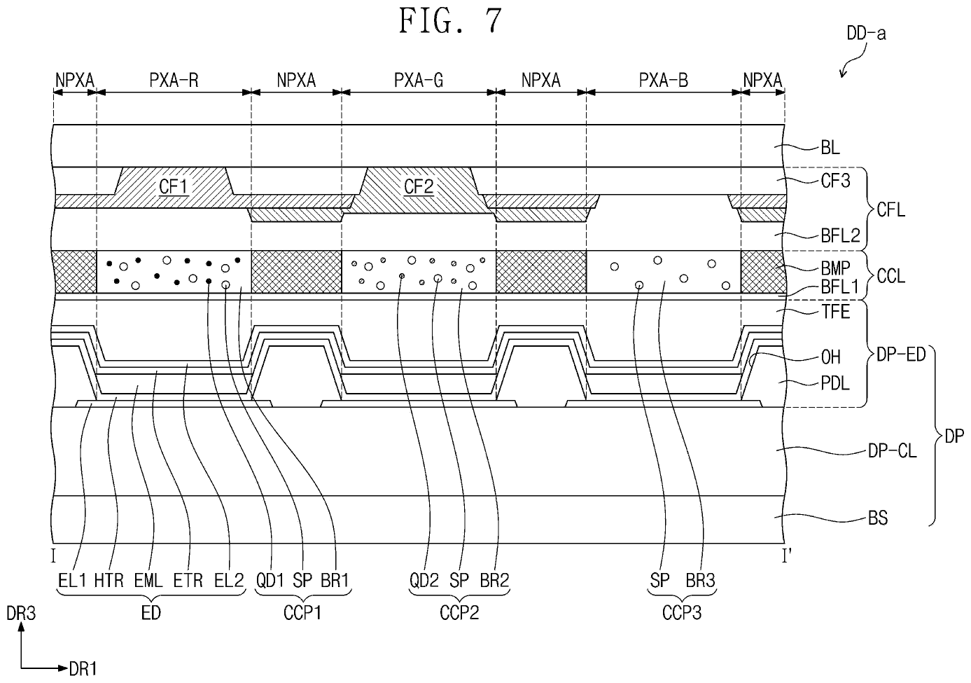

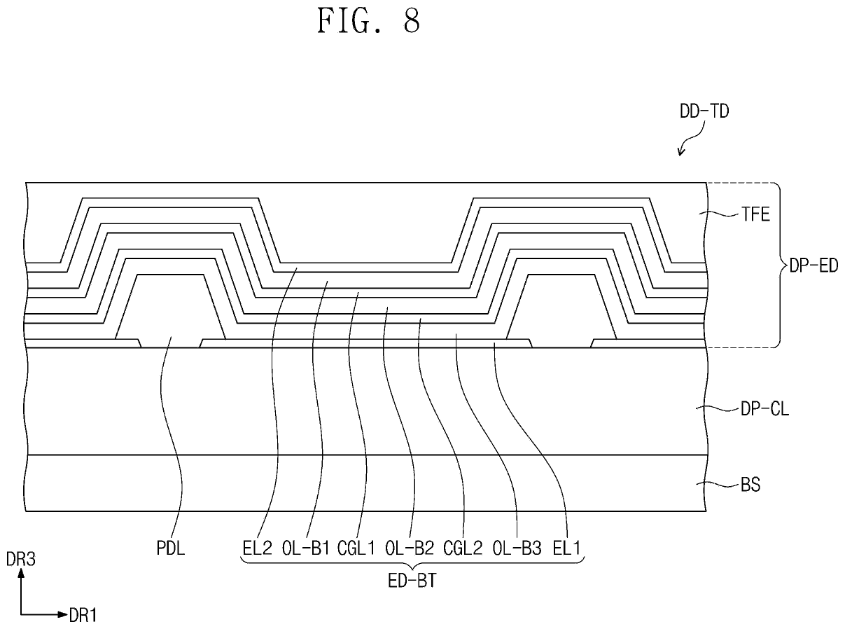

FIG. 7 and FIG. 8 are cross-sectional views of display apparatuses according to embodiments of the present disclosure. In the explanation on the display apparatuses of embodiments, referring to FIG. 7 and FIG. 8, the overlapping parts with the explanation on FIGS. 1 to 6 may not be explained again, and the different features will primarily be explained.

Referring to FIG. 7, the display apparatus DD according to an embodiment may include a display panel DP including a display device layer DP-ED, a light controlling layer CCL on the display panel DP and a color filter layer CFL.

In an embodiment shown in FIG. 7, the display panel DP includes a base layer BS, a circuit layer DP-CL provided on the base layer BS and a display device layer DP-ED, and the display device layer DP-ED may include a light emitting device ED.

The light emitting device ED may include a first electrode EL1, a hole transport region HTR on the first electrode EL1, an emission layer EML on the hole transport region HTR, an electron transport region ETR don the emission layer EML, and a second electrode EL2 on the electron transport region ETR. In some embodiments, the same structures of the light emitting devices of FIGS. 3 to 6 may be applied to the structure of the light emitting device ED shown in FIG. 7.

In the display apparatus DD-a according to an embodiment, the emission layer EML of the light emitting device ED included may include the above-described fused polycyclic compound of an embodiment.

Referring to FIG. 7, the emission layer EML may be disposed in an opening part OH defined in a pixel definition layer PDL. For example, the emission layer EML divided by the pixel definition layer PDL and correspondingly provided to each of luminous areas PXA-R, PXA-G and PXA-B may emit light in substantially the same wavelength region. In the display apparatus DD of an embodiment, the emission layer EML may emit blue light. In an embodiment, the emission layer EML may be provided as a common layer for all luminous areas PXA-R, PXA-G and PXA-B.

The light controlling layer CCL may be on the display panel DP. The light controlling layer CCL may include a light converter. The light converter may be a quantum dot or a phosphor. The light converter may transform the wavelength of light provided and then emit. For example, the light controlling layer CCL may be a layer including a quantum dot or a layer including a phosphor.

The light controlling layer CCL may include multiple light controlling parts CCP1, CCP2 and CCP3. The light controlling parts CCP1, CCP2 and CCP3 may be separated from one another.

Referring to FIG. 7, a partition pattern BMP may be disposed between the separated light controlling parts CCP1, CCP2 and CCP3, but an embodiment of the present disclosure is not limited thereto. In FIG. 8, the partition pattern BMP is shown not to be overlapped with the light controlling parts CCP1, CCP2 and CCP3, but at least a portion of the edge of the light controlling parts CCP1, CCP2 and CCP3 may be overlapped (may overlap) with the partition pattern BMP.

The light controlling layer CCL may include a first light controlling part CCP1 including a first quantum dot QD1 converting first color light provided from the light emitting device ED into second color light, a second light controlling part CCP2 including a second quantum dot QD2 converting first color light into third color light, and a third light controlling part CCP3 transmitting first color light.

In an embodiment, the first light controlling part CCP1 may provide red light which is the second color light, and the second light controlling part CCP2 may provide green light which is the third color light. The third color controlling part CCP3 may transmit and provide blue light which is the first color light provided from the light emitting device ED. For example, the first quantum dot QD1 may be a red quantum dot, and the second quantum dot QD2 may be a green quantum dot. On the quantum dots QD1 and QD2, the same contents (descriptions) as those described above may be applied.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) a quantum dot (e.g., not include any quantum dot) but include the scatterer SP.

The scatterer SP may be an inorganic particle. For example, the scatterer SP may include at least one selected from among TiO₂, ZnO, Al₂O₃, SiO₂, and hollow silica. The scatterer SP may include at least one selected from among TiO₂, ZnO, Al₂O₃, SiO₂, and hollow silica, or may be a mixture of two or more materials selected from among TiO₂, ZnO, Al₂O₃, SiO₂, and hollow silica.

Each of the first light controlling part CCP1, the second light controlling part CCP2, and the third light controlling part CCP3 may include base resins BR1, BR2 and BR3 dispersing the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3. The base resins BR1, BR2 and BR3 are mediums in which the quantum dots QD1 and QD2 and the scatterer SP are dispersed, and may be composed of one or more suitable resin compositions which may be generally referred to as a binder. For example, the base resins BR1, BR2 and BR3 may be acrylic resins, urethane-based resins, silicone-based resins, epoxy-based resins, etc. The base resins BR1, BR2 and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may play the role of blocking (or reducing) the penetration of moisture and/or oxygen (hereinafter, will be referred to as “humidity/oxygen”). The barrier layer BFL1 may be disposed on the light controlling parts CCP1, CCP2 and CCP3 to block or reduce the exposure of the light controlling parts CCP1, CCP2 and CCP3 to humidity/oxygen. In some embodiments, the barrier layer BFL1 may cover the light controlling parts CCP1, CCP2 and CCP3. In some embodiments, the barrier layer BFL2 may be provided between a color filter layer CFL and the light controlling parts CCP1, CCP2 and CCP3.

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and silicon oxynitride or a metal thin film securing light transmittance. In some embodiments, the barrier layers BFL1 and BFL2 may further include an organic layer. The barrier layers BFL1 and BFL2 may be composed of a single layer of multiple layers.

In the display apparatus DD of an embodiment, the color filter layer CFL may be on the light controlling layer CCL. For example, the color filter layer CFL may be disposed directly on the light controlling layer CCL. In this embodiment, the barrier layer BFL2 may not be provided.

The color filter layer CFL may include a light blocking part BM and filters CF1, CF2 and CF3. The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment or dye. In some embodiments, an embodiment of the present disclosure is not limited thereto, and the third filter CF3 may not include (e.g., may exclude) any pigment or dye. The third filter CF3 may include a polymer photosensitive resin and not include any pigment or dye. The third filter CF3 may be transparent. The third filter CF3 may be formed utilizing a transparent photosensitive resin.

In some embodiments, the first filter CF1 and the second filter CF2 may be yellow filters. The first filter CF1 and the second filter CF2 may be provided in one body without distinction.

The light blocking part BM may be a black matrix. The light blocking part BM may be formed by including an organic light blocking material or an inorganic light blocking material including a black pigment and/or black dye. The light blocking part BM may prevent or reduce light leakage phenomenon and divide (separate) the boundaries among (between) adjacent filters CF1, CF2 and CF3. In some embodiments, the light blocking part BM may be formed as a blue filter.

Each of the first to third filters CF1, CF2 and CF3 may be disposed corresponding to each of a red luminous area PXA-R, green luminous area PXA-G, and blue luminous area PXA-B.

On the color filter layer CFL, a base substrate BL may be disposed. The base substrate BL may be a member providing a base surface on which the color filter layer CFL, the light controlling layer CCL, etc. are disposed. The base substrate BL may be a glass substrate, a metal substrate, a plastic substrate, etc. However, an embodiment of the present disclosure is not limited thereto, and the base substrate BL may be an inorganic layer, an organic layer or a composite material layer. In some embodiments, the base substrate BL may not be provided.

FIG. 8 is a cross-sectional view showing a portion of the display apparatus according to an embodiment. In a display apparatus DD-TD of an embodiment, the light emitting device ED-BT may include multiple light emitting structures OL-B1, OL-B2 and OL-B3. The light emitting device ED-BT may include oppositely disposed first electrode EL1 and second electrode EL2, and the multiple light emitting structures OL-B1, OL-B2 and OL-B3 stacked in order in a thickness direction and provided between the first electrode EL1 and the second electrode EL2. Each of the light emitting structures OL-B1, OL-B2 and OL-B3 may include an emission layer EML (FIG. 7), and include a hole transport region HTR and an electron transport region ETR disposed with the emission layer EML (FIG. 7) therebetween.

For example, the light emitting device ED-BT included in the display apparatus DD-TD of an embodiment may be a light emitting device of a tandem structure including multiple emission layers.

In an embodiment shown in FIG. 8, light emitted from the light emitting structures OL-B1, OL-B2 and OL-B3 may be all blue light. However, an embodiment of the present disclosure is not limited thereto, and the wavelength regions of light emitted from the light emitting structures OL-B1, OL-B2 and OL-B3 may be different from each other. For example, the light emitting device ED-BT including the multiple light emitting structures OL-B1, OL-B2 and OL-B3 emitting light (e.g., light beams) in different wavelength regions may emit white light (e.g., a combined white light).

Between neighboring light emitting structures OL-B1, OL-B2 and OL-B3, charge generating layers CGL1 and CGL2 may be disposed. The charge generating layers CGL1 and CGL2 may include a p-type or kind charge generating layer (e.g., P-charge generation layer) and/or an n-type or kind charge generating layer (e.g., N-charge generation layer).

In at least one selected from among the light emitting structures OL-B1, OL-B2 and OL-B3, included in the display apparatus DD-TD of an embodiment, the fused polycyclic compound of an embodiment may be included. For example, at least one selected from among multiple emission layers included in the light emitting device ED-BT may include the fused polycyclic compound of an embodiment.

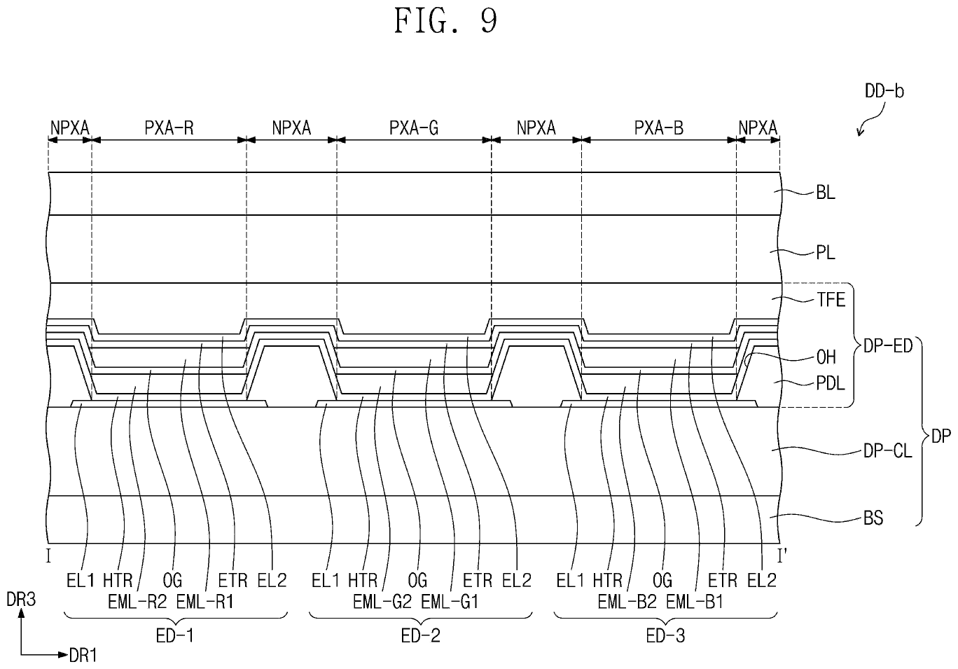

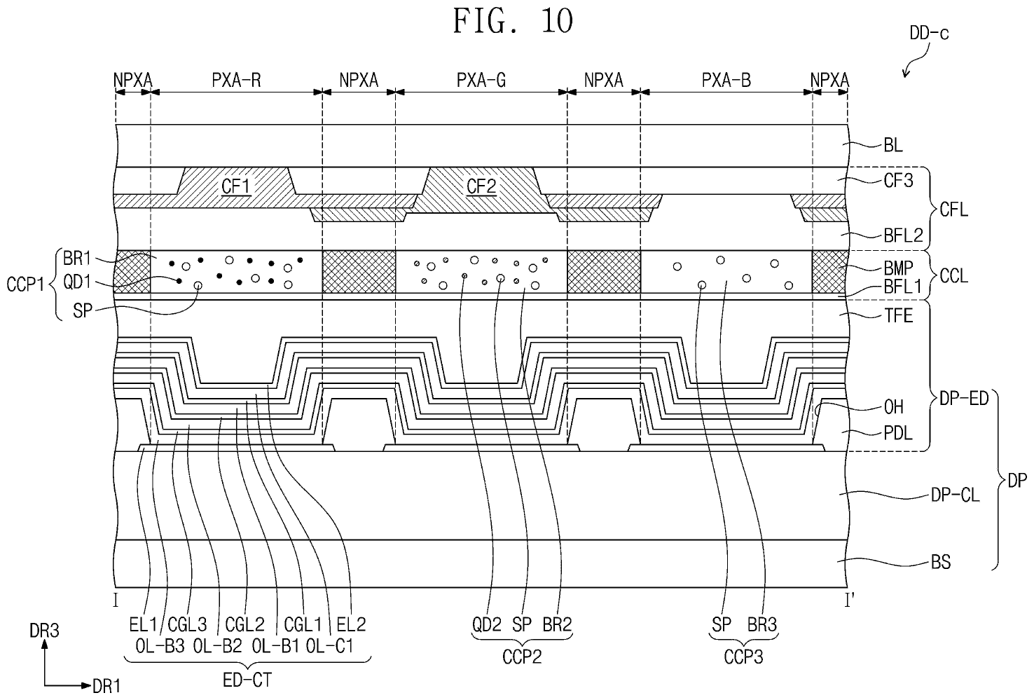

FIG. 9 is a cross-sectional view showing a display apparatus according to an embodiment of the present disclosure. FIG. 10 is a cross-sectional view showing a display apparatus according to an embodiment of the present disclosure.

Referring to FIG. 9, a display apparatus DD-b according to an embodiment may include light emitting devices ED-1, ED-2 and ED-3, formed by stacking two emission layers. Compared to the display apparatus DD of an embodiment, shown in FIG. 2, an embodiment shown in FIG. 9 is different in that the first to third light emitting devices ED-1, ED-2 and ED-3 include two emission layers stacked in a thickness direction, each. In the first to third light emitting devices ED-1, ED-2 and ED-3, two emission layers may emit light in substantially the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In some embodiments, the third light emitting device ED-3 may include a first blue emission layer EML-B1 and a second blue emission layer EML-B2. Between the first red emission layer EML-R1 and the second red emission layer EML-R2, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may include a single layer or a multilayer. The emission auxiliary part OG may include a charge generating layer. For example, the emission auxiliary part OG may include an electron transport region, a charge generating layer, and a hole transport region stacked in order. The emission auxiliary part OG may be provided as a common layer in all of the first to third light emitting devices ED-1, ED-2 and ED-3. However, an embodiment of the present disclosure is not limited thereto, and the emission auxiliary part OG may be patterned and provided in an opening part OH defined in a pixel definition layer PDL.

The first red emission layer EML-R1, the first green emission layer EML-G1 and the first blue emission layer EML-B1 may be disposed between the electron transport region ETR and the emission auxiliary part OG. The second red emission layer EML-R2, the second green emission layer EML-G2 and the second blue emission layer EML-B2 may be disposed between the emission auxiliary part OG and the hole transport region HTR.

For example, the first light emitting device ED-1 may include a first electrode EL1, a hole transport region HTR, a second red emission layer EML-R2, an emission auxiliary part OG, a first red emission layer EML-R1, an electron transport region ETR, and a second electrode EL2, stacked in order (in the stated order). The second light emitting device ED-2 may include a first electrode EL1, a hole transport region HTR, a second green emission layer EML-G2, an emission auxiliary part OG, a first green emission layer EML-G1, an electron transport region ETR, and a second electrode EL2, stacked in order (in the stated order). The third light emitting device ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in order (in the stated order).

In some embodiments, an optical auxiliary layer PL may be on a display device layer DP-ED. The optical auxiliary layer PL may include a polarization layer. The optical auxiliary layer PL may be on a display panel DP and may control reflected light at the display panel DP by external light. The optical auxiliary layer PL may not be provided with or in the display apparatus according to an embodiment.

At least one emission layer included in the display apparatus DD-b of an embodiment, shown in FIG. 9, may include the fused polycyclic compound of an embodiment. For example, in an embodiment, at least one selected from among the first blue emission layer EML-B1 and the second blue emission layer EML-B2 may include the fused polycyclic compound of an embodiment.

Different from FIG. 8 and FIG. 9, a display apparatus DD-c in FIG. 10 is shown to include four light emitting structures OL-B1, OL-B2, OL-B3 and OL-C1. A light emitting device ED-CT may include oppositely disposed first electrode EL1 and second electrode EL2, and first to fourth light emitting structures OL-B1, OL-B2, OL-B3 and OL-C1 stacked in order (in the stated order) in a thickness direction between the first electrode EL1 and the second electrode EL2. Between the first to fourth light emitting structures OL-B1, OL-B2, OL-B3 and OL-C1, charge generating layers CGL1, CGL2 and CGL3 may be disposed. Among the four light emitting structures, the first to third light emitting structures OL-B1, OL-B2 and OL-B3 emit blue light, and the fourth light emitting structure OL-C1 may emit green light. However, an embodiment of the present disclosure is not limited thereto, and the first to fourth light emitting structures OL-B1, OL-B2, OL-B3 and OL-C1 may emit different wavelengths of light.

Charge generating layers CGL1, CGL2 and CGL3 disposed among neighboring light emitting structures OL-B1, OL-B2, OL-B3 and OL-C1, respectively, may include a p-type or kind charge generating layer and/or an n-type or kind charge generating layer.

In at least one selected from among the light emitting structures OL-B1, OL-B2, OL-B3 and OL-C1, included in the display apparatus DD-c of an embodiment, the fused polycyclic compound of an embodiment may be included. For example, at least one selected from among the first to third light emitting structures OL-B1, OL-B2, and OL-B3 may include the fused polycyclic compound of an embodiment.

Hereinafter, the fused polycyclic compound of an embodiment and the light emitting device according to an embodiment of the present disclosure will be explained referring to embodiments (examples) and comparative embodiments (comparative examples). The embodiments are merely illustrations/examples to assist the understanding of the present disclosure, and the scope of the present disclosure is not limited thereto.

### EXAMPLES

### 1. Synthesis of Fused Polycyclic Compound

First, the synthetic method of the fused polycyclic compound according to an embodiment will be explained in more detail by illustrating the synthetic methods of Compounds 17, 25, 48, 104, 125, 133, 157, 165 and 193. The synthetic methods of the fused polycyclic compounds explained hereinafter are embodiments, and the synthetic method of the fused polycyclic compound according to an embodiment of the present disclosure is not limited to the embodiments.

### (1) Synthesis of Compound 17

Fused Polycyclic Compound 17 according to an embodiment may be synthesized, for example, by the reactions below.

### Synthesis of Intermediate 1-1

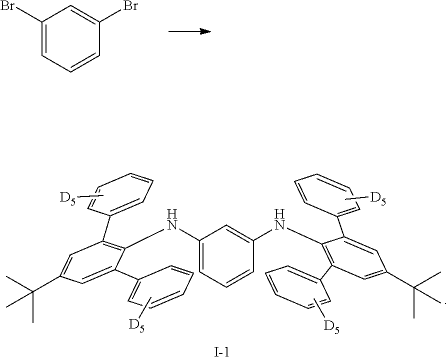

1,3-Dibromobenzene (1 eq), 5′-(tert-butyl)-[1,1′:3′,1″-terphenyl]-2,2″,3,3″,4,4″,5,5″,6,6″-d₁₀-2′-amine (2 eq), Pd₂(dba)₃ (0.05 eq), tri-tert-butylphosphine (0.1 eq), and sodium tert-butoxide (1.5 eq) were dissolved in toluene and stirred at about 100 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate 1-1 was obtained (yield: 60%).

### Synthesis of Intermediate 1-2

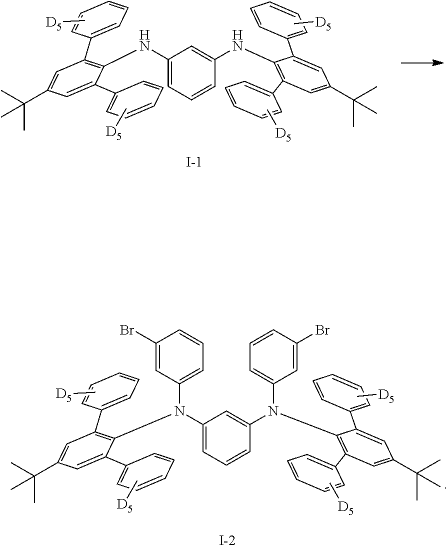

Intermediate 1-1 (1 eq), 1-bromo-3-iodobenzene (2 eq), Pd₂(dba)₃ (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate 1-2 was obtained (yield: 65%).

### Synthesis of Intermediate 1-3

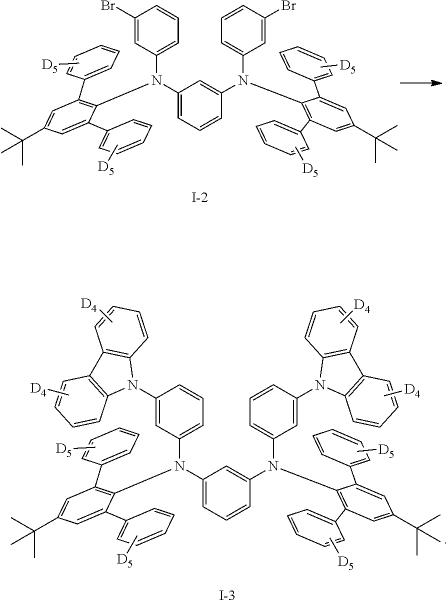

Intermediate 1-2 (1 eq), 9H-carbazole-1,2,3,4,5,6,7,8-d8 (2 eq), Pd₂(dba)₃ (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate 1-3 was obtained (yield: 62%).

### Synthesis of Compound 17

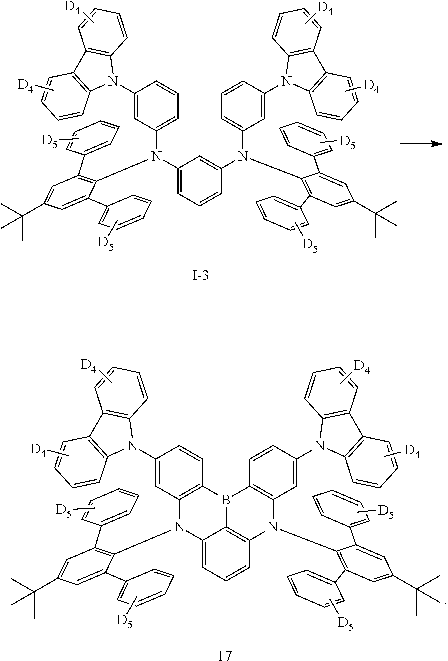

Intermediate I-3 (1 eq) was dissolved in o-dichlorobenzene and cooled to about 0 degrees centigrade, and BBr₃ (3 eq) was injected thereto slowly under a nitrogen atmosphere. After finishing the dropwise addition, the temperature was raised to about 180 degrees centigrade, followed by stirring for about 48 hours. After cooling, triethylamine was slowly added dropwise to a flask containing the reaction product to quench the reaction, and ethyl alcohol was added to the reaction product and a precipitate formed. The precipitate was filtered to obtain a solid. The solid thus obtained was separated by column chromatography utilizing methylene chloride and n-hexane and then, recrystallized to obtain Compound 17 (yield: 1.5%).

The product thus produced was identified through MS/FAB.

C₈₆H₃₁D₃₆BN₄ cal. 1202.77, found 1202.78.

### (2) Synthesis of Compound 25

Fused Polycyclic Compound 25 according to an embodiment may be synthesized, for example, by the reactions below.

### Synthesis of Intermediate 1-4

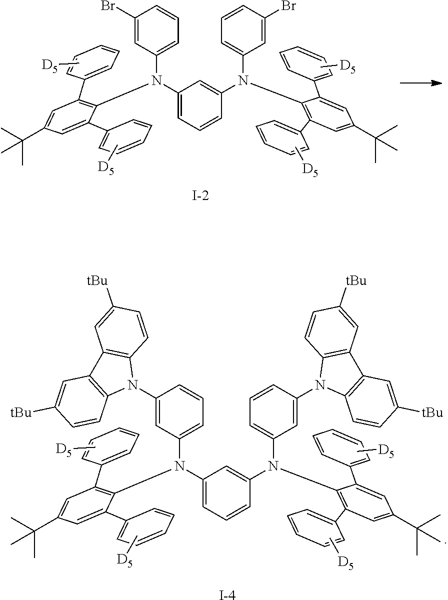

Intermediate I-2 (1 eq), 3,6-di-tert-butyl-9H-carbazole (2 eq), Pd₂(dba)₃ (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate 1-4 was obtained (yield: 70%).

### Synthesis of Compound 25

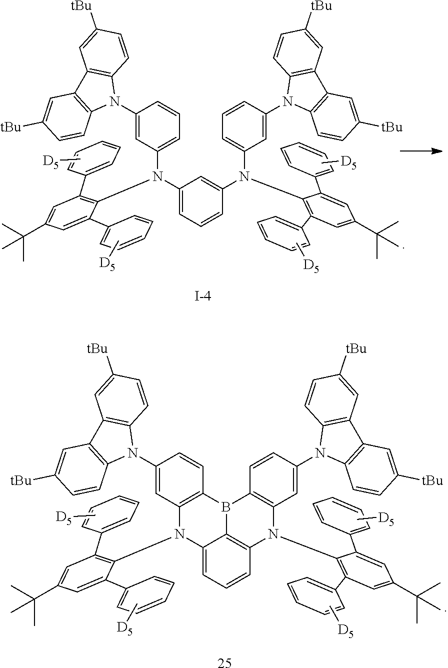

Intermediate I-4 (1 eq) was dissolved in o-dichlorobenzene and cooled to about 0 degrees centigrade, and BBr₃ (3 eq) was injected thereto slowly under a nitrogen atmosphere. After finishing the dropwise addition, the temperature was raised to about 180 degrees centigrade, followed by stirring for about 48 hours. After cooling, triethylamine was slowly added dropwise to a flask containing the reaction product to quench the reaction, and ethyl alcohol was added to the reaction product and a precipitate formed. The precipitate was filtered to obtain a solid. The solid thus obtained was separated by column chromatography utilizing methylene chloride and n-hexane and then, recrystallized to obtain Compound 25 (yield: 1.7%).

The product thus produced was identified through MS/FAB.

C₁₀₂H₇₉D₂₀BN₄ cal. 1410.92, found 1410.91.

### (3) Synthesis of Compound 48

Fused Polycyclic Compound 48 according to an embodiment may be synthesized, for example, by the reactions below.

### Synthesis of Intermediate 1-5

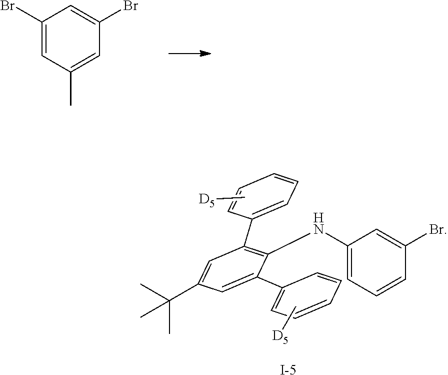

1,3-Dibromo-5-methylbenzene (1 eq), 5′-(tert-butyl)-[1,1′:3′,1″-terphenyl]-2,2″,3,3″,4,4″,5,5″,6,6″-d₁₀-2′-amine (1 eq), Pd₂(dba)₃ (0.05 eq), tri-tert-butylphosphine (0.1 eq), and sodium tert-butoxide (1.5 eq) were dissolved in toluene and stirred at about 100 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate 1-5 was obtained (yield: 37%).

### Synthesis of Intermediate I-6

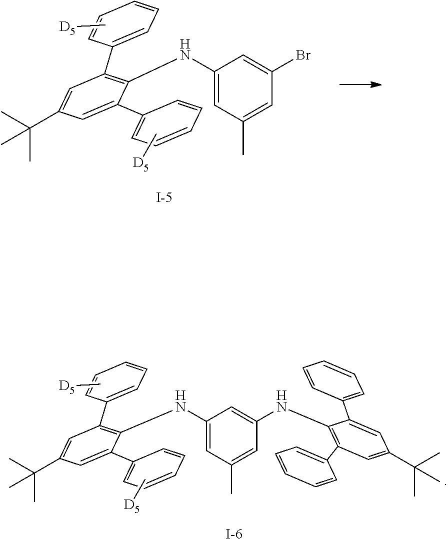

Intermediate I-5 (1 eq), 5′-(tert-butyl)-[1,1′:3′,1″-terphenyl]-2′-amine (1 eq), Pd₂(dba)₃ (0.05 eq), tri-tert-butylphosphine (0.1 eq), and sodium tert-butoxide (1.5 eq) were dissolved in toluene and stirred at about 100 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate I-6 was obtained (yield: 72%).

### Synthesis of Intermediate I-7

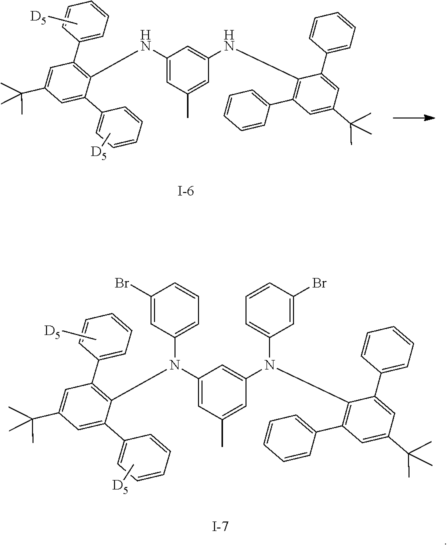

Intermediate I-6 (1 eq), 1-bromo-3-iodobenzene (2 eq), Pd₂(dba)₃ (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate I-7 was obtained (yield: 60%).

### Synthesis of Intermediate I-8

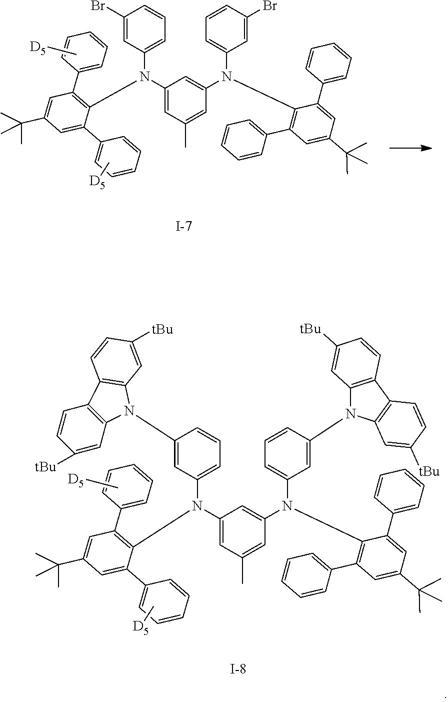

Intermediate I-7 (1 eq), 2,7-di-tert-butyl-9H-carbazole (2 eq), Pd₂(dba)₃ (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate 1-8 was obtained (yield: 59%).

### Synthesis of Compound 48

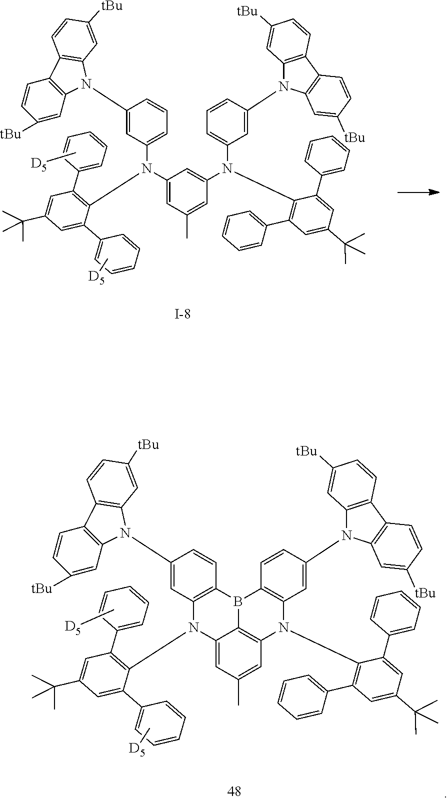

Intermediate I-8 (1 eq) was dissolved in o-dichlorobenzene and cooled to about 0 degrees centigrade, and BBr₃ (3 eq) was injected thereto slowly under a nitrogen atmosphere. After finishing the dropwise addition, the temperature was raised to about 180 degrees centigrade, followed by stirring for about 48 hours. After cooling, triethylamine was slowly added dropwise to a flask containing the reaction product to quench the reaction, and ethyl alcohol was added to the reaction product and a precipitate formed. The precipitate was filtered to obtain a solid. The solid thus obtained was separated by column chromatography utilizing methylene chloride and n-hexane and then, recrystallized to obtain Compound 48 (yield: 2.3%).

The product thus produced was identified through MS/FAB.

C₁₀₃H₉₁D₁₀BN₄ cal. 1414.87, found 1414.86.

### (4) Synthesis of Compound 104

Fused Polycyclic Compound 104 according to an embodiment may be synthesized, for example, by the reactions below.

### Synthesis of Intermediate I-9

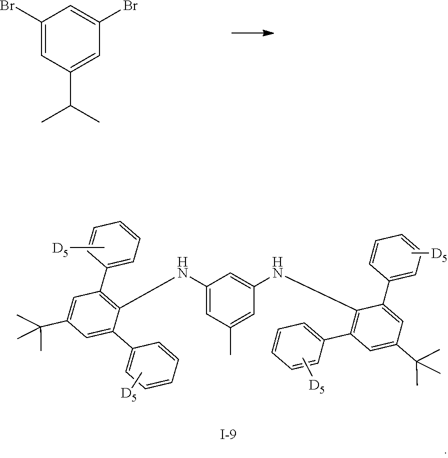

1,3-dibromo-5-isopropylbenzene (1 eq), 5′-(tert-butyl)-[1, 1:3′,1″-terphenyl]-2,2″,3,3″,4,4″,5,5″,6,6″-d₁₀-2′-amine (1 eq), Pd₂(dba)₃ (0.05 eq), tri-tert-butylphosphine (0.1 eq), and sodium tert-butoxide (1.5 eq) were dissolved in toluene and stirred at about 100 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate I-9 was obtained (yield: 63%).

### Synthesis of Intermediate I-10

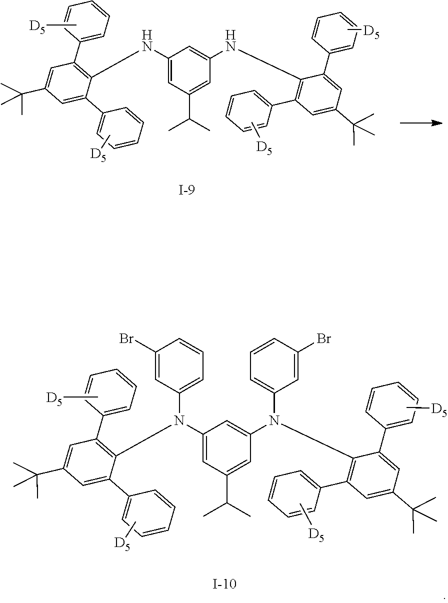

Intermediate I-9 (1 eq), 1-bromo-3-iodobenzene (2 eq), Pd₂(dba)₃ (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate 1-10 was obtained (yield: 60%).

### Synthesis of Intermediate I-11

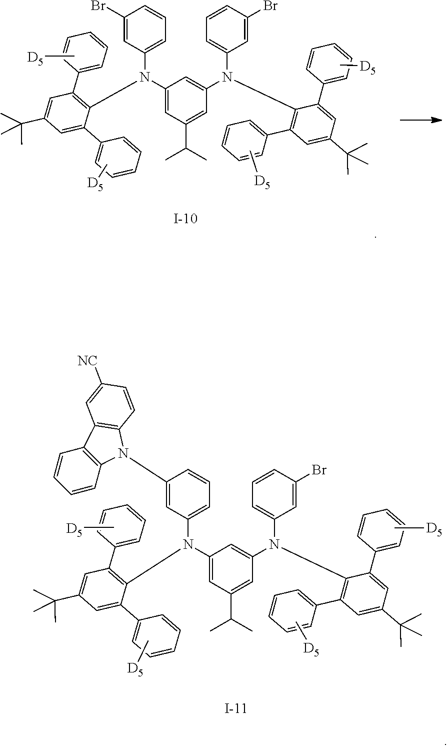

Intermediate 1-10 (1 eq), 9H-carbazole-3-carbonitrile (1 eq), Pd₂(dba)₃ (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate I-11 was obtained (yield: 29%).

### Synthesis of Intermediate I-12

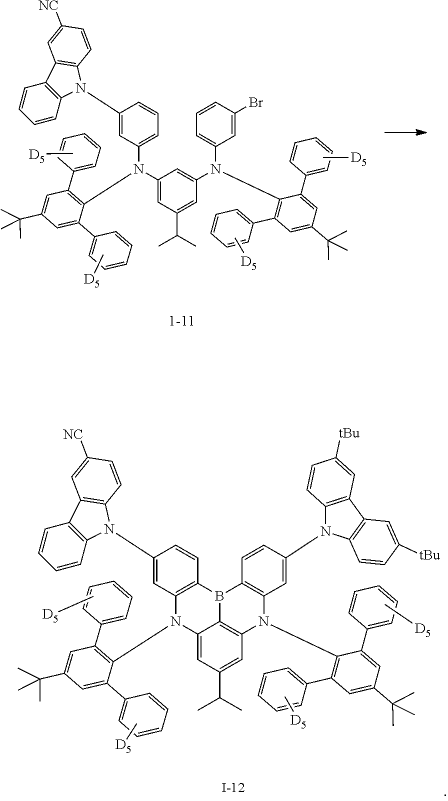

Intermediate 1-11 (1 eq), 3,6-di-tert-butyl-9H-carbazole (1 eq), Pd₂(dba)₃ (0.05 eq), tri-tert-butylphosphine (0.1 eq), and sodium tert-butoxide (3 eq) were dissolved in toluene and stirred at about 110 degrees centigrade for about 12 hours. After cooling, the resultant was washed with ethyl acetate three times and water three times, and layer separation was performed. The organic layer thus obtained was dried over MgSO₄ and then dried under a reduced pressure. Through the separation by column chromatography, Intermediate 1-12 was obtained (yield: 63%).

### Synthesis of Compound 104

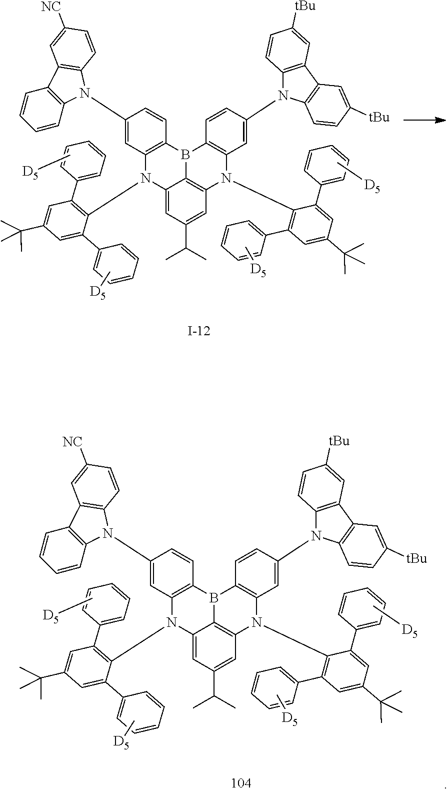

Intermediate I-12 (1 eq) was dissolved in o-dichlorobenzene and cooled to about 0 degrees centigrade, and BBr₃ (3 eq) was injected thereto slowly under a nitrogen atmosphere. After finishing the dropwise addition, the temperature was raised to about 180 degrees centigrade, followed by stirring for about 48 hours. After cooling, triethylamine was slowly added dropwise to a flask containing the reaction product to quench the reaction, and ethyl alcohol was added to the reaction product and a precipitate formed. The precipitate was filtered to obtain a solid. The solid thus obtained was separated by column chromatography utilizing methylene chloride and n-hexane and then, recrystallized to obtain Compound 104 (yield: 2.1%).

The product thus produced was identified through MS/FAB.

C₉₈H₆₈D₂₀BN₅ cal. 1365.84, found 1365.83.

### (5) Synthesis of Compound 125

Fused Polycyclic Compound 125 according to an embodiment may be synthesized, for example, by the reactions below.

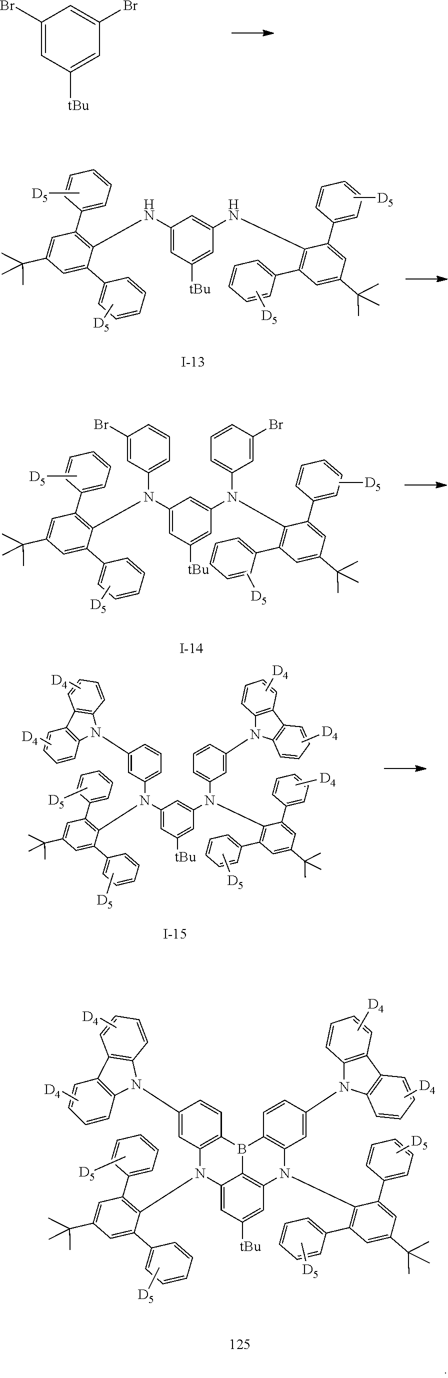

Compound 125 was obtained (yield: 5.7%) by substantially the same method as the synthetic method of Compound 17 except for utilizing 1,3-dibromo-5-(tert-butyl)benzene instead of 1,3-dibromobenzene in the synthesis of Compound 17.

The product thus produced was identified through MS/FAB.

C₉₀H₃₉D₃₆BN₄ cal. 1258.83, found 1258.82.

### (6) Synthesis of Compound 133

Fused Polycyclic Compound 133 according to an embodiment may be synthesized, for example, by the reactions below.

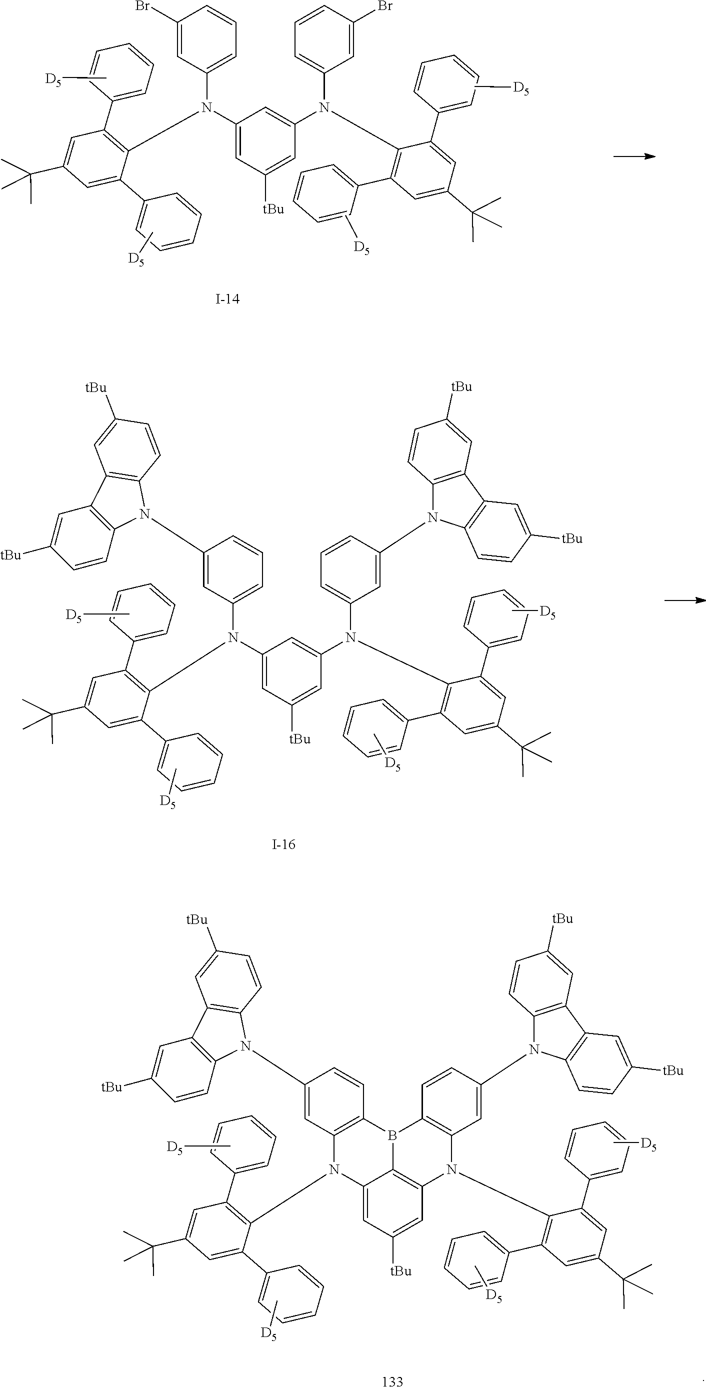

Compound 133 was obtained (yield: 6.2%) by substantially the same method as the synthetic method of Compound 17 except for utilizing 1,3-dibromo-5-(tert-butyl)benzene instead of 1,3-dibromobenzene and utilizing 3,6-di-tert-butyl-9H-carbazole instead of 9H-carbazole-1,2,3,4,5,6,7,8-d8 in the synthesis of Compound 17.

The product thus produced was identified through MS/FAB.

C₁₀₆H₈₇D₂₀BN₄ cal. 1466.98, found 1466.97.

### (7) Synthesis of Compound 157

Fused Polycyclic Compound 157 according to an embodiment may be synthesized, for example, by the reactions below.

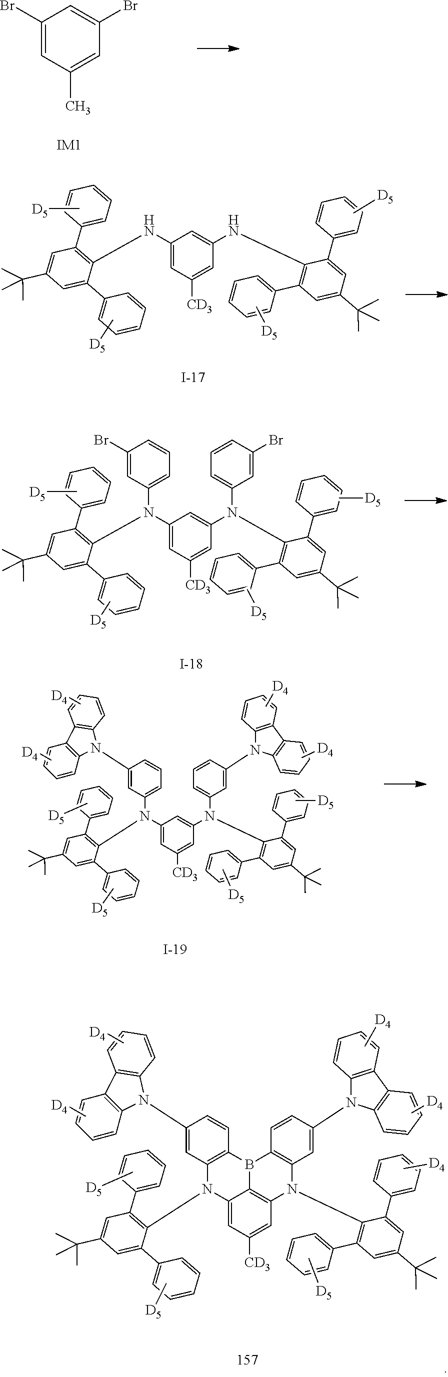

Compound 157 was obtained (yield: 5.5%) by substantially the same method as the synthetic method of Compound 17 except for utilizing intermediate IM1 instead of 1,3-dibromobenzene in the synthesis of Compound 17.

The product thus produced was identified through MS/FAB.

C₈₇H₃₀D₃₉BN₄ cal. 1220.82, found 1220.83.

### (8) Synthesis of Compound 165

Fused Polycyclic Compound 165 according to an embodiment may be synthesized, for example, by the reactions below.

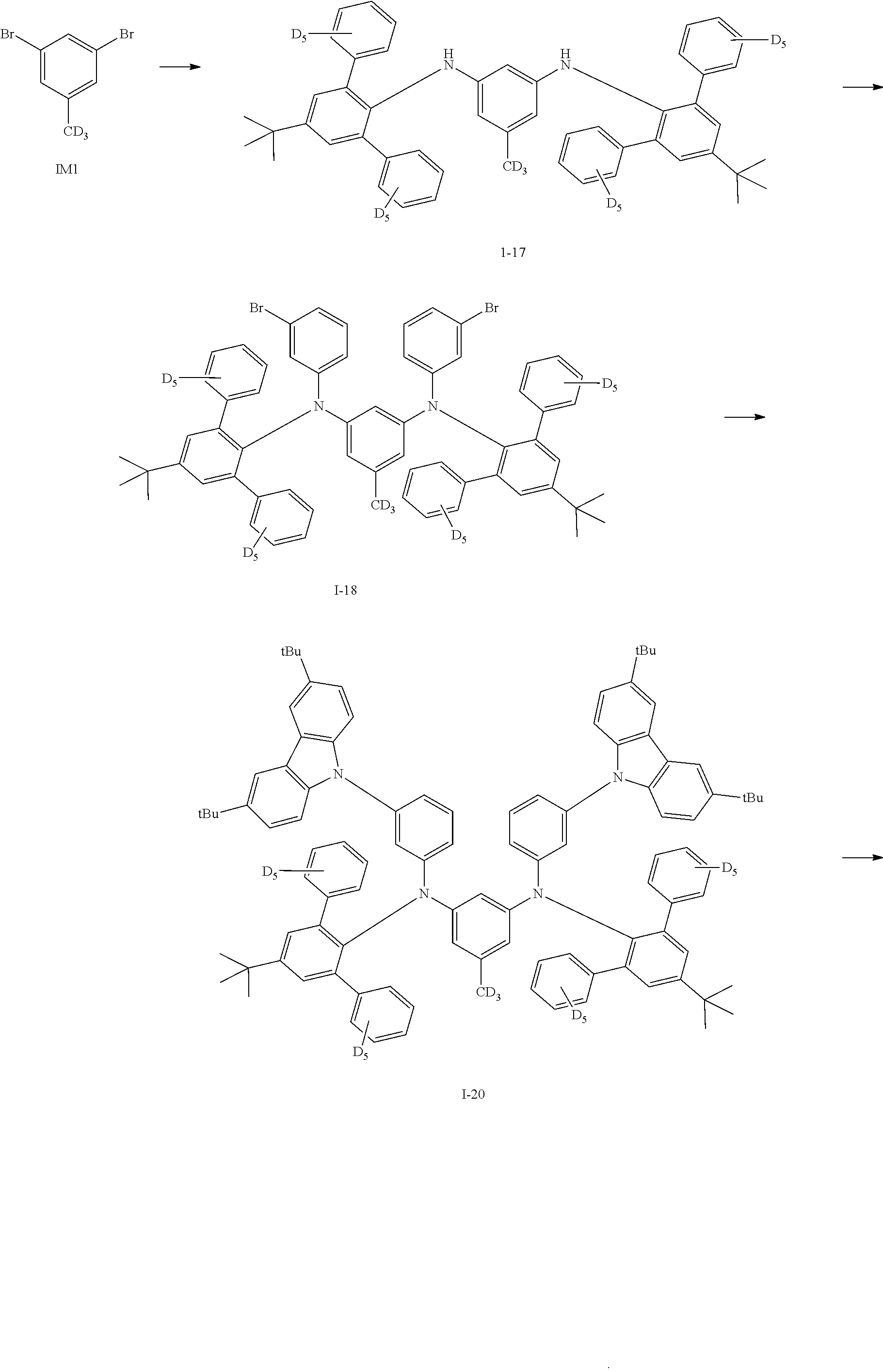

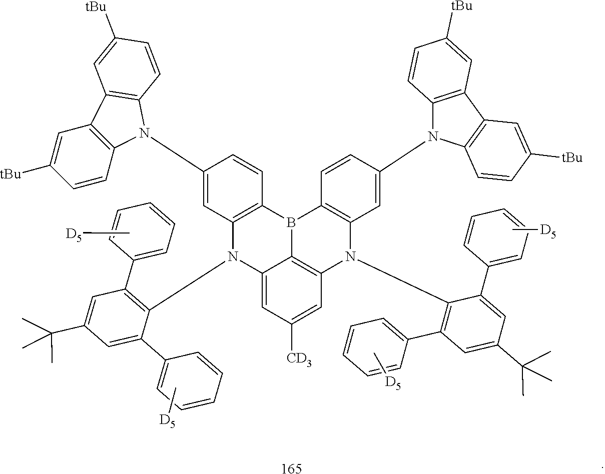

Compound 165 was obtained (yield: 5.8%) by substantially the same method as the synthetic method of Compound 17 except for utilizing intermediate IM1 instead of 1,3-dibromobenzene and utilizing 3,6-di-tert-butyl-9H-carbazole instead of 9H-carbazole-1,2,3,4,5,6,7,8-d8 in the synthesis of Compound 17.

The product thus produced was identified through MS/FAB.

C₁₀₃H₇₈D₂₃BN₄ cal. 1427.96, found 1427.97.

### (8) Synthesis of Compound 193

Fused Polycyclic Compound 193 according to an embodiment may be synthesized, for example, by the reactions below.

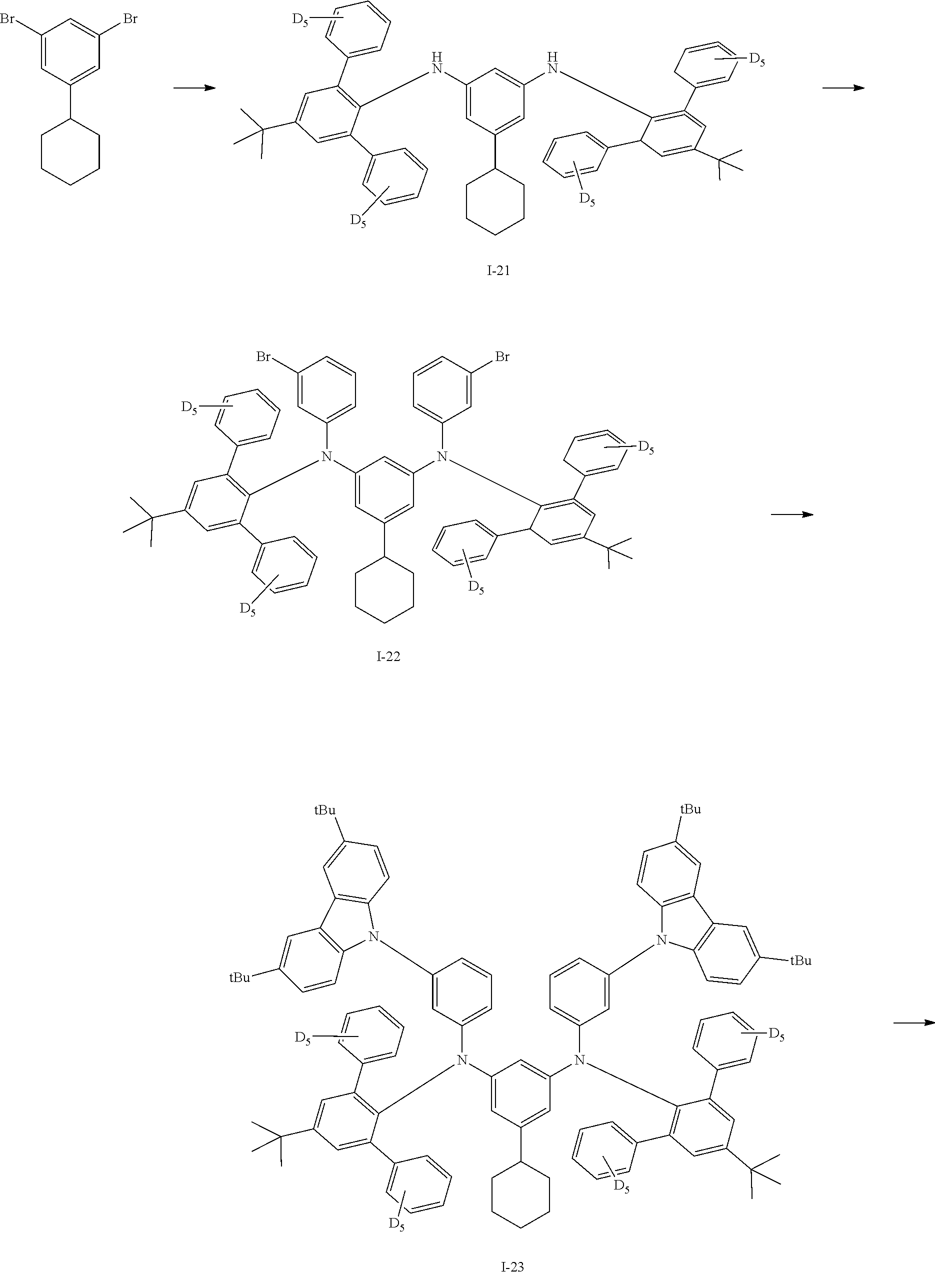

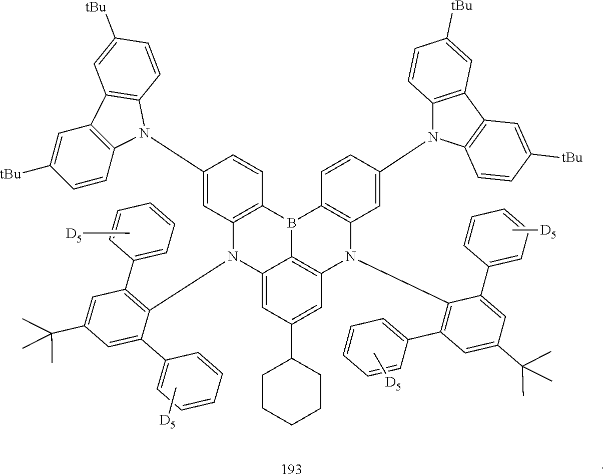

Compound 193 was obtained (yield: 4.6%) by substantially the same method as the synthetic method of Compound 17 except for utilizing 1,3-dibromo-5-cyclohexylbenzene instead of 1,3-dibromobenzene and utilizing 3,6-di-tert-butyl-9H-carbazole instead of 9H-carbazole-1,2,3,4,5,6,7,8-d8 in the synthesis of Compound 17.

The product thus produced was identified through MS/FAB.

C₁₀₈H₈₉D₂₀BN₄ cal. 1493.00, found 1493.00.

### 2. Manufacture and Evaluation of Light Emitting Device Including Fused Polycyclic Compound

A light emitting device of an embodiment including a fused polycyclic compound of an embodiment in an emission layer was manufactured by a method below. Light emitting devices of Examples 1 to 22 were manufactured utilizing the fused polycyclic compounds of Compounds 17, 25, 48, 104, 125, 133, 157, 165 and 193 as the dopant materials for the respective emission layers. Comparative Example 1 to Comparative Example 4 corresponded to light emitting devices manufactured utilizing Comparative Compound C1 to Comparative Compound C4 as the dopant materials for the respective emission layers.

### Example Compounds

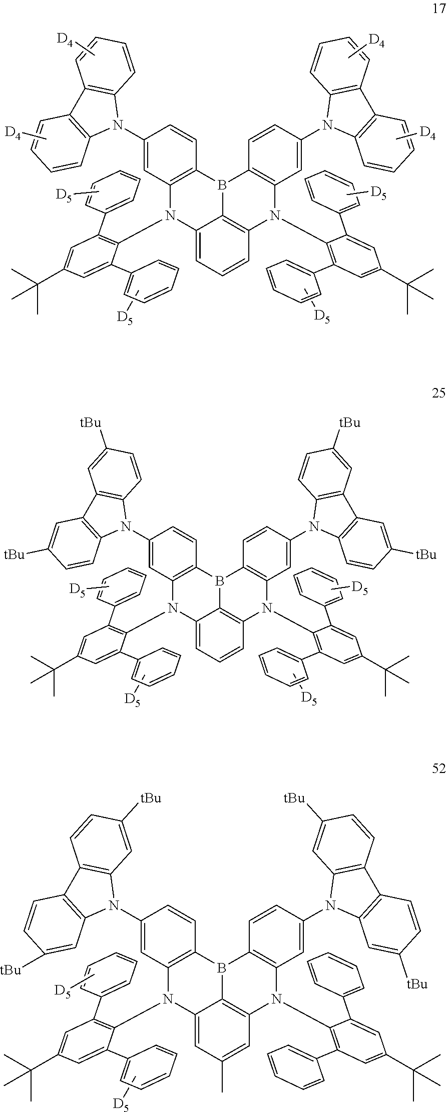

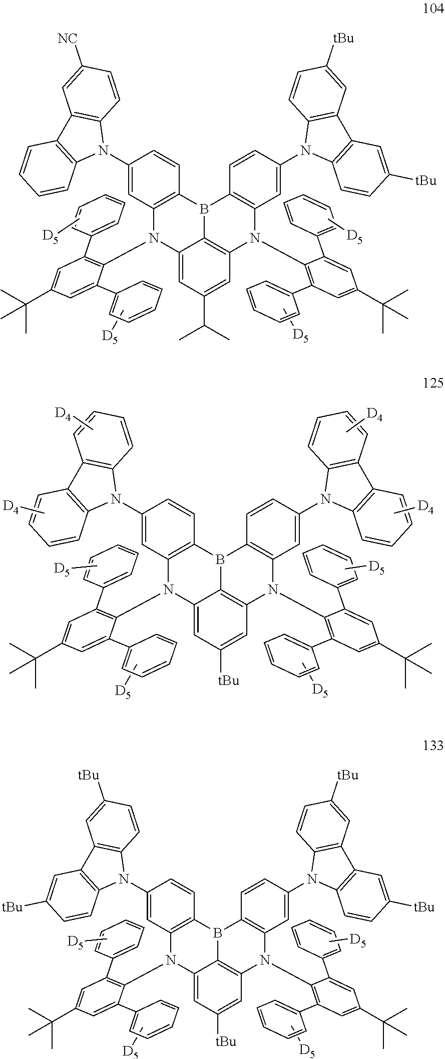

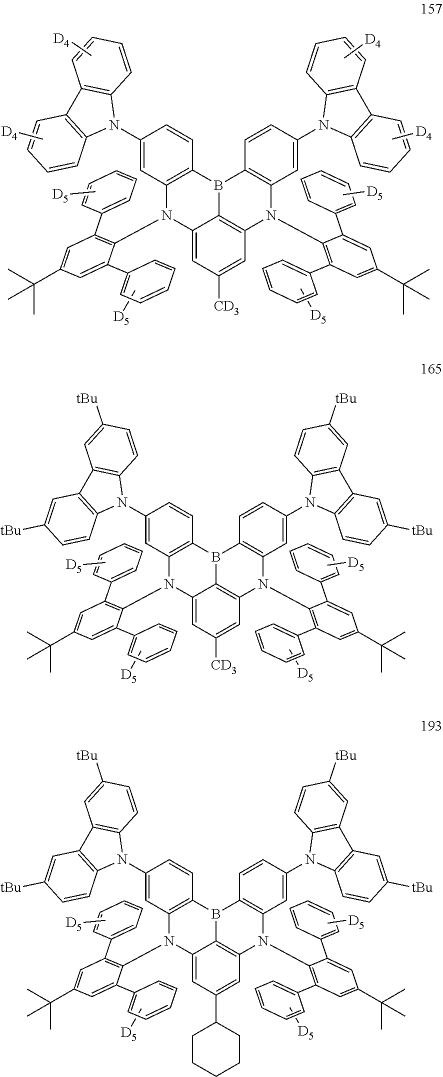

### Comparative Compounds

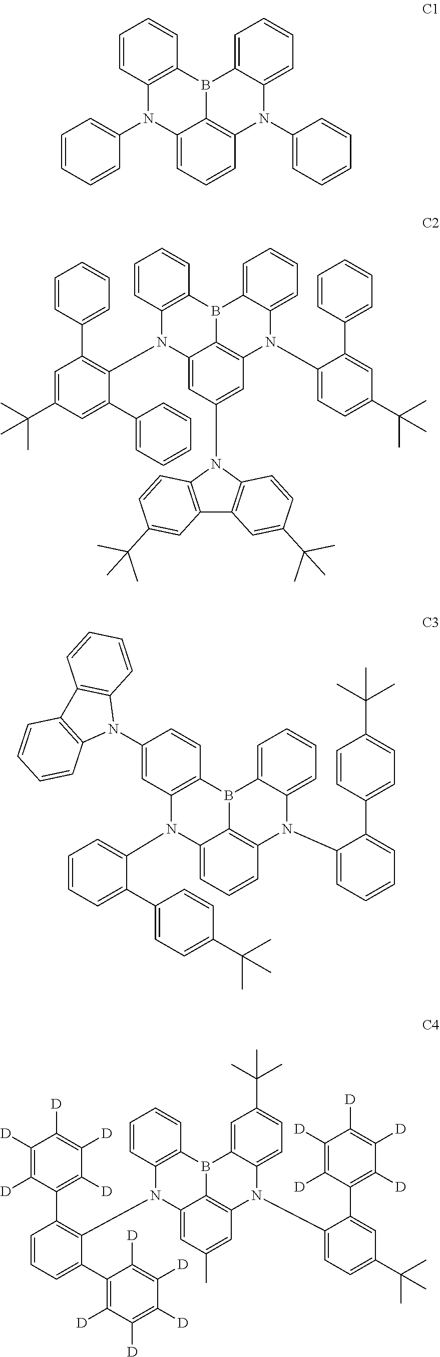 [SMILES: c1ccc(N2c3ccccc3B3c4ccccc4N(c4ccccc4)c4cccc2c43)cc1 ; CC(C)(C)c1ccc(N2c3ccccc3B3c4ccccc4N(c4c(-c5ccccc5)cc(C(C)(C)C)cc4-c4ccccc4)c4cc(-n5c6ccc(C(C)(C)C)cc6c6cc(C(C)(C)C)ccc65)cc2c43)c(-c2ccccc2)c1 ; CC(C)(C)c1ccc(-c2ccccc2N2c3ccccc3B3c4ccc(-n5c6ccccc6c6ccccc65)cc4N(c4ccccc4-c4ccc(C(C)(C)C)cc4)c4cccc2c43)cc1 ; [2H]c1c([2H])c([2H])c(-c2cc(C(C)(C)C)ccc2N2c3ccc(C(C)(C)C)cc3B3c4ccccc4N(c4c(-c5c([2H])c([2H])c([2H])c([2H])c5[2H])cccc4-c4c([2H])c([2H])c([2H])c([2H])c4[2H])c4cc(C)cc2c43)c([2H])c1[2H]]

### Manufacture of Light Emitting Device

The light emitting device of each of the Examples and the Comparative Examples was manufactured as follows. An ITO glass substrate was cut into a size of about 50 mm×50 mm×0.7 mm, washed by ultrasonic waves utilizing isopropyl alcohol and distilled water for about 5 minutes each, and cleaned by irradiating ultraviolet rays for about 30 minutes and then, ozone. Then, the ITO glass substrate was installed in a vacuum deposition apparatus. Then, a hole injection layer HIL with a thickness of about 300 Å was formed utilizing NPD, a hole transport layer HTL with a thickness of about 200 Å was formed utilizing HT-1-1, and an emission auxiliary layer with a thickness of about 100 Å was formed utilizing CzSi. Then, a host compound of a mixture of a second compound and a third compound according to embodiments in a ratio (e.g., amount) of 1:1, a fourth compound, and the Example Compound or Comparative Compound were co-deposited in a weight ratio of about 83:14:3 to form an emission layer EML with a thickness of about 200 Å, and a hole blocking layer with a thickness of about 200 Å was formed utilizing TSPO1. Then, an electron transport layer ETL with a thickness of about 300 Å was formed utilizing TPBi, and an electron injection layer EIL with a thickness of about 10 Å was formed utilizing LiF. Then, a second electrode with a thickness of about 3000 Å was formed utilizing Al to obtain a LiF/Al electrode. All layers were formed by a vapor deposition method. In some embodiments, the second compound utilized one or more (e.g., a corresponding one of) HT1, HT2, HT3, and HT4 among the compounds in Compound Group 2, the third compound utilized one or more (e.g., a corresponding one of) ETH66, ETH85, and ETH86 among the compounds in Compound Group 3, and the fourth compound utilized one or more (e.g., a corresponding one of) AD-37 and AD-38 among the compounds in Compound Group 4.

The compounds utilized for the manufacture of the light emitting devices of the Examples and Comparative Examples are shown below. The materials below were utilized after purchasing commercial products and performing sublimation purification.

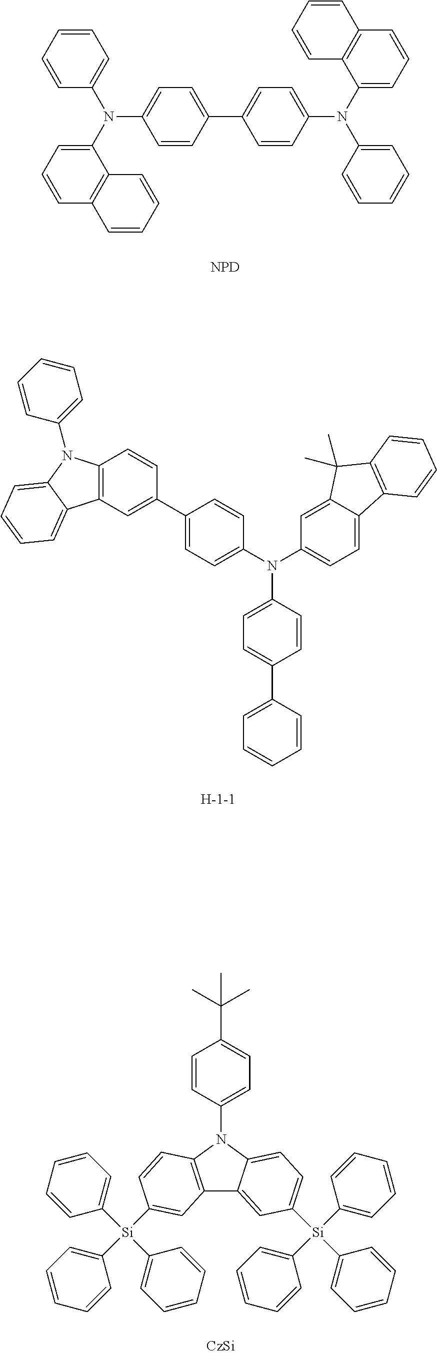 [SMILES: c1ccc(N(c2ccc(-c3ccc(N(c4ccccc4)c4cccc5ccccc45)cc3)cc2)c2cccc3ccccc23)cc1 ; "NPD" ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

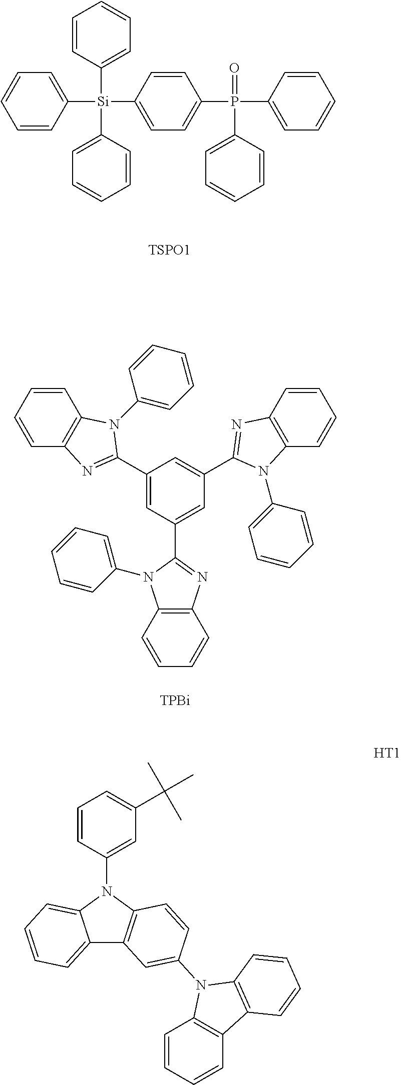

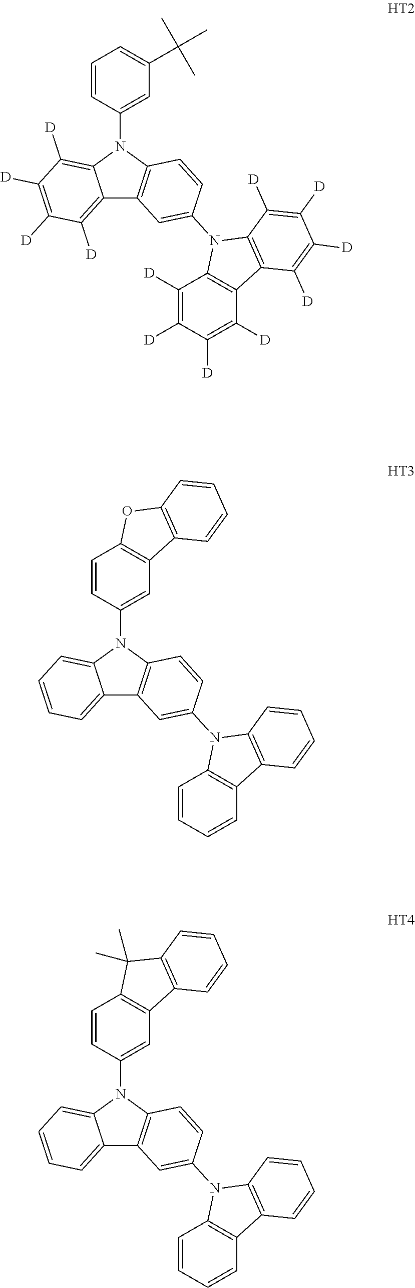 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12 ; CC1(C)c2ccccc2-c2cc(-n3c4ccccc4c4cc(-n5c6ccccc6c6ccccc65)ccc43)ccc21]

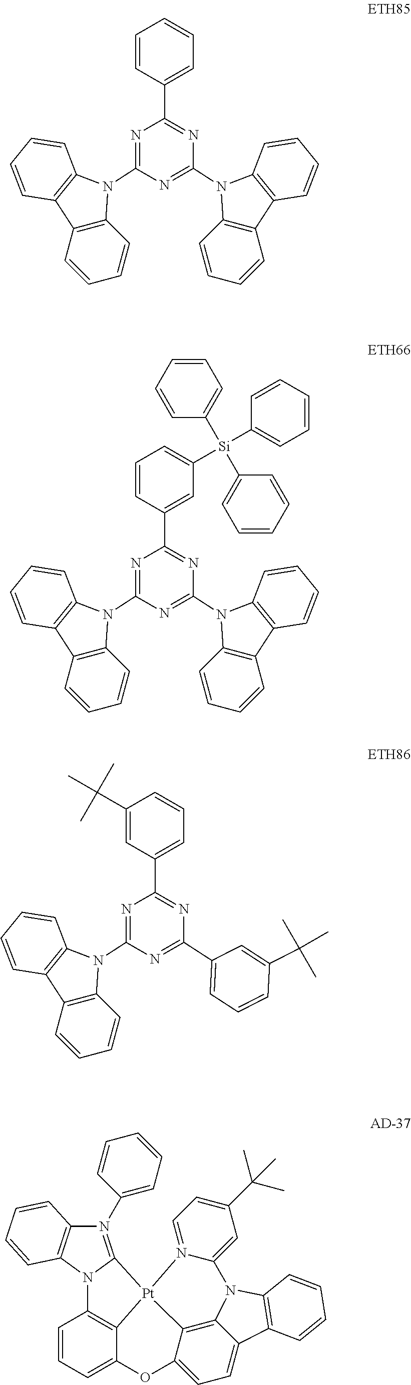

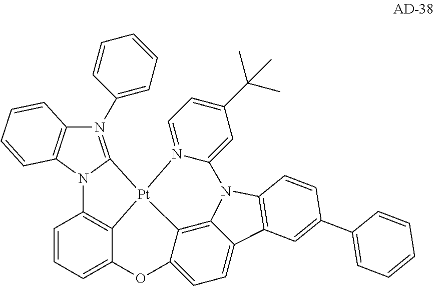

### Evaluation of Properties of Light Emitting Devices

The device efficiency and device lifetime of the light emitting devices manufactured utilizing Compounds 17, 25, 48,104,125,133,157,165, and 193, and Comparative Compound C to Comparative Compound C4 were evaluated. In Table 1, the evaluation results of the light emitting devices of Example 1 to Example 22, and Comparative Example 1 to Comparative Example 4 are shown. In the evaluation results of the properties on the Examples and Comparative Examples, shown in Table 1, the driving voltage and the current density were measured utilizing V7000 OLED IVL Test System, (Polaronix). In order to evaluate the properties of the light emitting devices manufactured in Examples 1 to 22, and Comparative Example 1 to Comparative Example 4, the driving voltage and efficiency (cd/A) at a current density of about 10 mA/cm² were measured, and the time from an initial value to 50% luminance deterioration when continuously operating at a current density of about 10 mA/cm², was compared to the value of Comparative Example 1 to obtain relative device lifetime.

TABLE 1

| | Second | | | | | | |
|---|---|---|---|---|---|---|---|
| | compound:third | | | Driving | | Emission | Lifetime |
| | compound | Fourth | First | voltage | Efficiency | wavelength | ratio |
| | (HT:ET = 5:5) | compound | compound | (V) | (cd/A) | (nm) | (T95) |
| Example 1 | HT2/ETH66 | AD-38 | 17 | 4.1 | 27.8 | 461 | 6.2 |
| Example 2 | HT2/ETH66 | AD-38 | 25 | 4.3 | 28.3 | 461 | 6.5 |
| Example 3 | HT2/ETH66 | AD-38 | 48 | 4.2 | 27.0 | 461 | 5.5 |
| Example 4 | HT2/ETH66 | AD-38 | 104 | 4.2 | 27.9 | 460 | 5.7 |
| Example 5 | HT2/ETH66 | AD-38 | 125 | 4.2 | 26.5 | 461 | 7.1 |
| Example 6 | HT2/ETH66 | AD-38 | 133 | 4.1 | 26.2 | 459 | 6.9 |
| Example 7 | HT2/ETH66 | AD-38 | 157 | 4.2 | 27.1 | 459 | 7.0 |
| Example 8 | HT2/ETH66 | AD-37 | 165 | 4.1 | 28.5 | 459 | 6.8 |
| Example 9 | HT2/ETH66 | AD-37 | 193 | 4.3 | 26.9 | 459 | 6.3 |
| Example 10 | HT3/ETH86 | AD-37 | 17 | 4.0 | 27.8 | 461 | 6.0 |
| Example 11 | HT3/ETH86 | AD-37 | 25 | 4.0 | 28.8 | 461 | 6.3 |
| Example 12 | HT3/ETH86 | AD-37 | 48 | 4.0 | 27.8 | 461 | 5.3 |
| Example 13 | HT3/ETH86 | AD-37 | 104 | 4.0 | 28.8 | 460 | 5.2 |
| Example 14 | HT3/ETH86 | AD-37 | 125 | 4.0 | 27.8 | 461 | 7.0 |
| Example 15 | HT3/ETH86 | AD-37 | 133 | 4.1 | 28.2 | 459 | 6.8 |
| Example 16 | HT1/ETH86 | AD-37 | 157 | 4.2 | 27.1 | 459 | 6.9 |
| Example 17 | HT1/ETH86 | AD-37 | 165 | 4.2 | 27.7 | 459 | 6.6 |
| Example 18 | HT4/ETH85 | AD-37 | 125 | 4.3 | 27.4 | 459 | 6.0 |
| Example 19 | HT4/ETH85 | AD-37 | 133 | 4.2 | 28.1 | 459 | 5.6 |
| Example 20 | HT4/ETH85 | AD-37 | 157 | 4.2 | 27.8 | 459 | 6.3 |
| Example 21 | HT4/ETH85 | AD-37 | 165 | 4.0 | 27.6 | 459 | 5.8 |
| Example 22 | HT4/ETH85 | AD-37 | 193 | 4.1 | 26.8 | 459 | 5.6 |
| Comparative | HT2/ETH66 | AD-37 | C1 | 5.2 | 11.5 | 458 | 1.0 |
| Example 1 | | | | | | | |
| Comparative | HT2/ETH66 | AD-37 | C2 | 5.0 | 12.2 | 456 | 1.2 |
| Example 2 | | | | | | | |
| Comparative | HT2/ETH66 | AD-37 | C3 | 5.1 | 11.9 | 454 | 1.1 |
| Example 3 | | | | | | | |
| Comparative | HT2/ETH66 | AD-37 | C4 | 4.9 | 13.0 | 455 | 1.3 |
| Example 4 | | | | | | | |

Referring to the results of Table 1, it could be confirmed that the Examples of the light emitting devices utilizing the fused polycyclic compounds according to embodiments of the present disclosure as light emitting materials showed low driving voltages when compared to the Comparative Examples, and improved emission efficiency and life-characteristics. Because the Example Compounds include first and second substituents connected with nitrogen atoms constituting a fused ring to effectively protect a boron atom, high efficiency and long-lifetime could be achieved. Due to the introduction of the first substituent into the Example Compounds, intermolecular interaction was suppressed or reduced, the formation of excimers or exciplexes was controlled or selected, and emission efficiency could be improved, and the red shift of an emission wavelength could be suppressed or reduced. In some embodiments, because the Example Compounds have a structure having large steric hindrance, the distance between adjacent molecules was increased and dexter energy transfer could be suppressed or reduced. Accordingly, lifetime deterioration resulted from the increase of the triplet concentration could be suppressed or reduced.

In some embodiments, because the Example Compounds have a structure in which third and fourth substituents are respectively connected with first and second aromatic rings among multiple aromatic rings fused via a boron atom and nitrogen atoms, multiple resonance effects could be increased, and low ΔE_{ST} could be achieved. Accordingly, the production of reverse intersystem crossing from a triplet excitation state to a singlet excitation state may become easier, delayed fluorescence properties may be improved, and emission efficiency may be improved.

In view of Comparative Example 1, Comparative Compound C1 includes a fused ring structure with one boron atom as a center, but does not include first and second substituents in a fused ring skeleton as suggested in the present disclosure. Accordingly, when applied to a device, it could be confirmed that a driving voltage was high, and emission efficiency and lifetime were degraded when compared to the Examples.

In view of Comparative Example 2, it could be confirmed that Comparative Compound C2 includes a substituent having a large volume as in the Example Compounds, but has inferior emission efficiency and device lifetime when compared to the Examples. Although not wanting to be bound by theory, it is believed that in Comparative Compound C2, an ortho-type or kind terphenyl group is connected with one nitrogen atom, but an ortho-type or kind biphenyl group is connected with another nitrogen atom among nitrogen atoms constituting a fused ring, and emission efficiency and life-characteristics were degraded when compared to the Examples. In contrast, when ortho-type or kind terphenyl groups are introduced as substituents into first and second nitrogen atoms constituting a fused ring as in the Example Compounds, it could be confirmed that emission efficiency and life-characteristics were improved when compared to Comparative Example 2.

In view of Comparative Example 3, Comparative Compound C3 includes a fused ring structure through one boron atom and two nitrogen atoms, but does not include first and second substituents in a fused ring skeleton as suggested in the present disclosure, and it could be confirmed that emission efficiency and lifetime were degraded when compared to the Examples. It is believed that Comparative Compound C3 has a structure in which an ortho-type or kind biphenyl group is substituted at a nitrogen atom connecting fused rings, but the biphenyl group has insufficient steric hindrance effects, and when applied to a light emitting device, emission efficiency and lifetime were degraded when compared to the Examples.

When comparing the Examples with Comparative Examples 2 and 3, Comparative Compound C2 and Comparative Compound C3 do not include a deuterium atom as a substituent connected with a fused ring skeleton, and it could be found that, when applied to a device, emission efficiency and device lifetime were degraded. When a deuterium atom is substituted at a specific position of the core of the fused ring as in the fused polycyclic compound of the Examples of the present disclosure, effective improvement of emission efficiency and device lifetime could be achieved.

In view of Comparative Example 4, Comparative Compound C4 includes a substituent having a large volume and a deuterium atom as a substituent connected with a fused ring skeleton, as in the Example Compounds, but it could be confirmed that emission efficiency and device lifetime were degraded when compared to the Examples. It is believed that, in Comparative Compound C4, an ortho-type or kind terphenyl group is connected with a nitrogen atom, but an ortho-type or kind biphenyl group is connected with another nitrogen atom among nitrogen atoms constituting a fused ring, and emission efficiency and life-characteristics were degraded when compared to the Examples.

The light emitting device of an embodiment may show improved device properties of high efficiency and long lifetime.

The fused polycyclic compound of an embodiment may be included in the emission layer of a light emitting device and may contribute to the increase of efficiency and lifetime of the light emitting device.

The use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this disclosure is intended to include all higher numerical limitations subsumed therein. Accordingly, Applicant reserves the right to amend this disclosure, including the claims, to expressly recite any sub-range subsumed within the ranges expressly recited herein.

The light emitting device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present present disclosure have been described, it is understood that the present present disclosure should not be limited to these embodiments, but one or more suitable changes and modifications can be made by one ordinary skilled in the art within the spirit and scope of the present disclosure as defined by the following claims and equivalents thereof.

What is claimed is:

1. A light emitting device, comprising:
a first electrode;
a second electrode; and
an emission layer between the first electrode and the second electrode,
wherein the emission layer comprises a first compound represented by Formula 1: 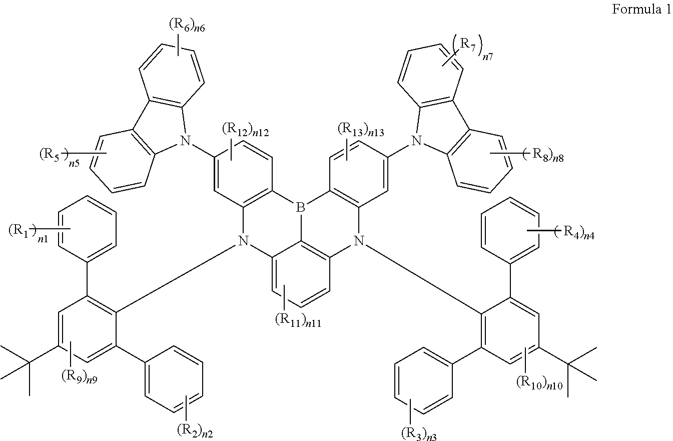
wherein Formula 1,
R₁ to R₁₃ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
n1 to n4 are each independently an integer from 0 to 5,
n5 to n8 are each independently an integer from 0 to 4,
n9 and n10 are each independently an integer from 0 to 2, and
n11 to n13 are each independently an integer from 0 to 3.

2. The light emitting device of claim 1, wherein
R₁ to R₄ are deuterium atoms, and
a sum of n1 to n4 is 1 to 20.

3. The light emitting device of claim 1, wherein the first compound represented by Formula 1 is represented by any one selected from among Formula 2-1 to Formula 2-4: 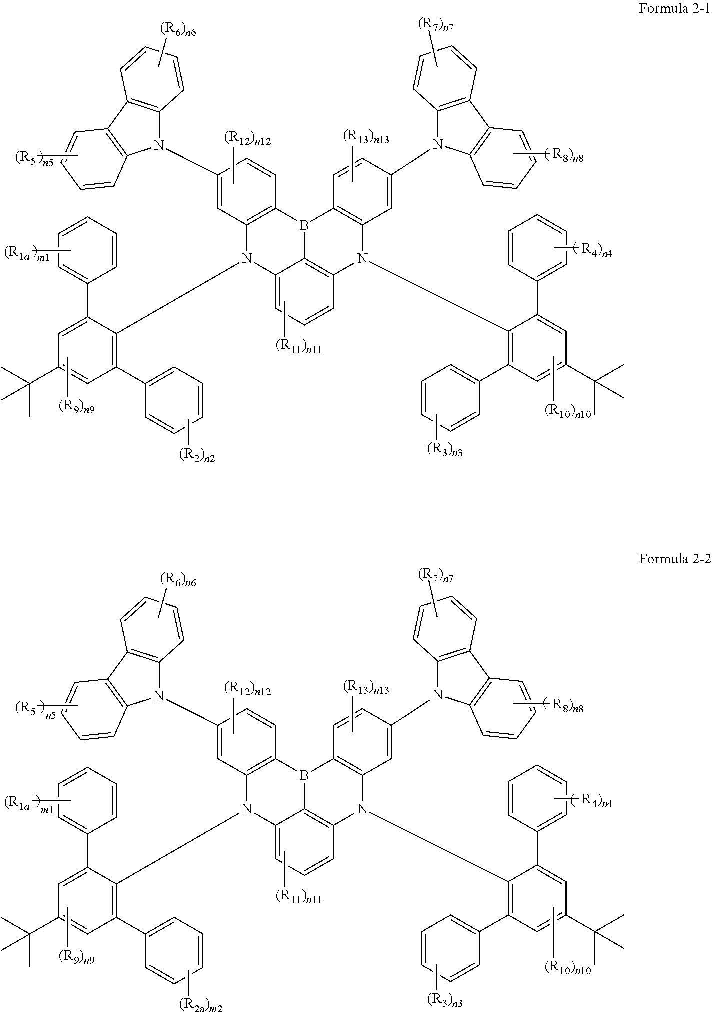 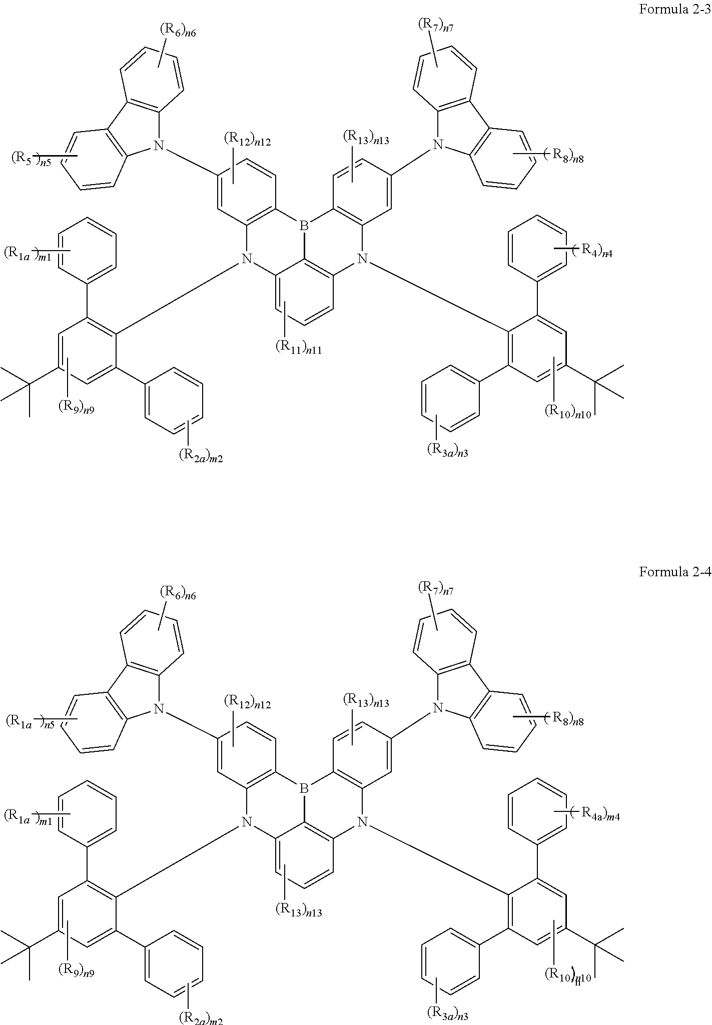
wherein Formula 2-1 to Formula 2-4,
R₁ₐ to R₄ₐ are deuterium atoms,
m1 to m4 are each independently an integer from 1 to 5, and
R₂ to R₁₃, and n2 to n13 are the same as defined in Formula 1.

4. The light emitting device of claim 3, wherein the first compound represented by Formula 1 is represented by any one selected from among Formula 3-1 to Formula 3-3: 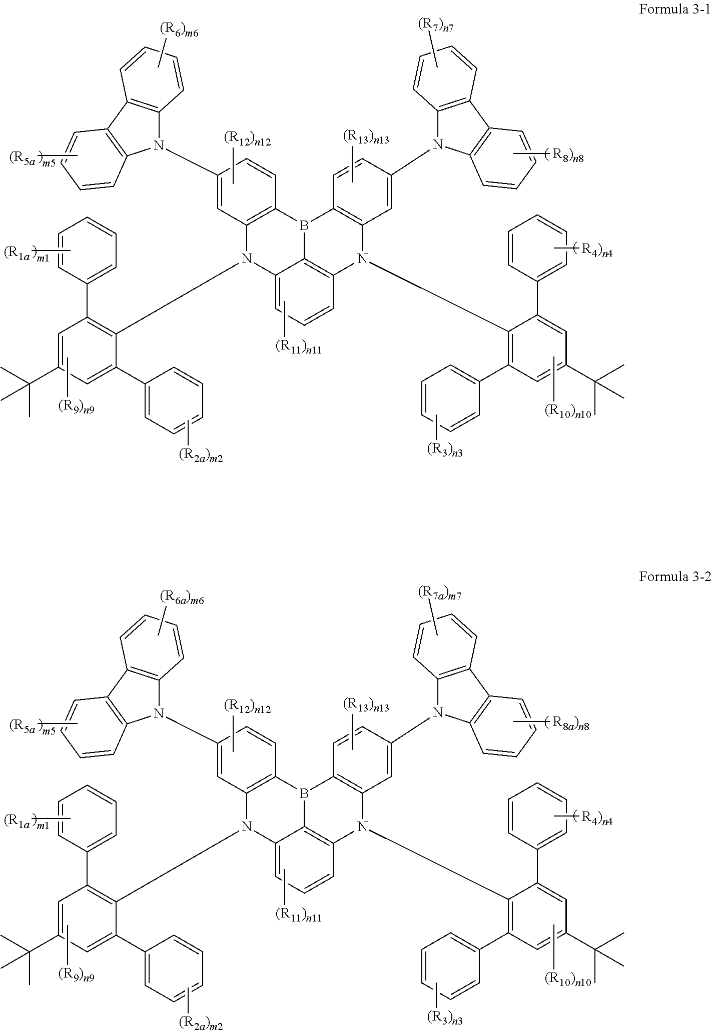 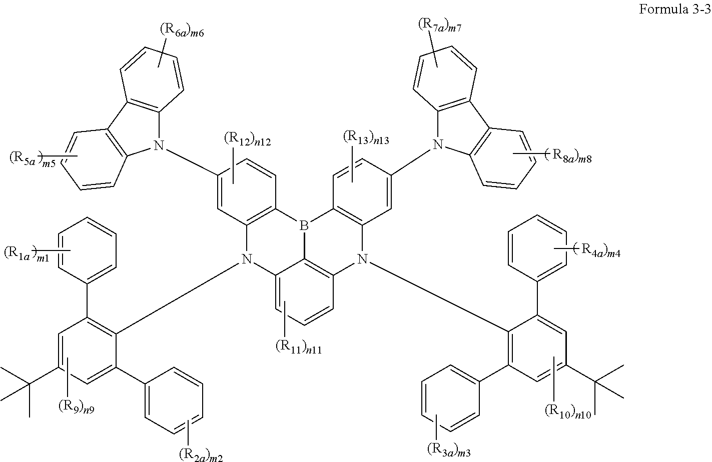
wherein Formula 3-1 to Formula 3-3,
R₅ₐ to R₈ₐ are deuterium atoms,
m5 to m8 are each independently an integer from 1 to 4, and
R₁ₐ to R₄ₐ, R₃, R₄, R₇ to R₁₃, m1 to m4, n3, n4, and n7 to n13 are the same as defined in Formula 1 and Formula 2-1 to Formula 2-4.

5. The light emitting device of claim 1, wherein the first compound represented by Formula 1 is represented by any one selected from among Formula 4-1 to Formula 4-8: 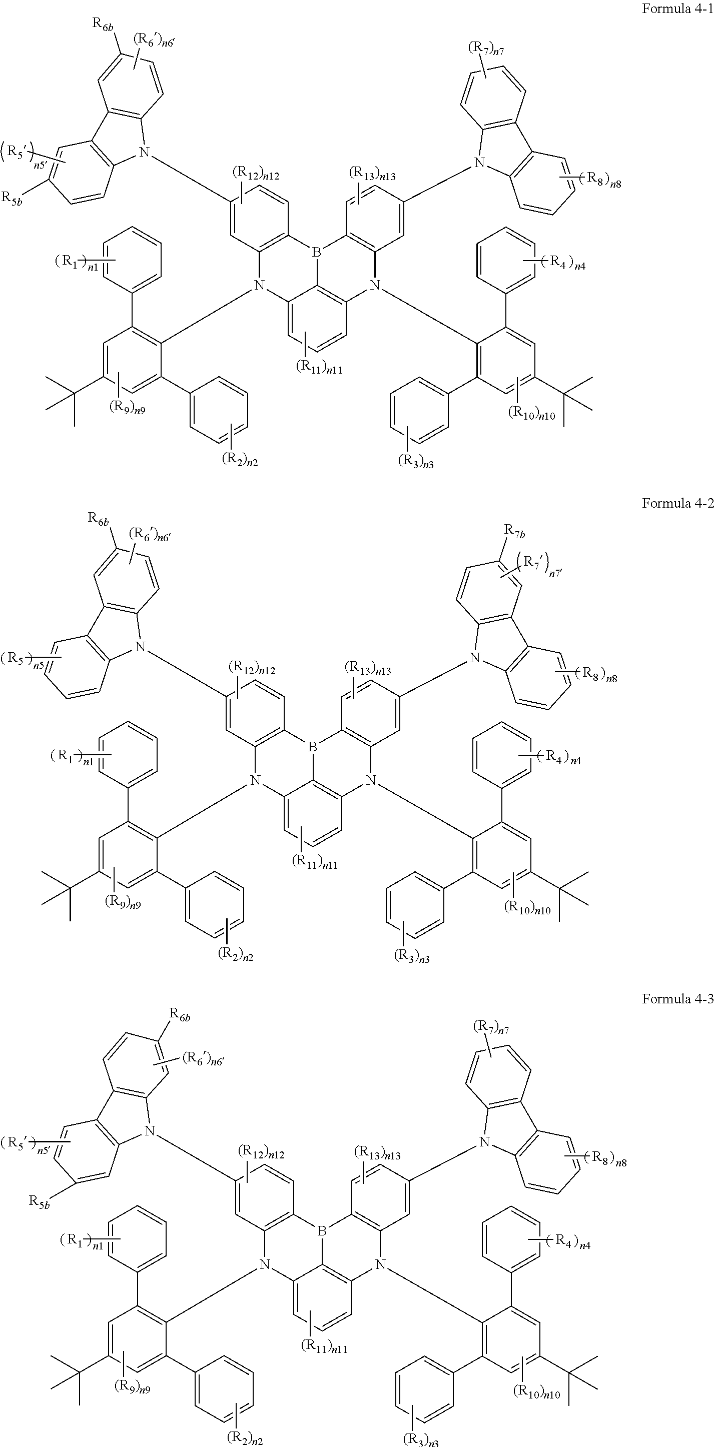 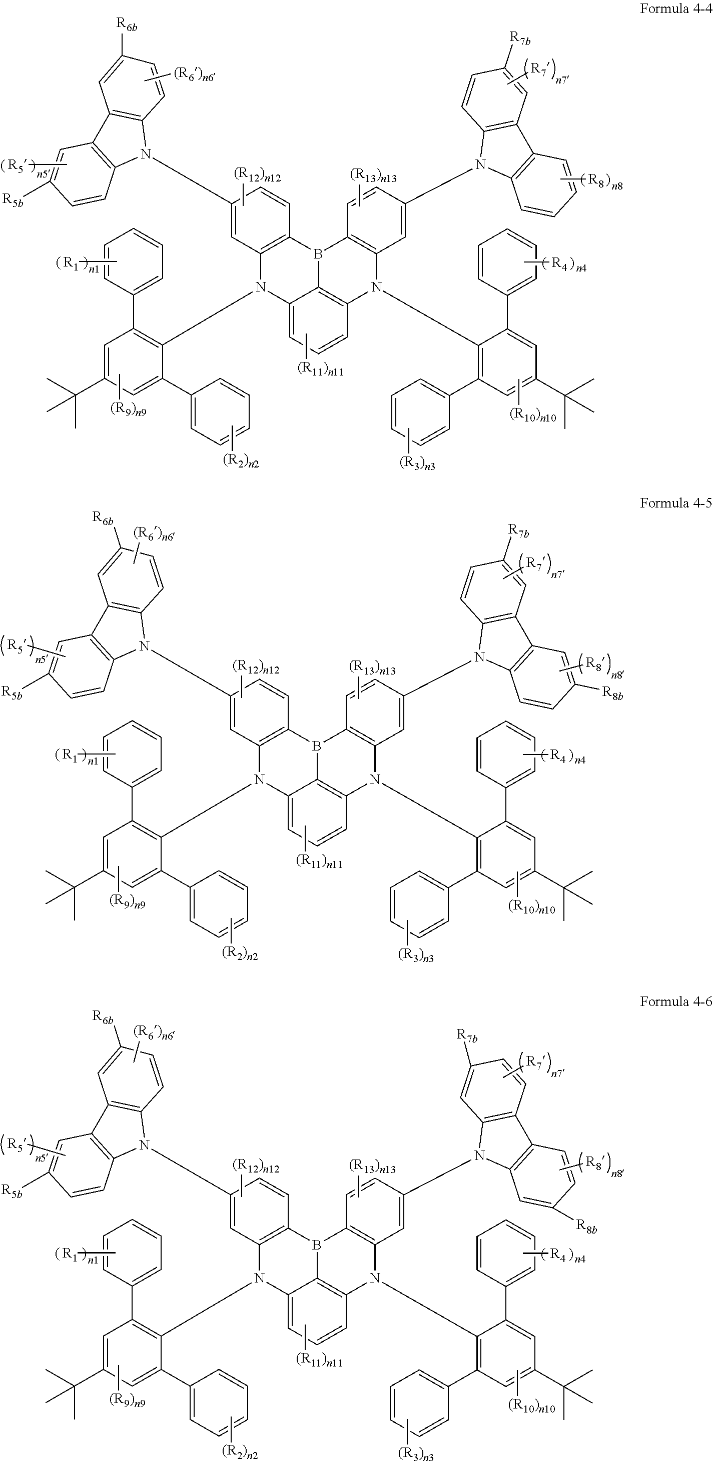 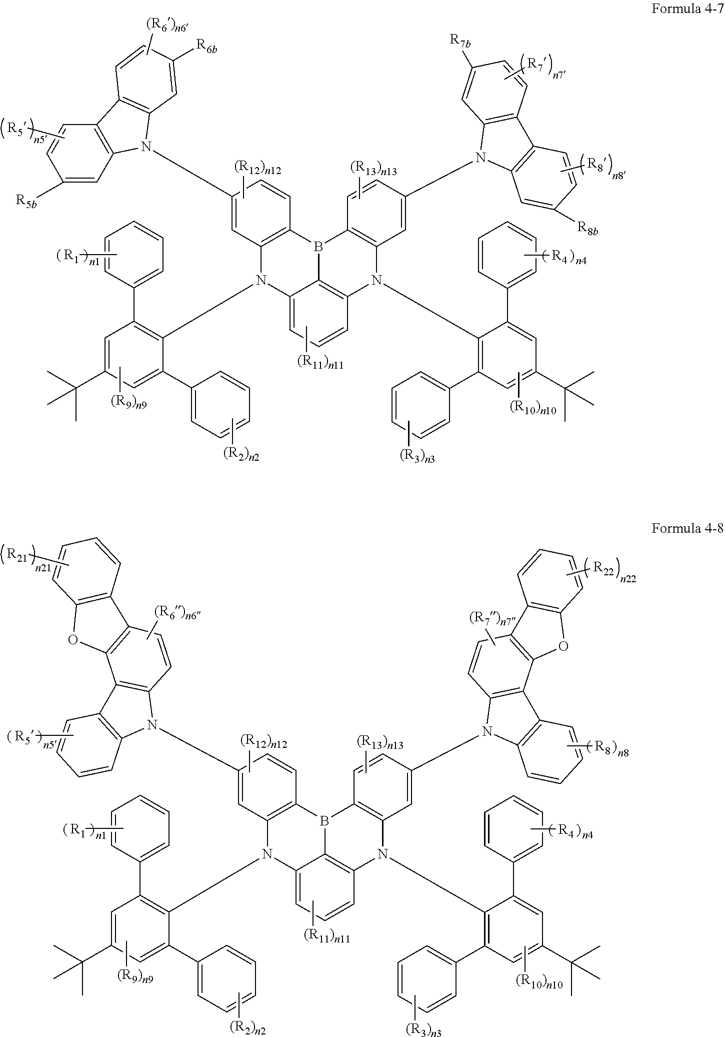
wherein Formula 4-1 to Formula 4-8
R_{5b} to R_{8b} are each independently a deuterium atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R₅′ to R₈′, R₆″, R₇″, R₂₁, and R₂₂ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n5′ to n8′ are each independently an integer from 0 to 3,
n6″ and n7″ are each independently an integer from 0 to 2,
n21 and n22 are each independently an integer from 0 to 4, and
R₁ to R₅, R₇ to R₁₃, n1 to n5, and n7 to n13 are the same as defined in Formula 1.

6. The light emitting device of claim 1, wherein the first compound represented by Formula 1 is represented by any one selected from among Formula 5-1 to Formula 5-3: 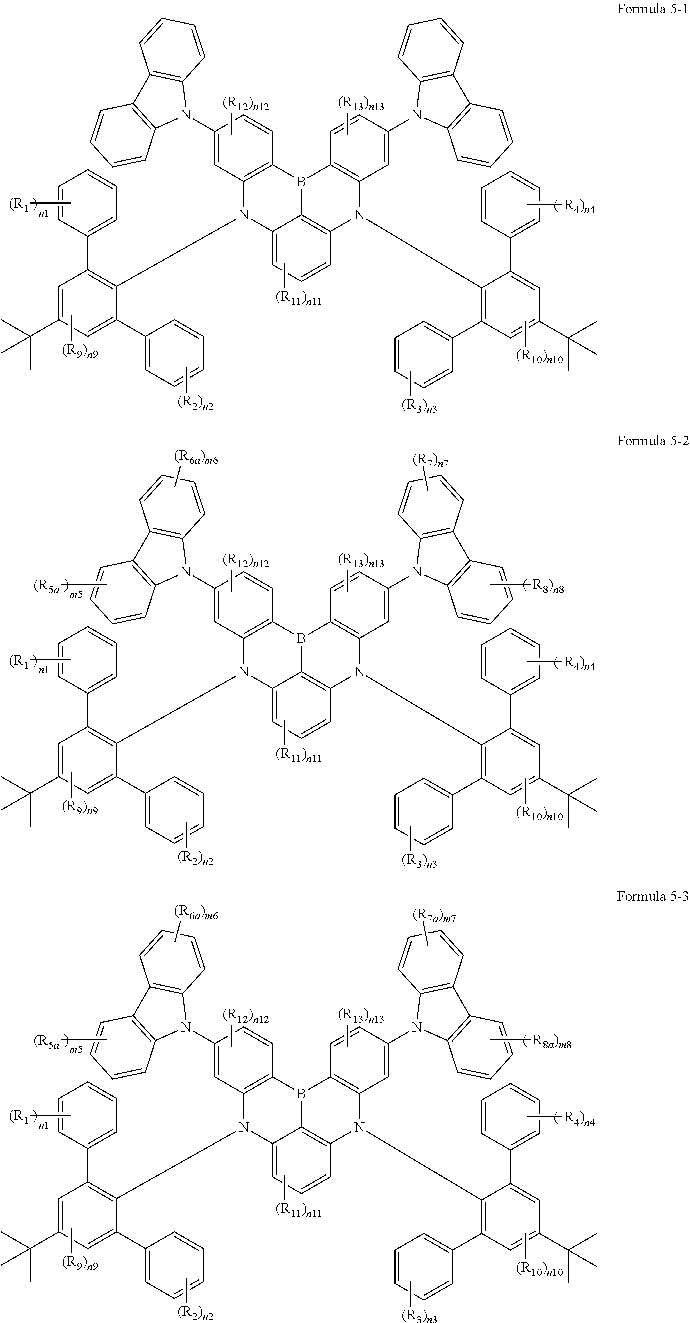
wherein Formula 5-1 to Formula 5-3,
R₅ₐ to R₈ₐ are deuterium atoms,
m5 to m8 are each independently an integer from 1 to 4, and
R₁ to R₄, R₇ to R₁₃, n1 to n4, and n7 to n13 are the same as defined in Formula 1.

7. The light emitting device of claim 1, wherein the first compound represented by Formula 1 is represented by Formula 6: 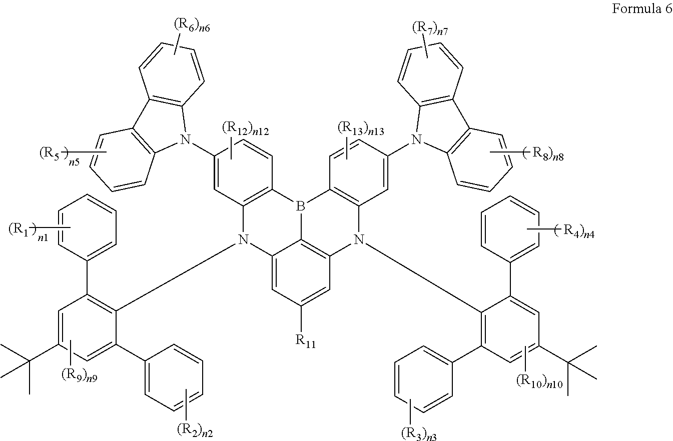
wherein Formula 6,
R₁ to R₁₃, n1 to n10, n12, and n13 are the same as defined in Formula 1.

8. The light emitting device of claim 7, wherein R₁₁ is a hydrogen atom, a substituted or unsubstituted alkyl group of 1 to 10 carbon atoms, or a substituted or unsubstituted cycloalkyl group of 3 to 10 ring-forming carbon atoms.

9. The light emitting device of claim 1, wherein the first compound represented by Formula 1 comprises at least one selected from among compounds in Compound Group 1:

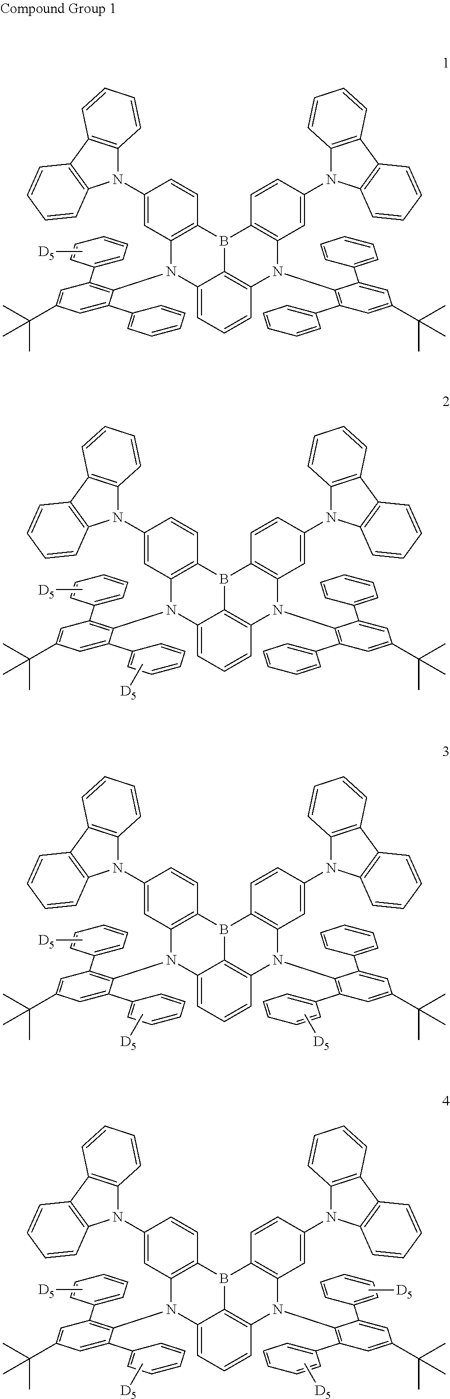

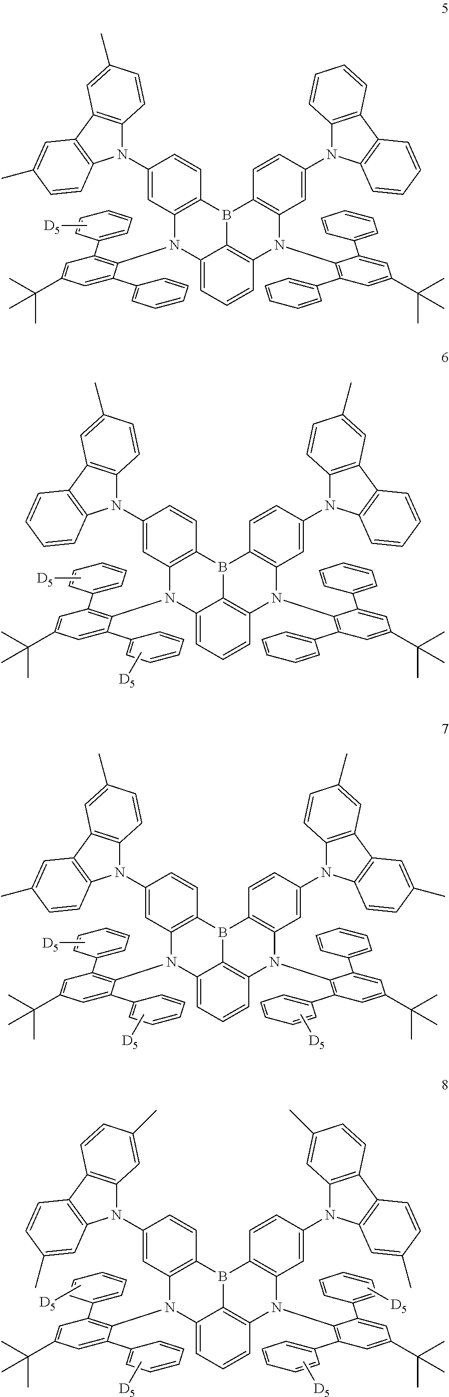

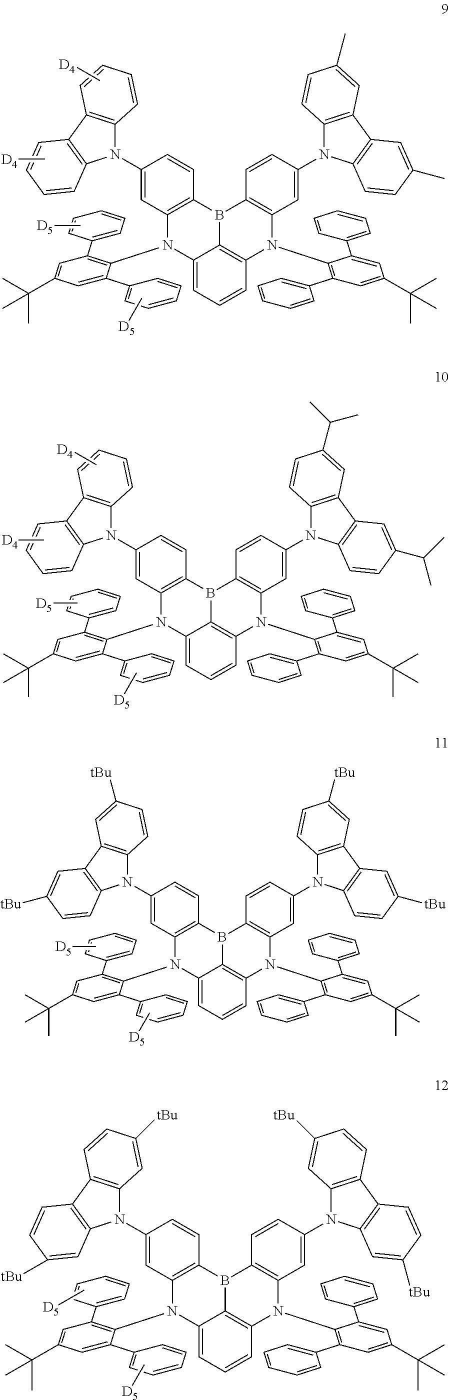

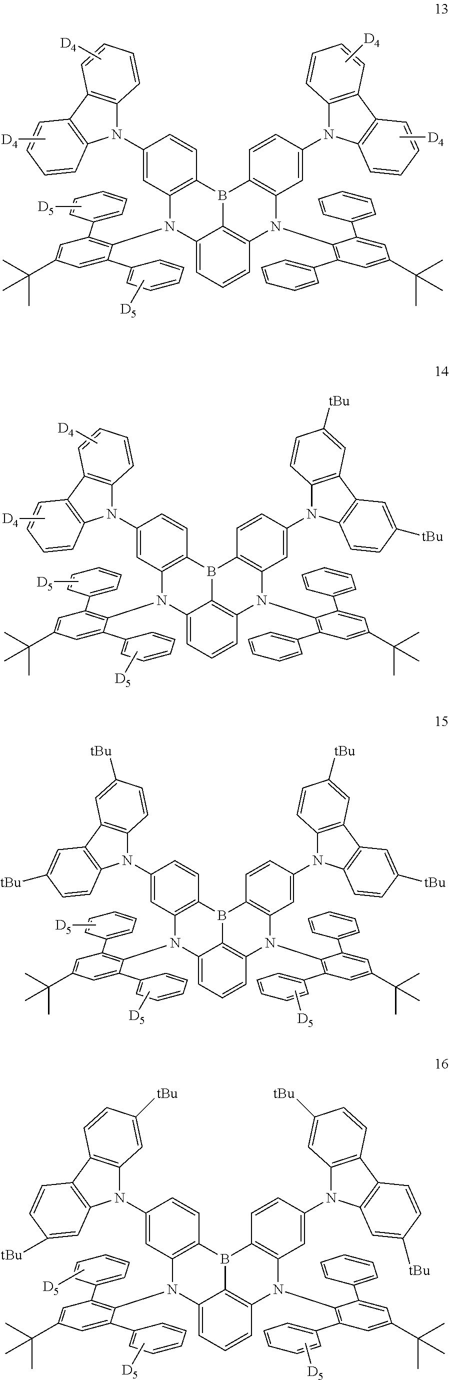

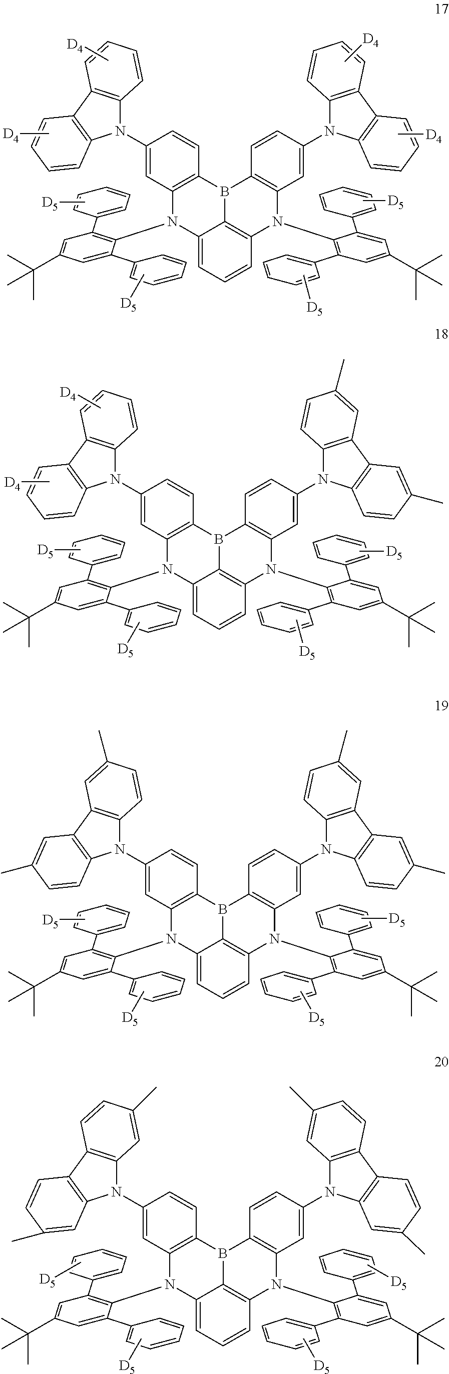

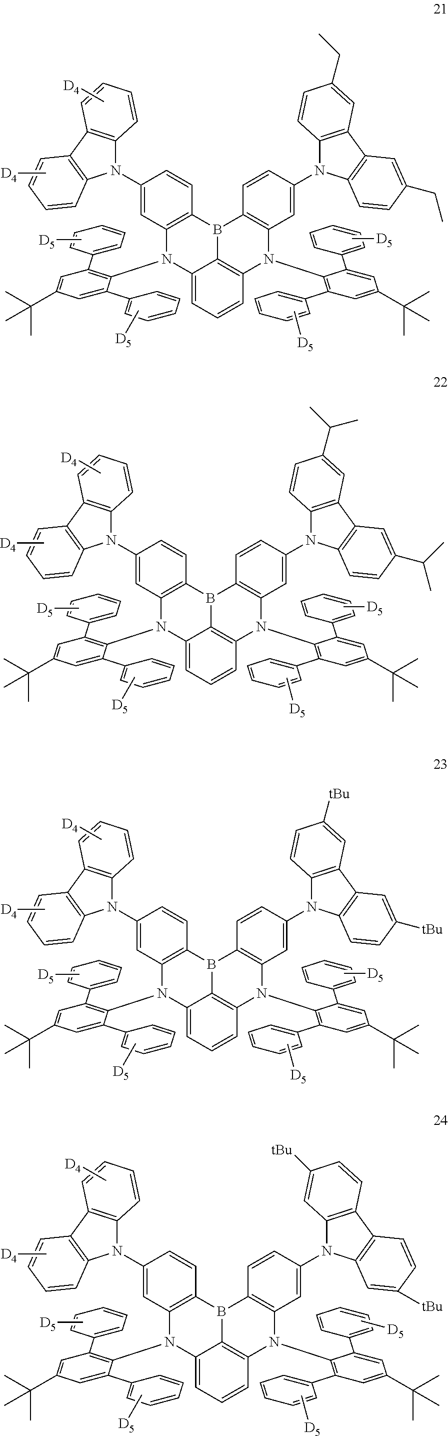

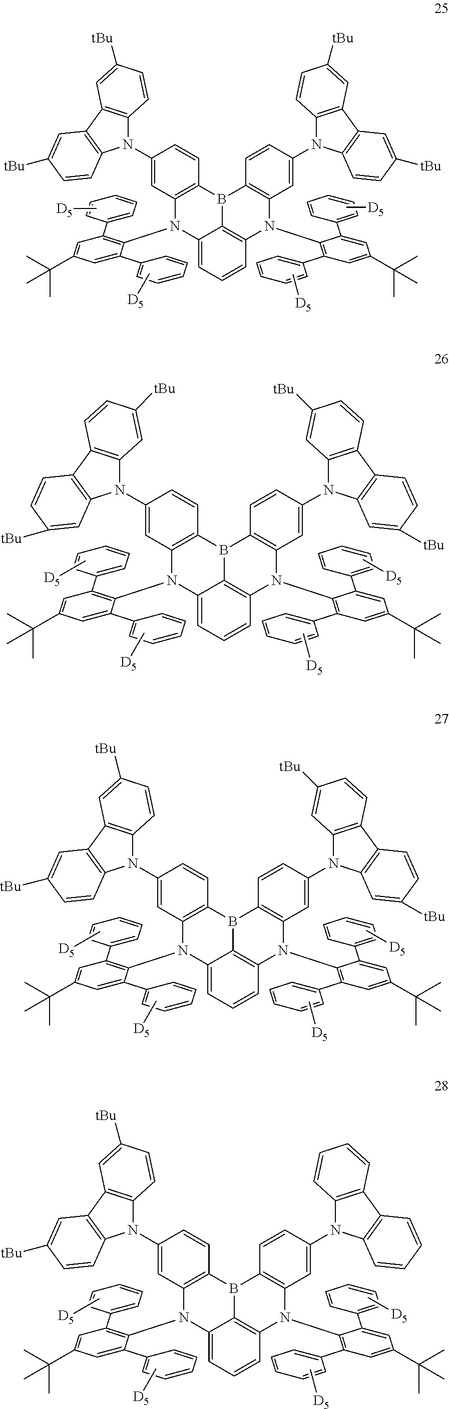

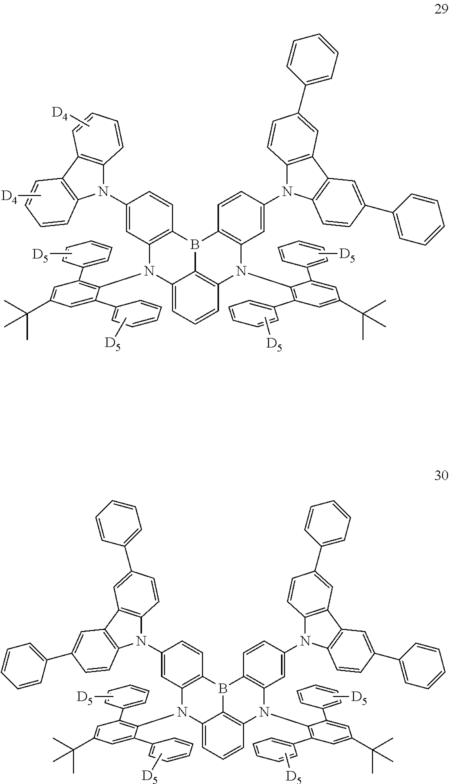

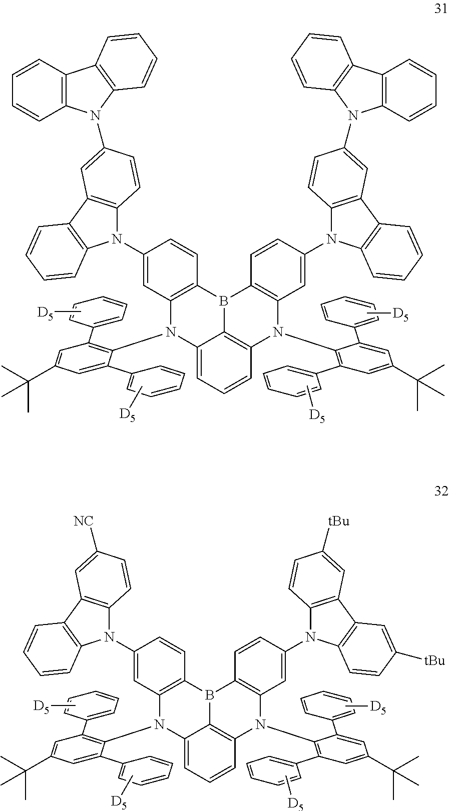

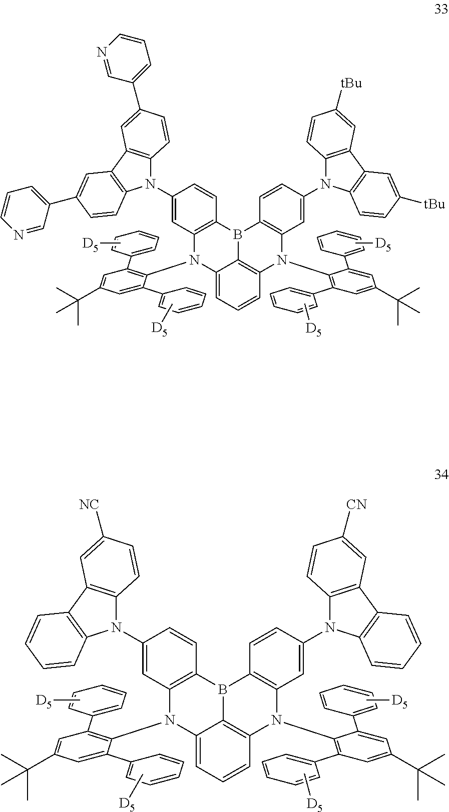

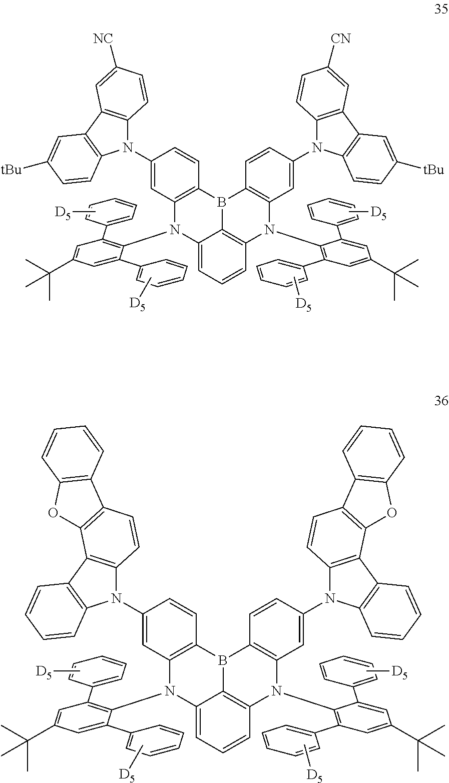

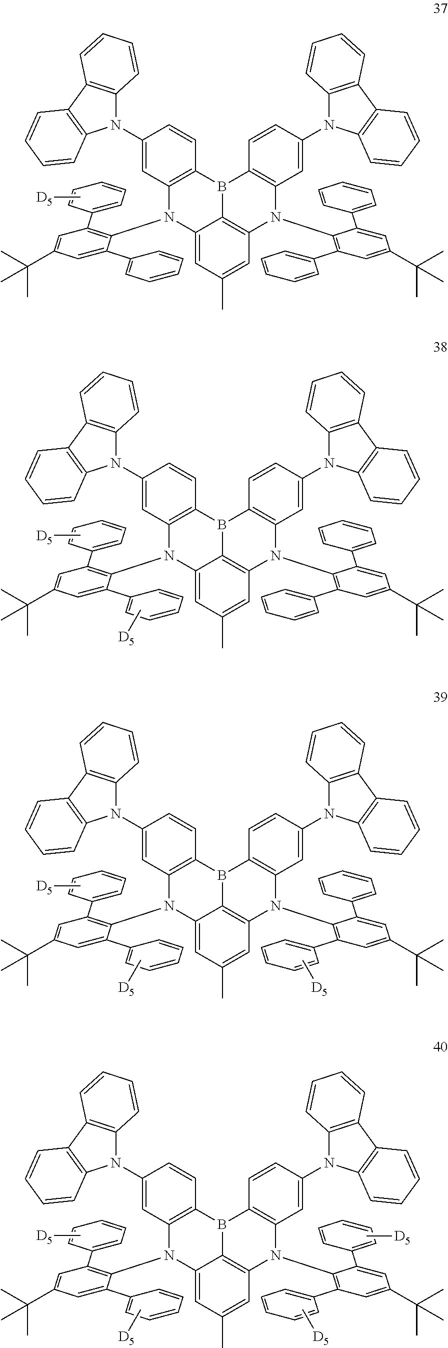

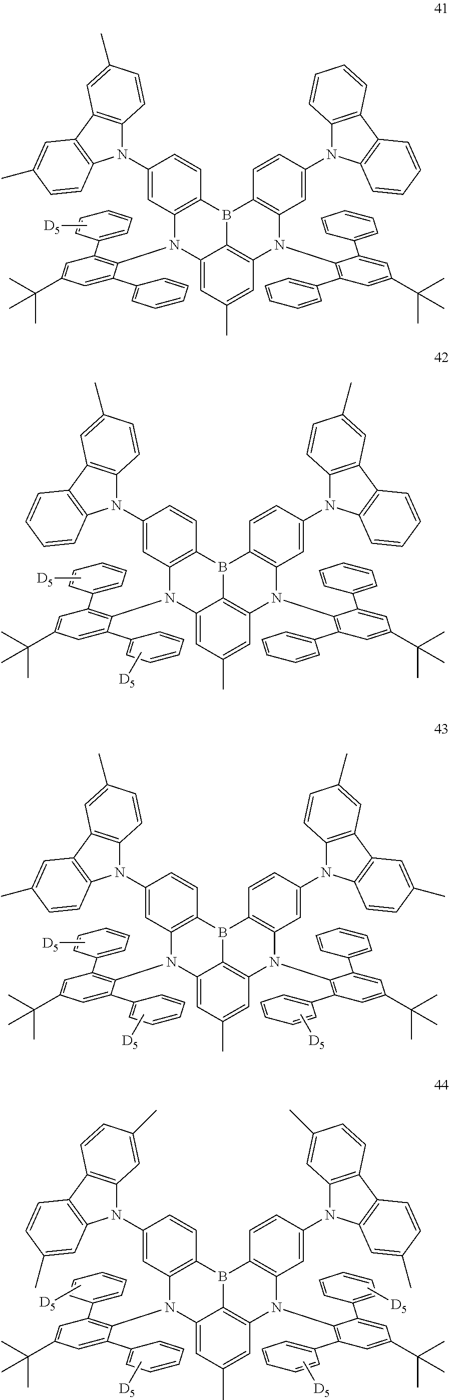

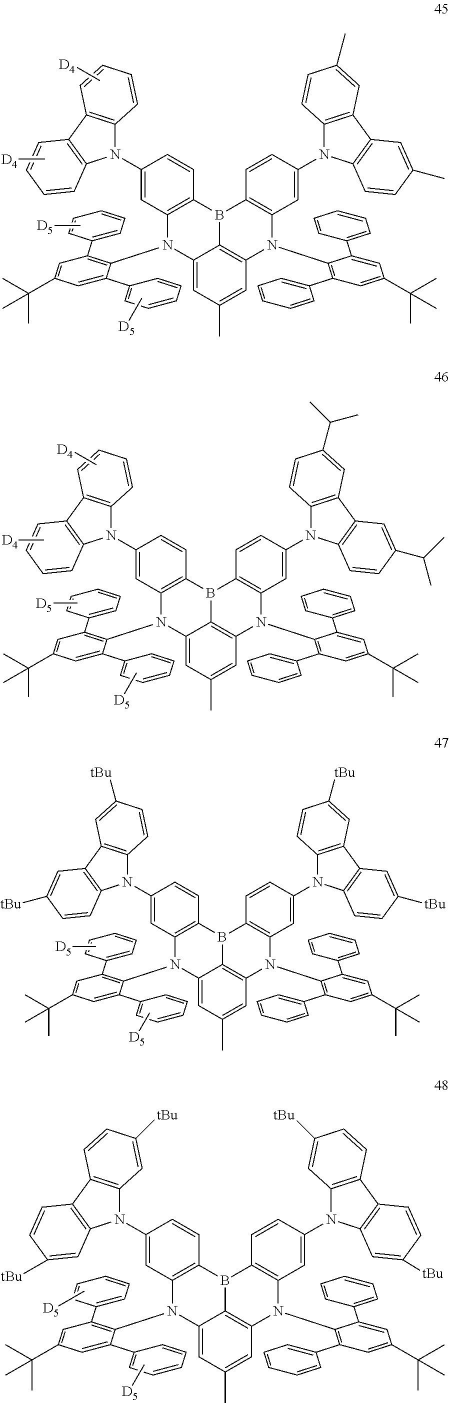

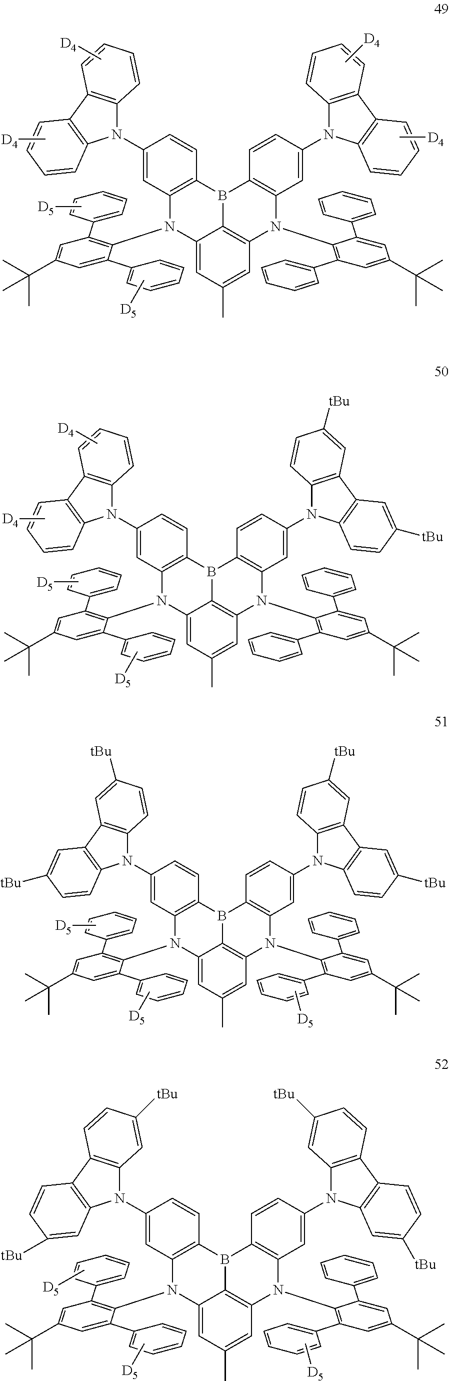

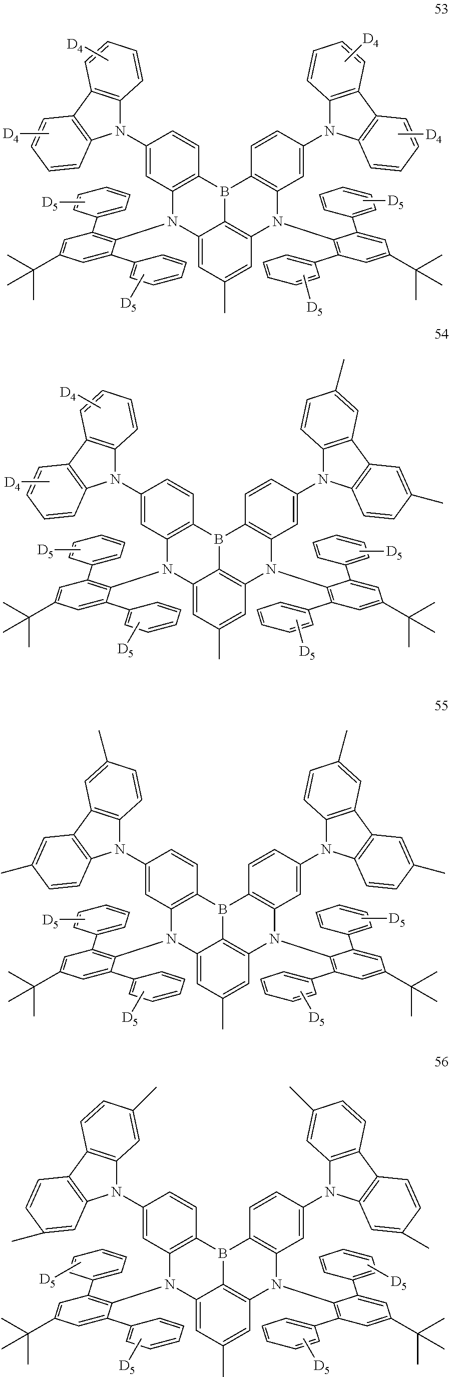

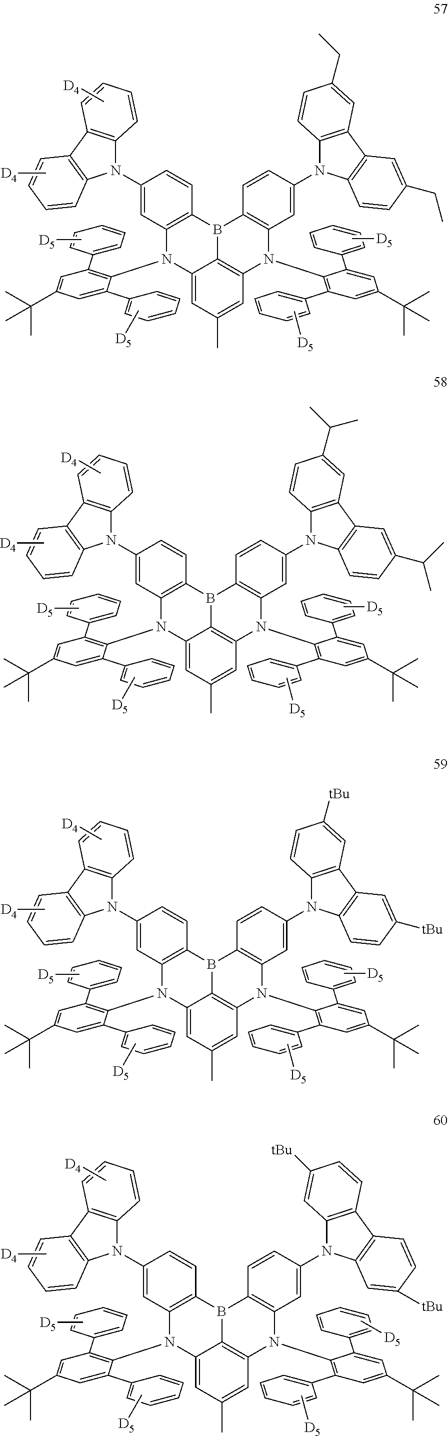

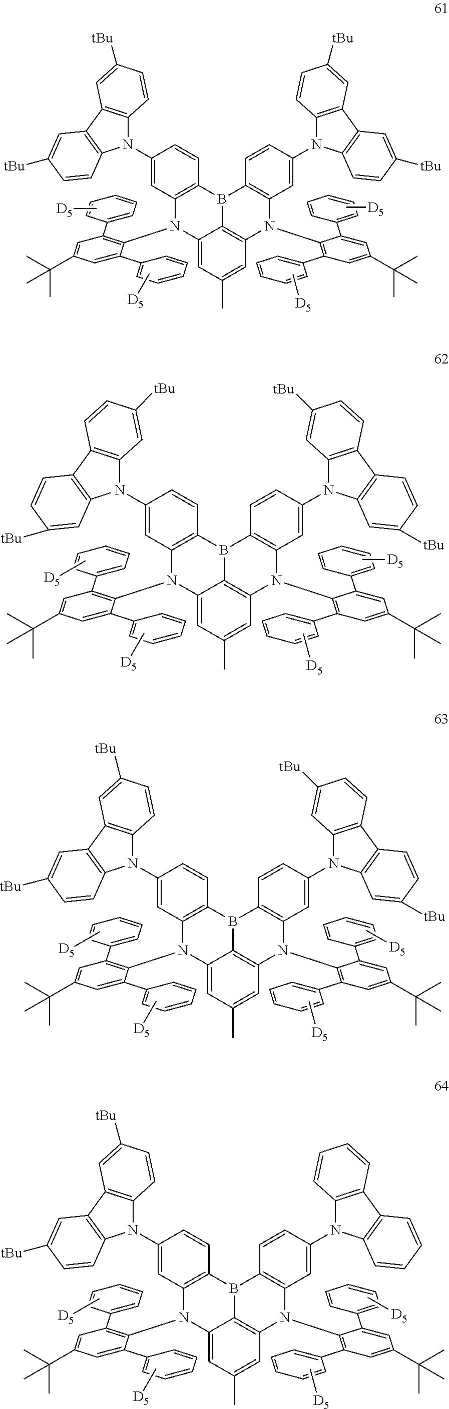

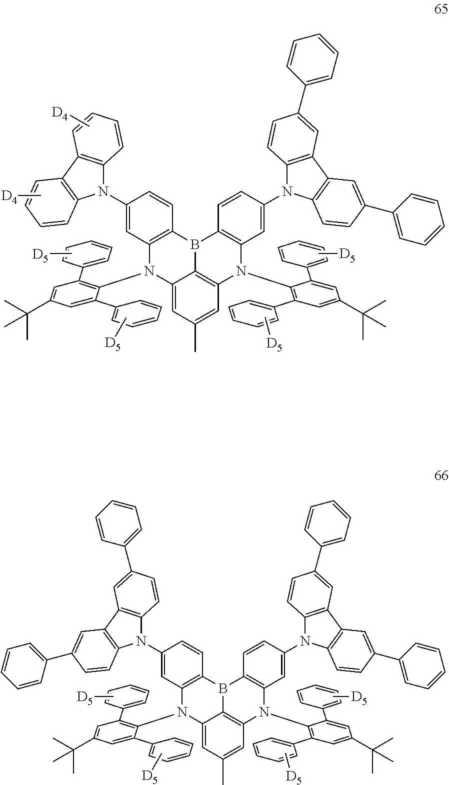

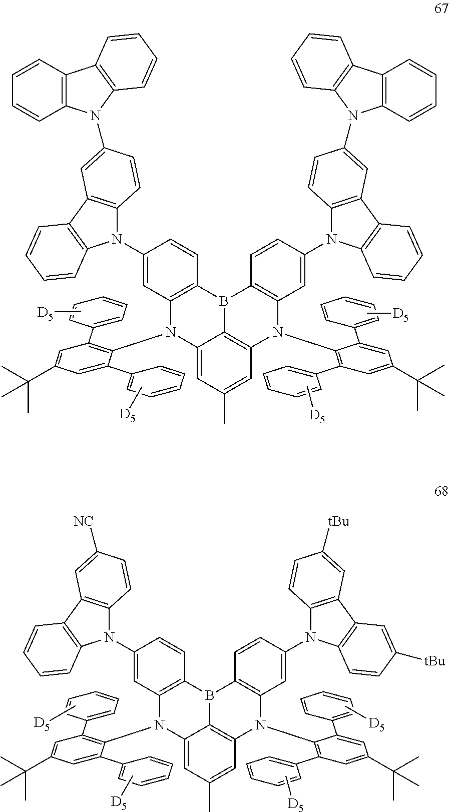

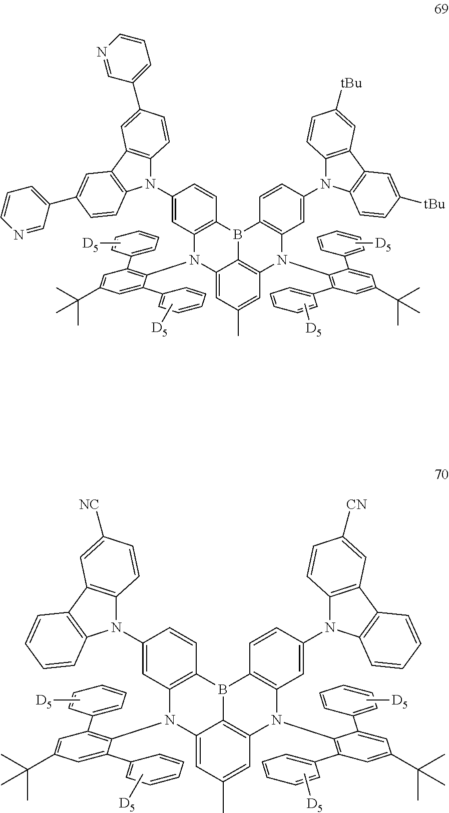

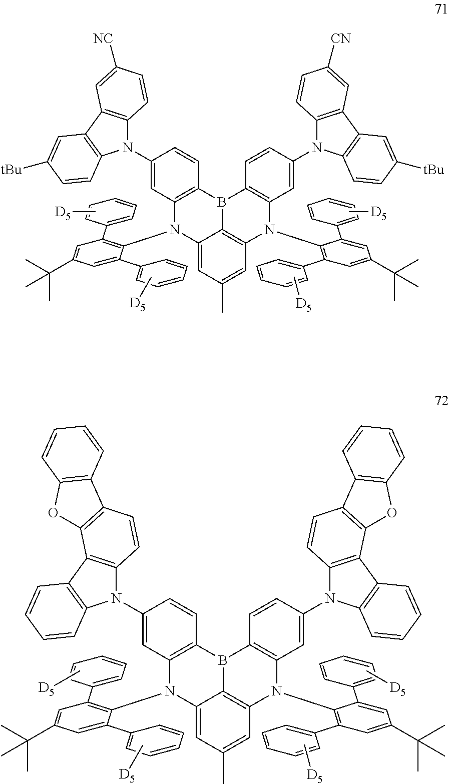

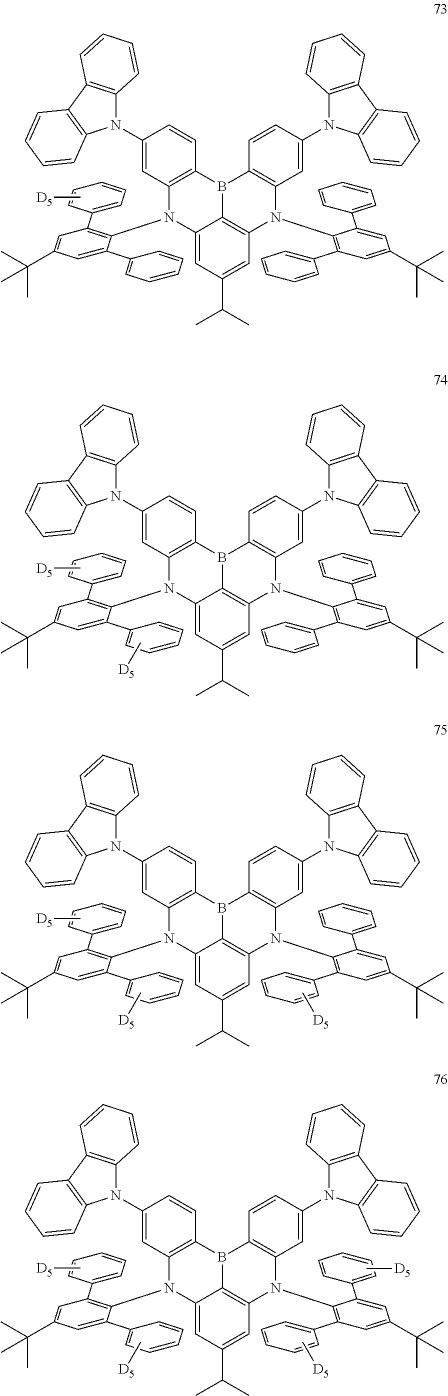

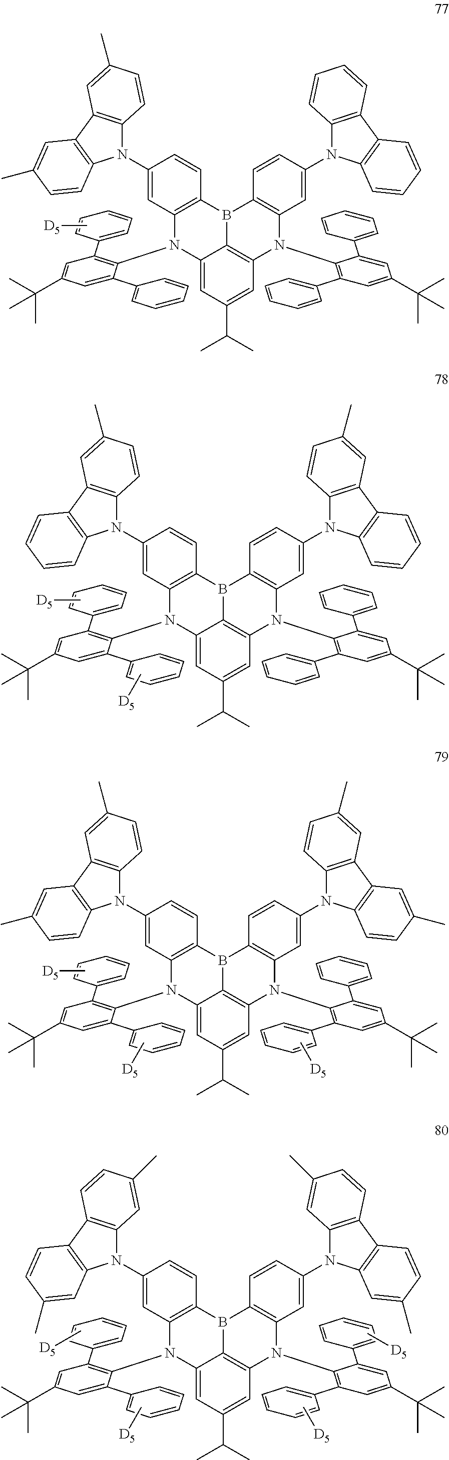

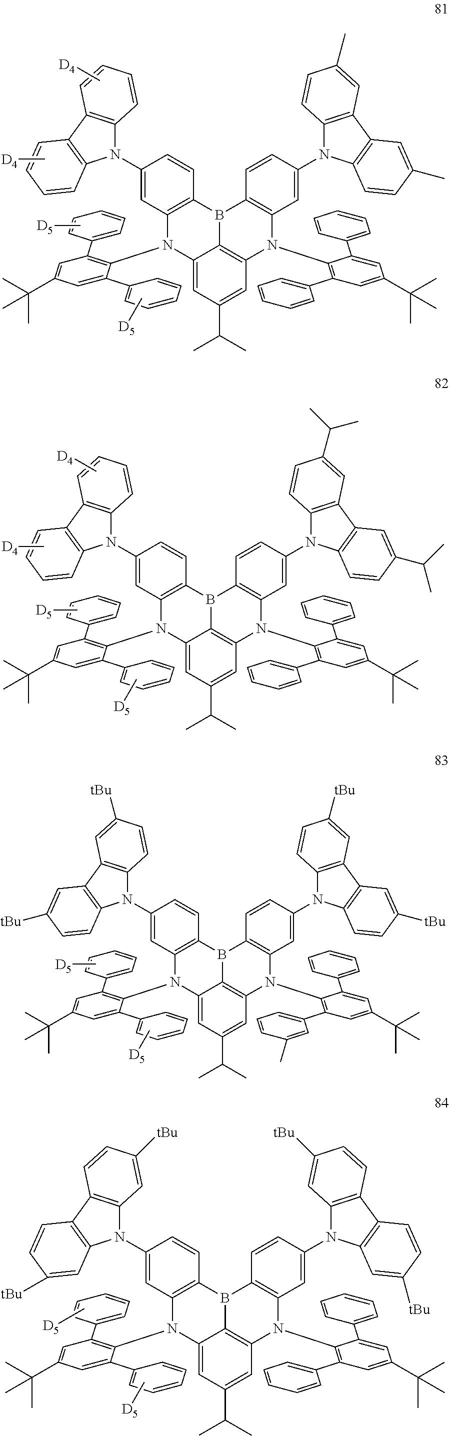

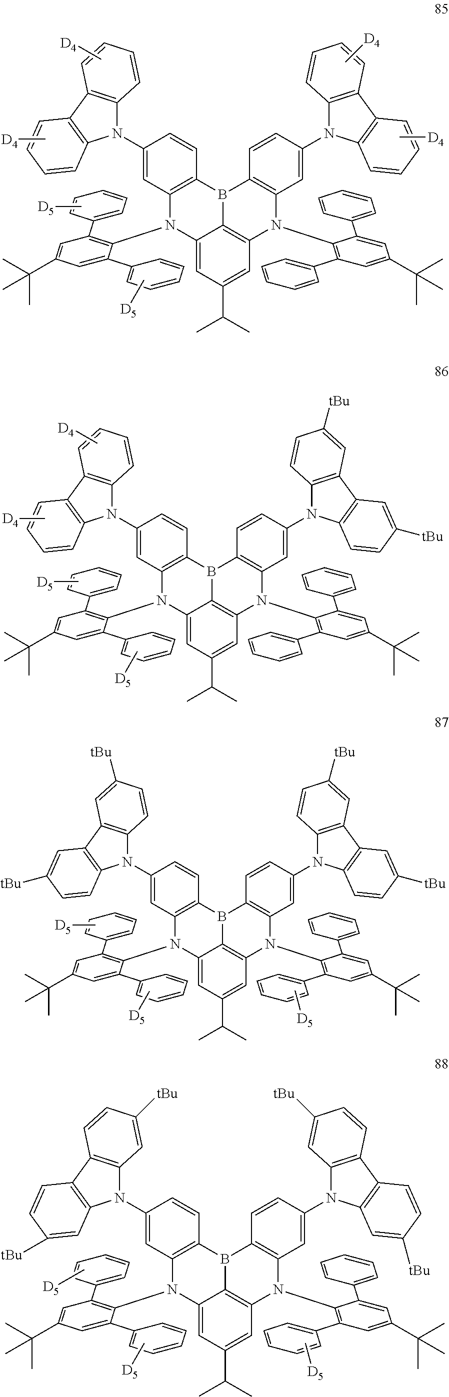

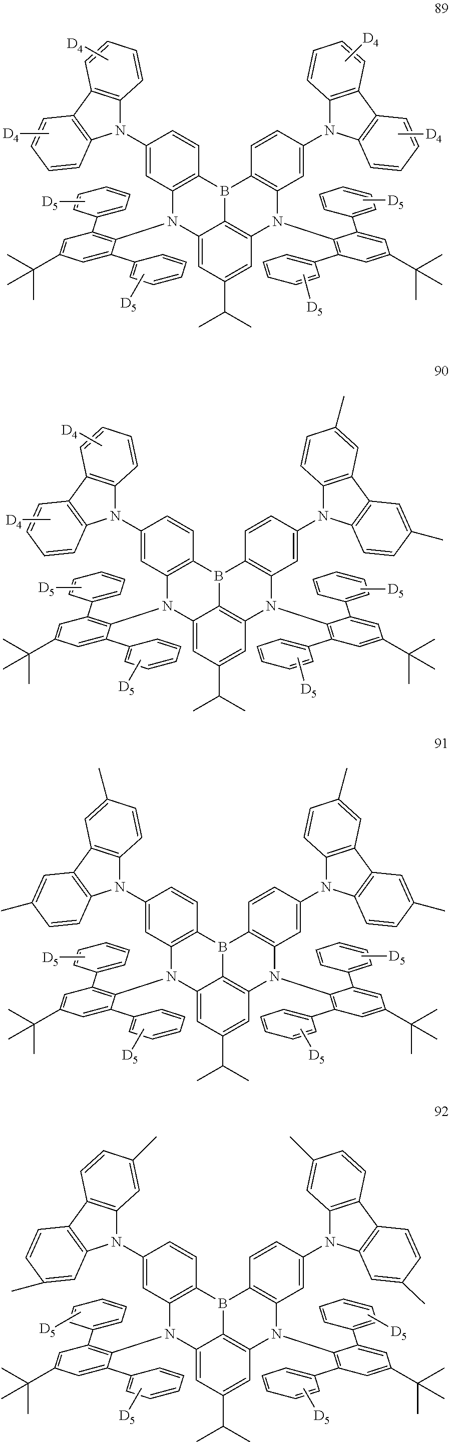

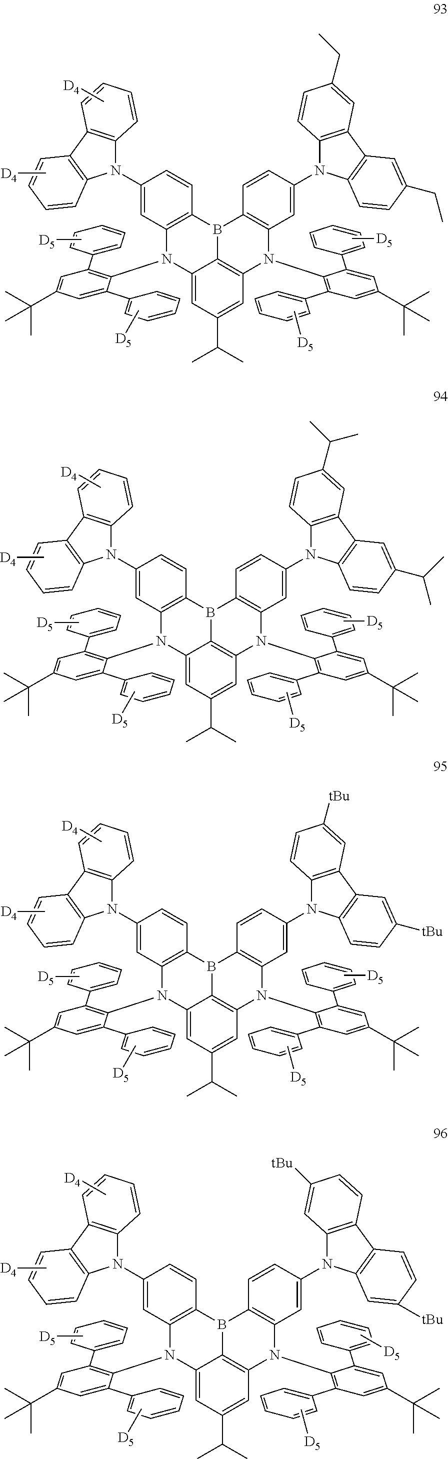

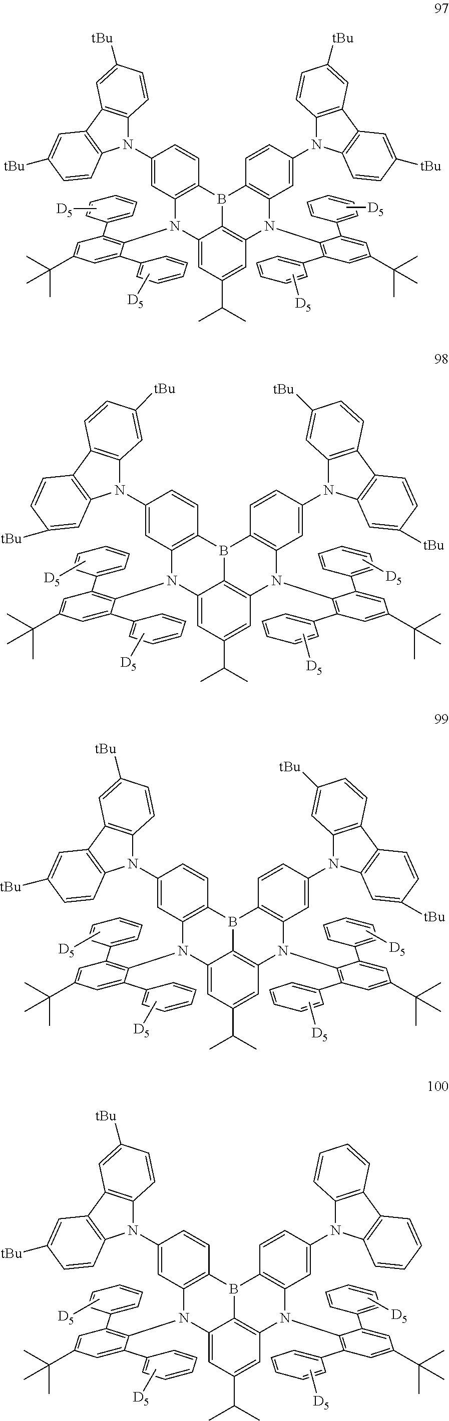

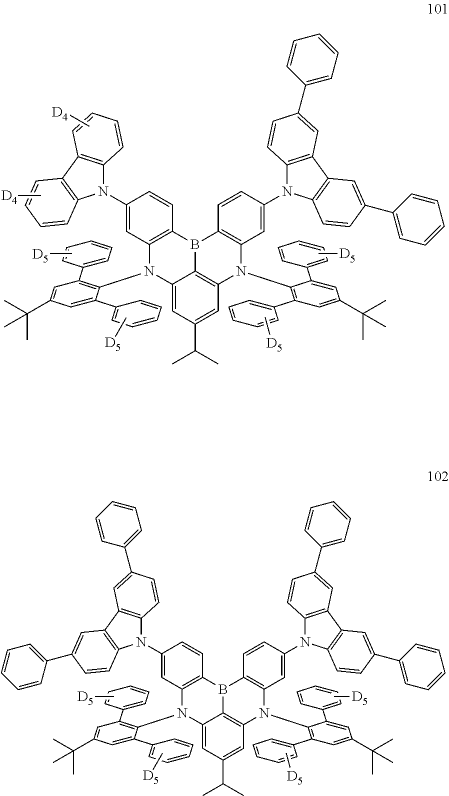

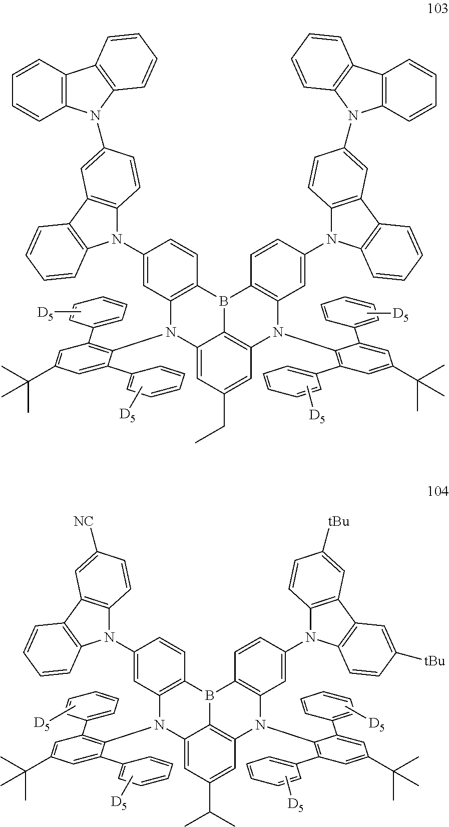

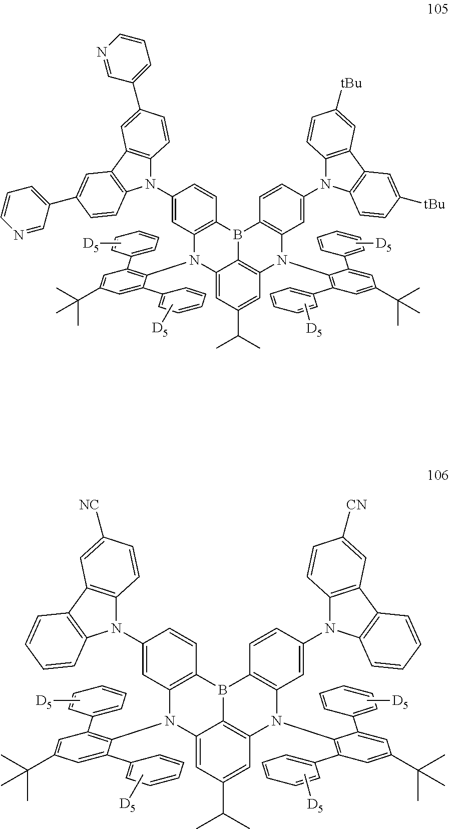

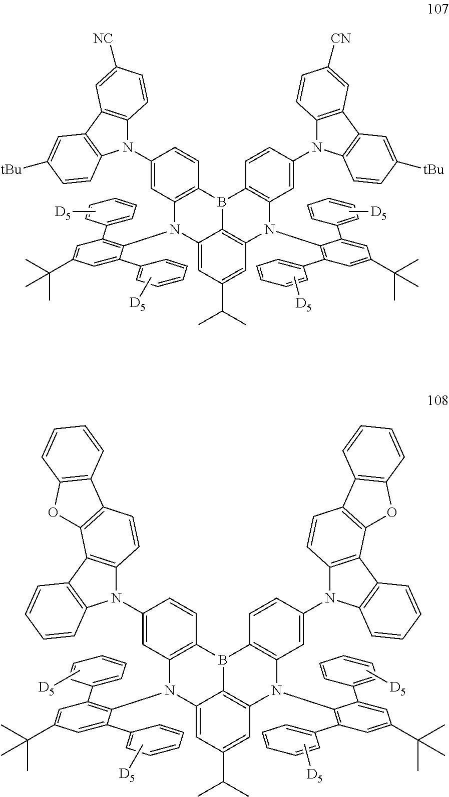

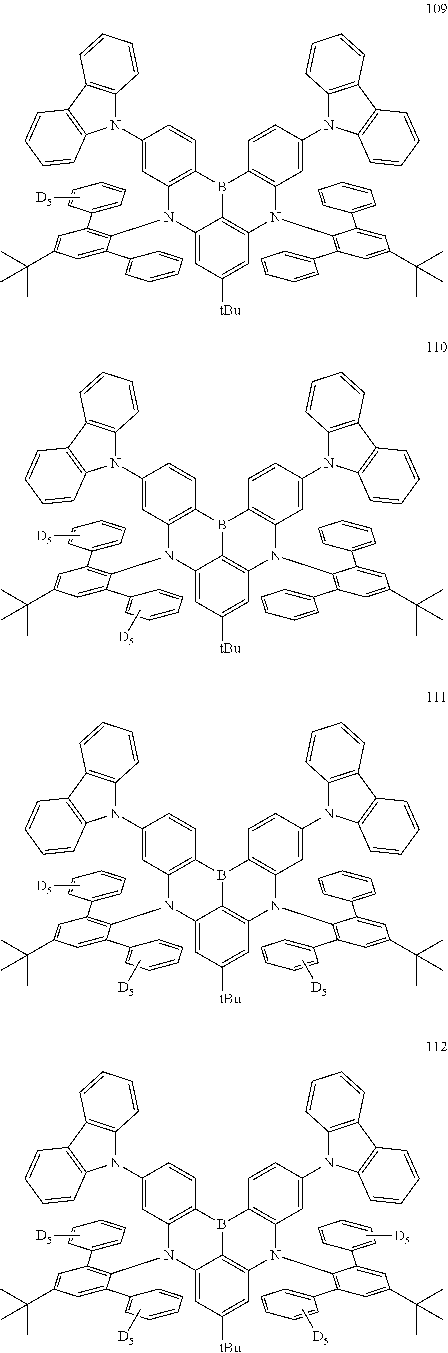

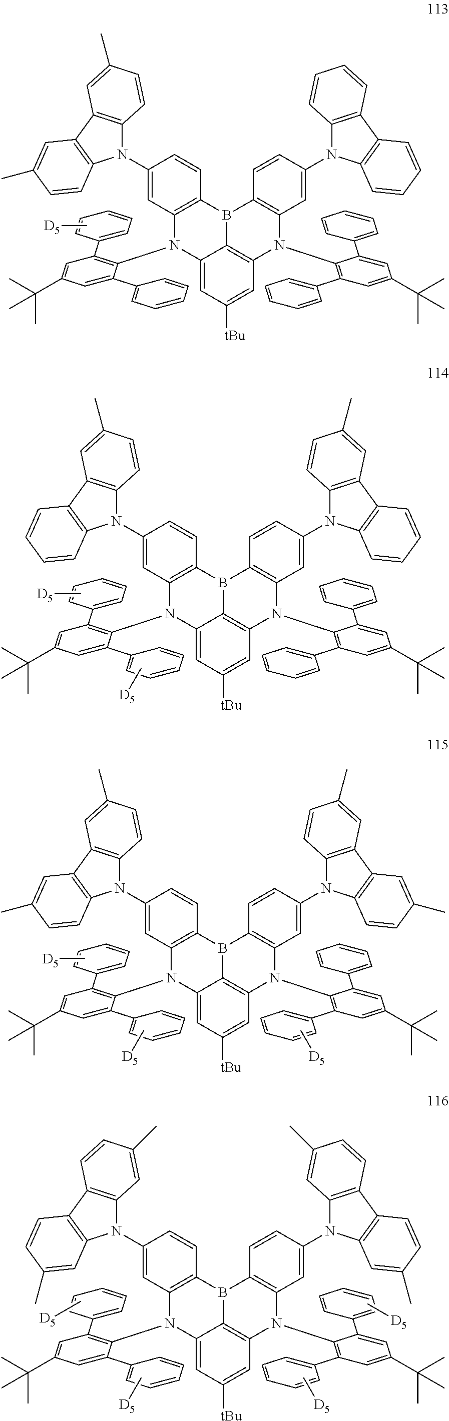

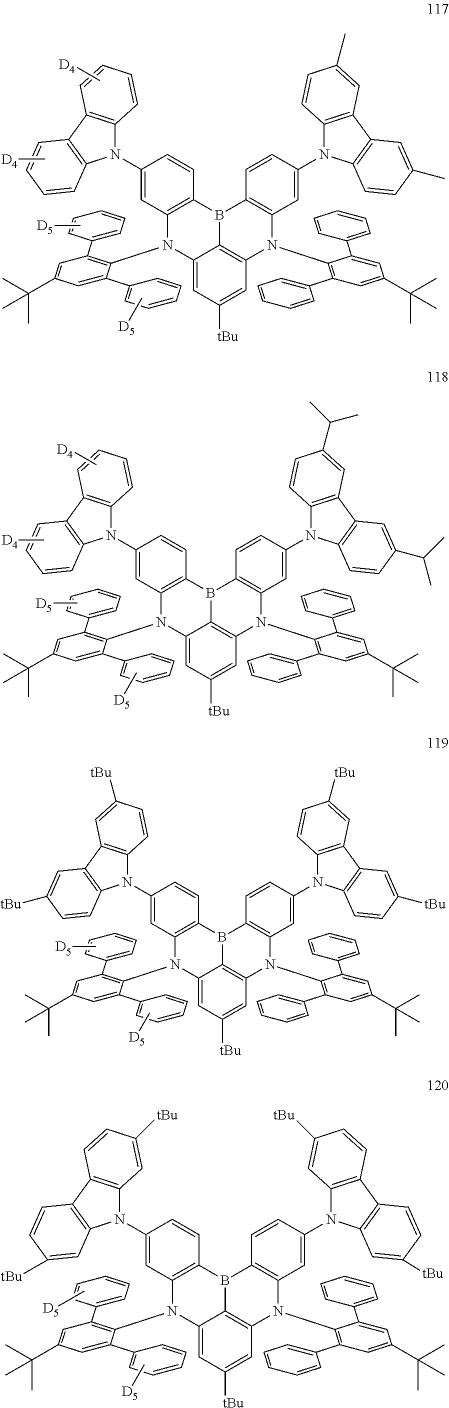

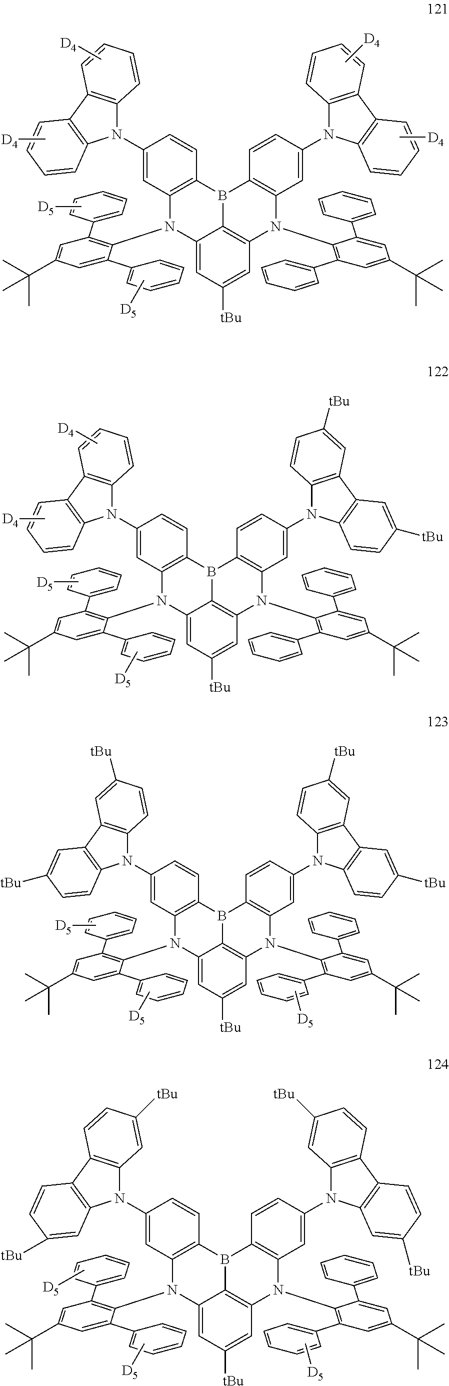

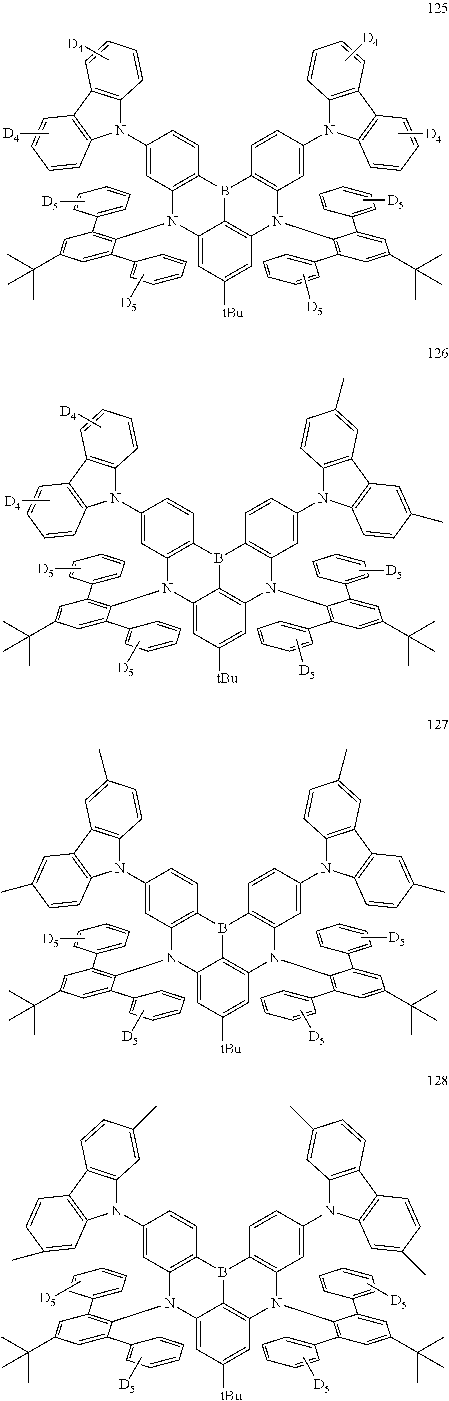

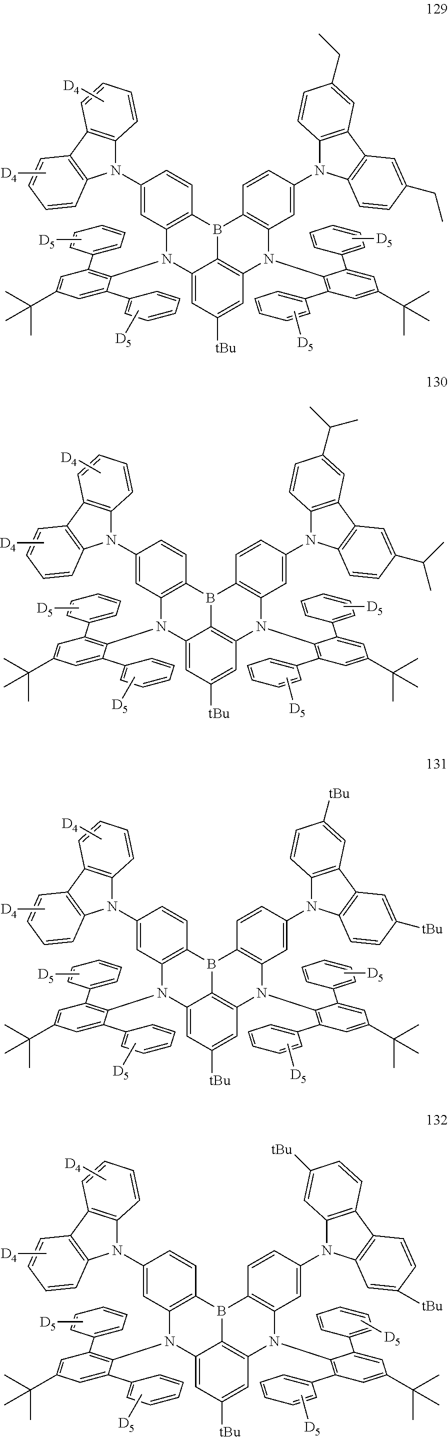

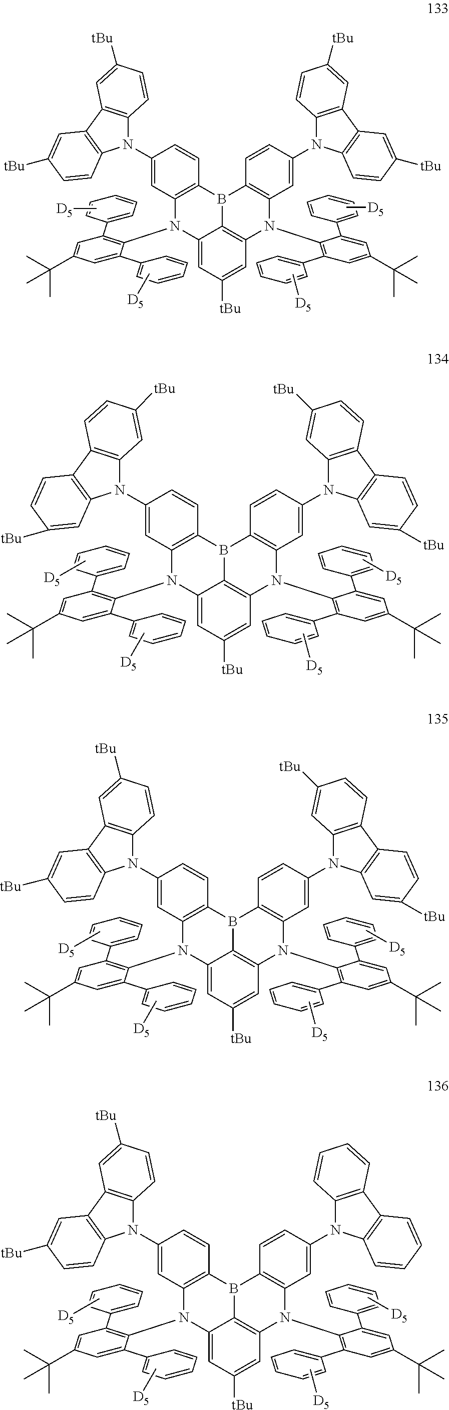

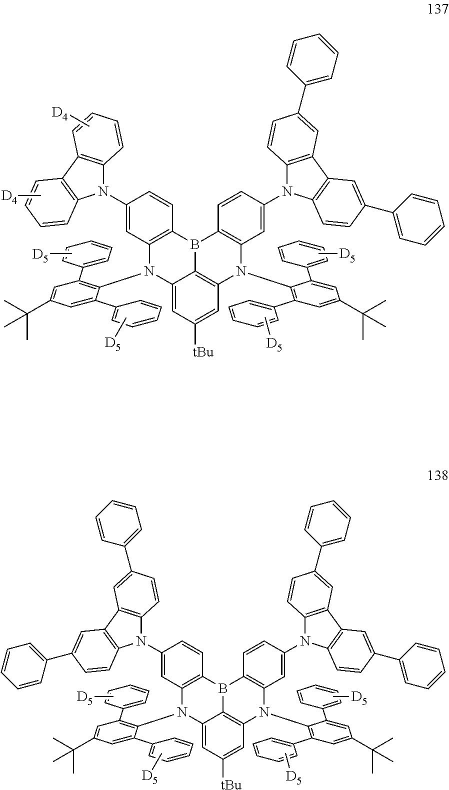

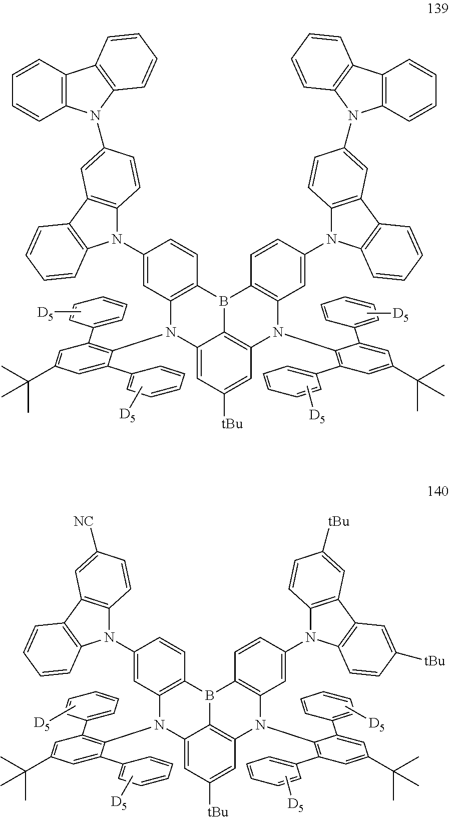

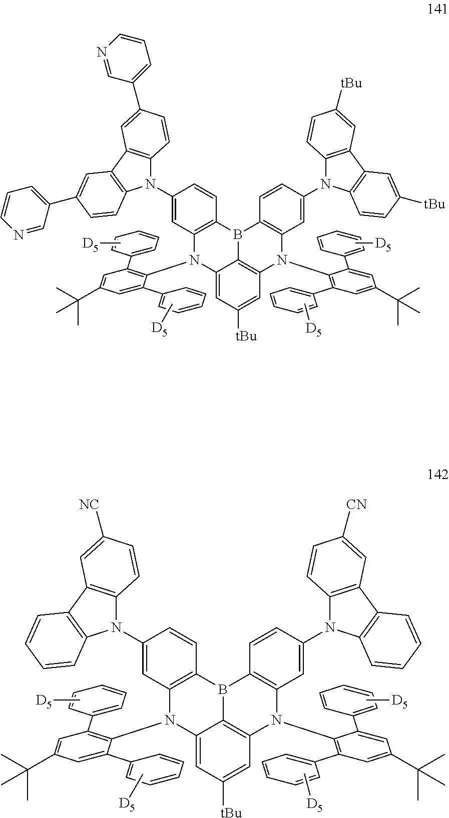

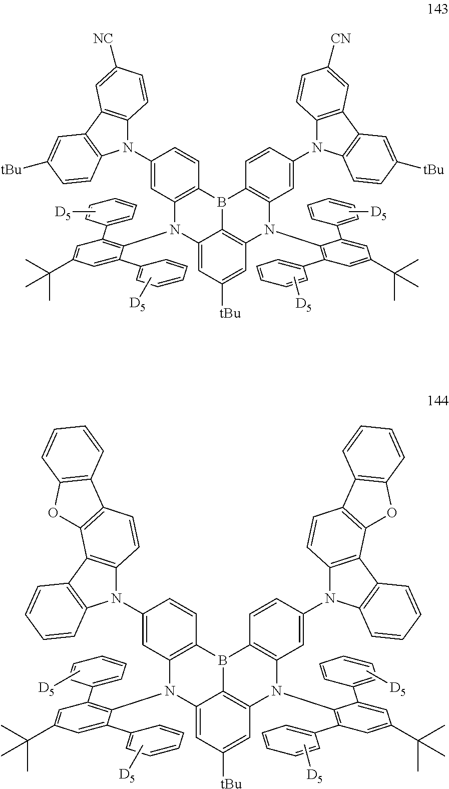

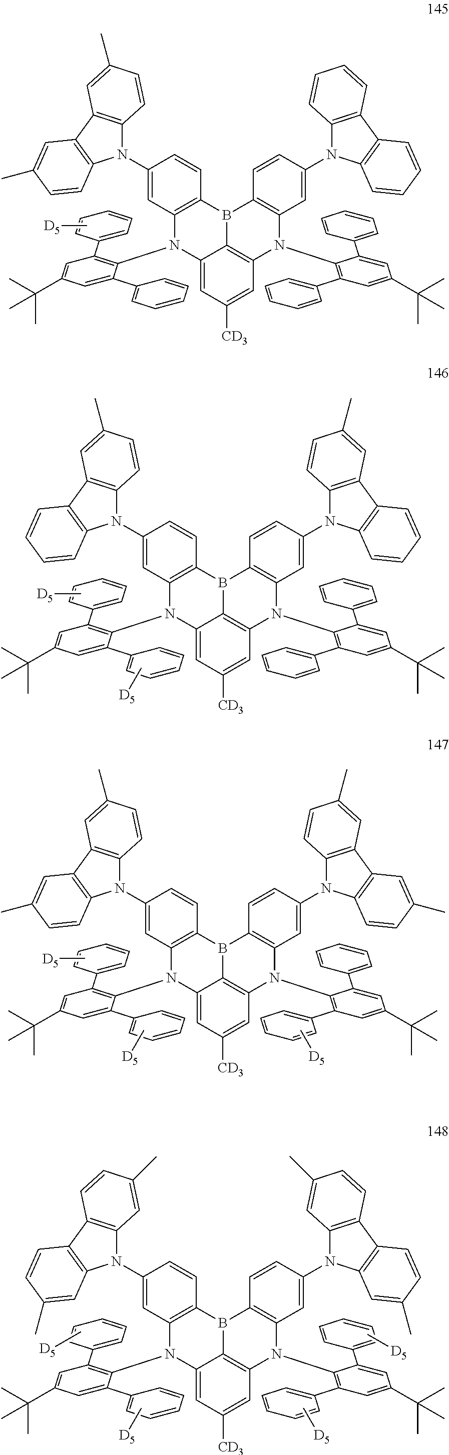

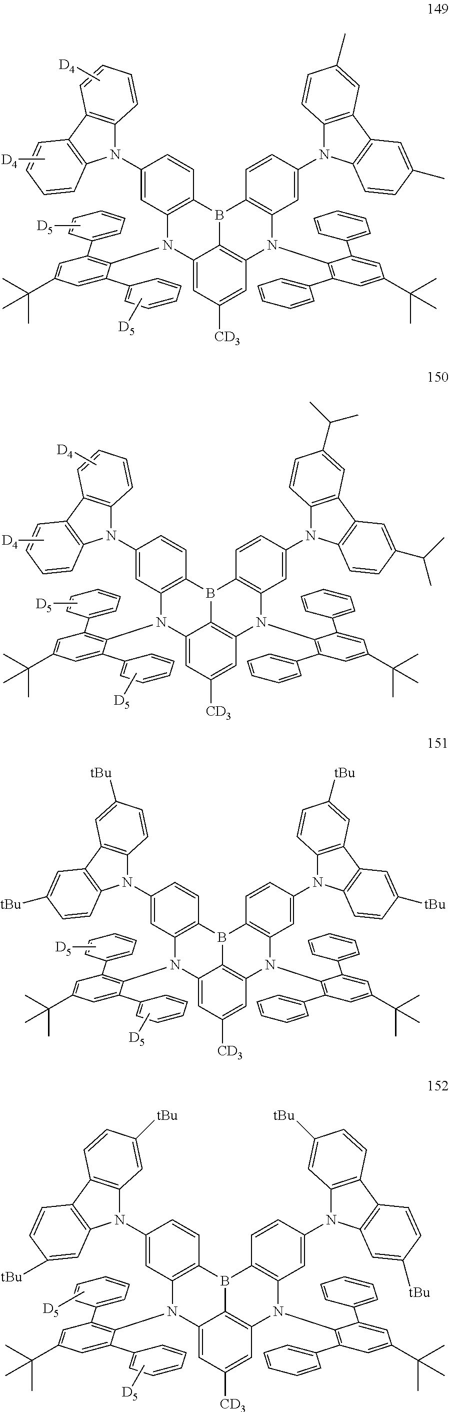

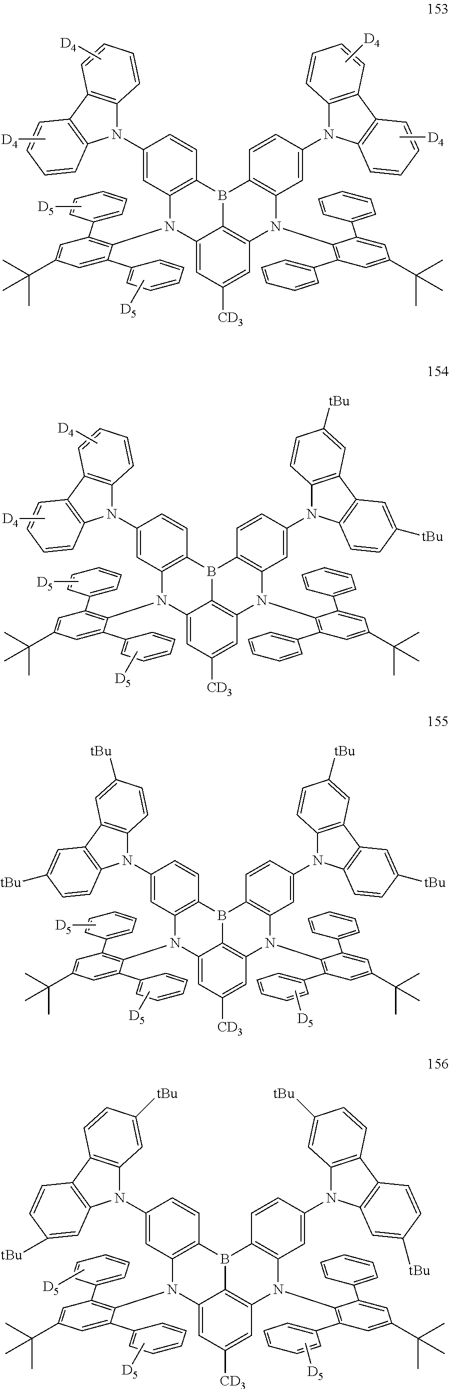

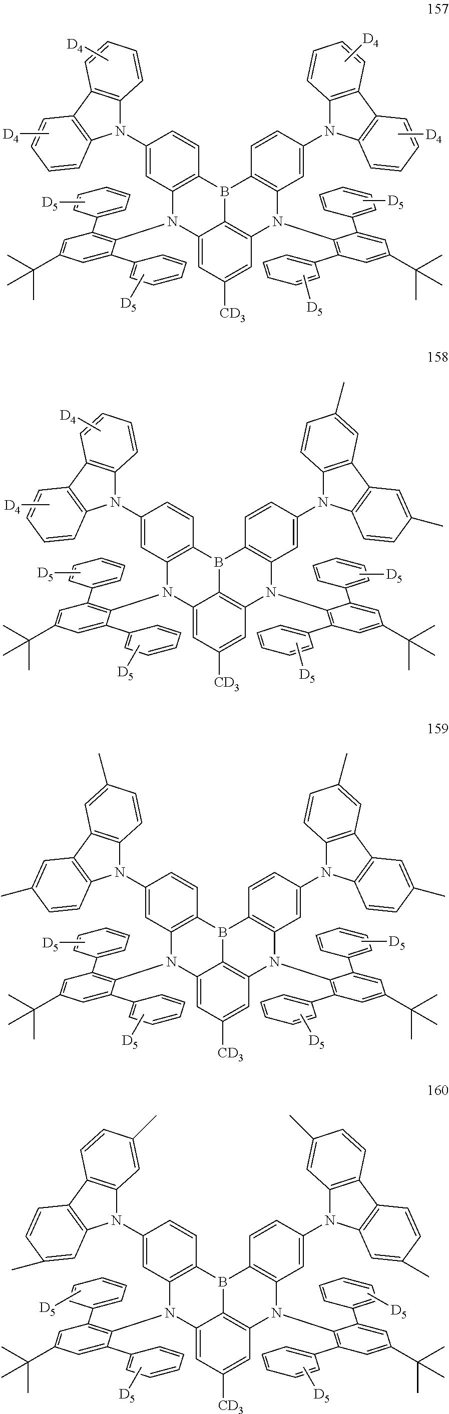

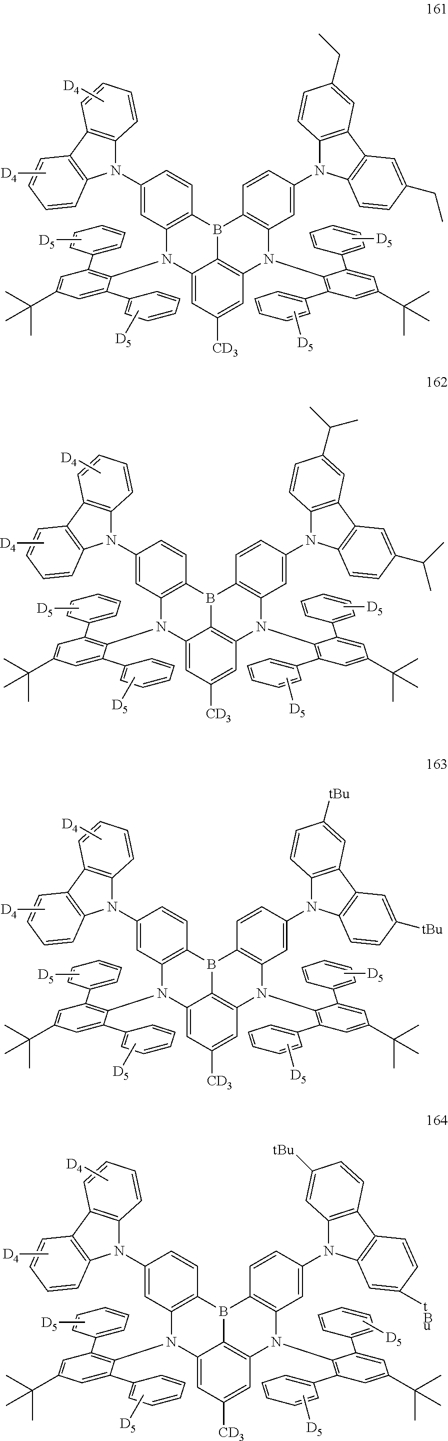

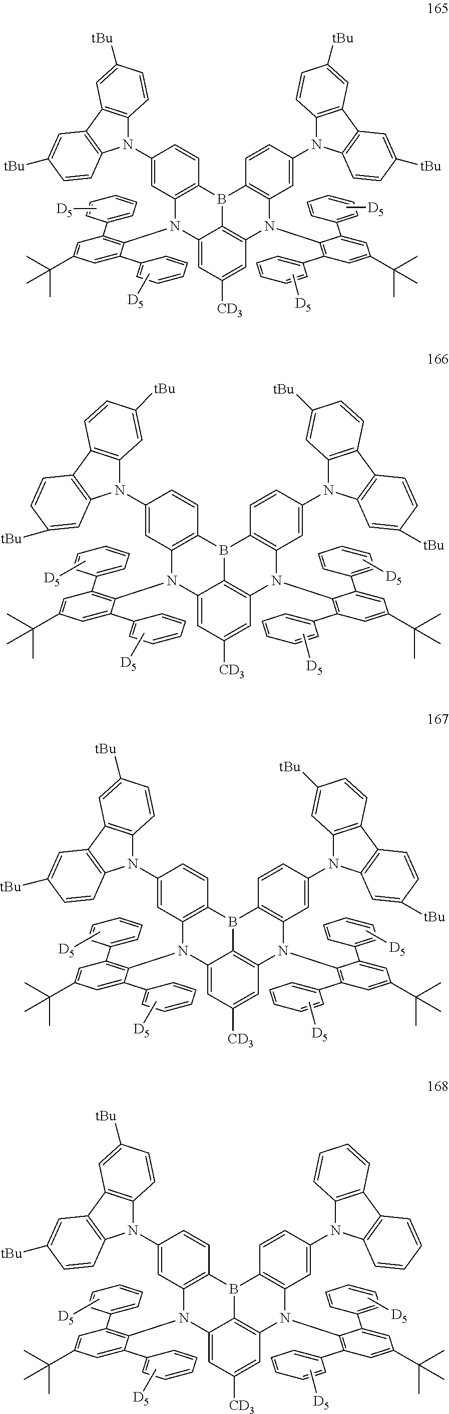

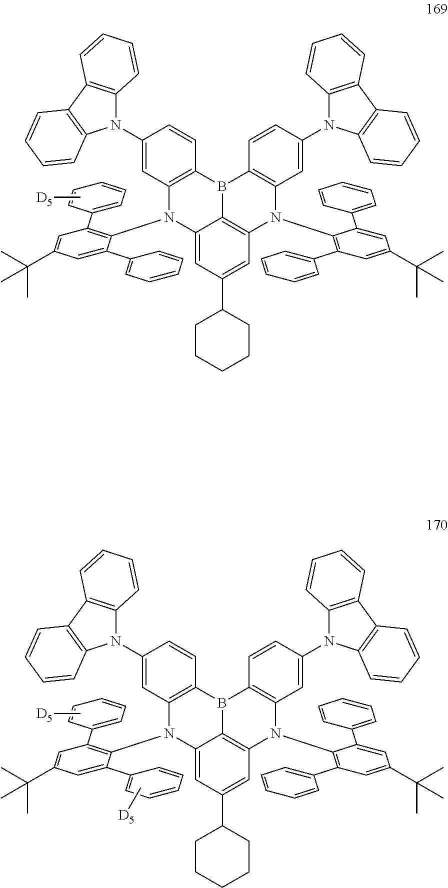

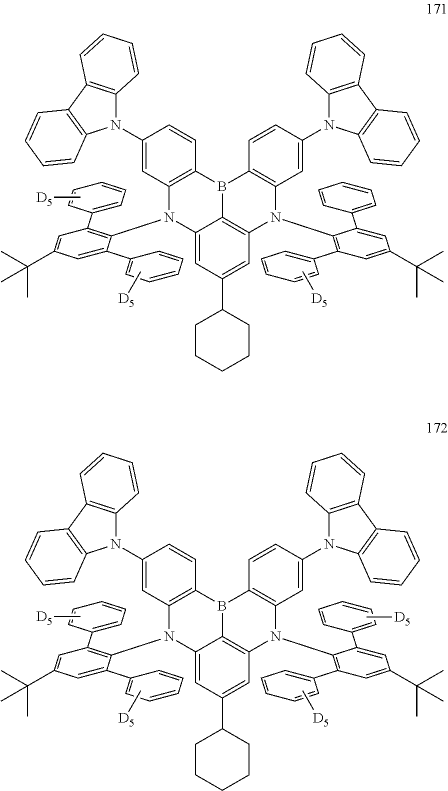

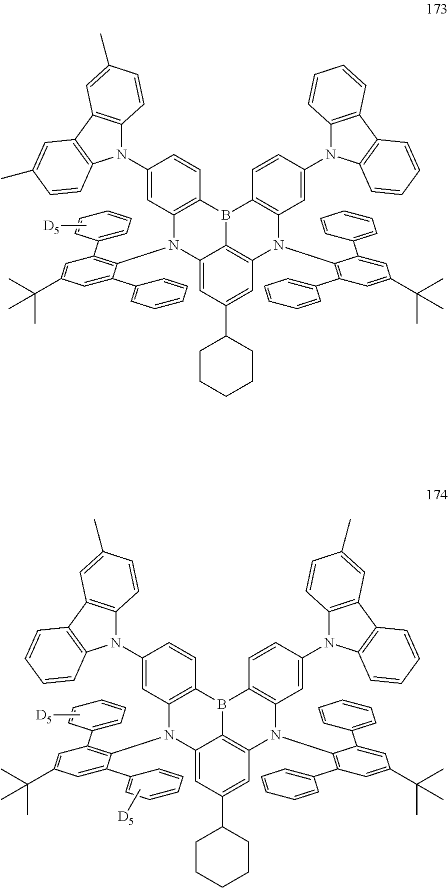

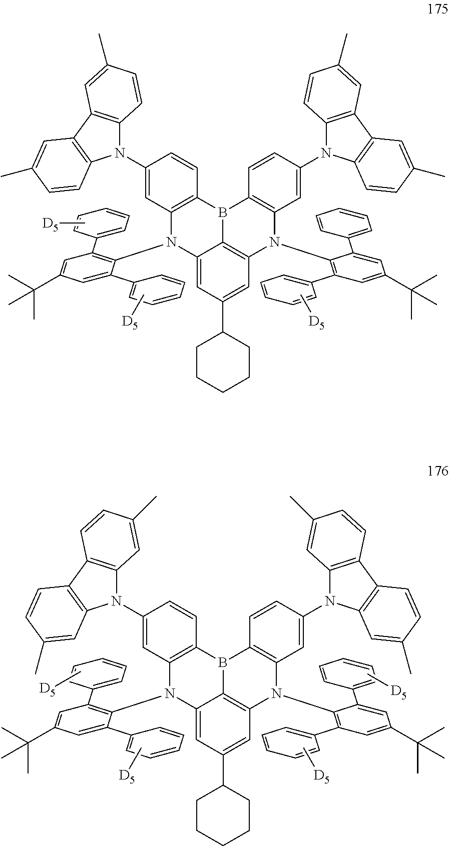

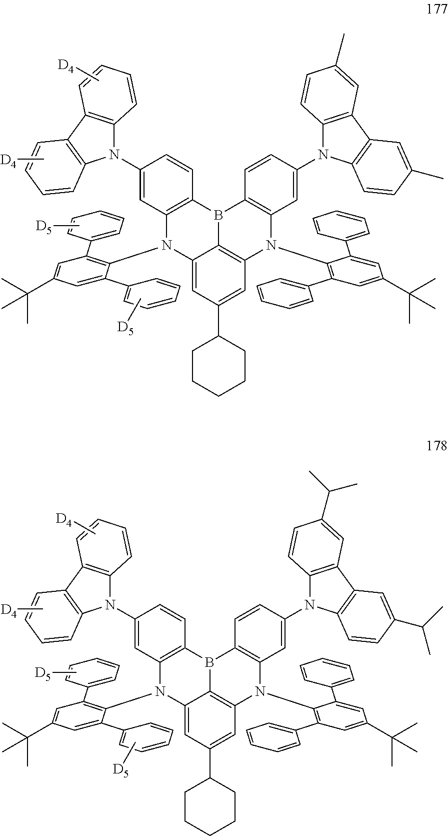

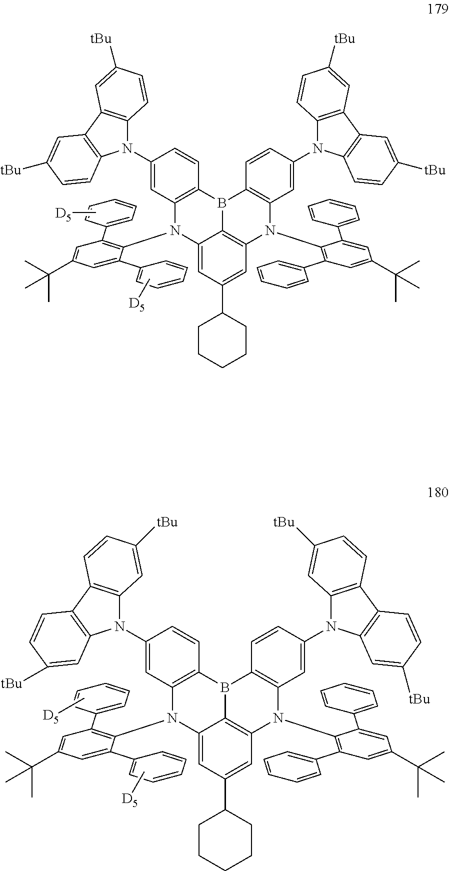

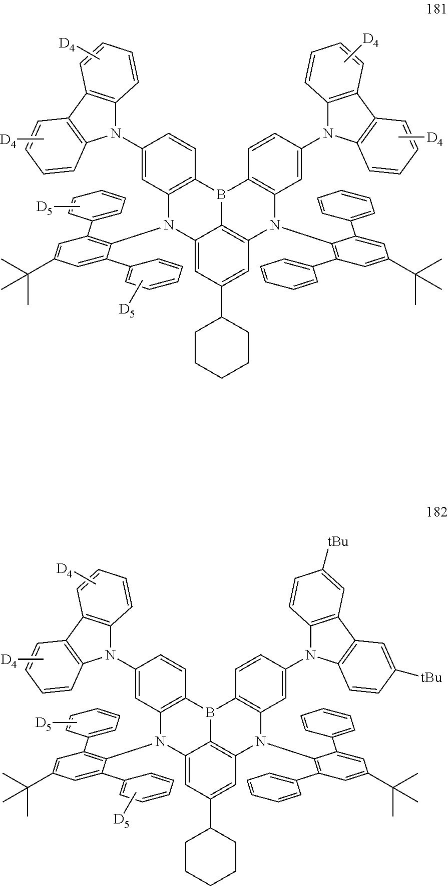

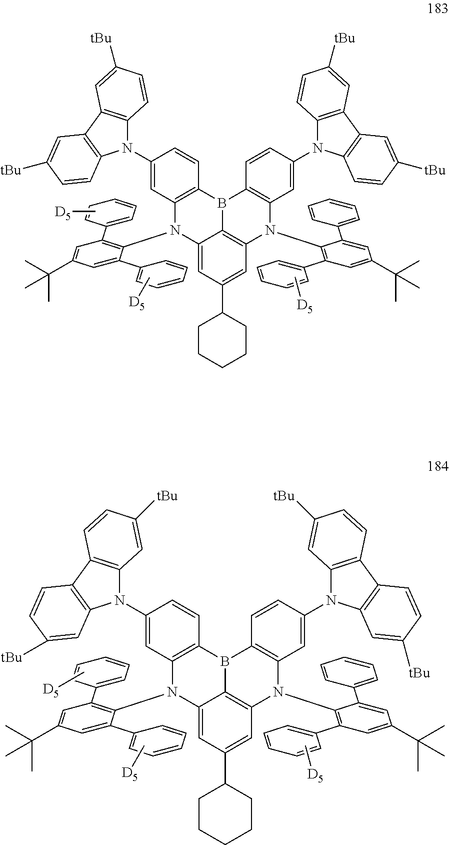

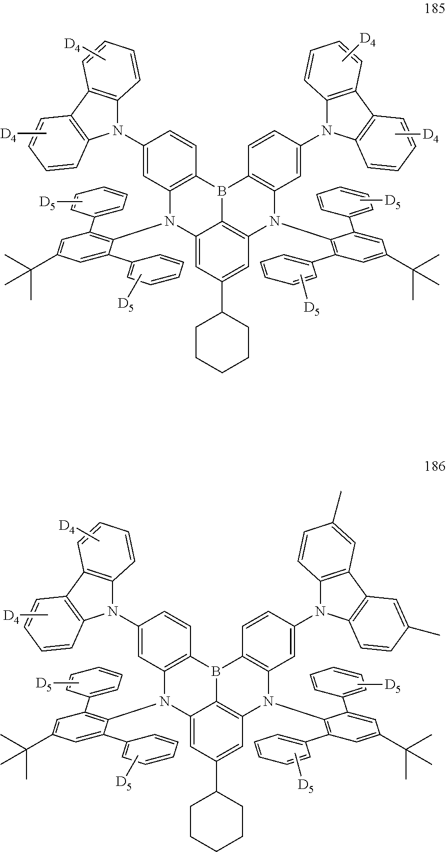

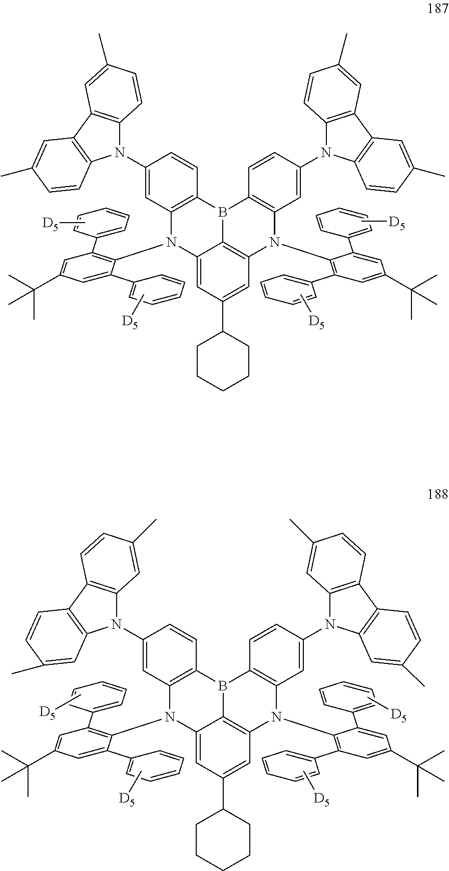

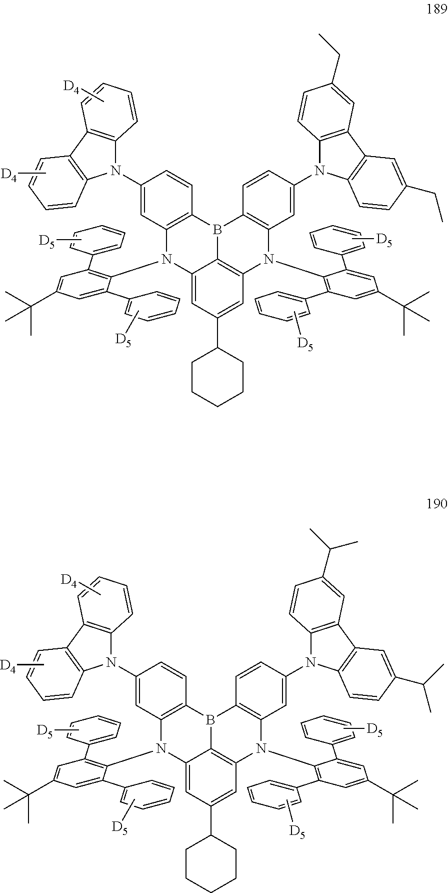

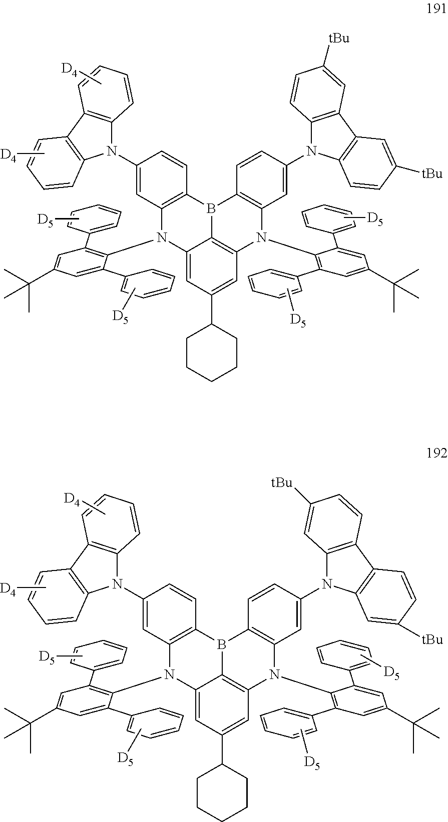

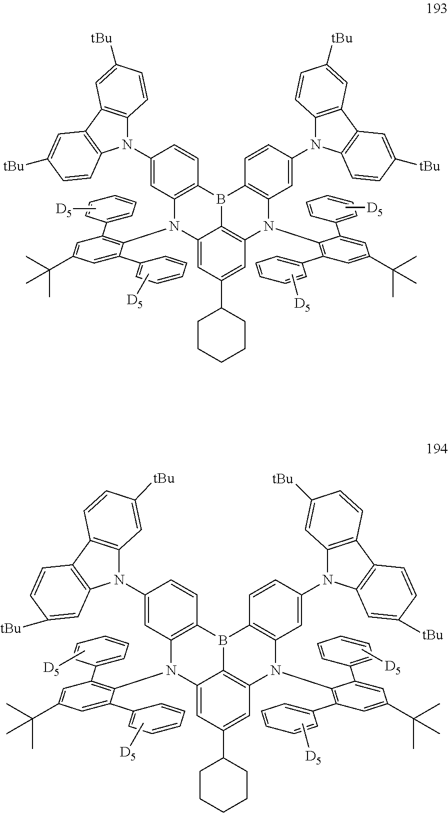

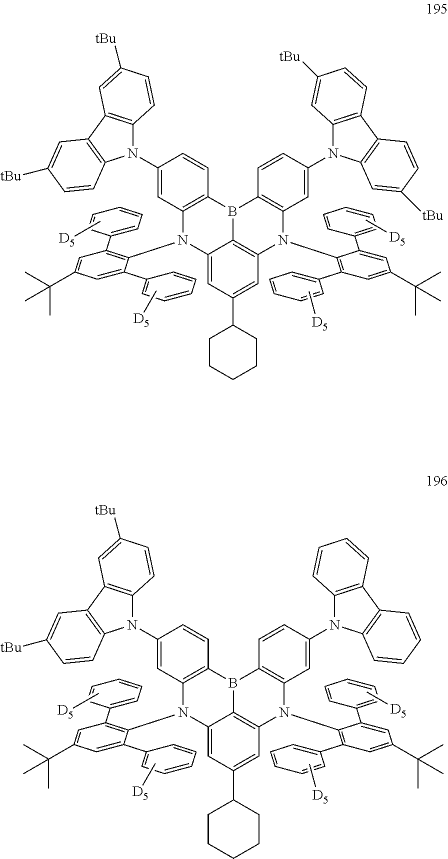

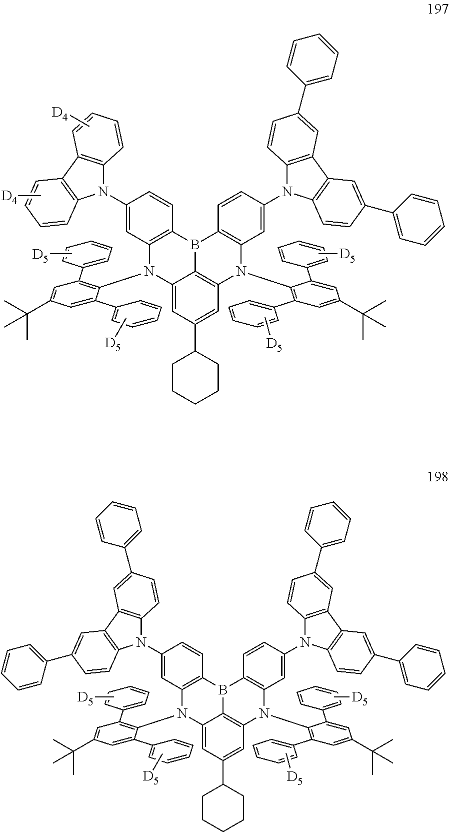

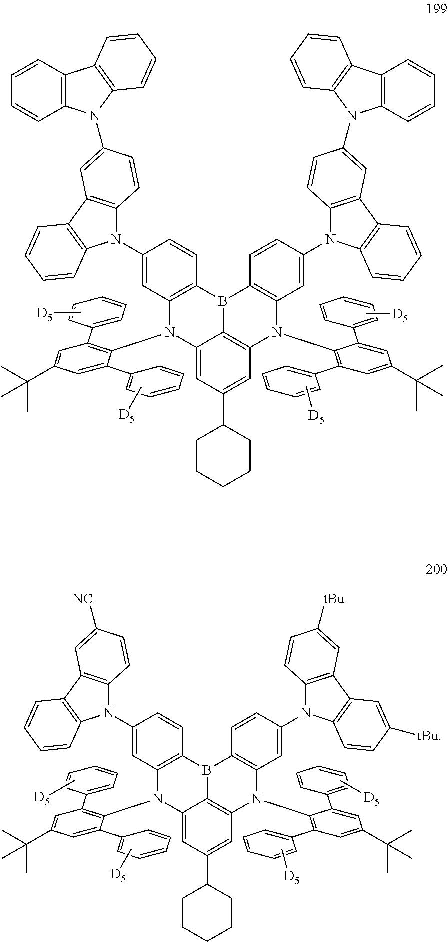

10. The light emitting device of claim 1, wherein the emission layer further comprises a second compound represented by Formula H-1: 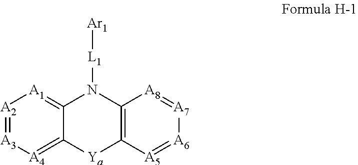
wherein Formula H-1,
A₁ to A₈ are each independently N or CR₅₁,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, CR₅₂R₅₃, or SiR₅₄R₅₅,
Ar₁ is a substituted or unsubstituted aryl group of 6 to 30 ring-forming carbon atoms, or a substituted or unsubstituted heteroaryl group of 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

11. The light emitting device of claim 1, wherein the emission layer further comprises a third compound represented by Formula H-2: 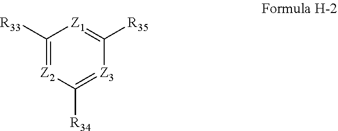
wherein Formula H-2,
Z₁ to Z₃ are each independently N or CR₃₆,
at least one selected from among Z₁ to Z₃ is N, and
R₃₃ to R₃₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring.

12. The light emitting device of claim 1, wherein the emission layer further comprises a fourth compound represented by Formula D-1: 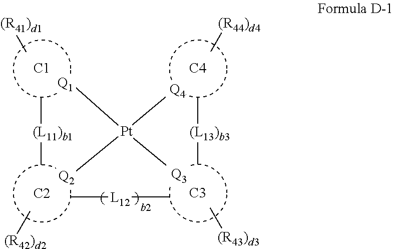
wherein Formula D-1,
Q₁ to Q₄ are each independently C or N,
C1 to C4 are each independently a substituted or unsubstituted hydrocarbon ring of 5 to 30 ring-forming carbon atoms, or a substituted or unsubstituted heterocycle of 2 to 30 ring-forming carbon atoms,
L₁₁ to L₁₃ are each independently a direct linkage, 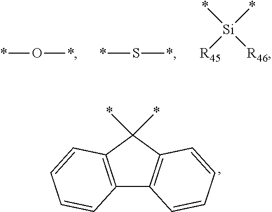
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b1 to b3 are each independently 0 or 1,
R₄₁ to R₄₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, and
d1 to d4 are each independently an integer from 0 to 4.

13. A fused polycyclic compound represented by Formula 1: 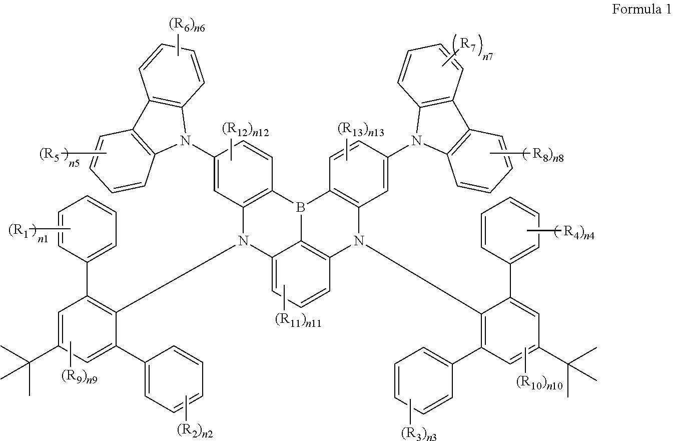
wherein Formula 1,
R₁ to R₁₃ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring,
n1 to n4 are each independently an integer from 0 to 5,
n5 to n8 are each independently an integer from 0 to 4,
n9 and n10 are each independently an integer from 0 to 2, and
n11 to n13 are each independently an integer from 0 to 3.

14. The fused polycyclic compound of claim 13, wherein
R₁ to R₄ are deuterium atoms, and
a sum of n1 to n4 is 1 to 20.

15. The fused polycyclic compound of claim 13, wherein the fused polycyclic compound represented by Formula 1 is represented by any one selected from among Formula 2-1 to Formula 2-4: 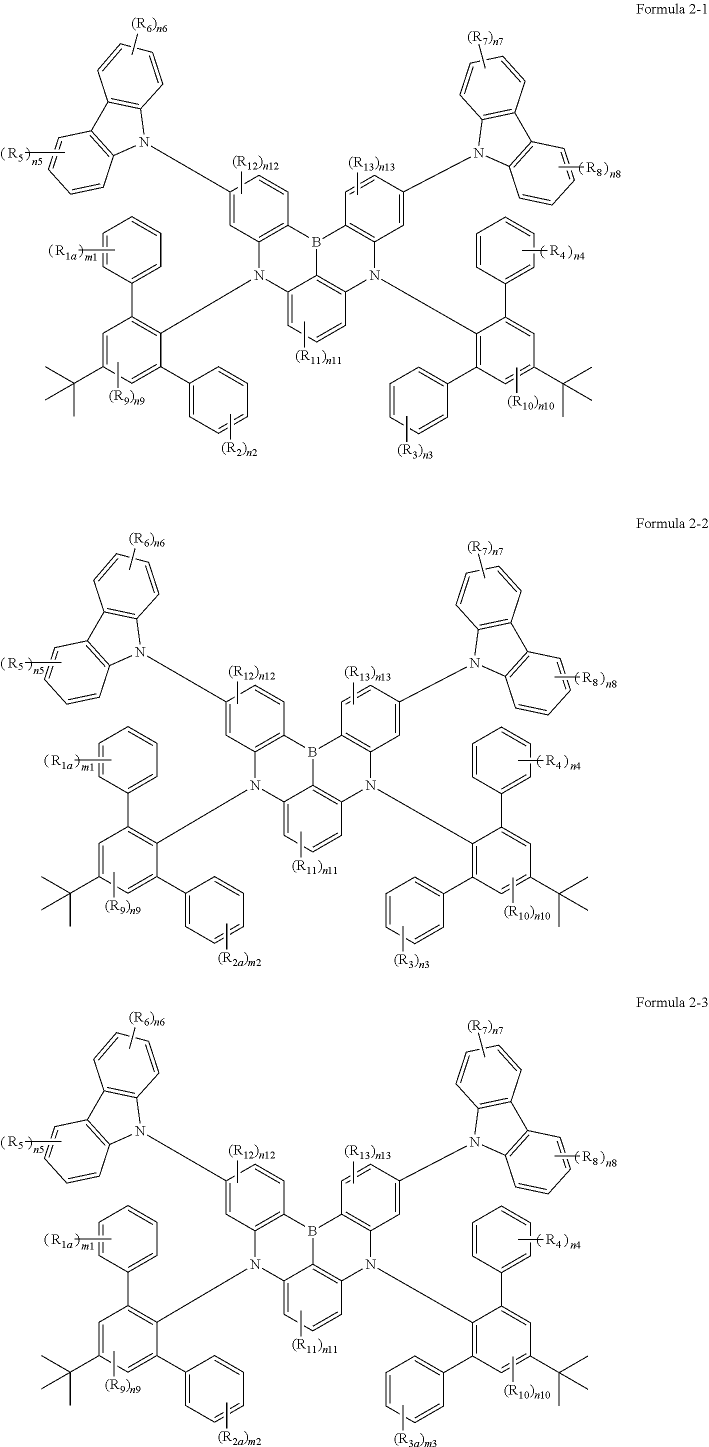 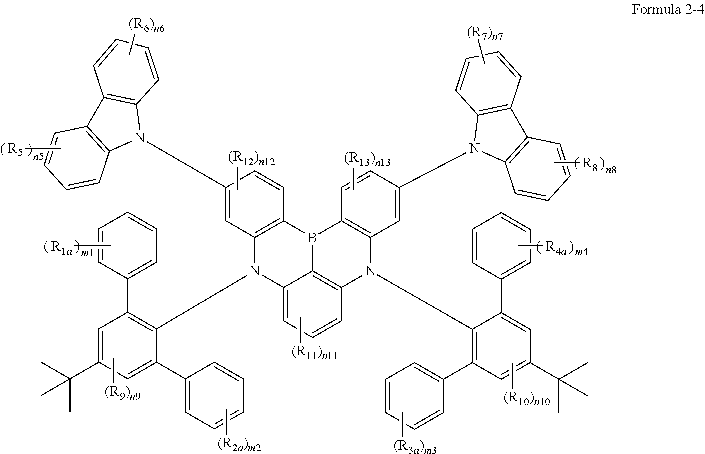
wherein Formula 2-1 to Formula 2-4,
R₁ₐ to R₄ₐ are deuterium atoms,
m1 to m4 are each independently an integer from 1 to 5, and
R₂ to R₁₃, and n2 to n13 are the same as defined in Formula 1.

16. The fused polycyclic compound of claim 15, wherein the fused polycyclic compound represented by Formula 1 is represented by any one selected from among Formula 3-1 to Formula 3-3: 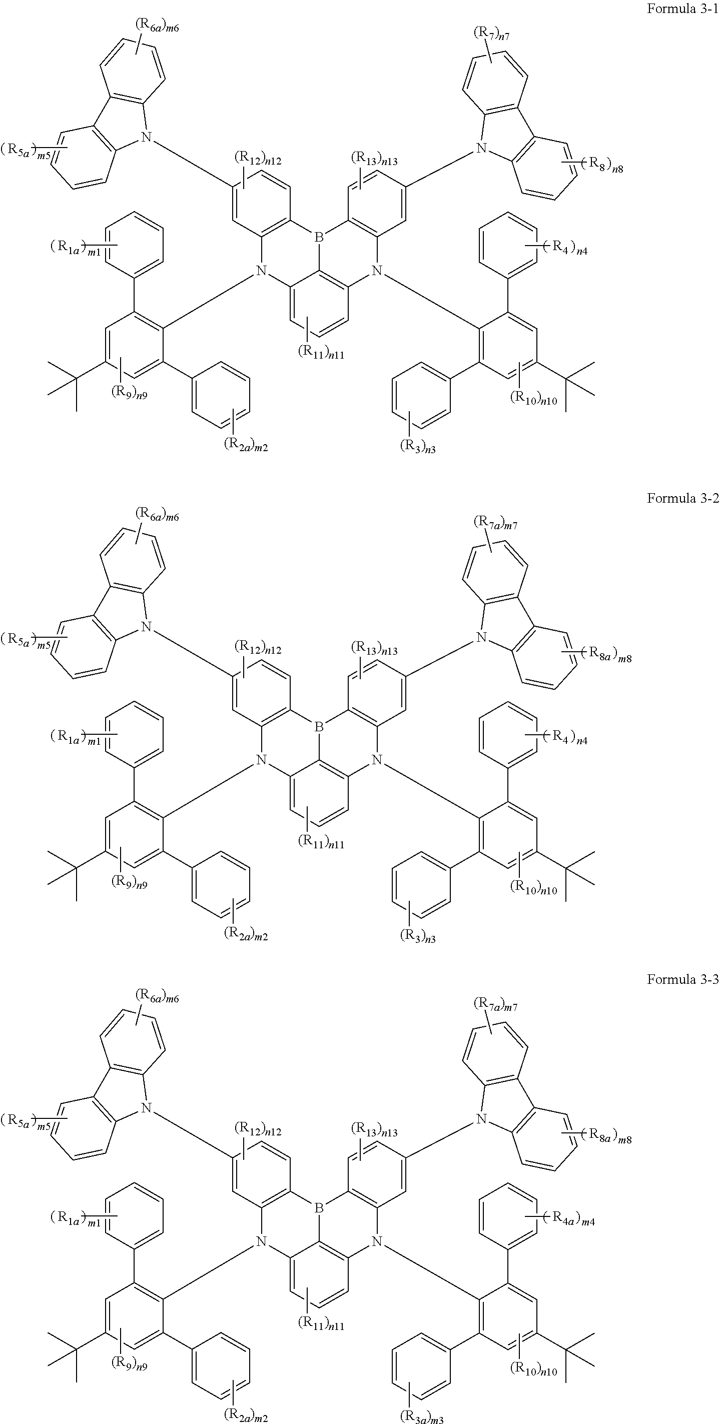
wherein Formula 3-1 to Formula 3-3,
R₅ₐ to R₈ₐ are deuterium atoms,
m5 to m8 are each independently an integer from 1 to 4, and
R₁ₐ to R₄ₐ, R₃, R₄, R₇ to R₁₃, m1 to m4, n3, n4, and n7 to n13 are the same as defined in Formula 1, and Formula 2-1 to Formula 2-4.

17. The fused polycyclic compound of claim 13, wherein the fused polycyclic compound represented by Formula 1 is represented by any one selected from among Formula 4-1 to Formula 4-8: 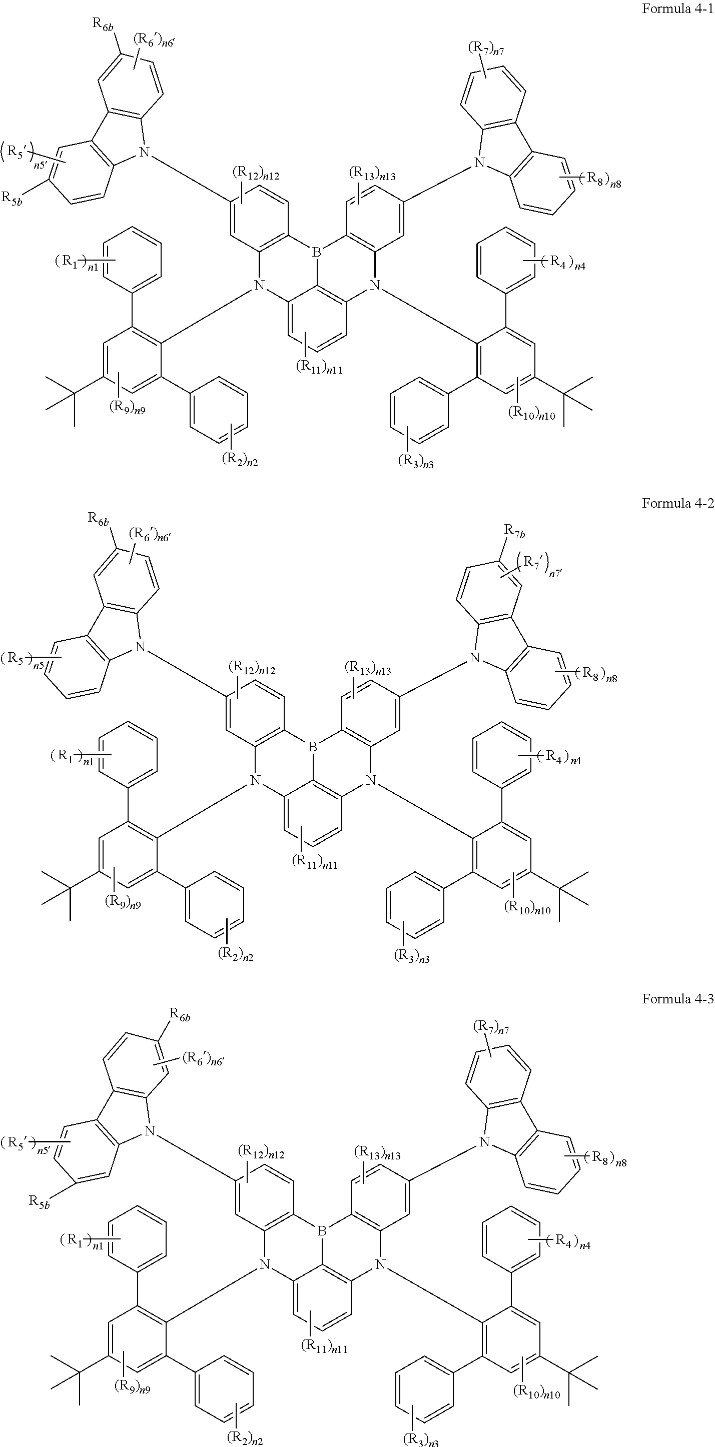 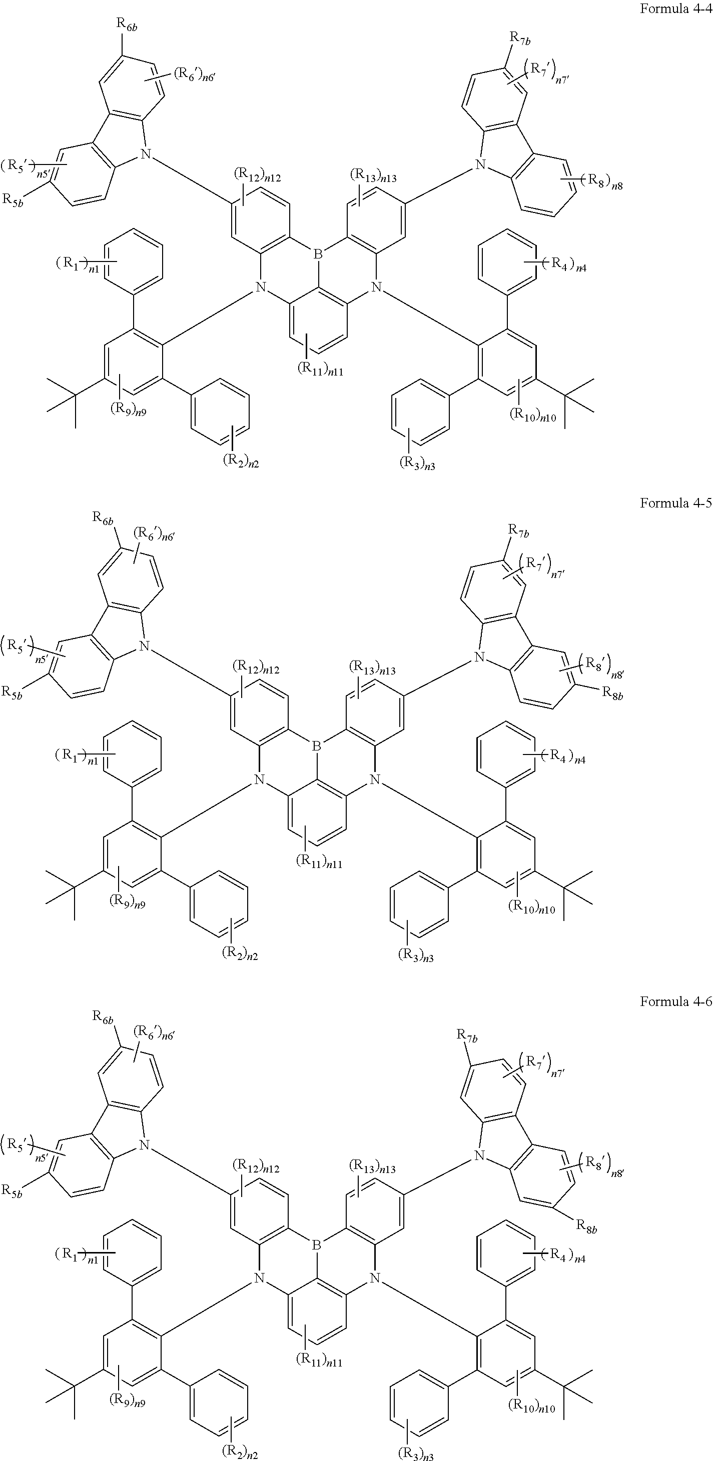 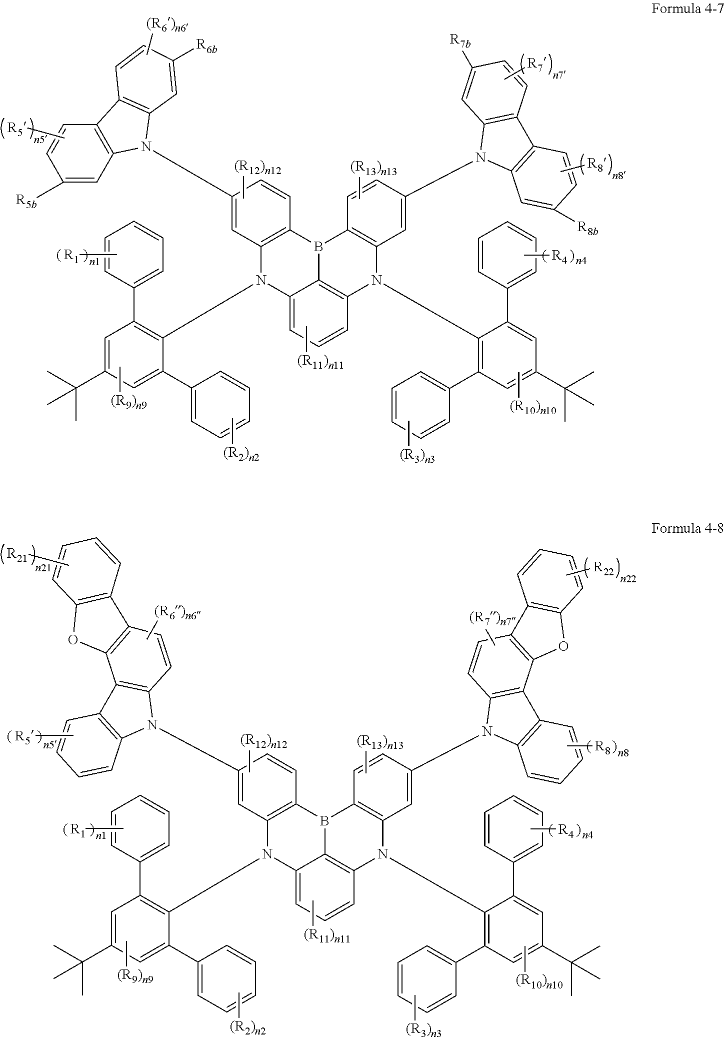
wherein Formula 4-1 to Formula 4-8
R_{5b} to R_{8b} are each independently a deuterium atom, a cyano group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
R₅′ to R₈′, R₆″, R₇″, R₂₁, and R₂₂ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms,
n5′ to n8′ are each independently an integer from 0 to 3,
n6″ and n7″ are each independently an integer from 0 to 2,
n21 and n22 are each independently an integer from 0 to 4, and
R₁ to R₅, R₇ to R₁₃, n1 to n5, and n7 to n13 are the same as defined in Formula 1.

18. The fused polycyclic compound of claim 13, wherein the fused polycyclic compound represented by Formula 1 is represented by any one selected from among Formula 5-1 to Formula 5-3: 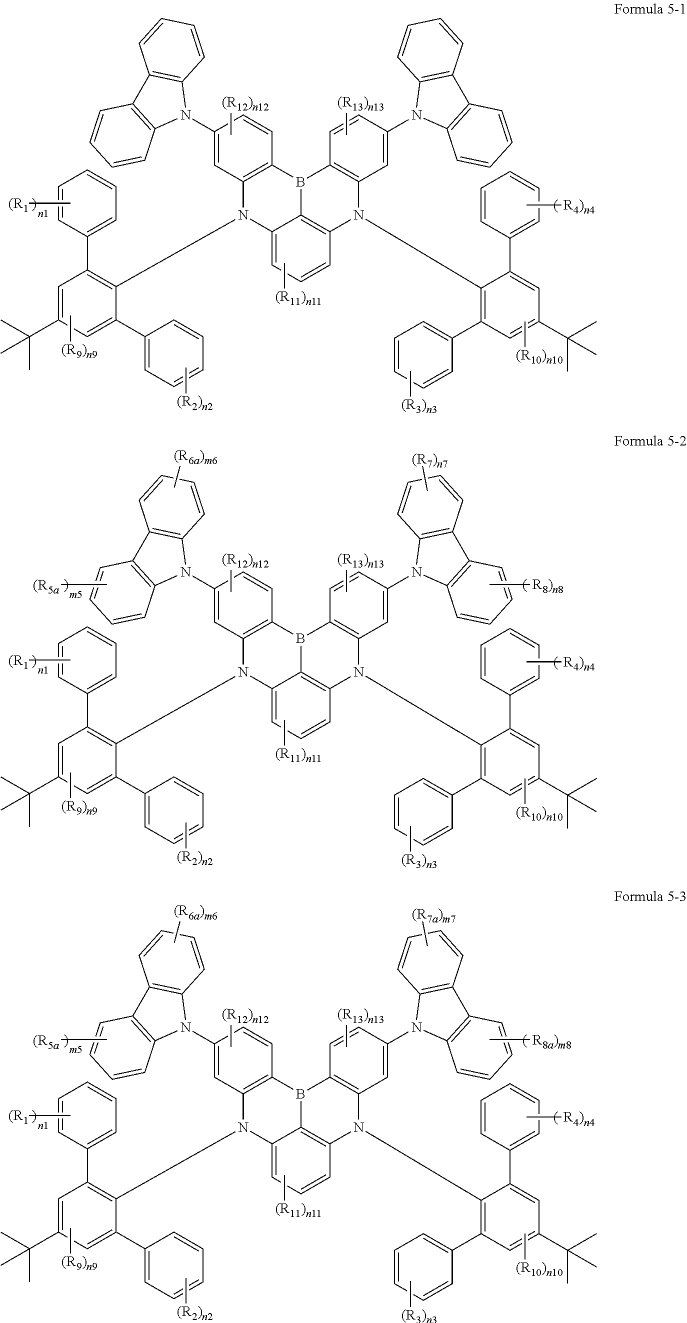
wherein Formula 5-1 to Formula 5-3,
R₅ₐ to R₈ₐ are deuterium atoms
m5 to m8 are each independently an integer from 1 to 4, and
R₁ to R₄, R₇ to R₁₃, n1 to n4, and n7 to n13 are the same as defined in Formula 1.

19. The fused polycyclic compound of claim 13, wherein the fused polycyclic compound represented by Formula 1 is represented by Formula 6: 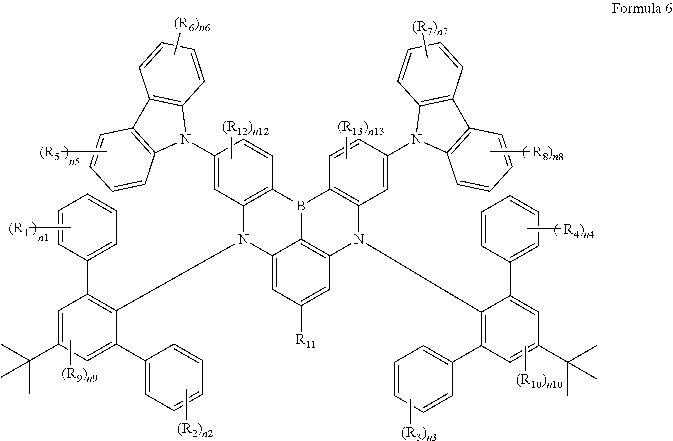
wherein Formula 6,
R₁ to R₁₃, n1 to n10, n12, and n13 are the same as defined in Formula 1.

20. The fused polycyclic compound of claim 13, wherein the fused polycyclic compound represented by Formula 1 comprises at least one selected from among compounds in Compound Group 1: 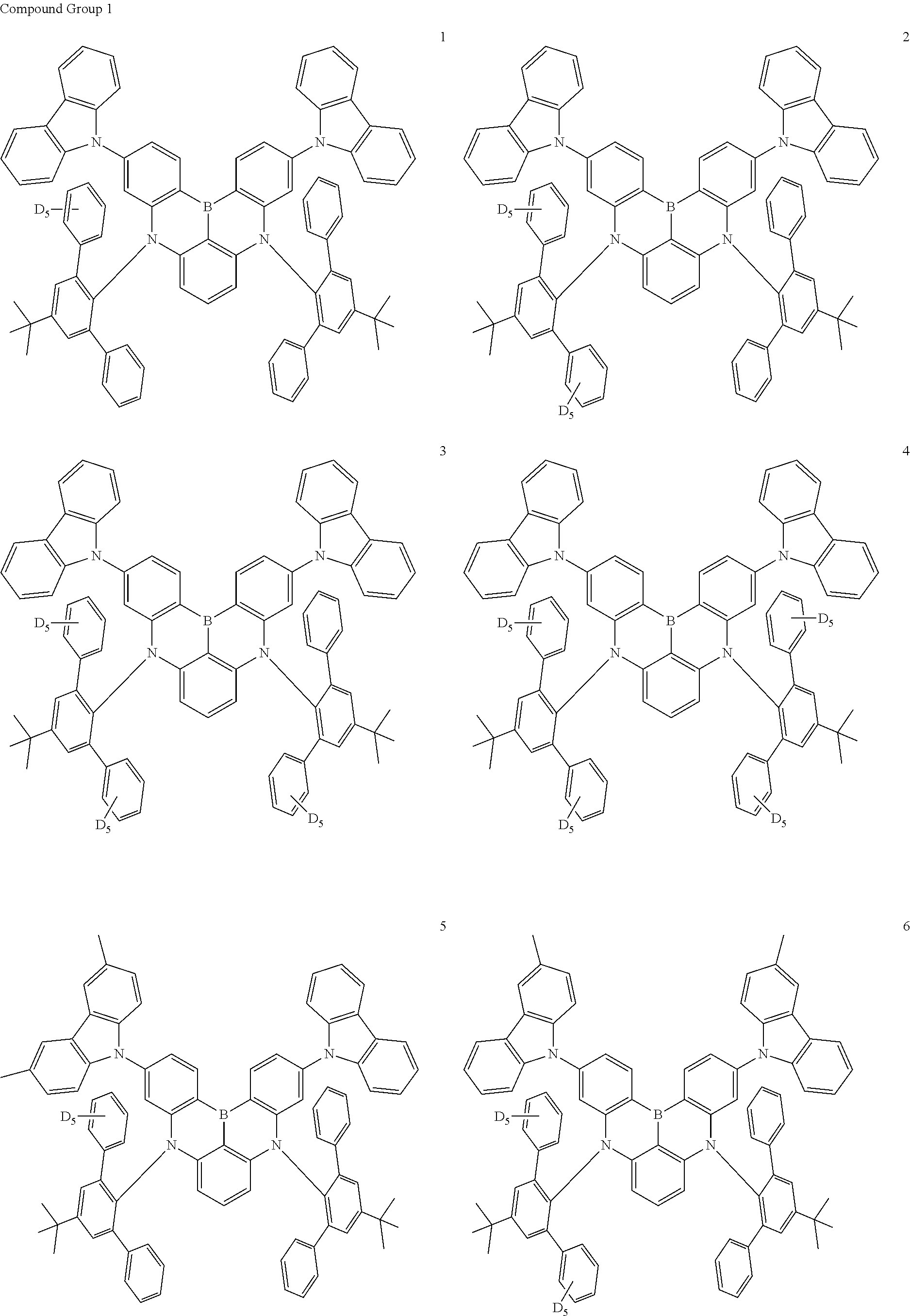 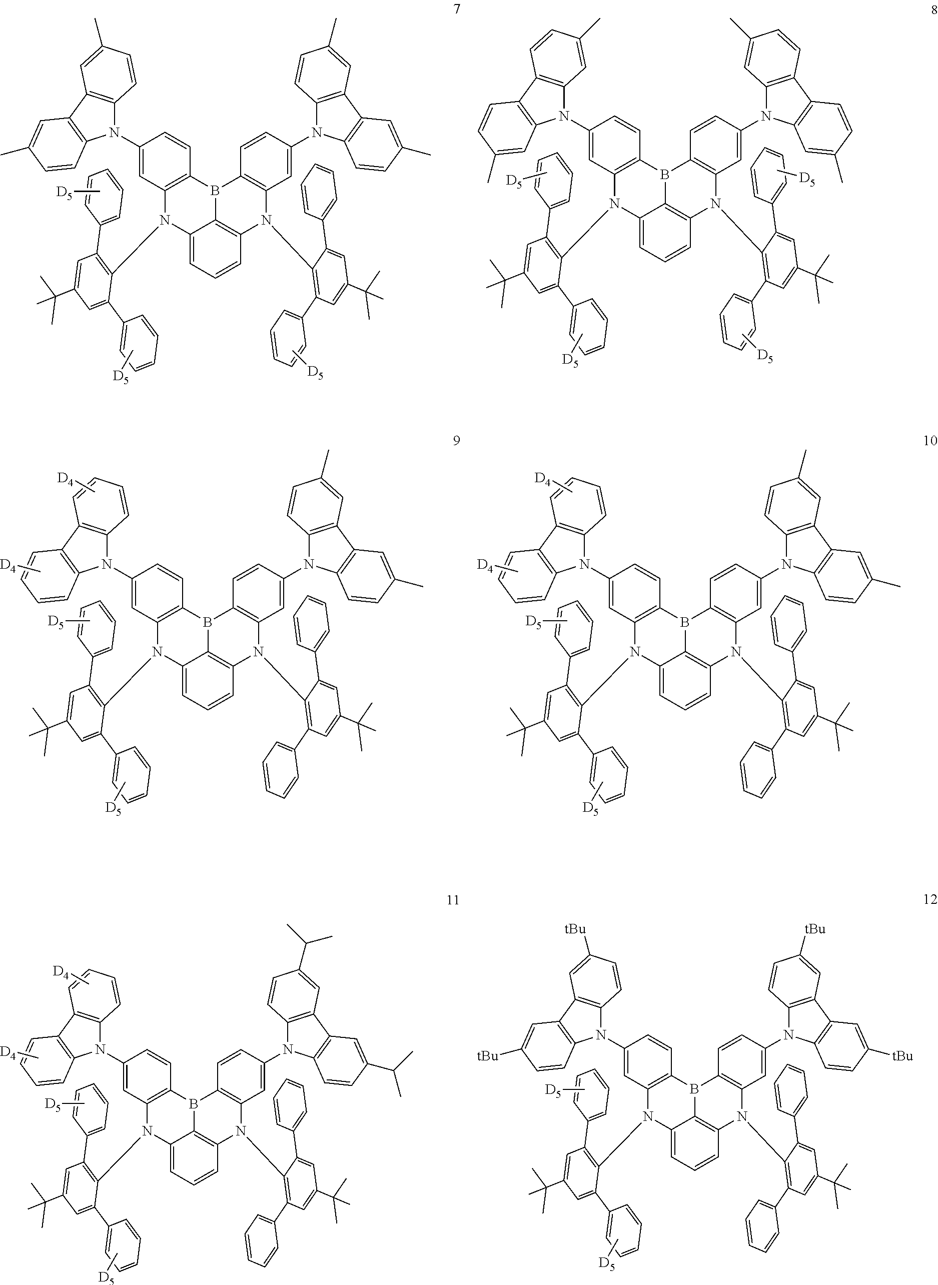 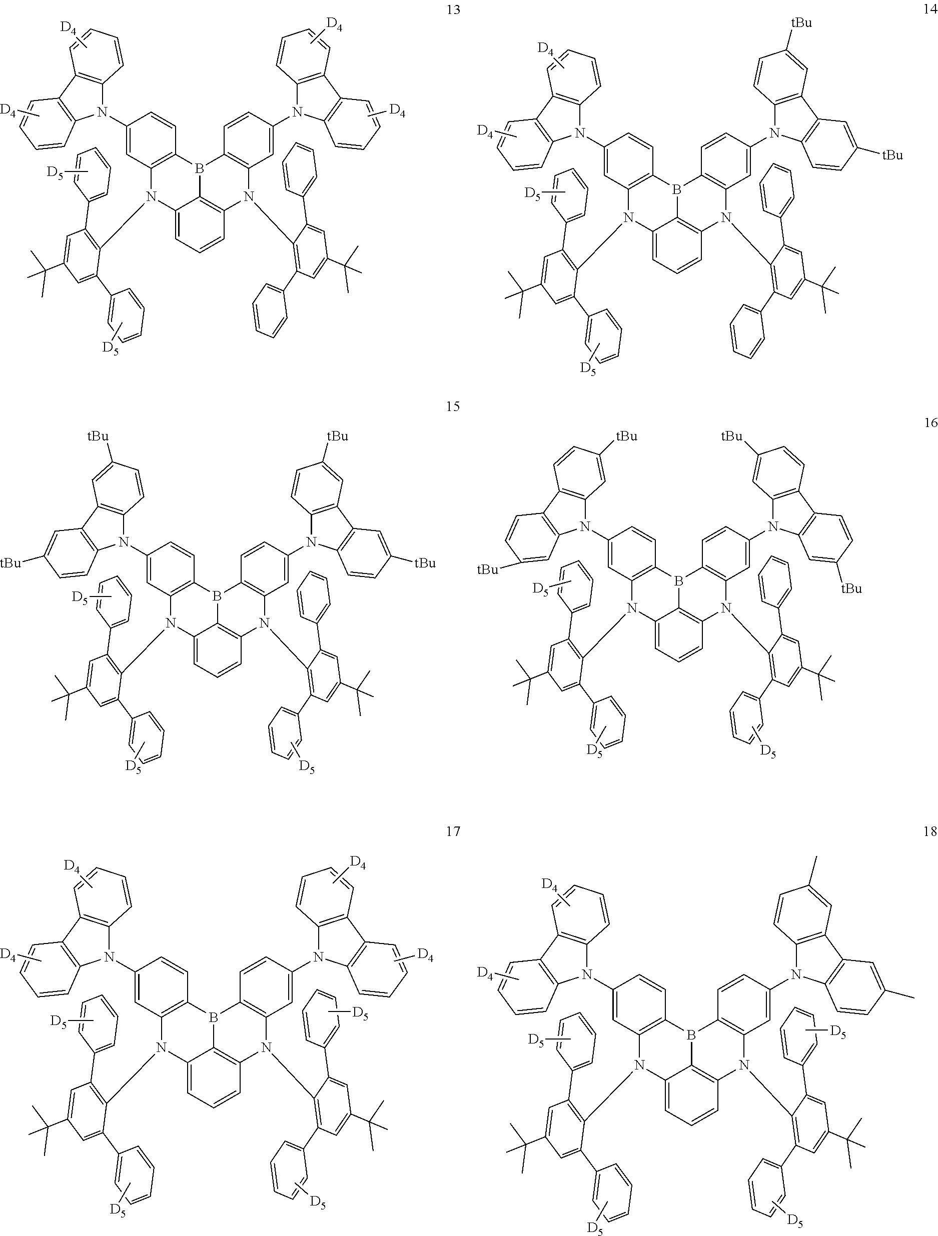 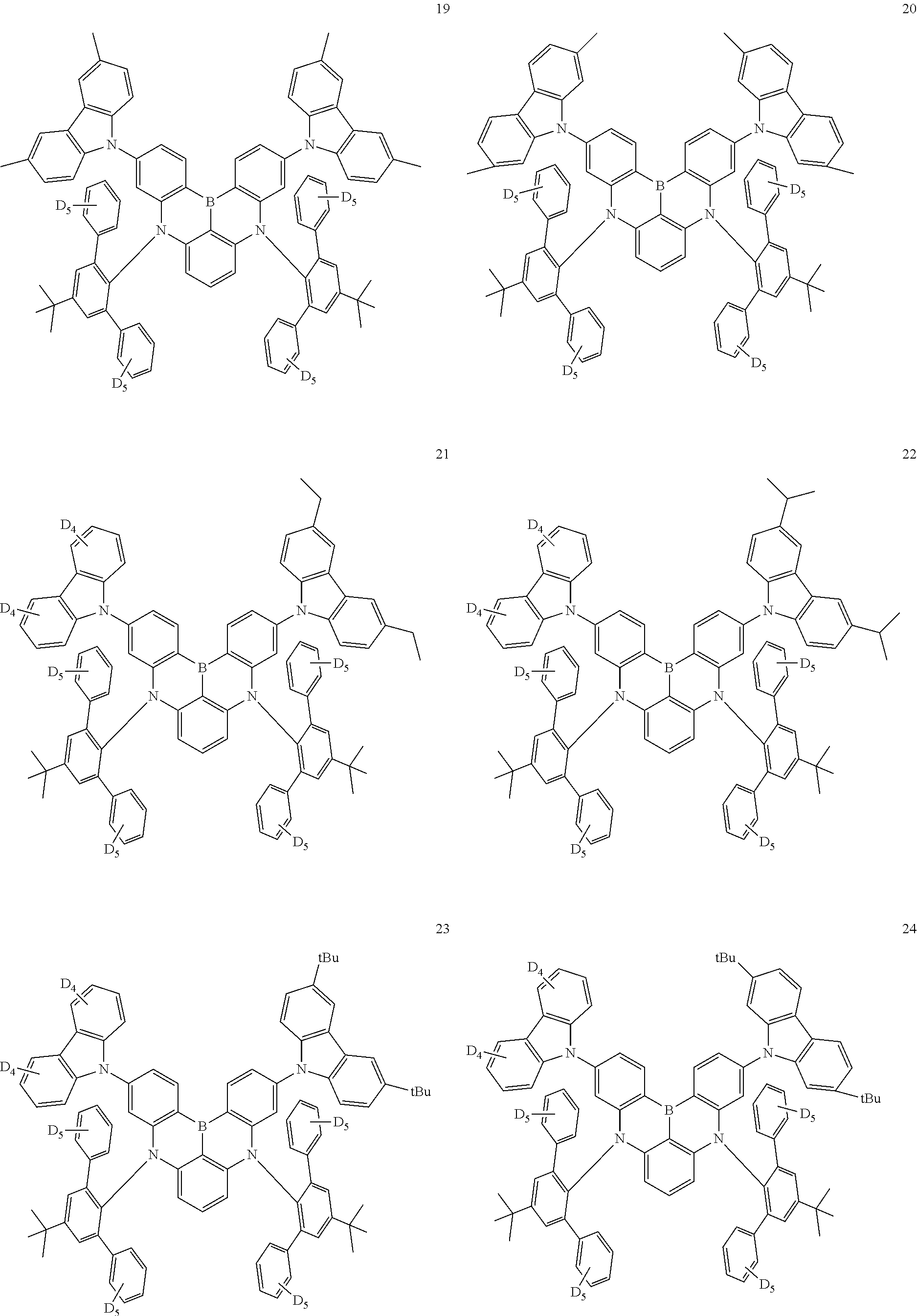 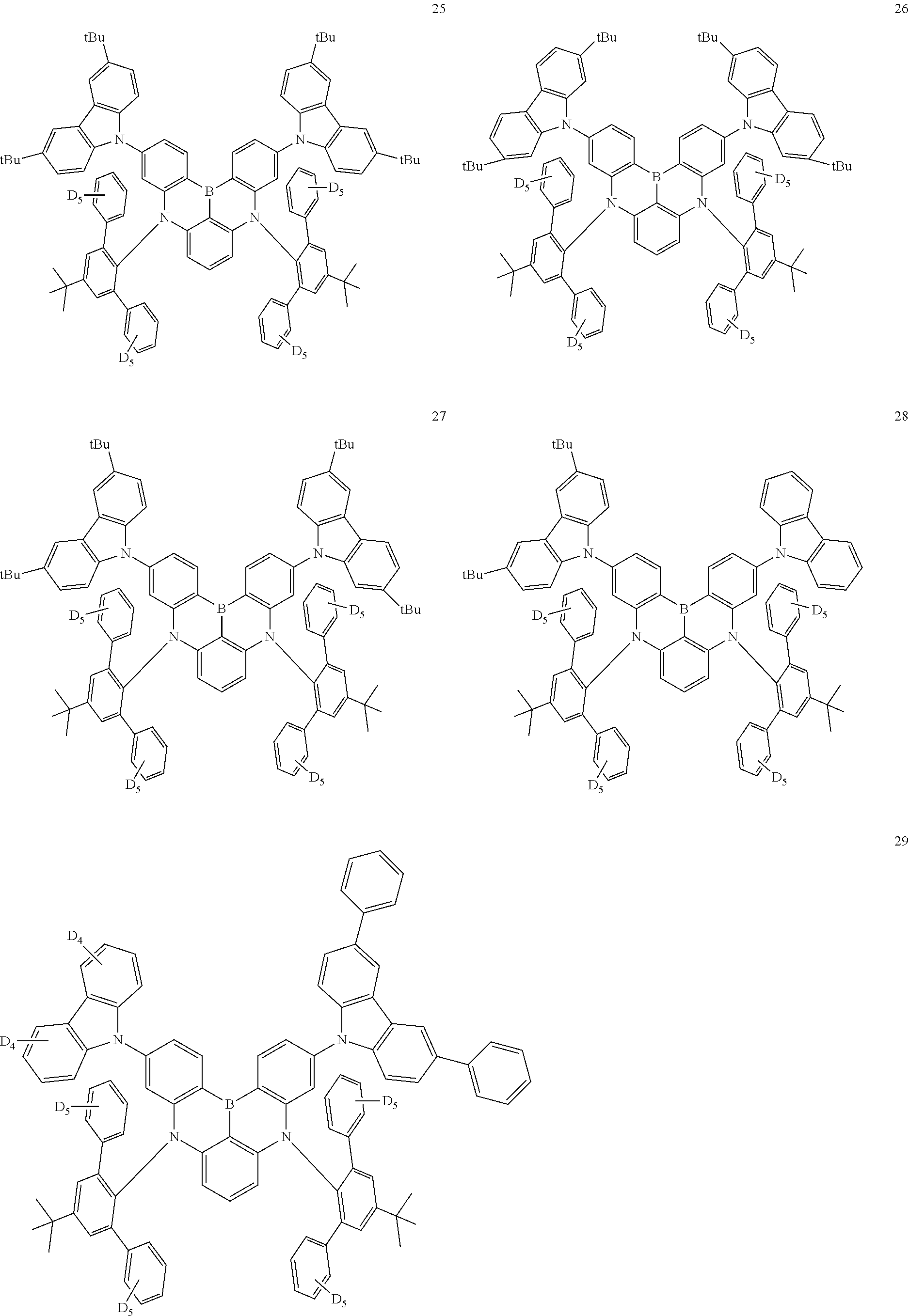 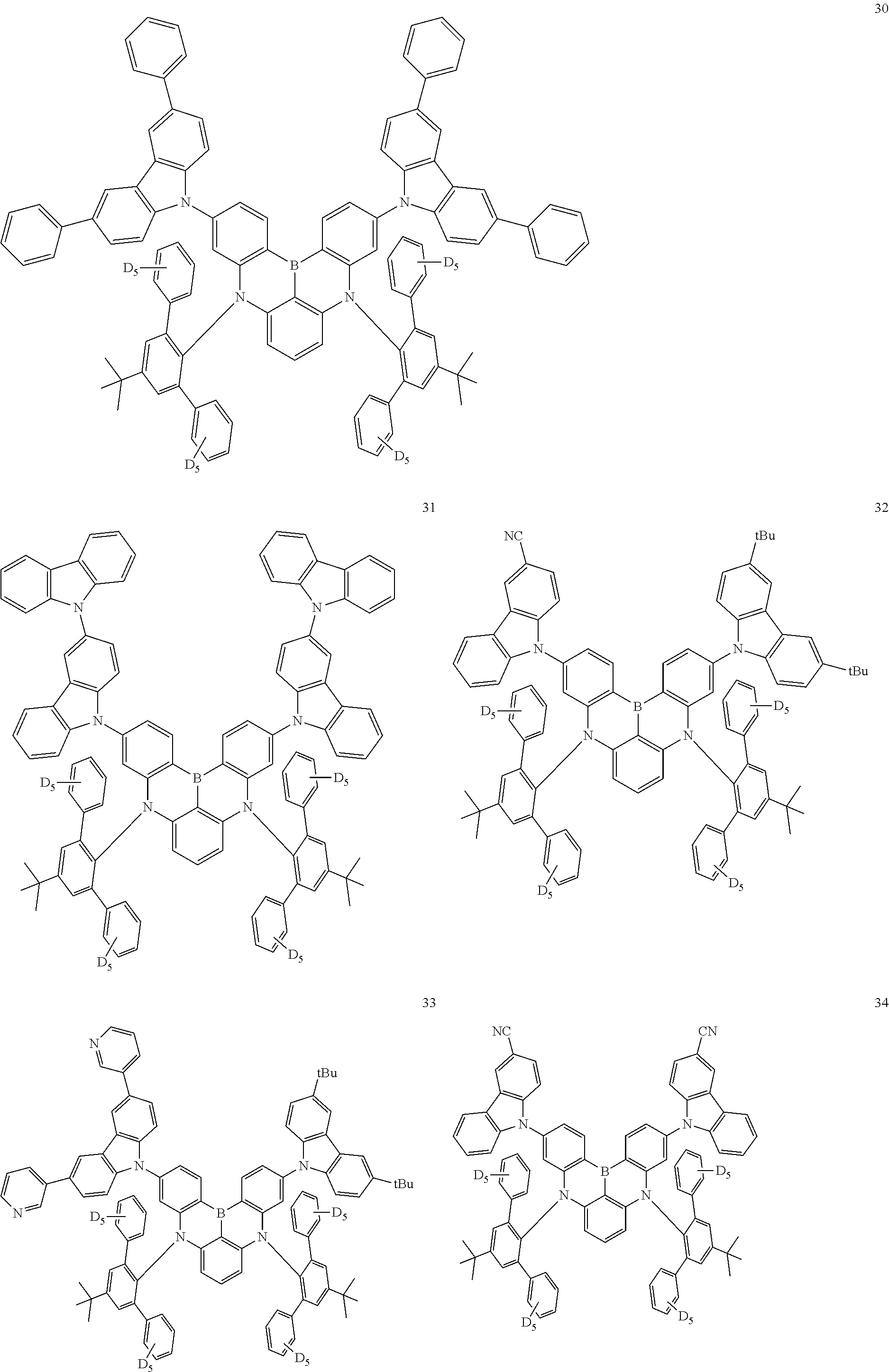 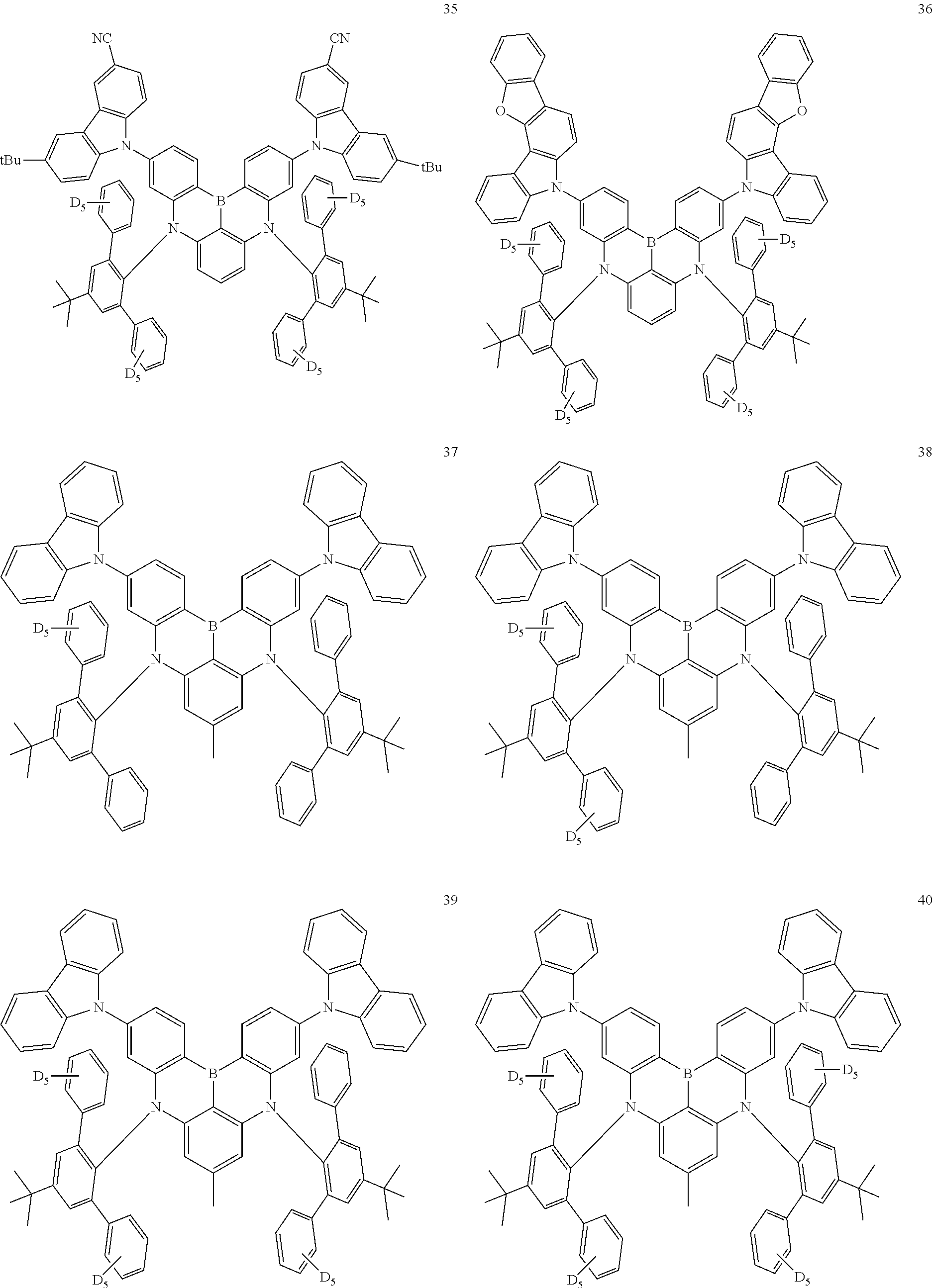 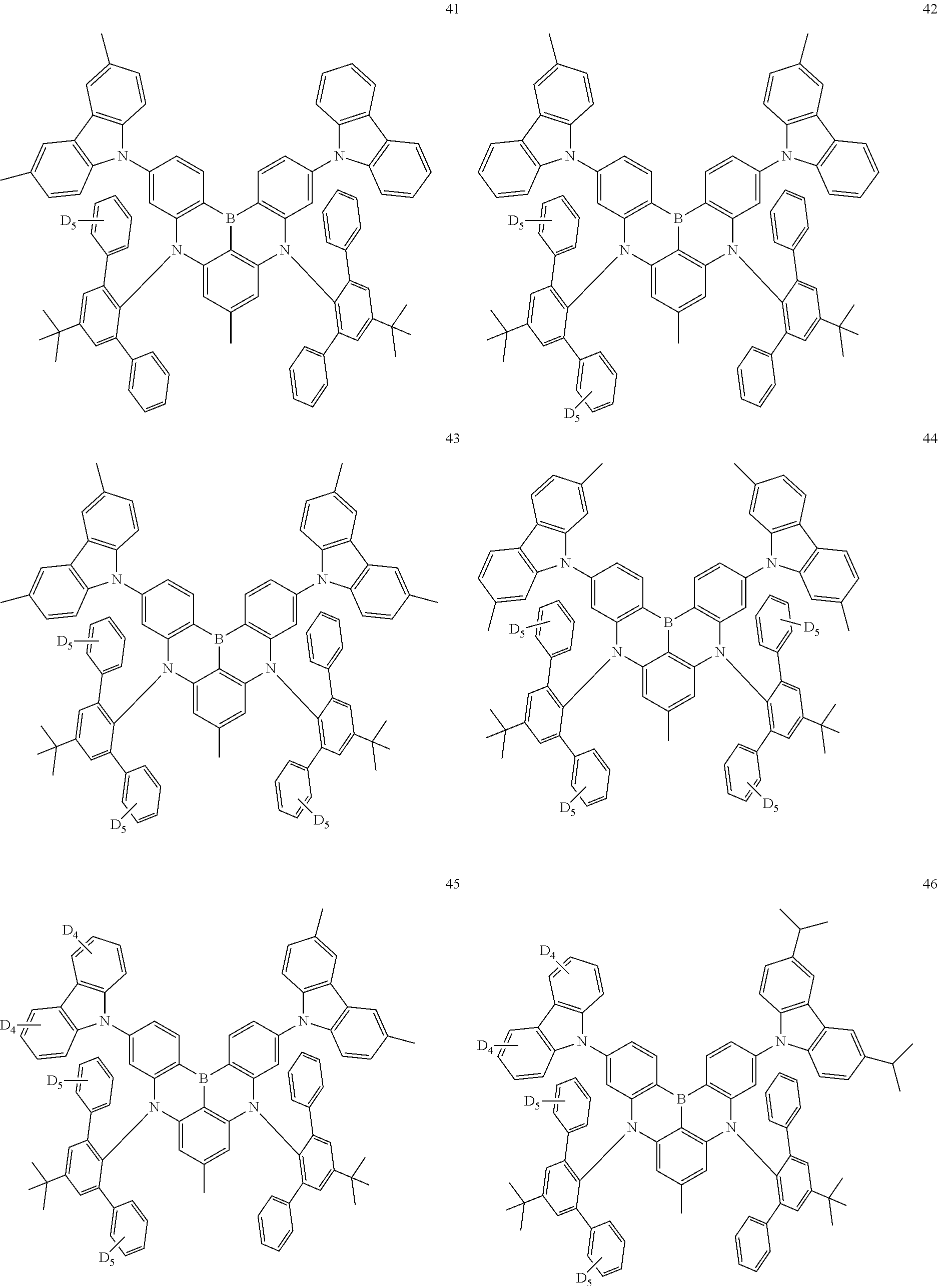 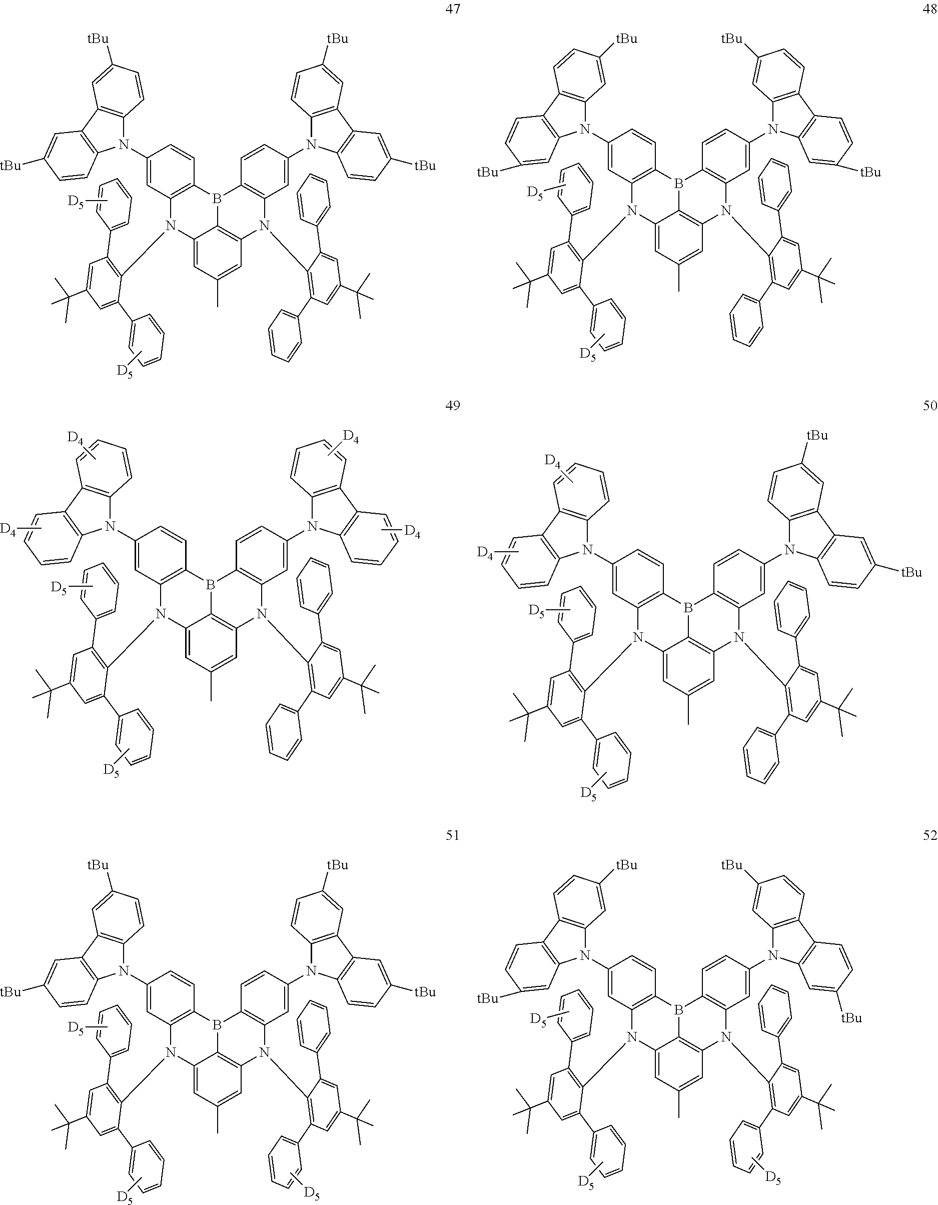 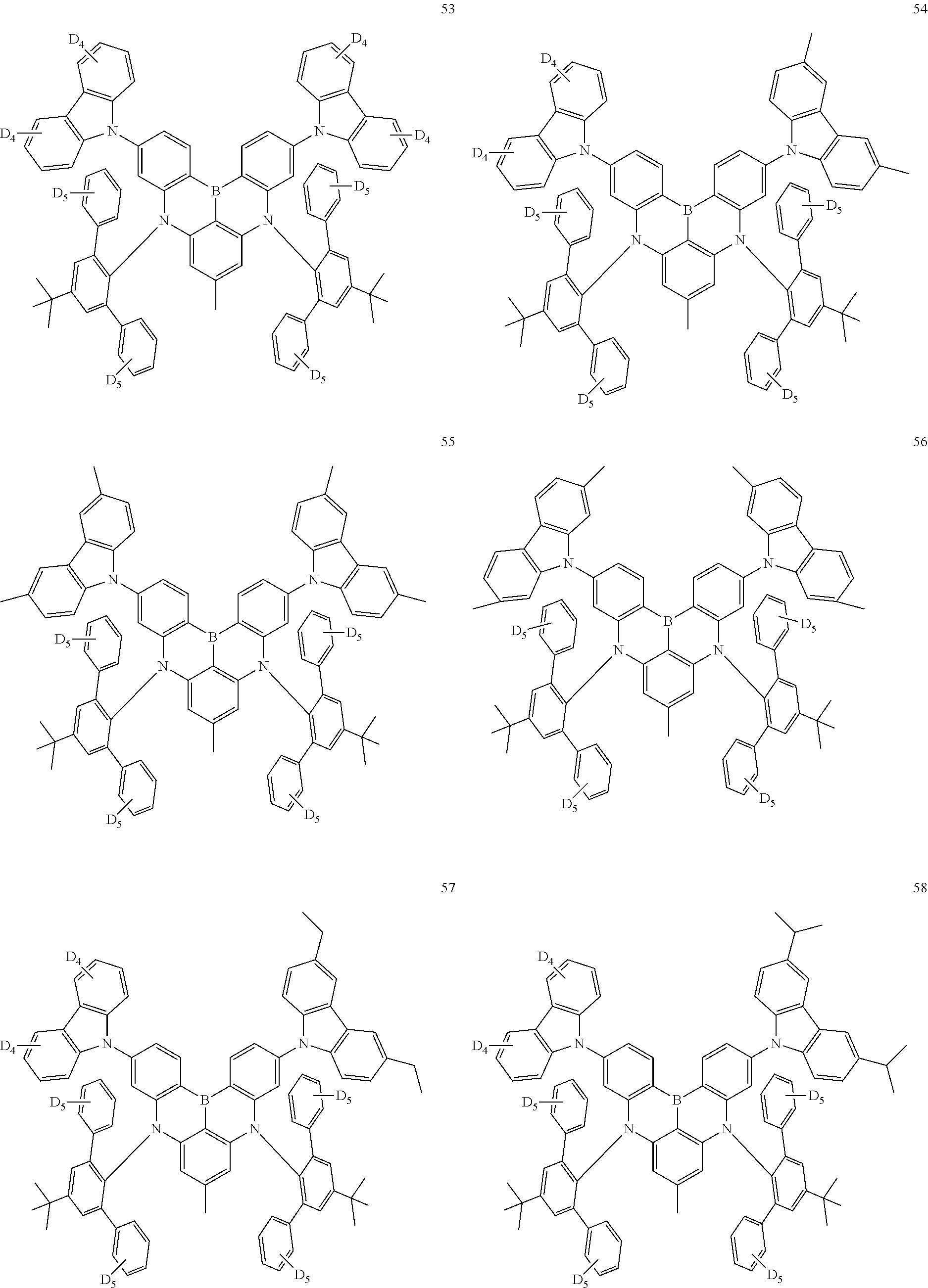 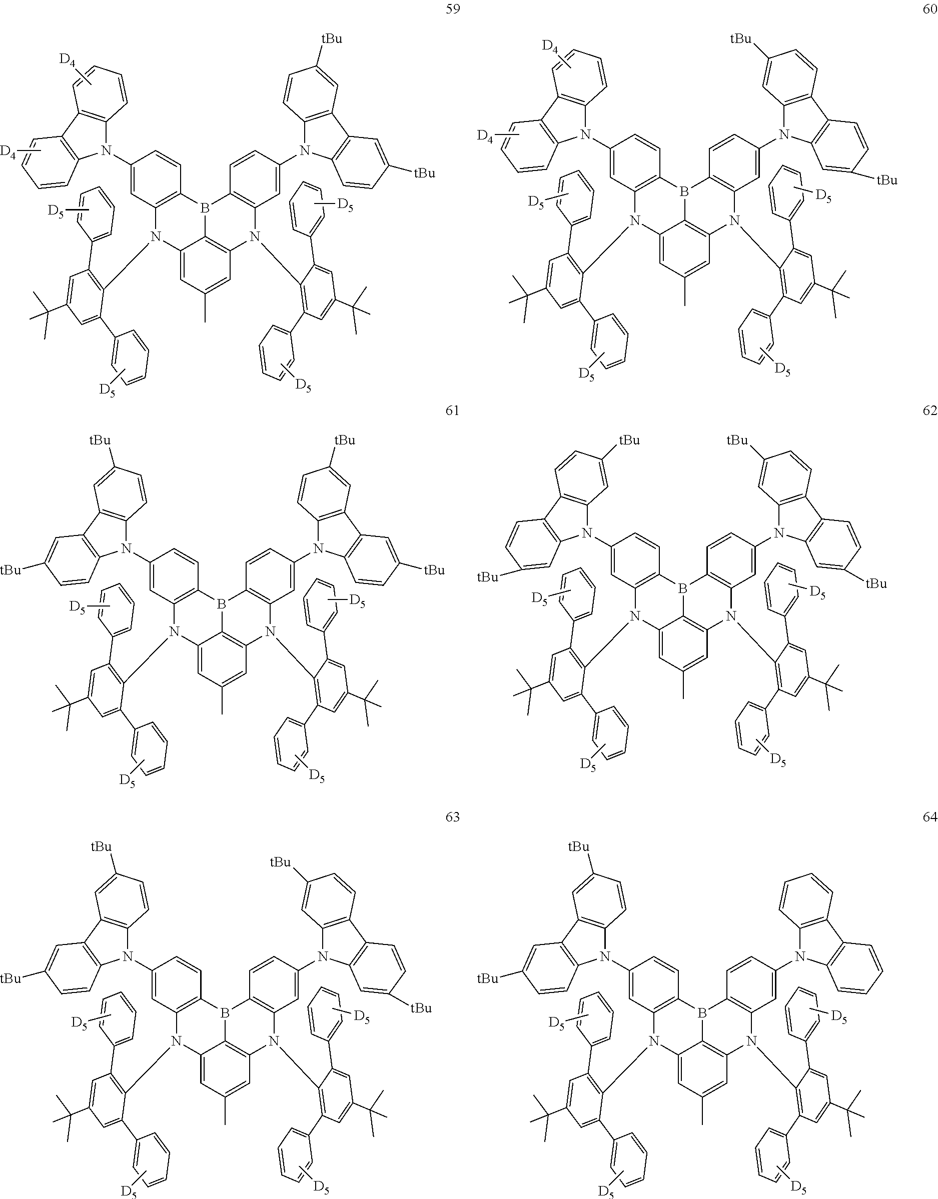 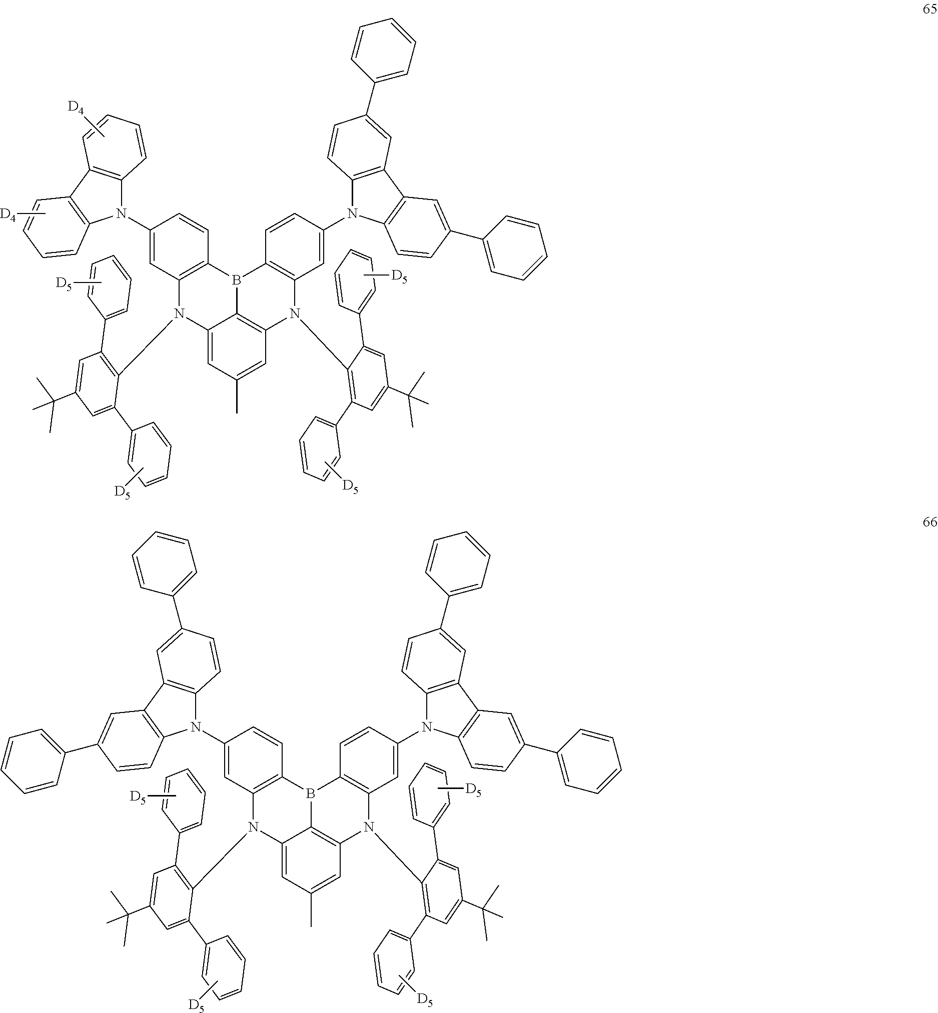 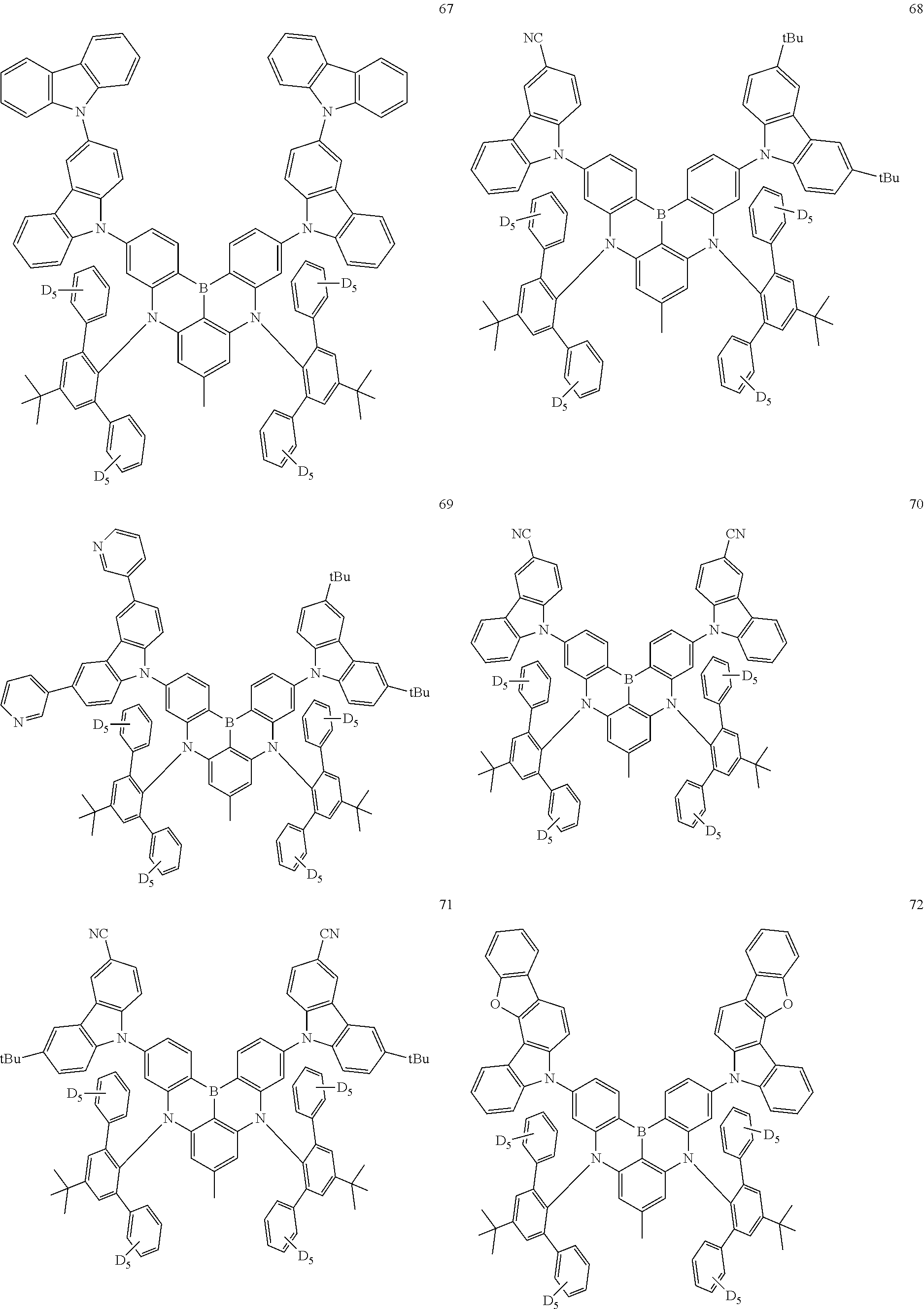 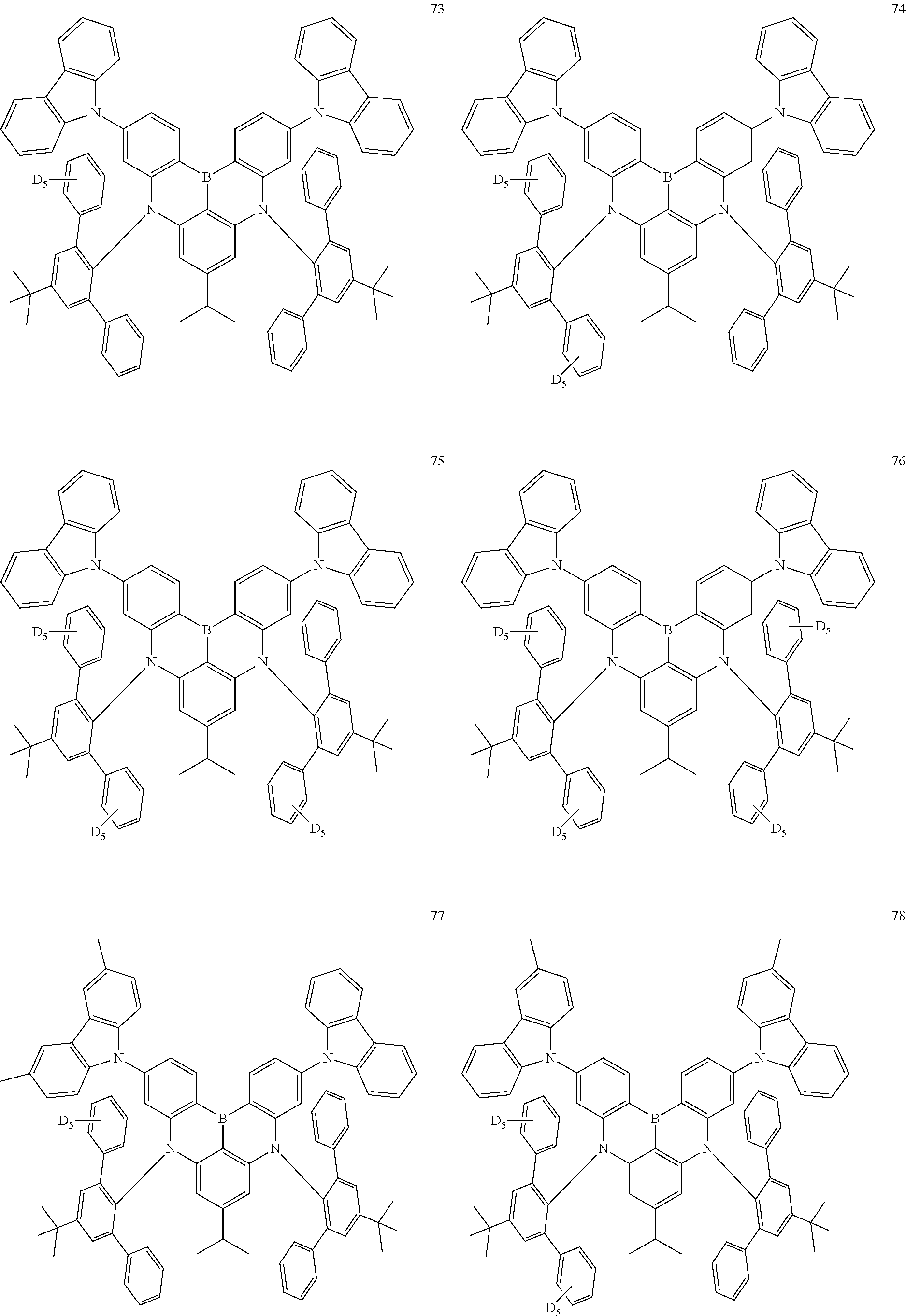 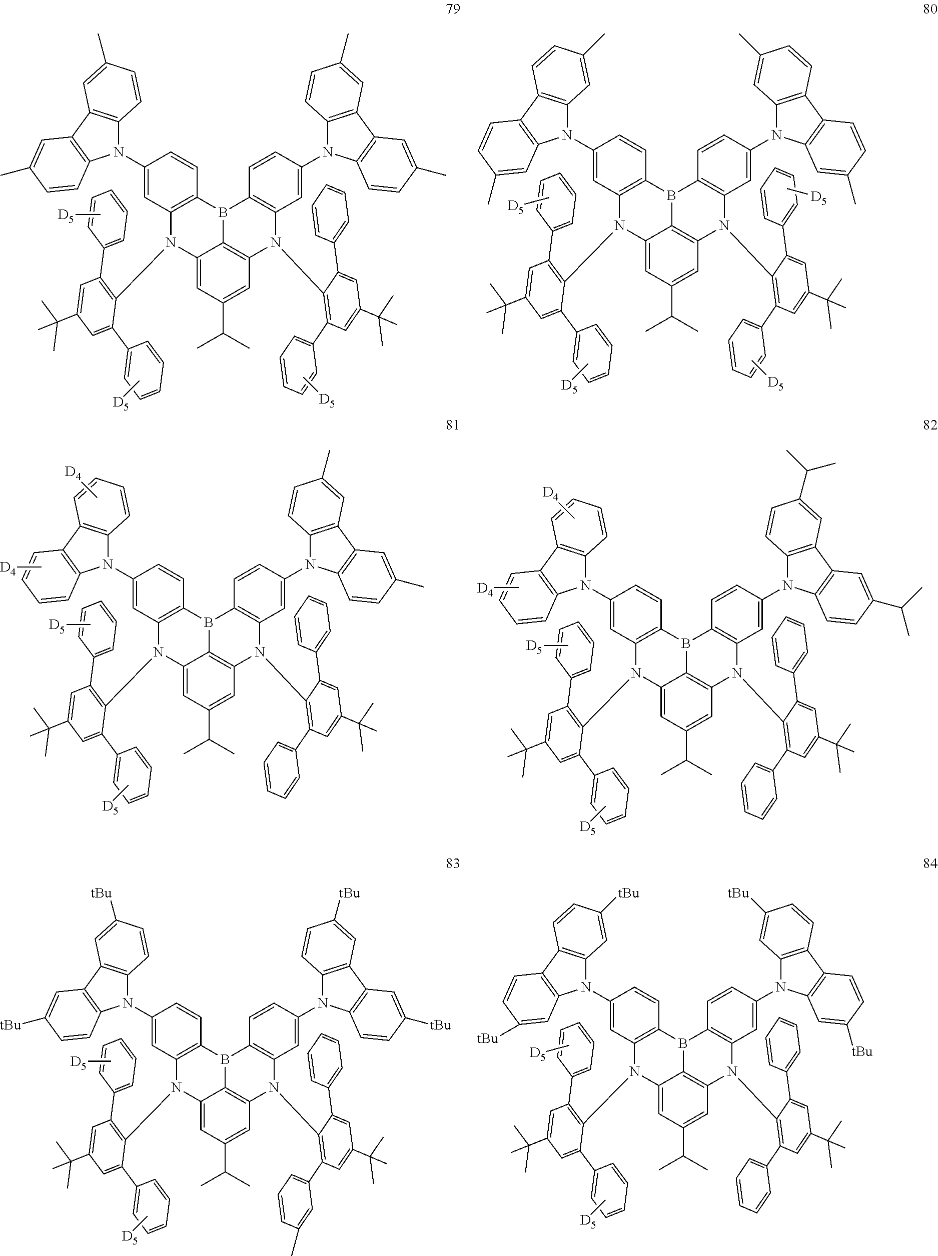 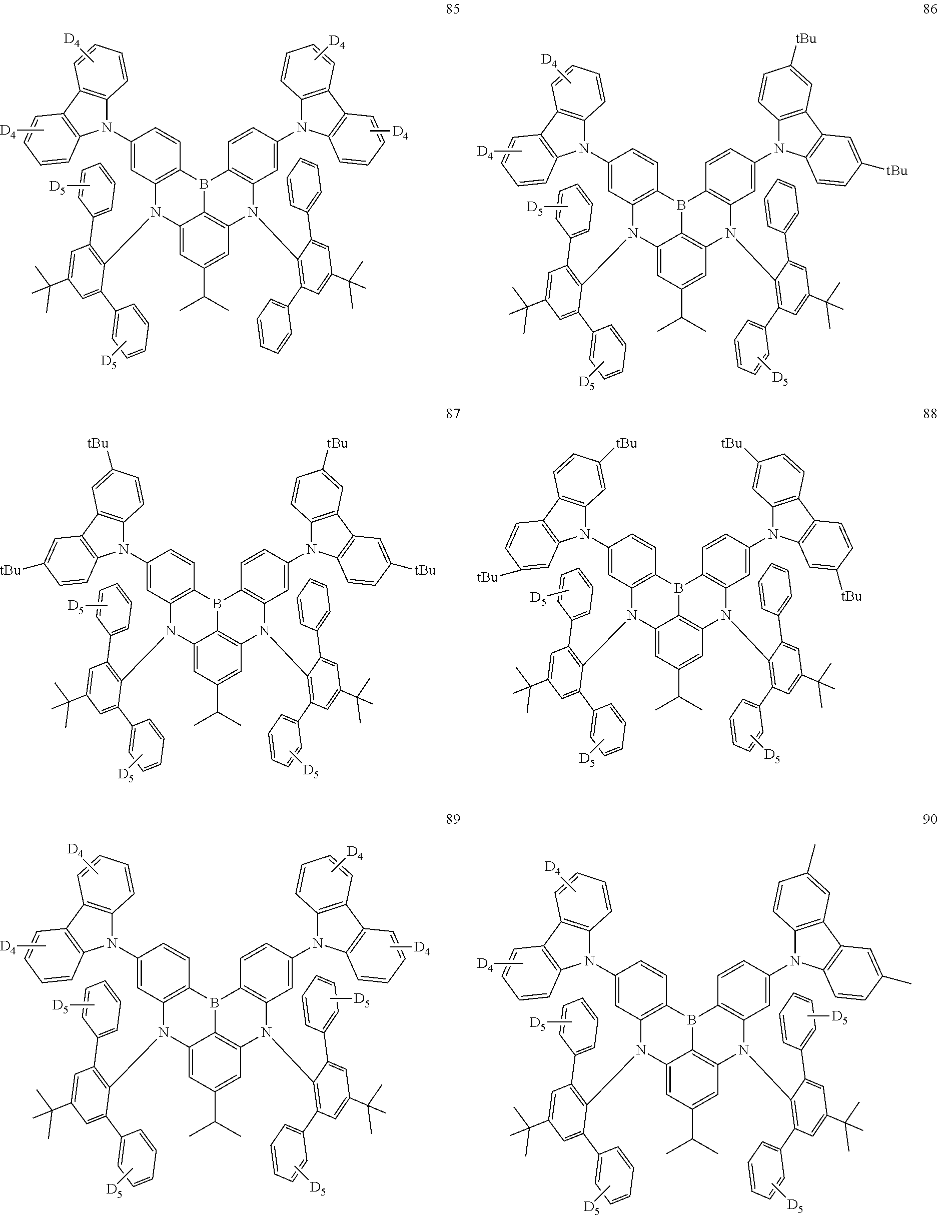 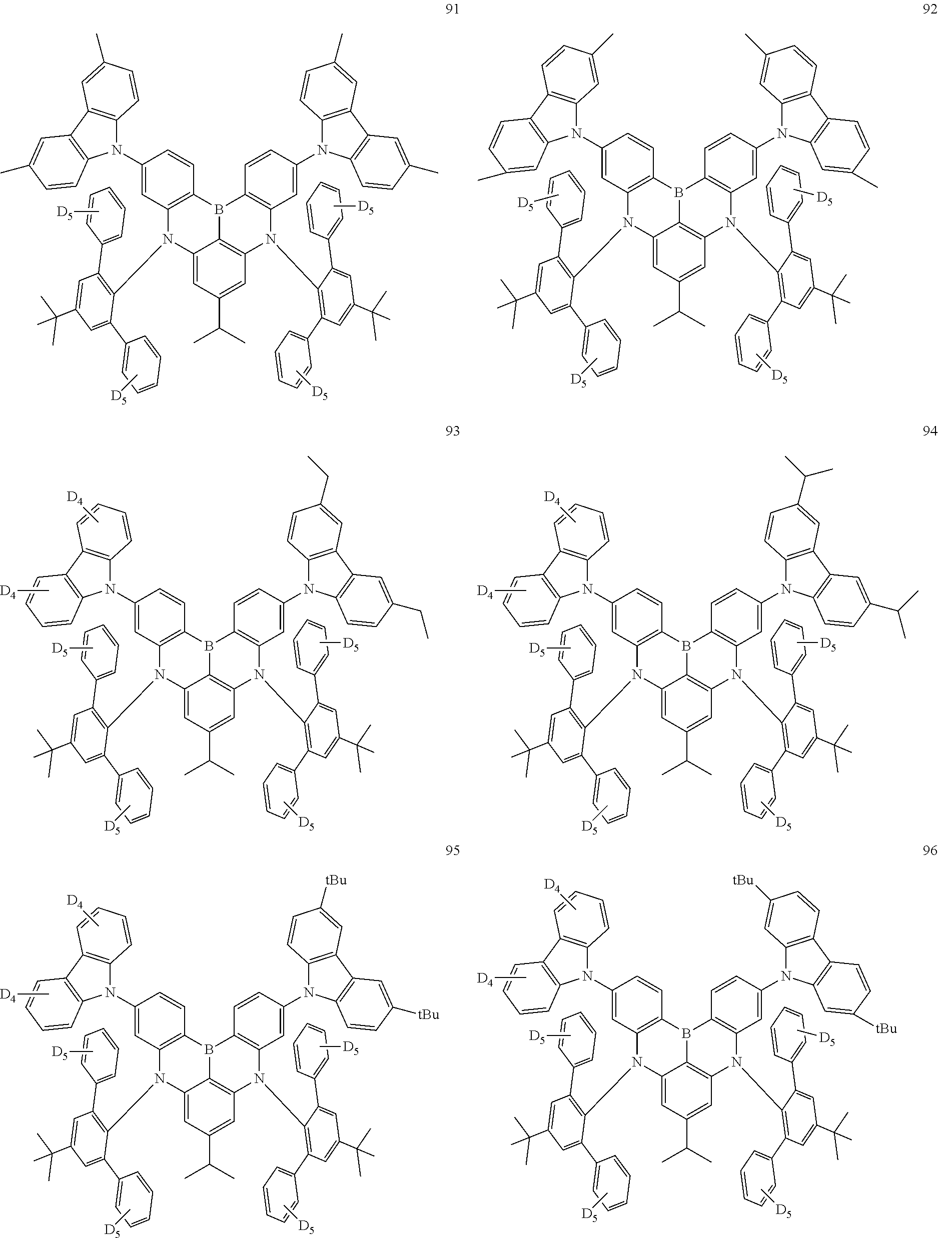 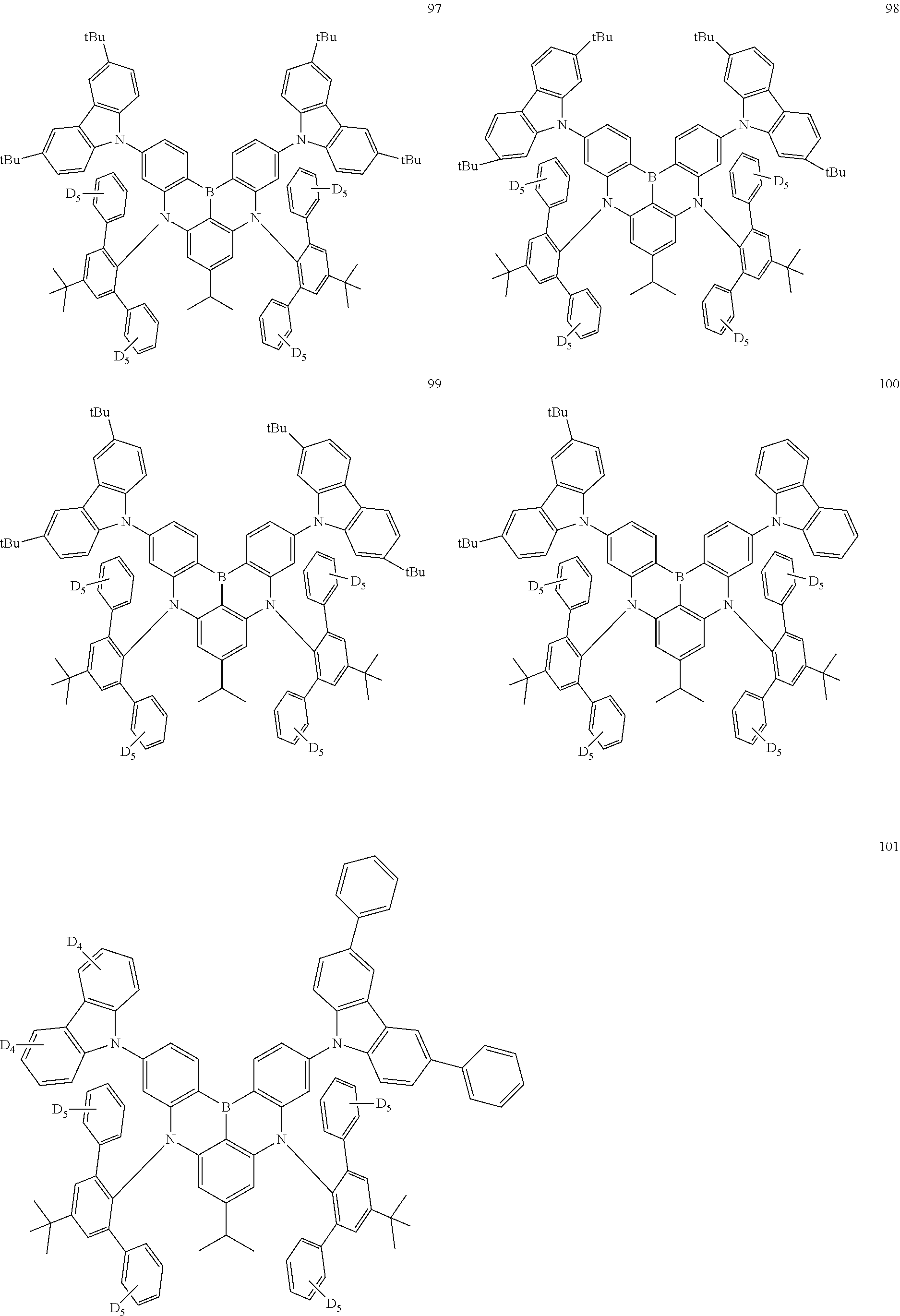 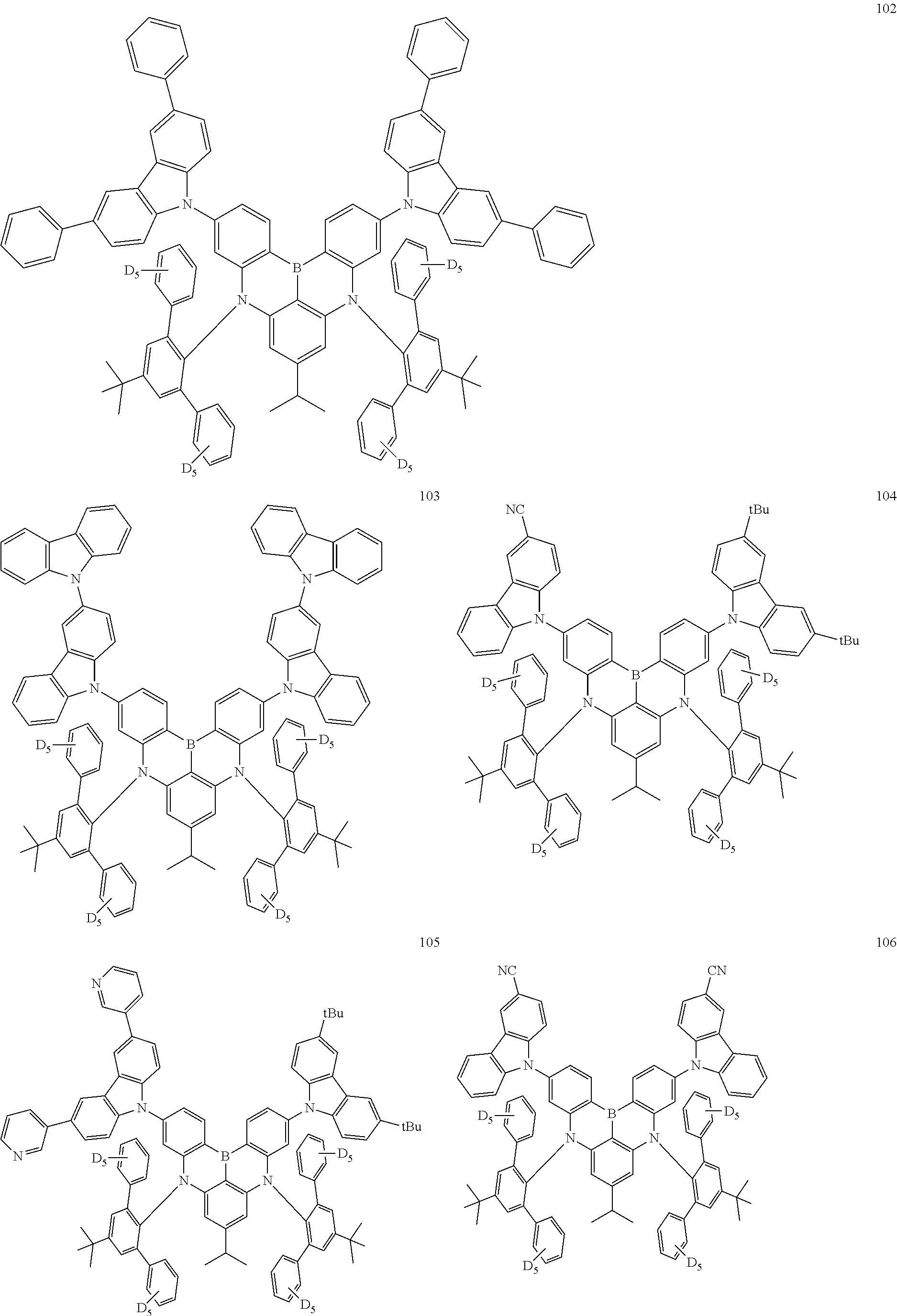 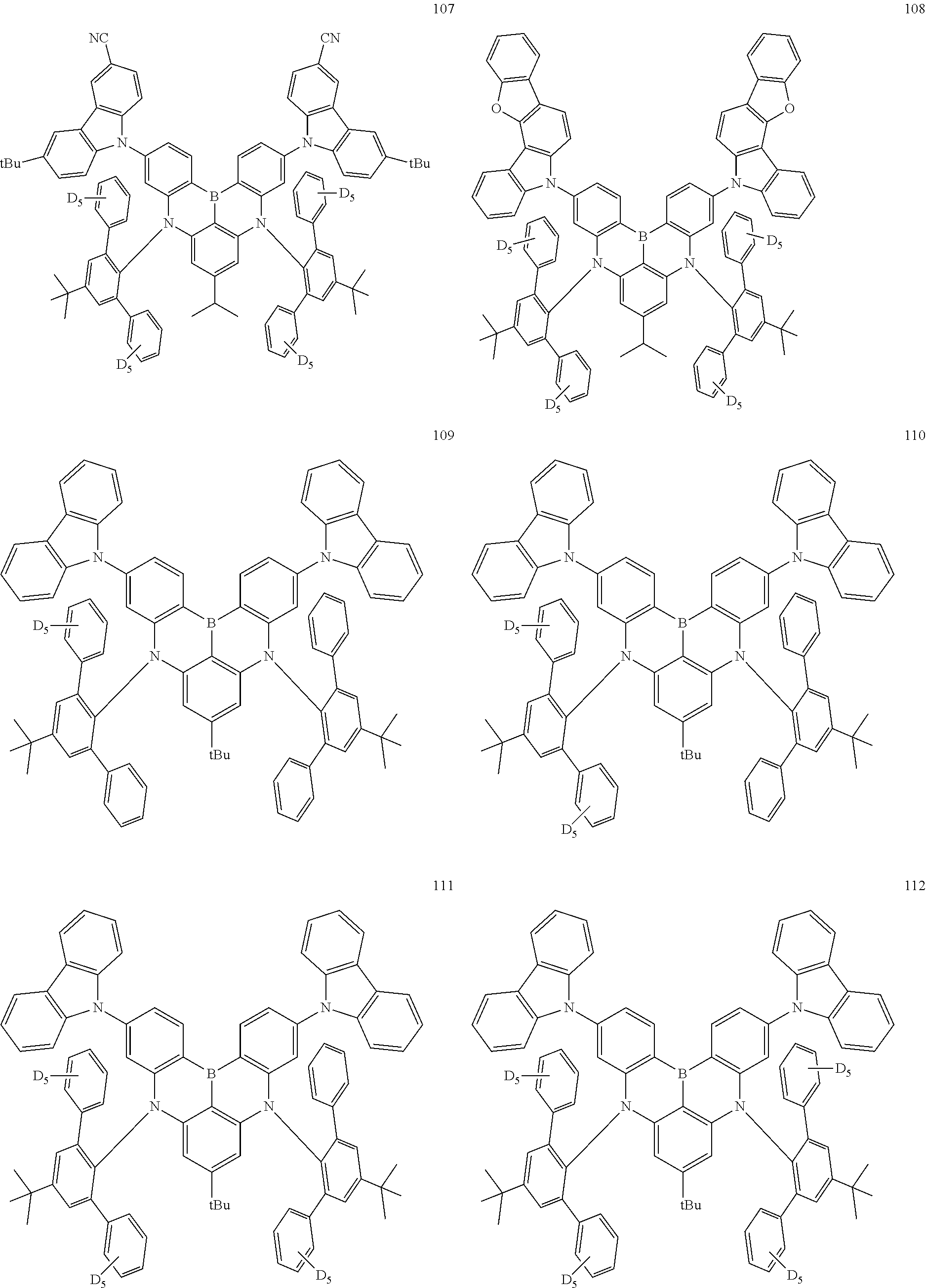 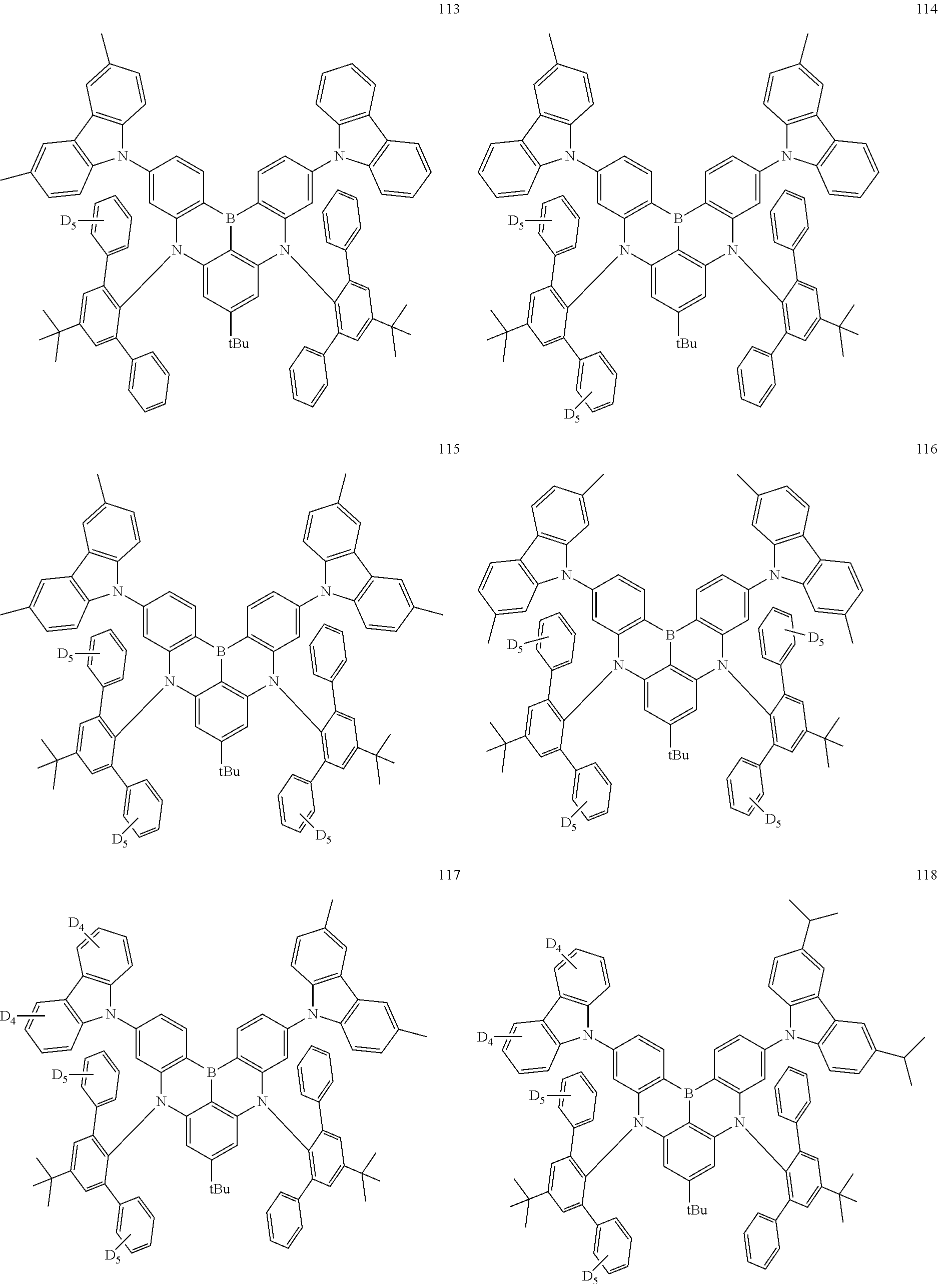 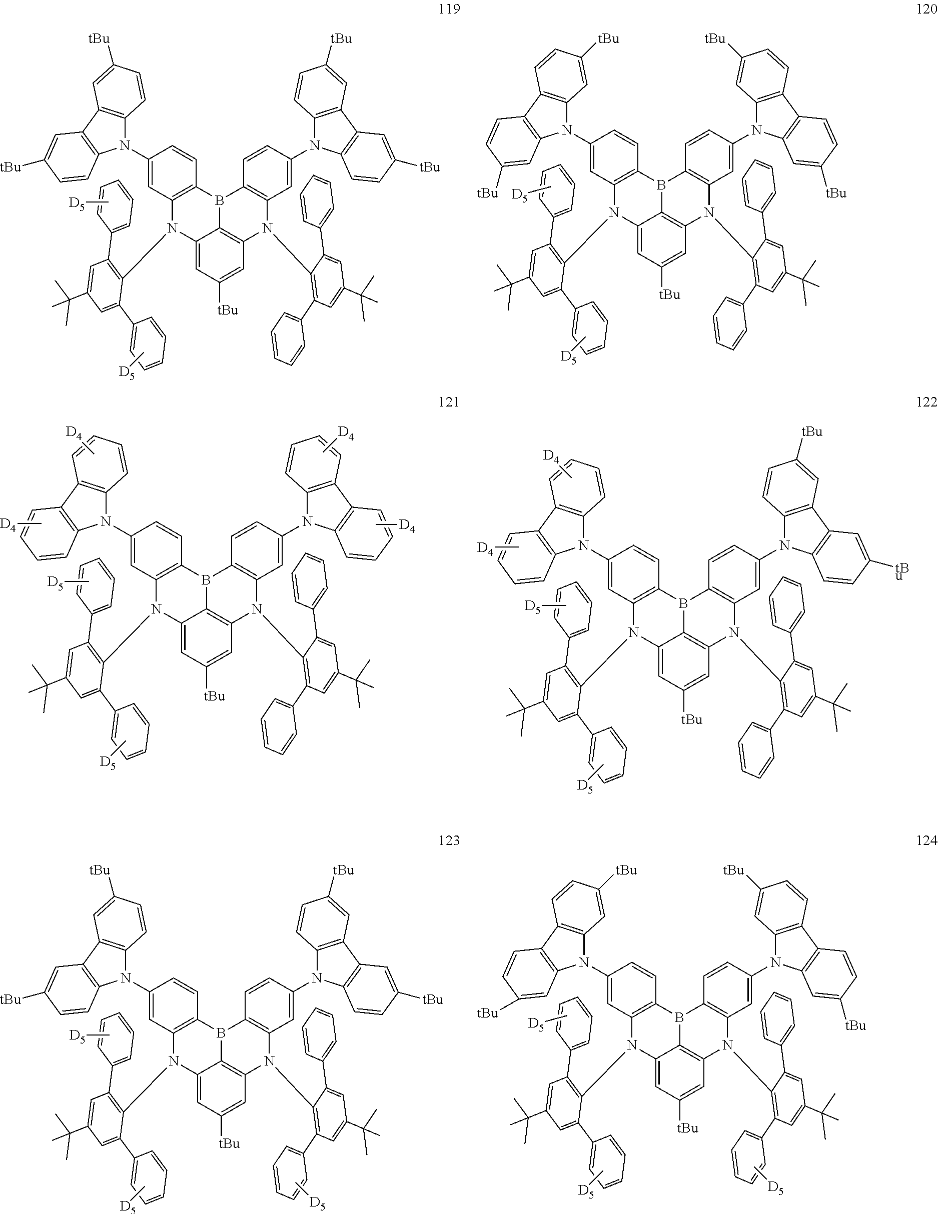 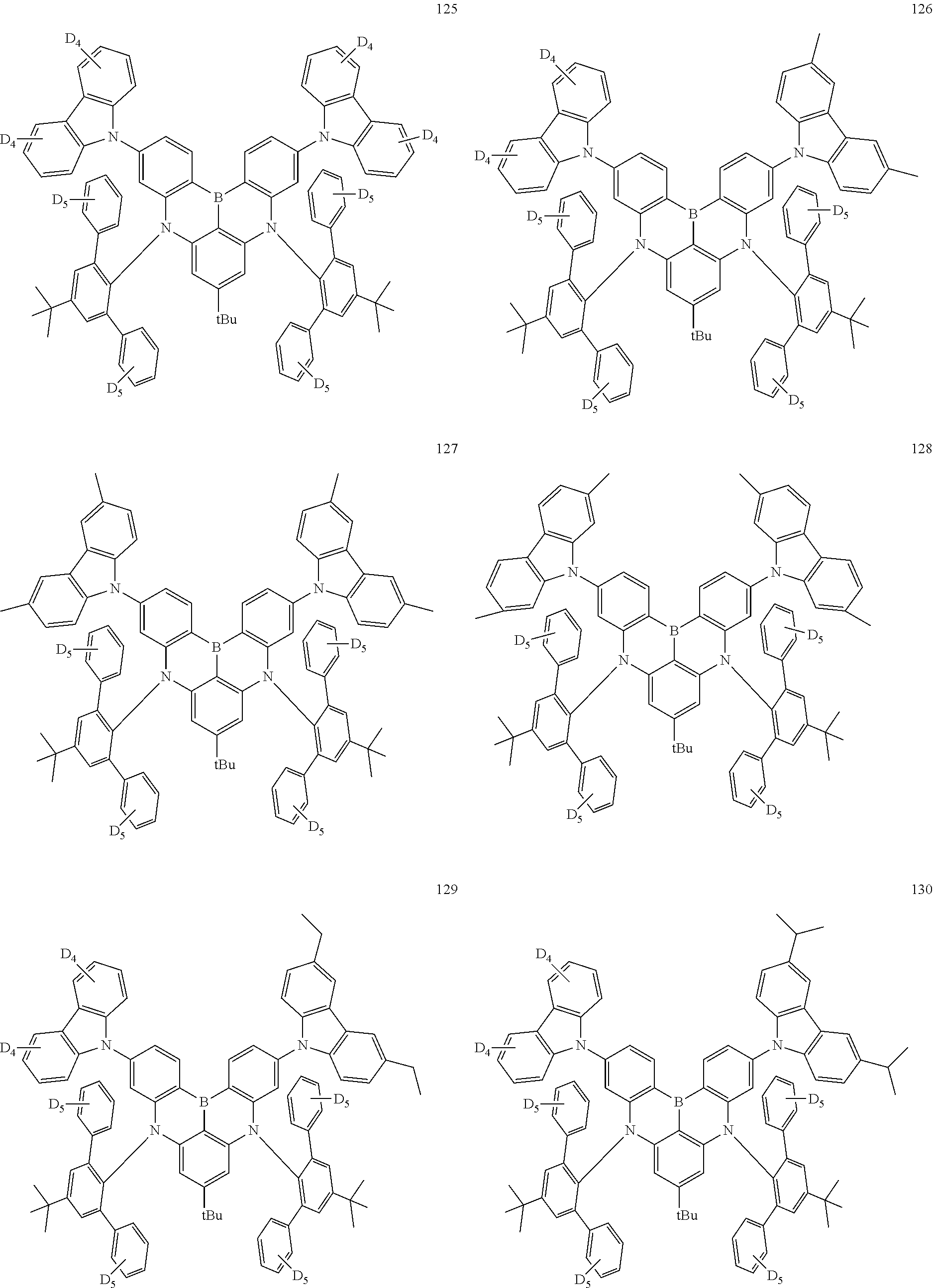 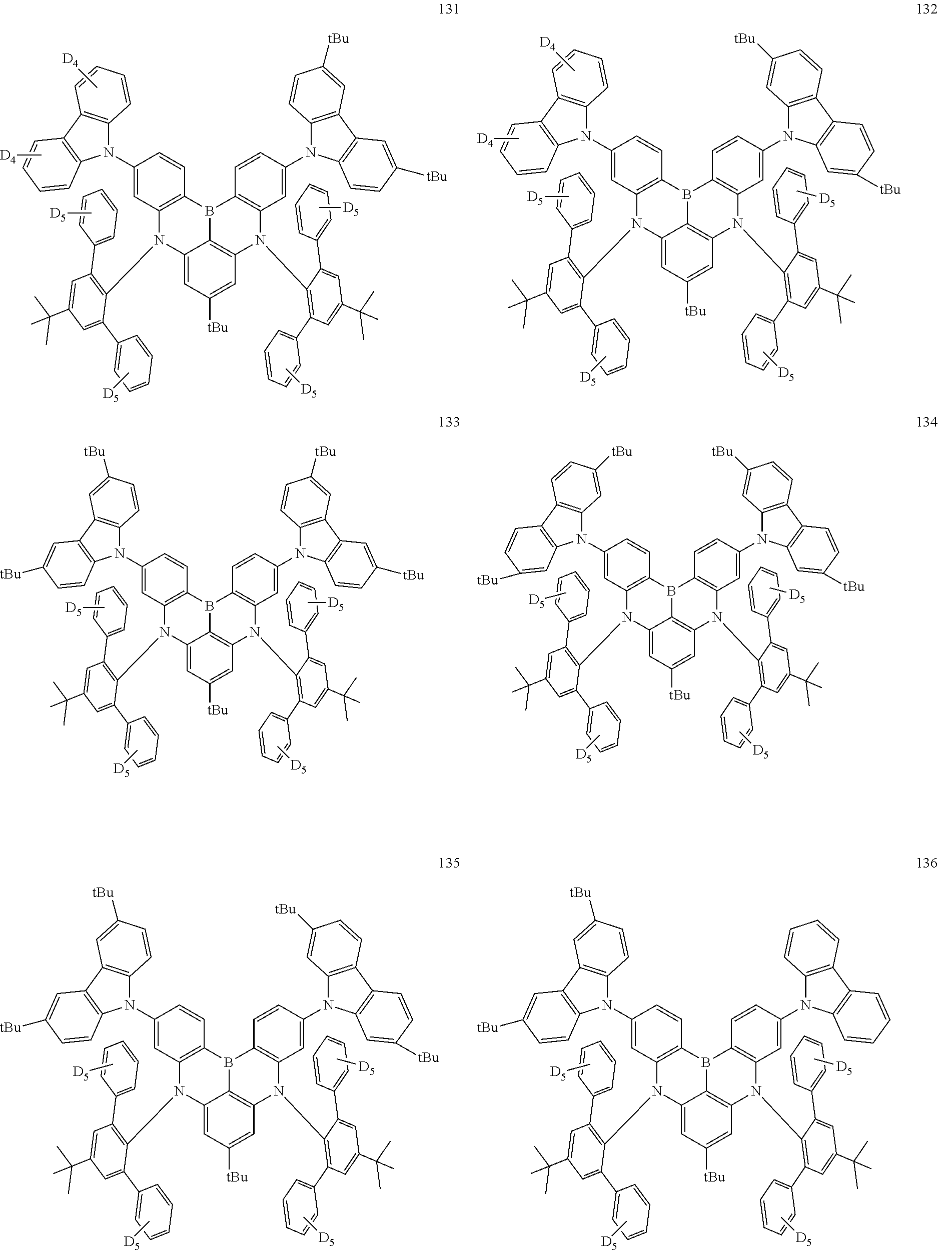 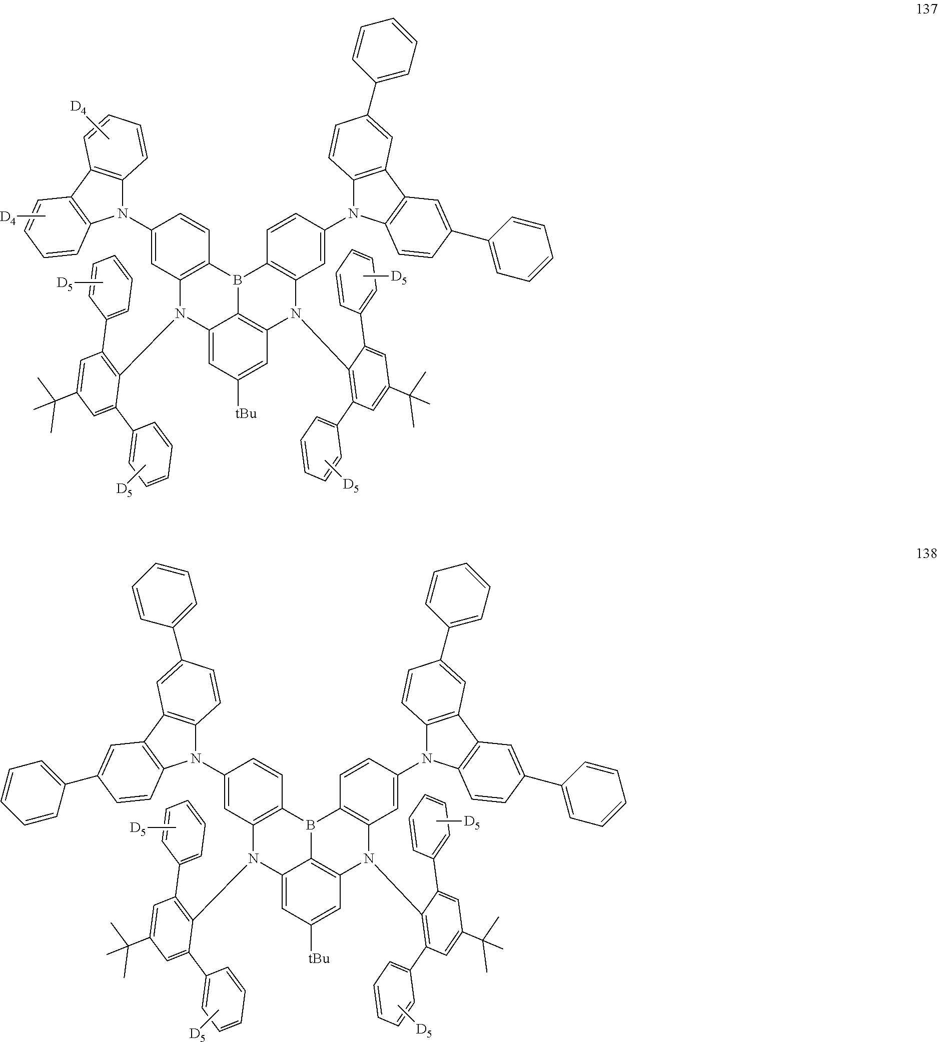 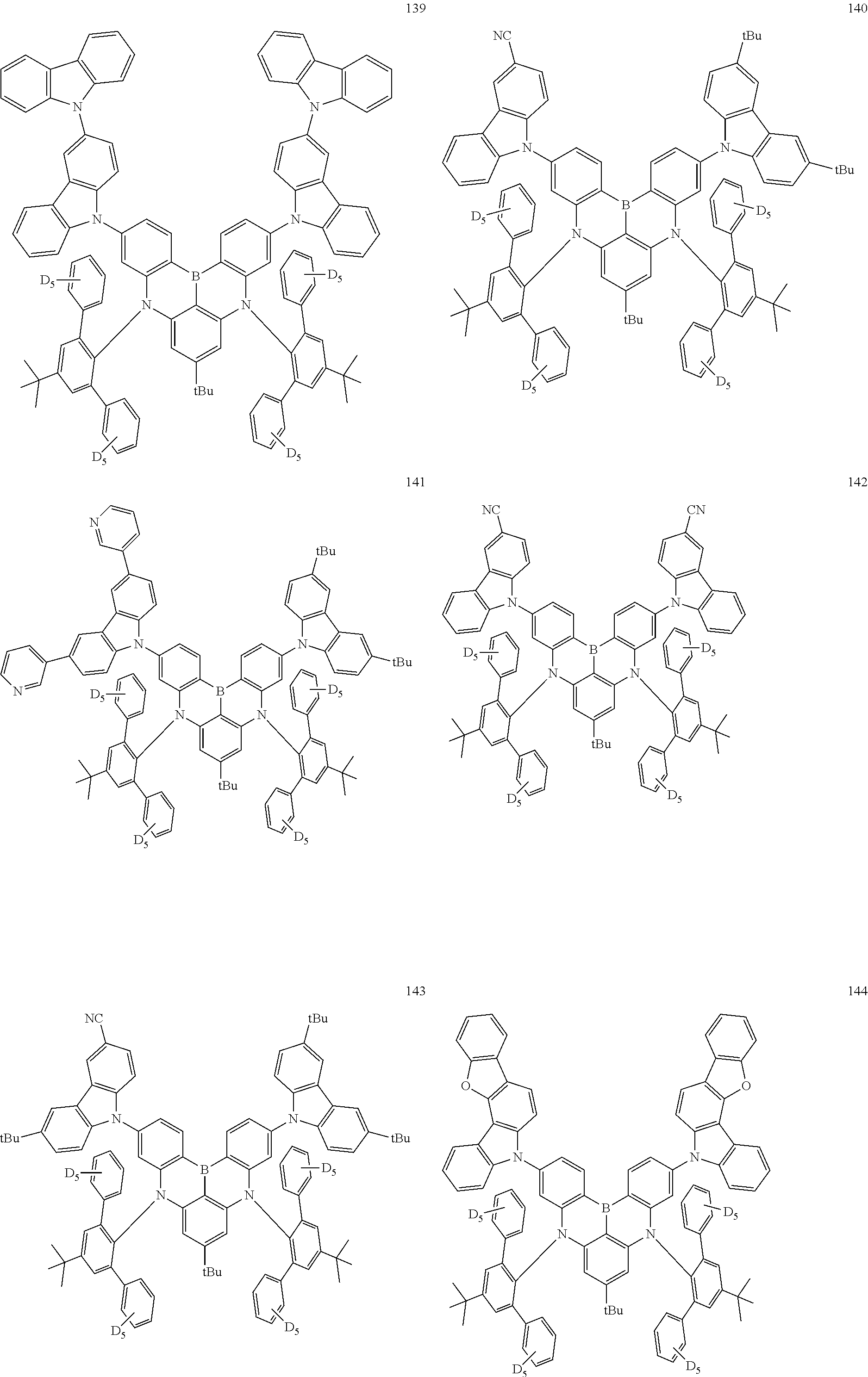 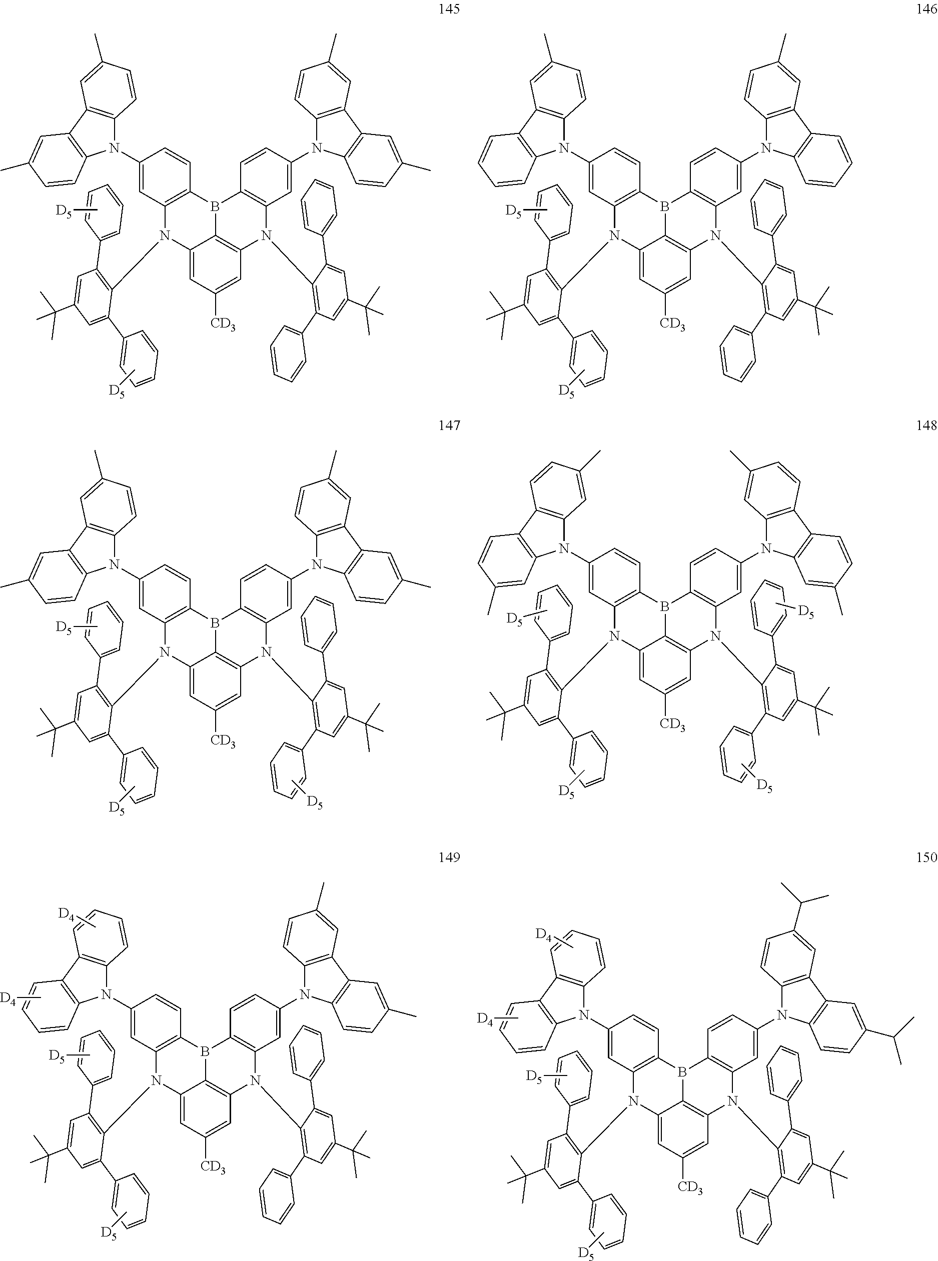 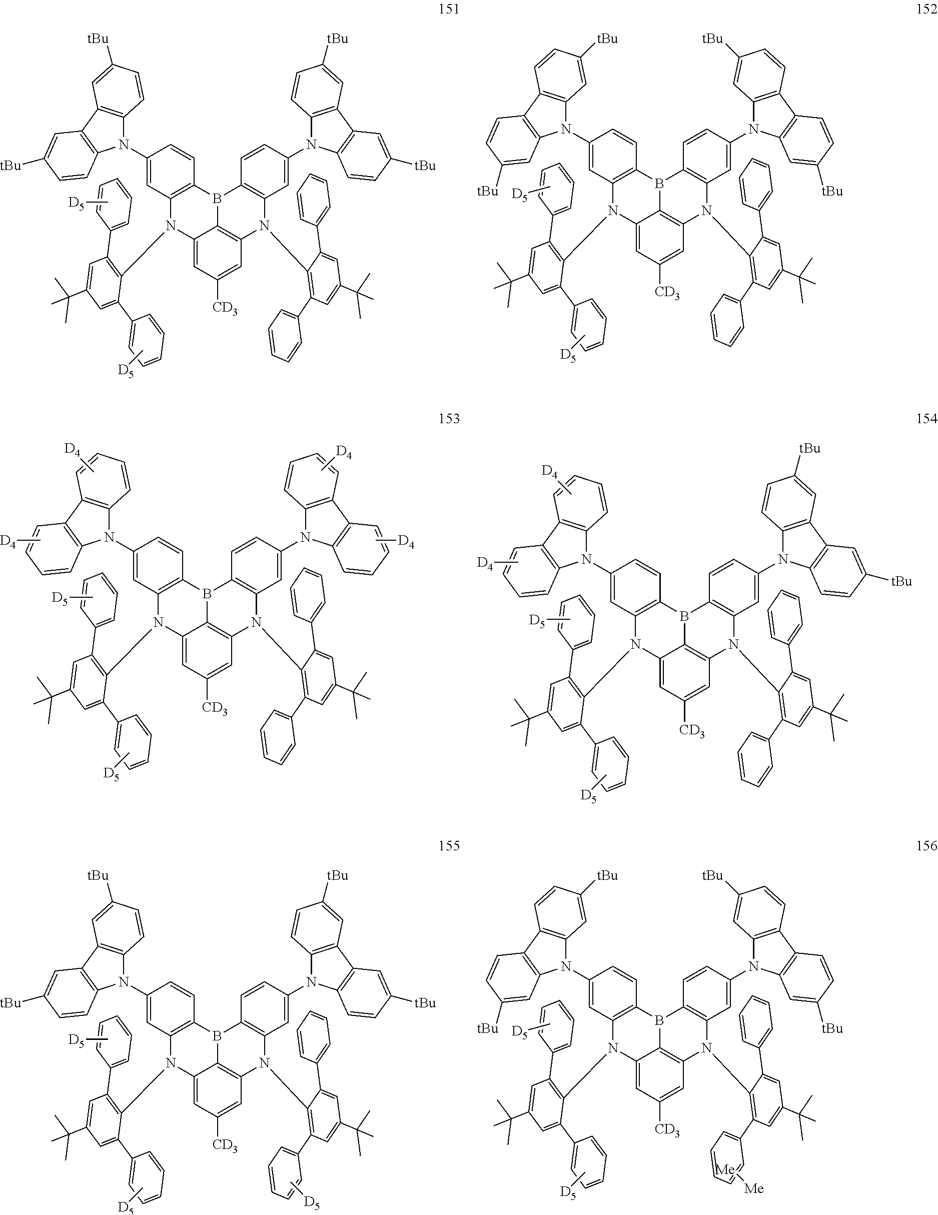 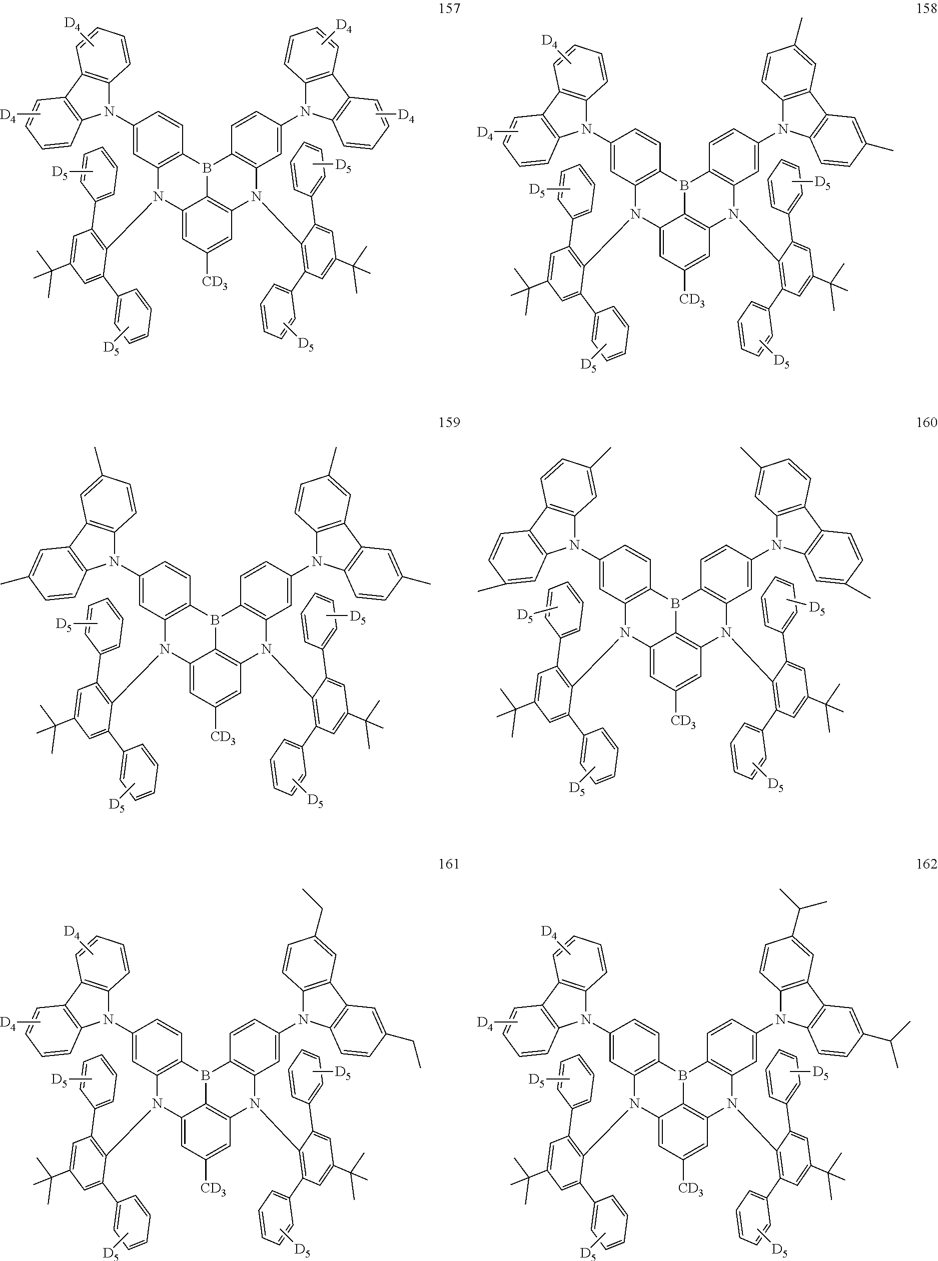 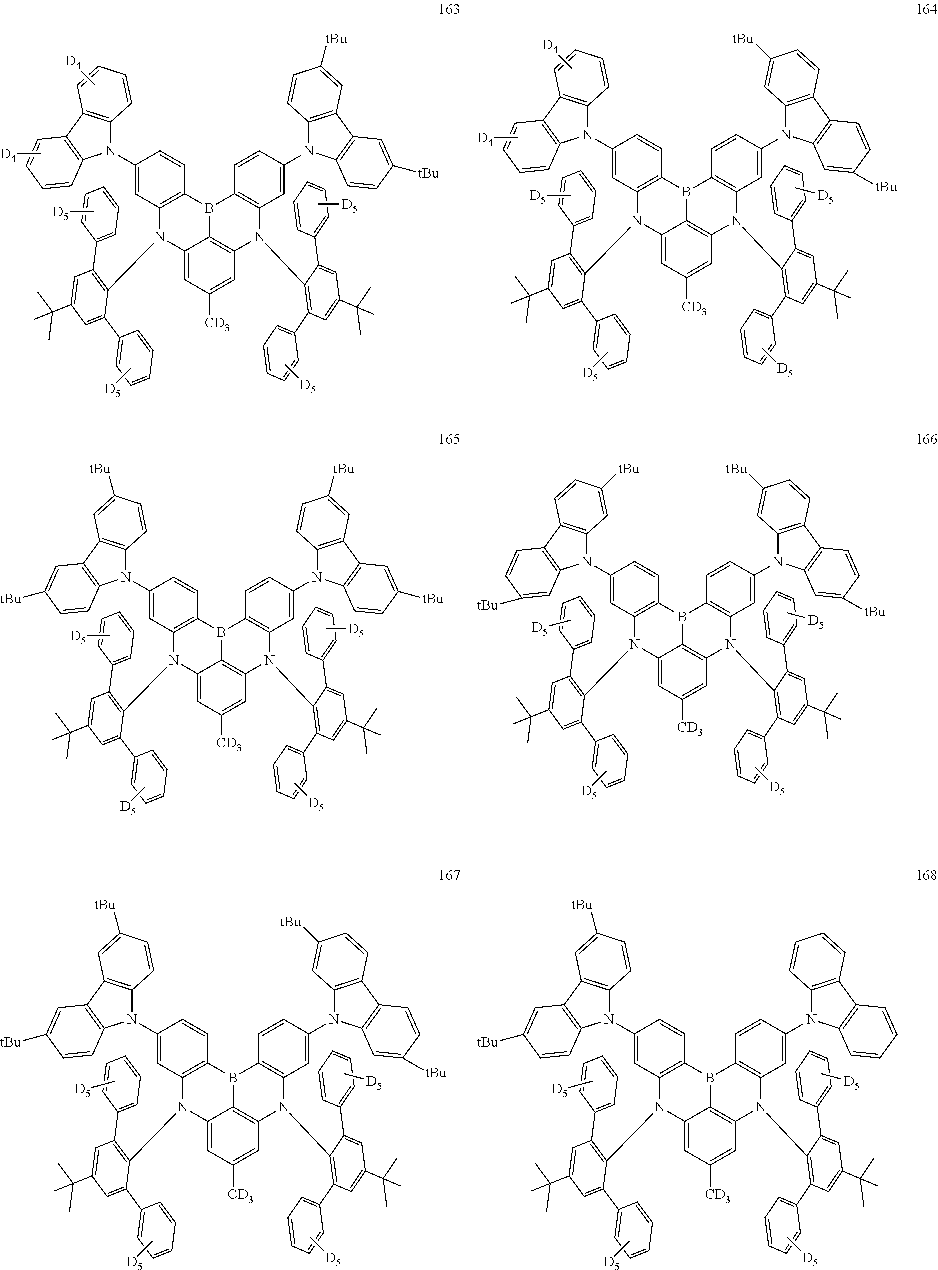 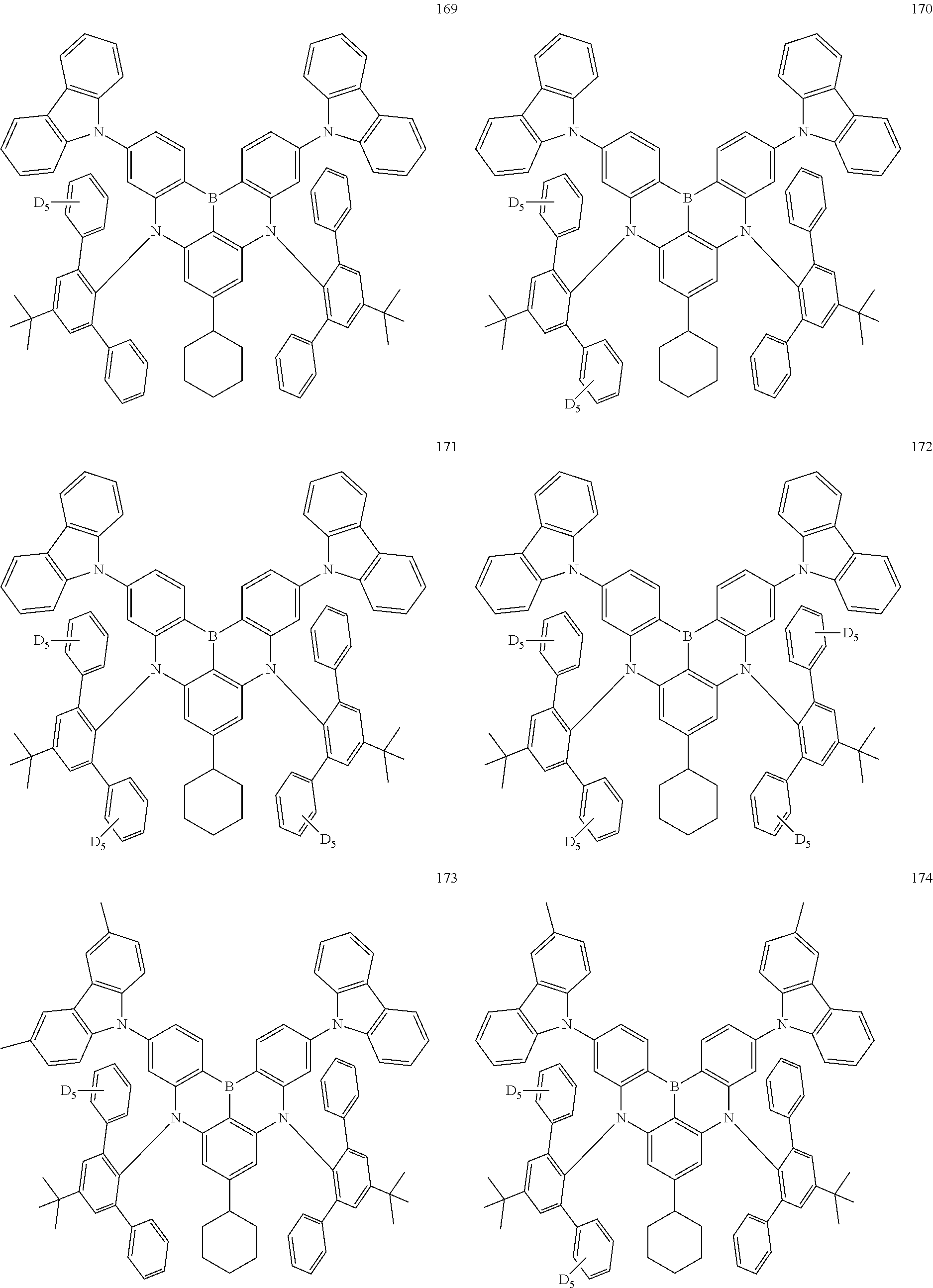 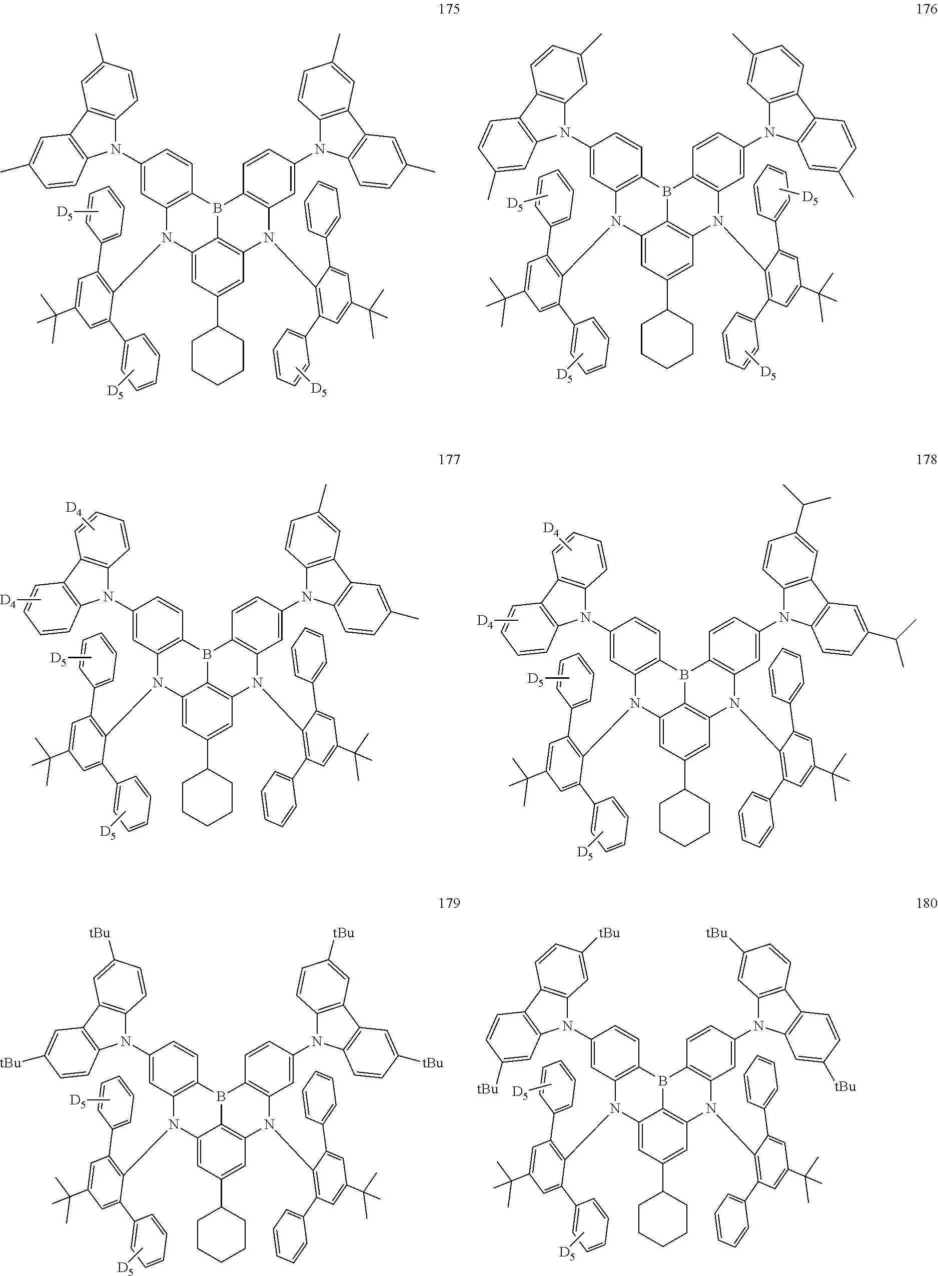 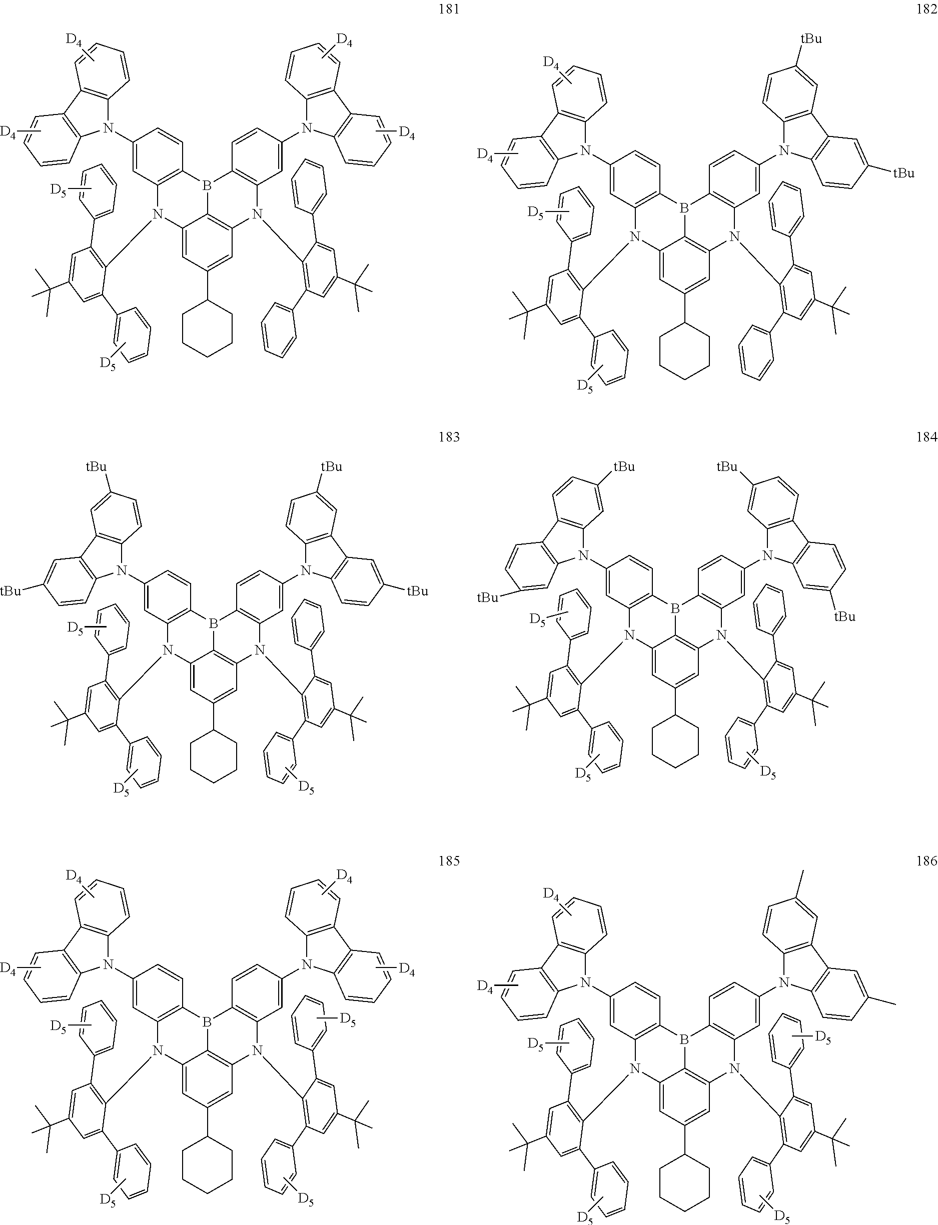 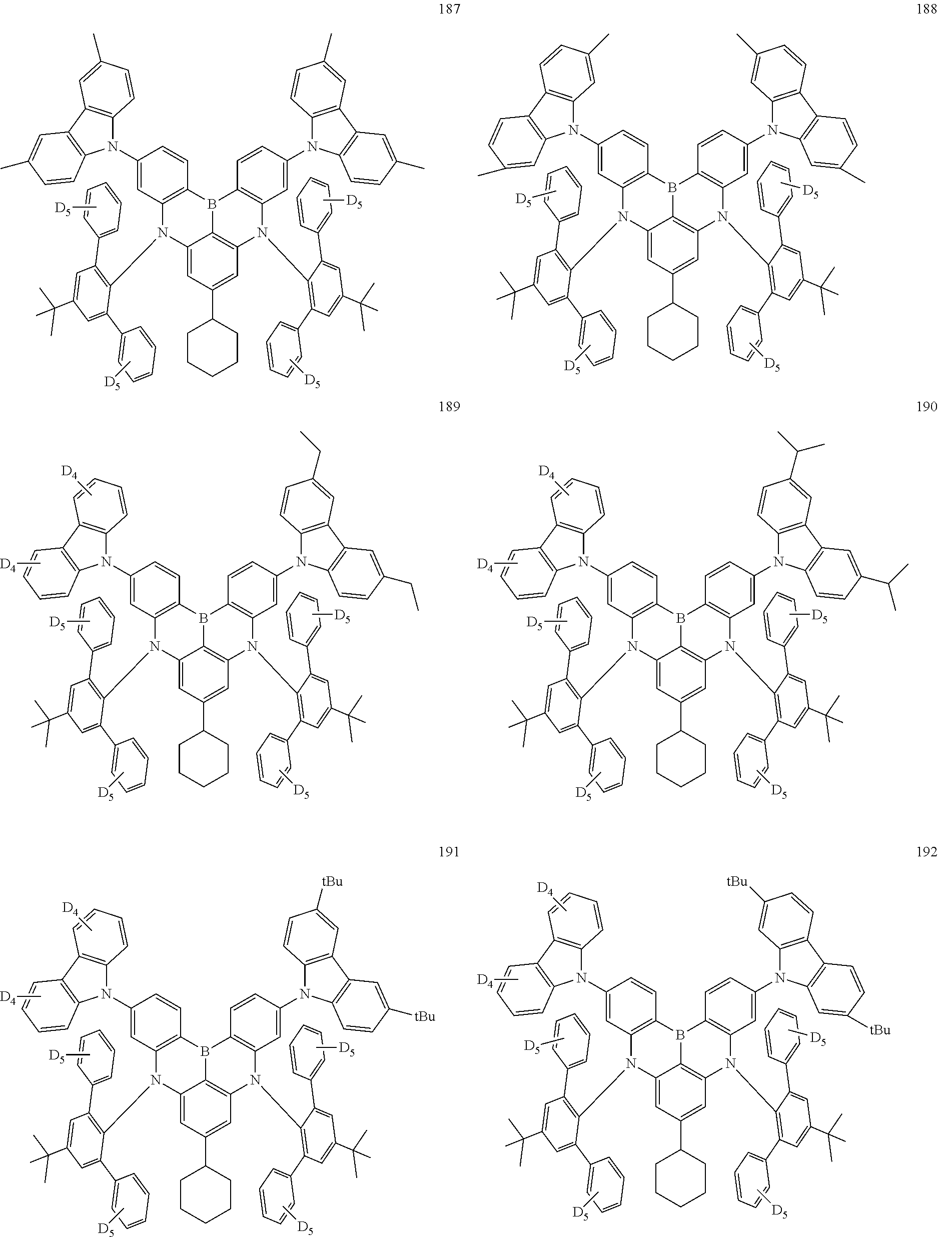 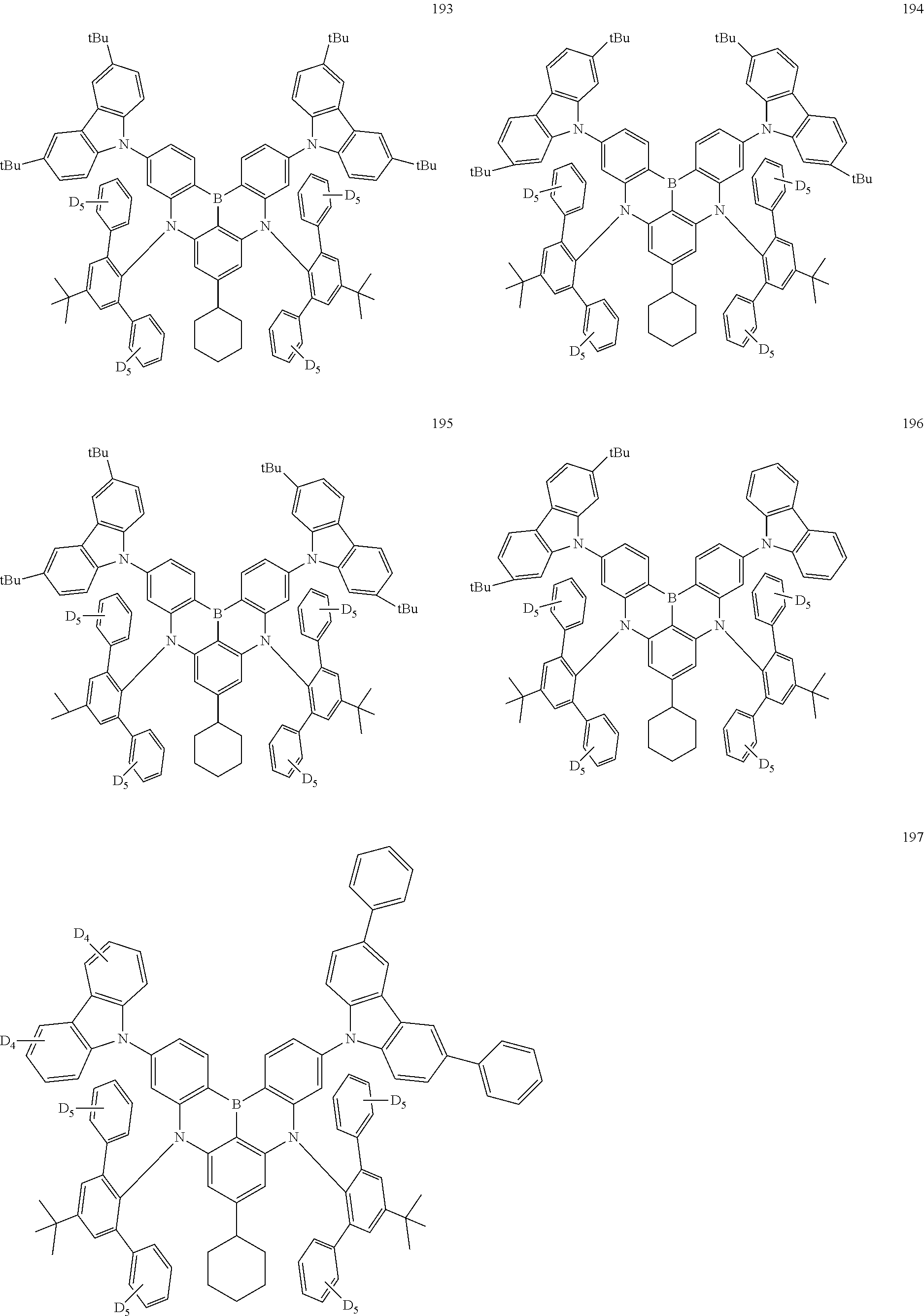 [chemical structure]
